(19) United States
(12) Patent Application Publication
(10) Pub. No.: US 2024/0140968 A1
(43) Pub. Date: May 2, 2024

(54) ORGANIC COMPOUND, LIGHT-EMITTING COMPONENT, AND DISPLAY PANEL

(71) Applicant: Shenzhen China Star Optoelectronics Semiconductor Display Technology Co., Ltd., Shenzhen (CN)

(72) Inventors: Ruifeng HE, Shenzhen (CN); Canjie WU, Shenzhen (CN); Yan LI, Shenzhen (CN); Jingyao SONG, Shenzhen (CN)

(21) Appl. No.: 17/988,118

(22) Filed: Nov. 16, 2022

(30) Foreign Application Priority Data
Sep. 30, 2022 (CN) 202211231782.0

(51) Int. Cl. C07F 5/02; H01L 51/00; H01L 51/50

(52) U.S. Cl. CPC C07F 5/027; H01L 51/008; H01L 51/50

(57) ABSTRACT

An organic compound, a light-emitting component, and a display panel are disclosed. The organic compound has a structure shown as general formula (1):

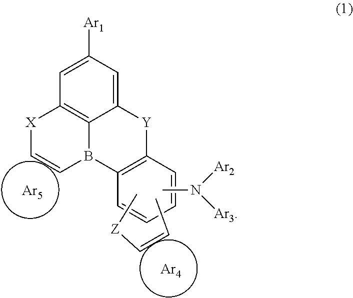

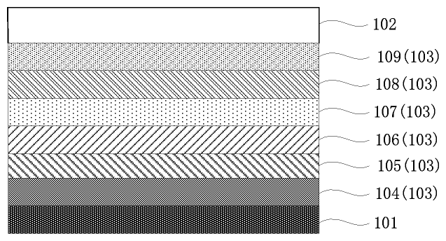

This organic compound can enhance conjugated effect and resonance effect of materials applied into the light-emitting component by having a heterocyclic group and an amino group at a same time. Therefore, material performances can be improved, a luminous efficiency of the light-emitting component can be improved, and a light-emitting service life of the light-emitting component can be extended.

### FIELD OF INVENTION

The present disclosure relates to the field of display technologies, and more particularly, to an organic compound, a light-emitting component, and a display panel.

### BACKGROUND OF INVENTION

At present, organic electroluminescent components usually have a positive electrode, a negative electrode, and an organic layer between the electrodes. Electrical energy is converted into light energy by organic materials of the organic layer, thereby realizing organic electroluminescence. In order to improve the luminous efficiency and service life of the organic electroluminescent components, the organic layer is often multi-layered, and organic matter of each layer is different. Specifically, the organic layer mainly includes a hole injection layer, a hole transport layer, a light-emitting layer, an electron transport layer, and an electron injection layer. When a voltage is applied between the positive electrode and the negative electrode of the organic electroluminescent components, the positive electrode injects holes into the organic layer, and the negative electrode injects electrons into the organic layer. The injected holes and electrons meet to form excitons, which emit light when they transition back to the ground state, thereby realizing luminescence of the organic electroluminescent components. Organic electroluminescent devices have characteristics of self-luminescence, high brightness, high efficiency, low driving voltage, wide viewing angles, high contrasts, and high response times. Therefore, the organic electroluminescent devices have broad application prospects.

Correspondingly, material development of organic light-emitting diodes (OLEDs) has also received extensive attention due to a series of advantages such as diversity in synthesis, simple composition, and simple process. Meanwhile, in order to improve the luminous efficiency of the organic electroluminescent components, attempts have been made for material systems with various energy transmission and conversion mechanisms. However, the luminous efficiency, stability, and lifespan of light-emitting materials used in OLED components (especially the light-emitting materials of blue light-emitting OLED components) are still low, resulting in limited performance improvement of the OLED components.

Therefore, it is necessary to provide an organic compound, a light-emitting component, and a display panel to solve the above technical problems.

### SUMMARY OF INVENTION

The present disclosure provides an organic compound, a light-emitting component, and a display panel, which can solve the technical problems of limited performance improvement of OLED components caused by low luminous efficiency, stability, and lifespan of light-emitting materials used in the OLED components.

The present disclosure provides an organic compound, which has a structure shown as general formula (1):

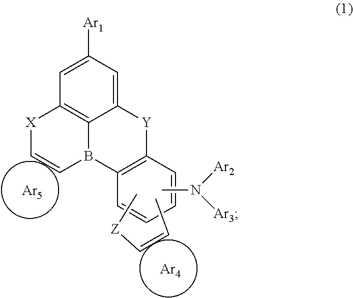

wherein, Z is selected from CR₁R₂, NR₃, O, or S;

X and Y are each independently selected from O or NR₄;

R₁ to R₄ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms;

R₁ and R₂ are connected in a ring or independent of each other;

Ar₁ is selected from H, D, a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms;

Ar₂ and Ar₃ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms; and

Ar₄ and Ar₅ are each independently selected from a substituted or unsubstituted aromatic group with 6 to 30 carbon atoms or a substituted or unsubstituted heteroaromatic group with 5 to 30 carbon atoms.

Preferably, the organic compound has a structure shown as general formula (2), general formula (3), general formula (4), general formula (5), general formula (6), or general formula (7):

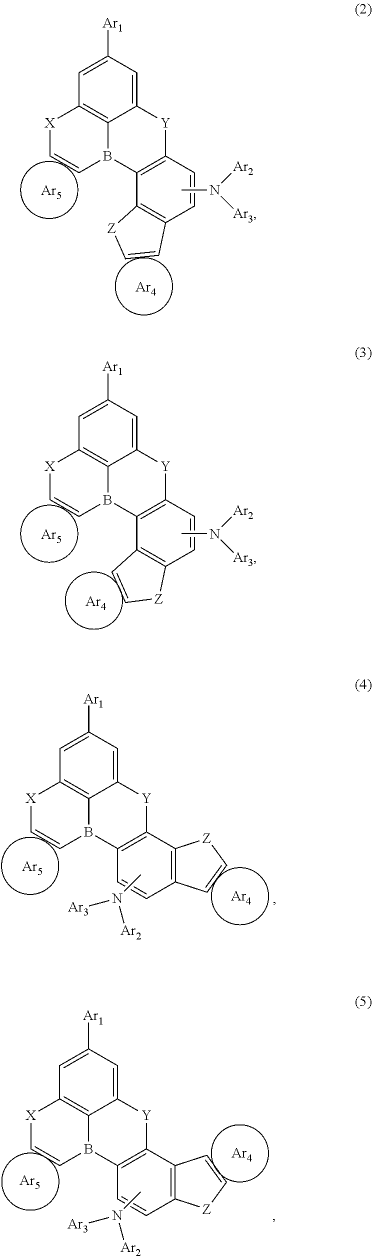

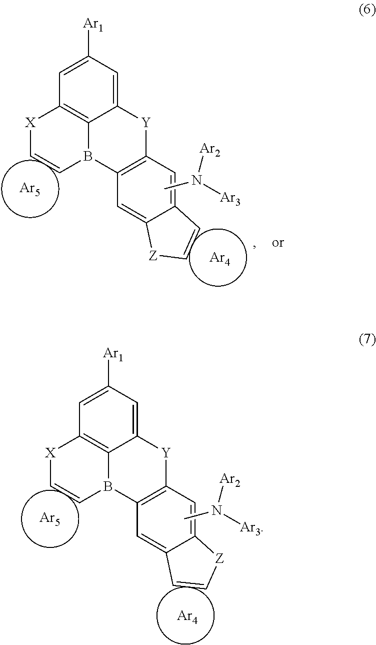

Preferably, the organic compound has a structure shown as general formula (8), general formula (9), general formula (10), general formula (11), general formula (12), or general formula (13):

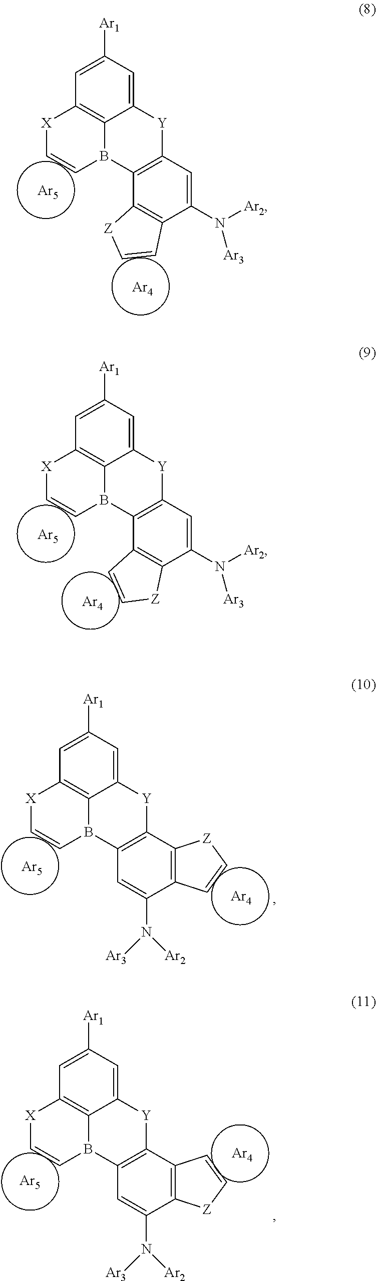

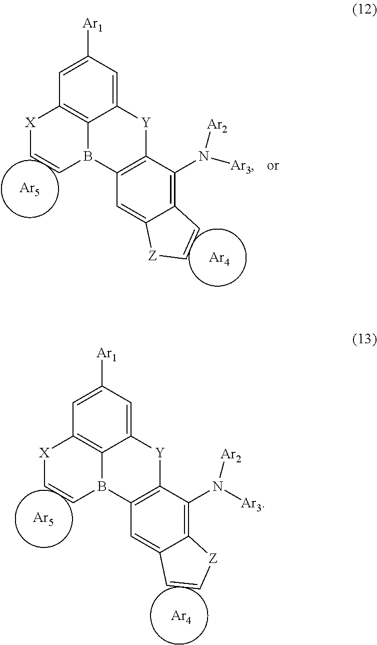

Preferably, the organic compound has a structure shown as general formula (14):

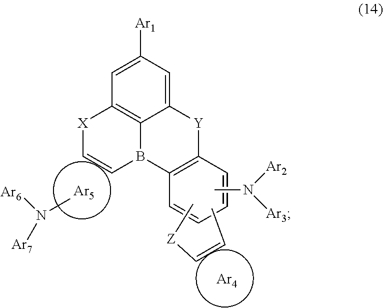

wherein, Ar₆ and Ar₇ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms.

Preferably, the organic compound has a structure shown as general formula (15):

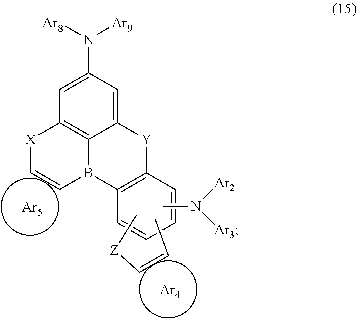

wherein, Ar₆ and Ar₇ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms.

Preferably, Z is selected from CR₁R₂, O, or S,

X and Y are each independently selected from O or NR₄, and X and Y are not O at a same time; and

R₁ to R₄ are each independently selected from a substituted or unsubstituted alkyl group with 1 to 12 carbon atoms, a substituted or unsubstituted aromatic group with 6 to 20 carbon atoms, or a substituted or unsubstituted heteroaromatic group with 5 to 20 carbon atoms.

Preferably, R₄ is selected from a methyl group, a substituted or unsubstituted phenyl group, a substituted or unsubstituted naphthyl group, a substituted or unsubstituted dibenzofuryl group, a substituted or unsubstituted dibenzothienyl group, a substituted or unsubstituted fluorenyl group, or a substituted or unsubstituted carbazolyl group.

Preferably, Ar₁ is selected from H, D, a methyl group, an isopropyl group, a tert-butyl group, a tert-amyl group, a substituted or unsubstituted phenyl group, a substituted or unsubstituted naphthyl group, a substituted or unsubstituted dibenzofuryl group, a substituted or unsubstituted dibenzothienyl group, a substituted or unsubstituted fluorenyl group, a substituted or unsubstituted carbazolyl group, or an amino group.

Preferably, Ar₂ and Ar₃ are independently selected from a substituted or unsubstituted phenyl group, a substituted or unsubstituted naphthyl group, a substituted or unsubstituted triphenyl group, a substituted or unsubstituted dibenzofuryl group, a substituted or unsubstituted dibenzothienyl group, a substituted or unsubstituted fluorenyl group, a substituted or unsubstituted carbazolyl group, or a methyl group; and

Ar₄ and Ar₅ are independently selected from a substituted or unsubstituted phenyl group, a substituted or unsubstituted naphthyl group, a substituted or unsubstituted triphenyl group, a substituted or unsubstituted dibenzofuryl group, a substituted or unsubstituted dibenzothienyl group, a substituted or unsubstituted fluorenyl group, or a substituted or unsubstituted carbazolyl group.

Preferably, the organic compound is one selected from following compounds:

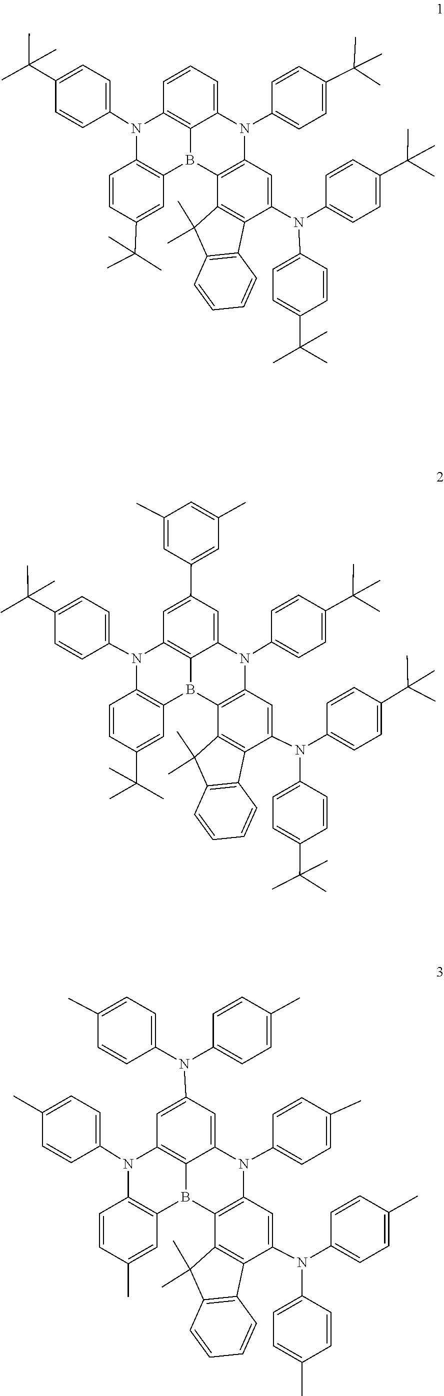

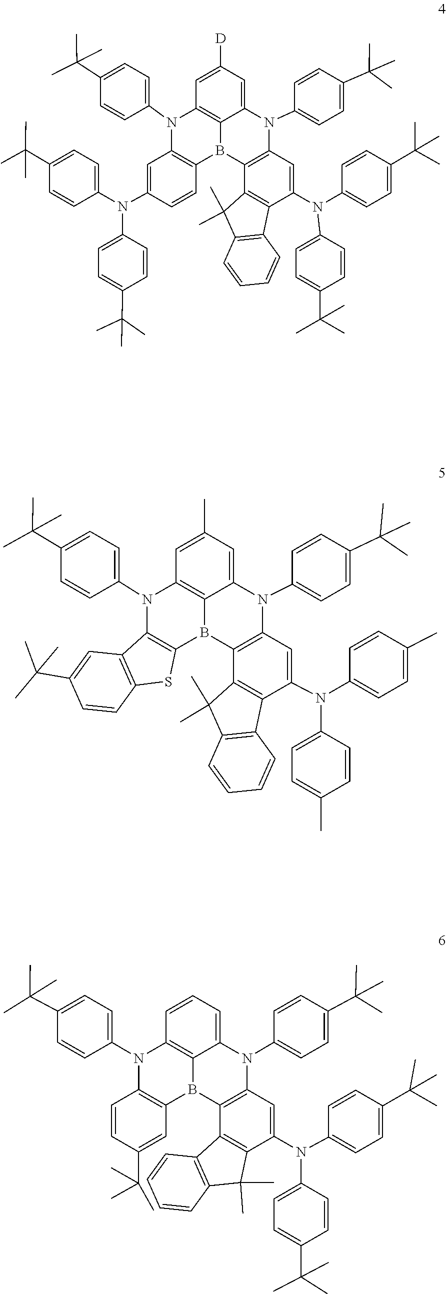

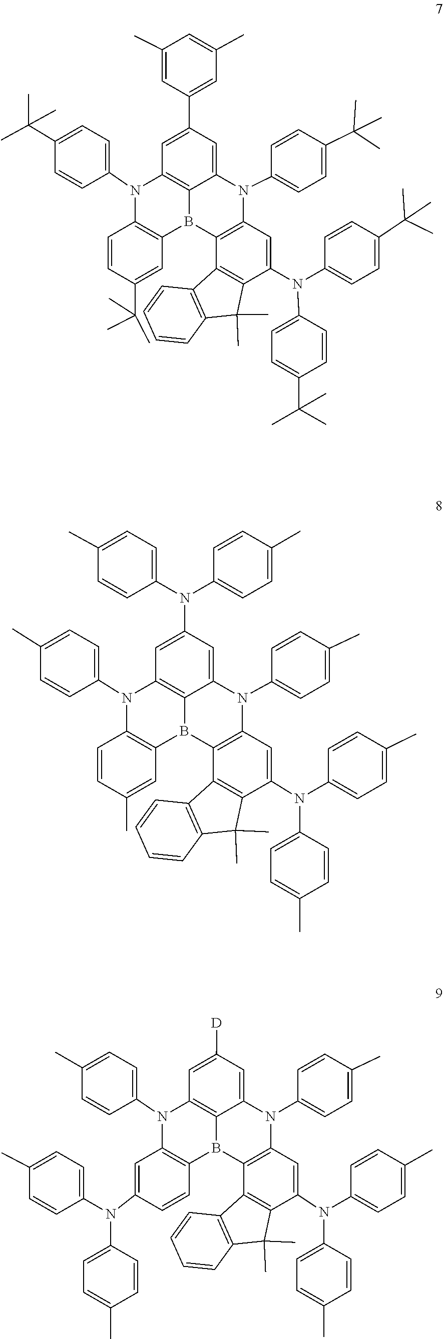

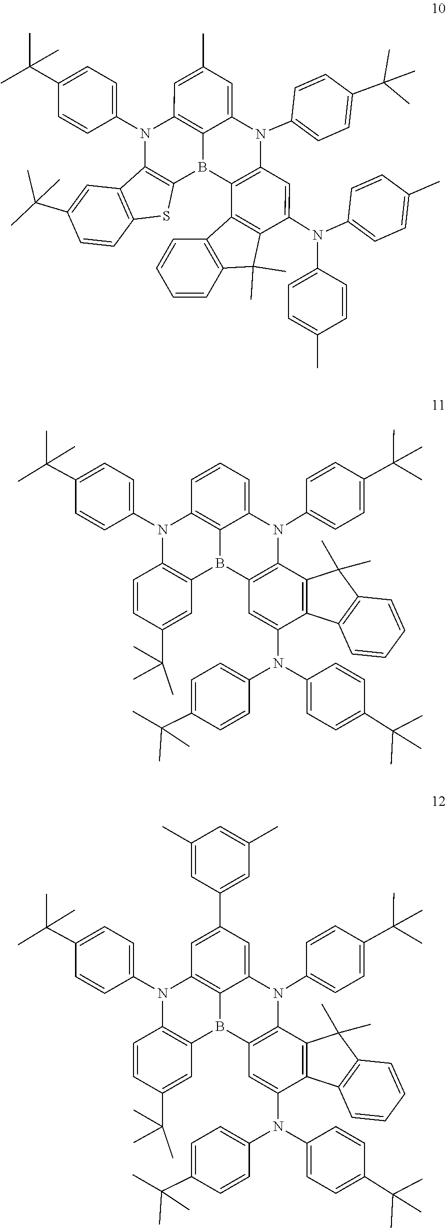

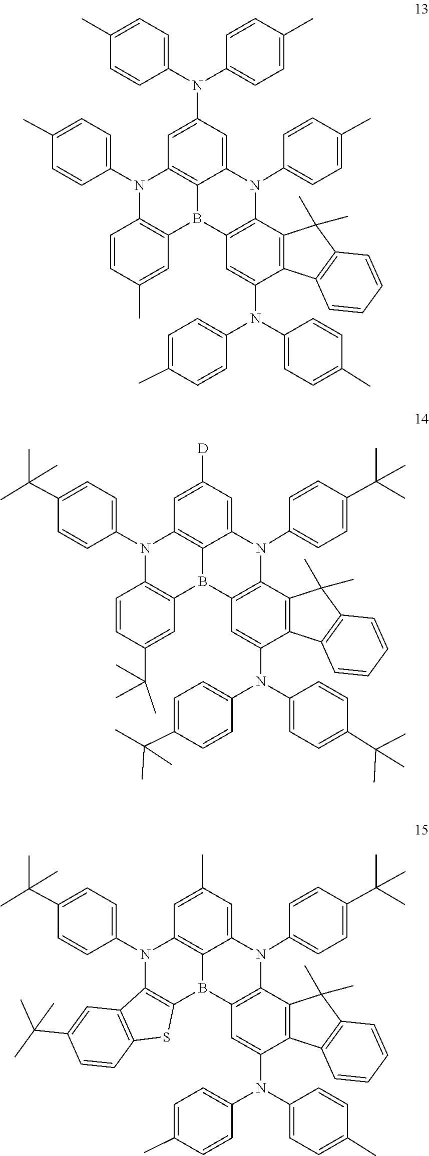

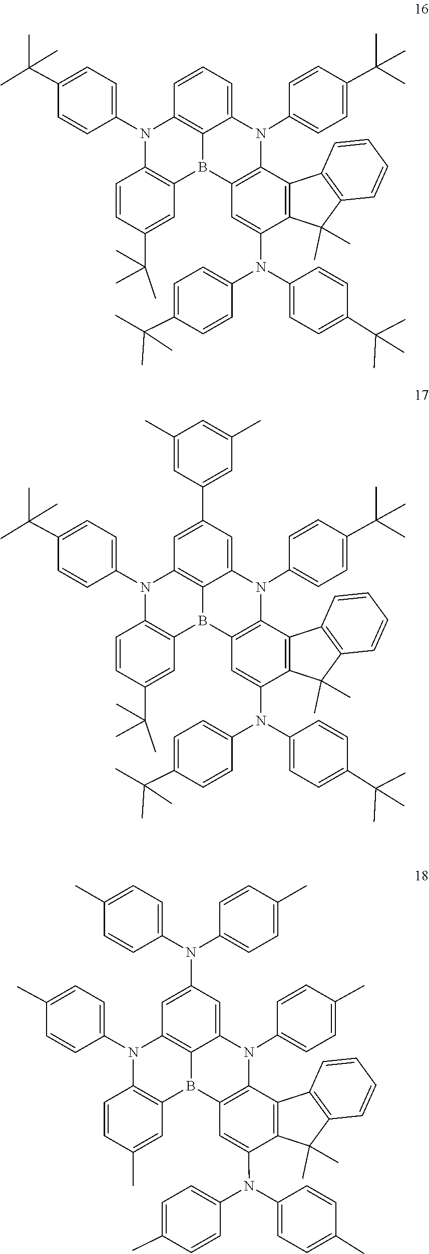

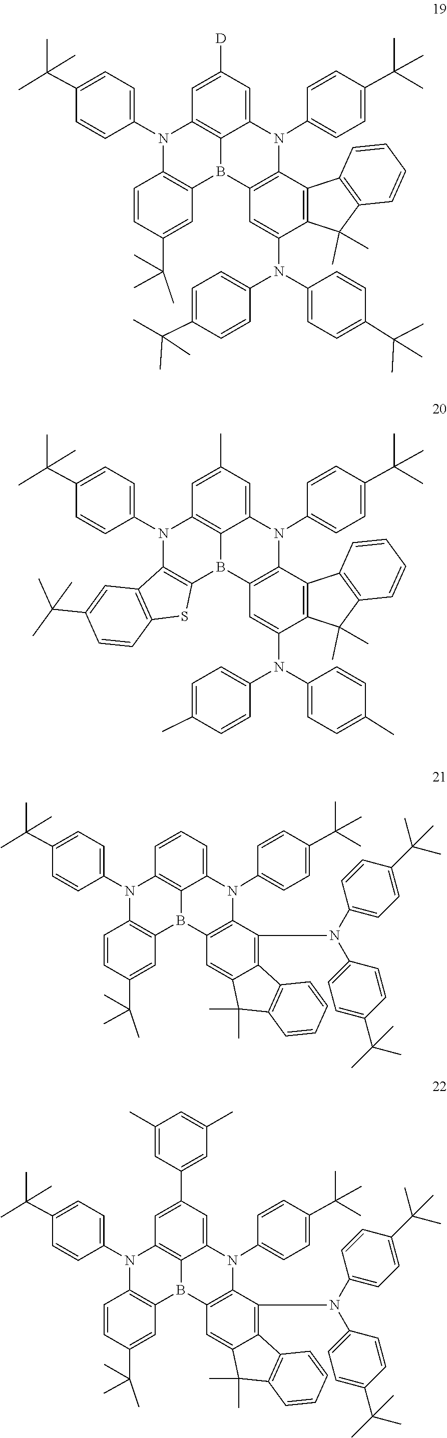

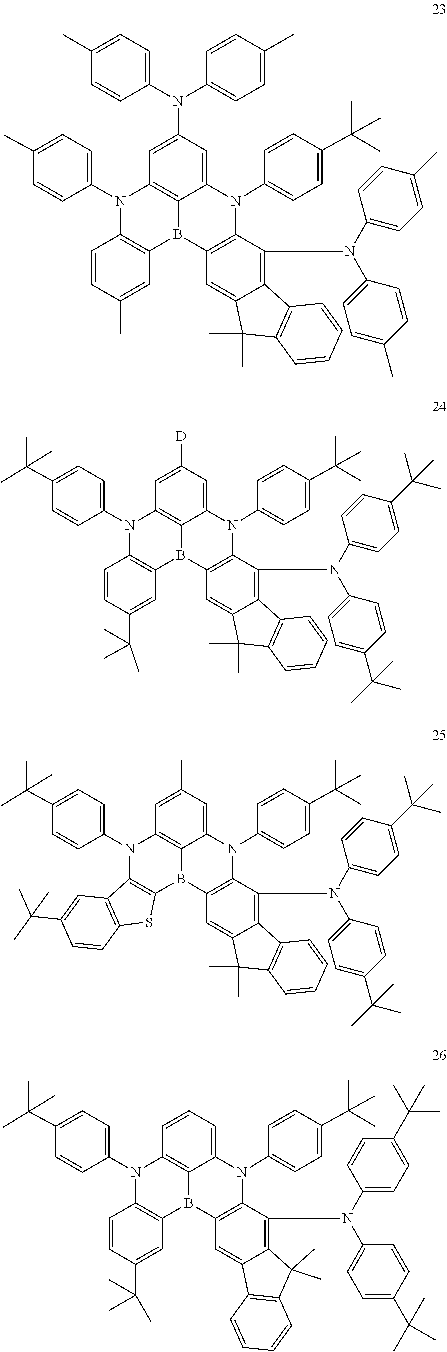

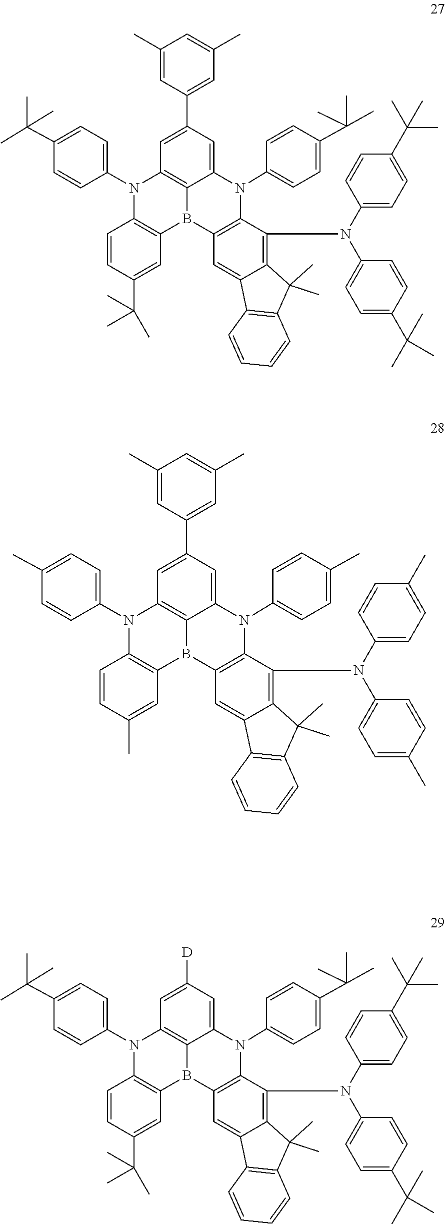

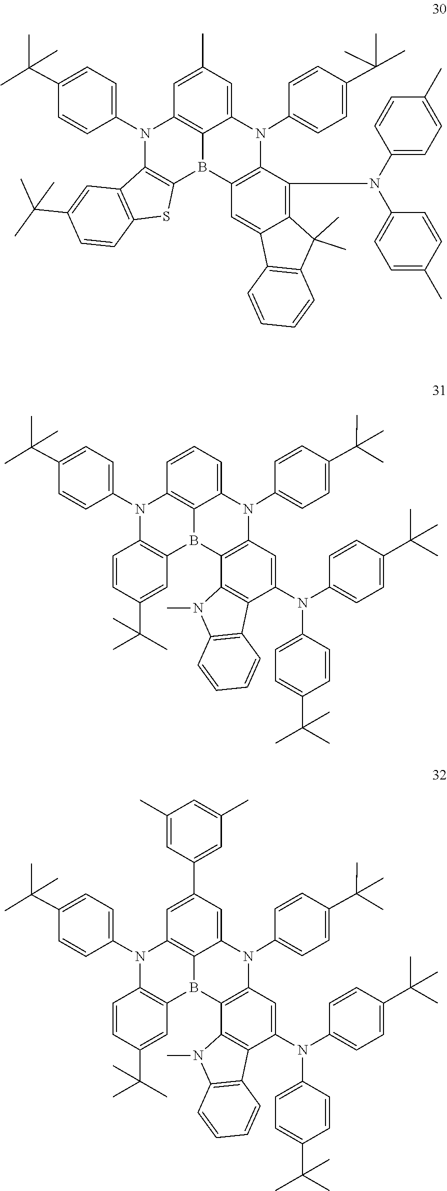

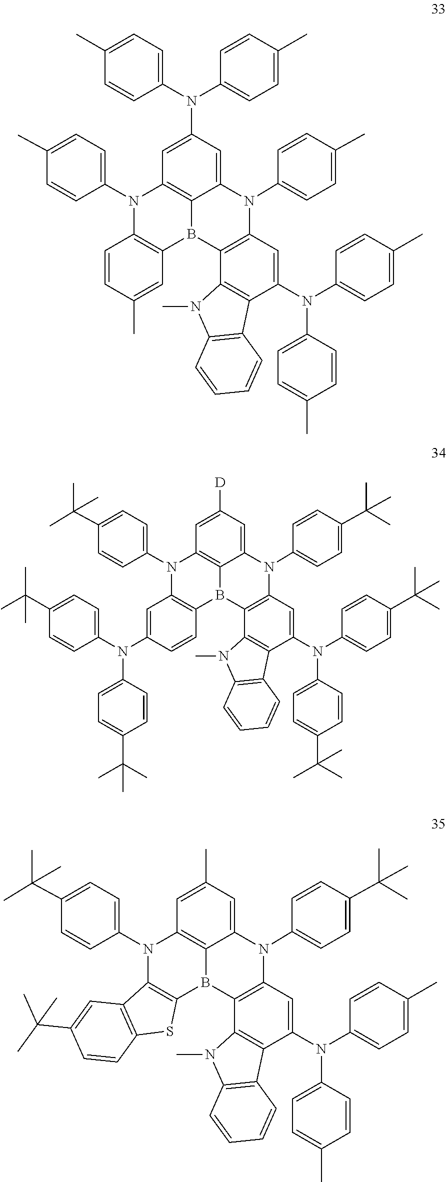

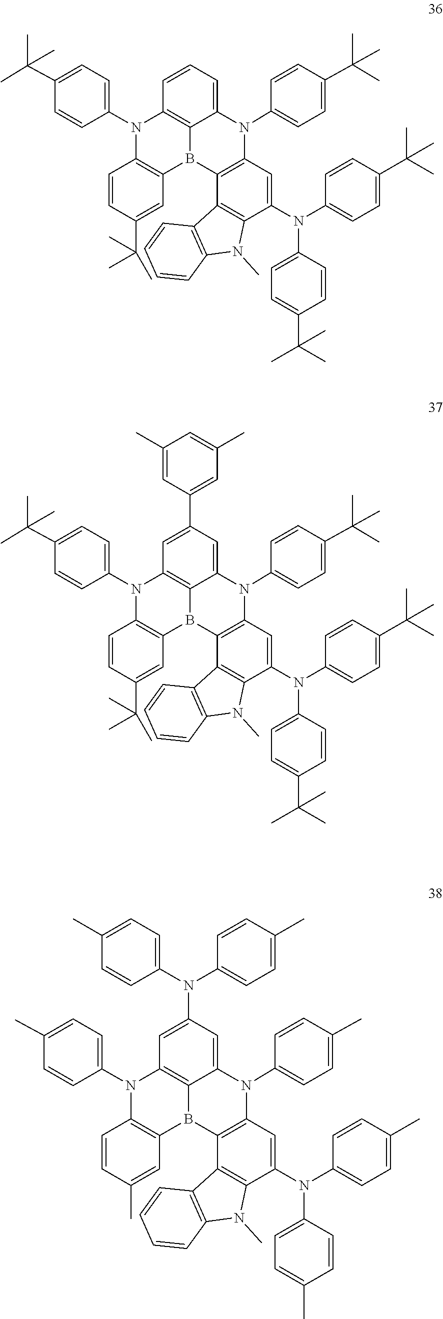

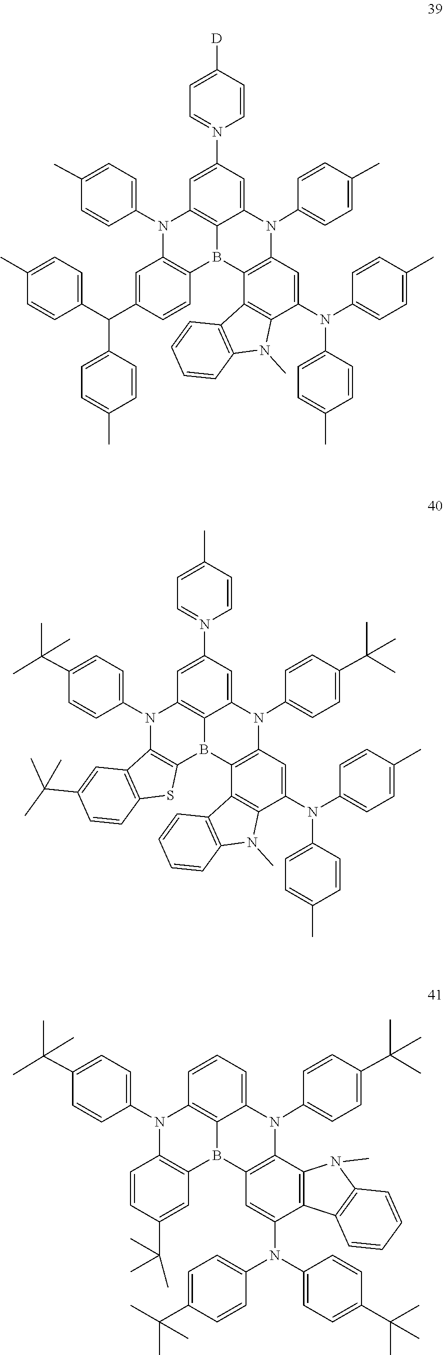

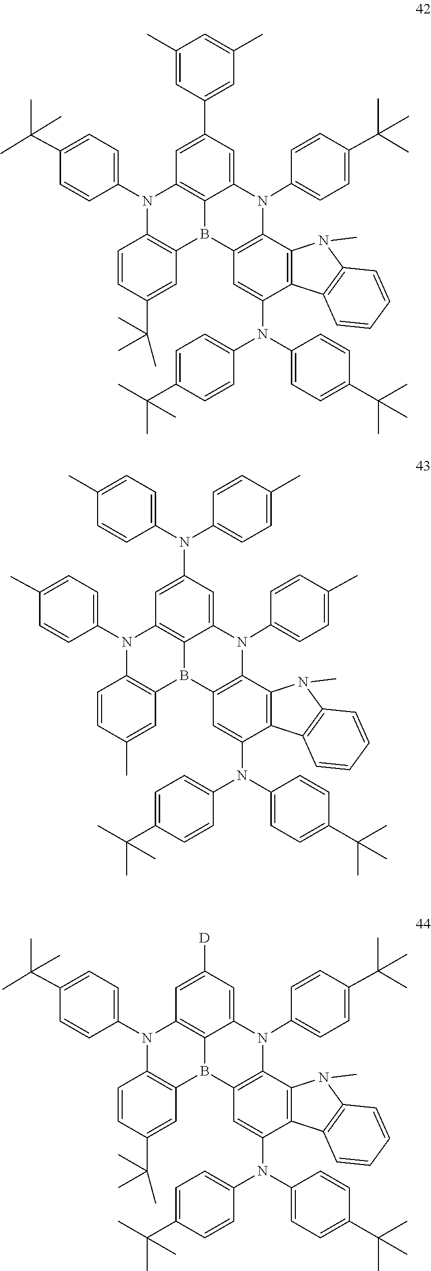

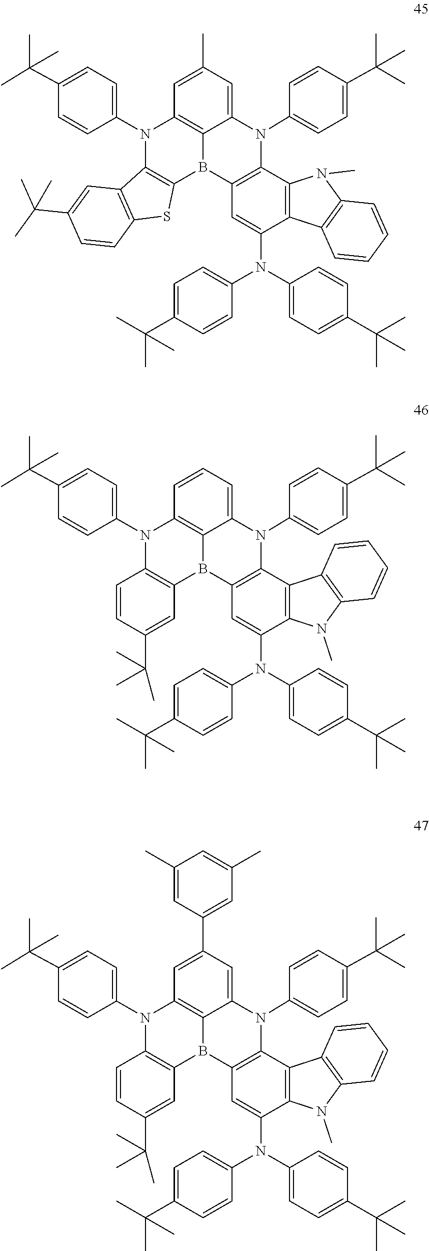

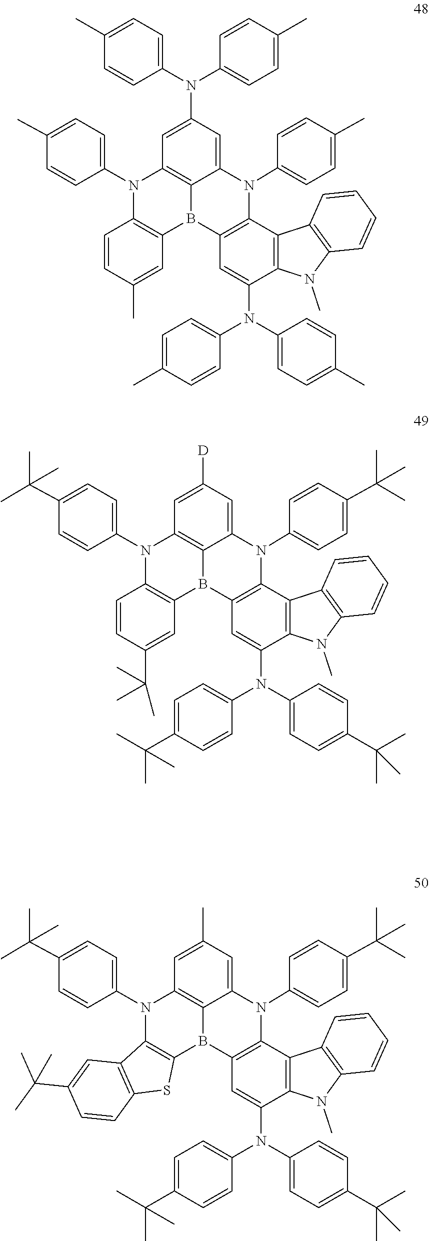

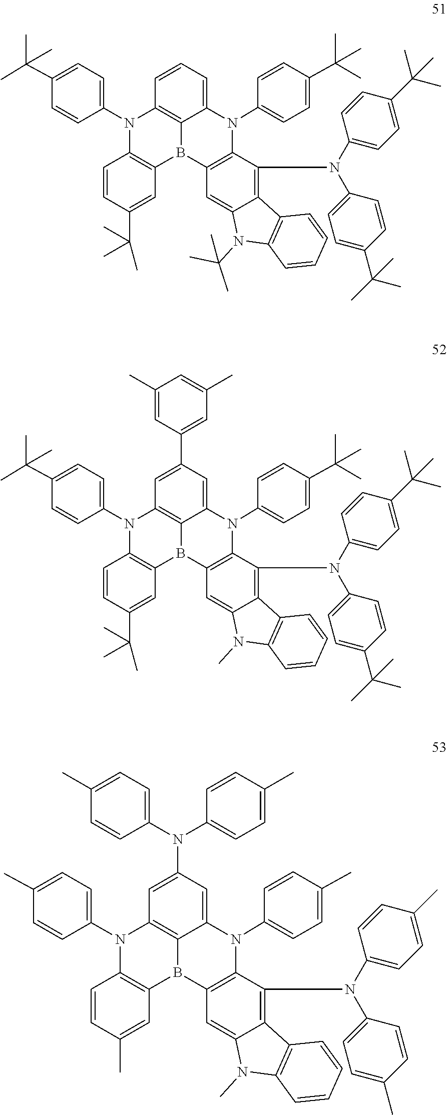

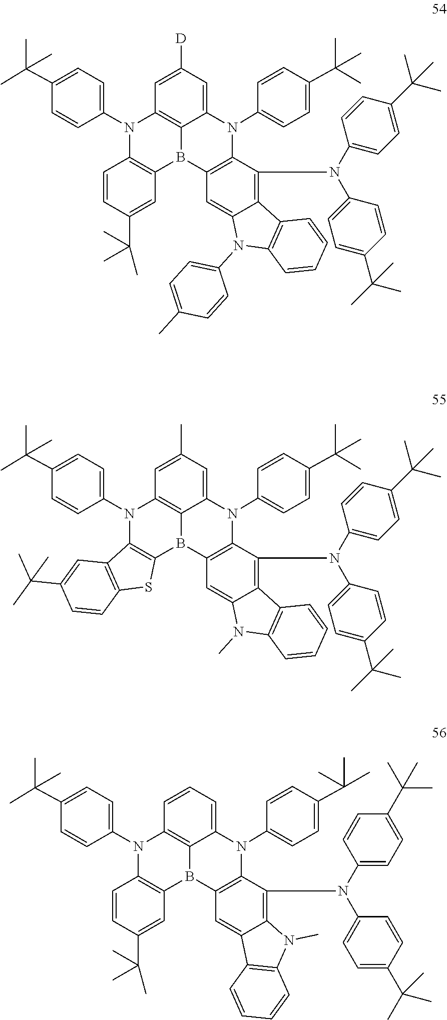

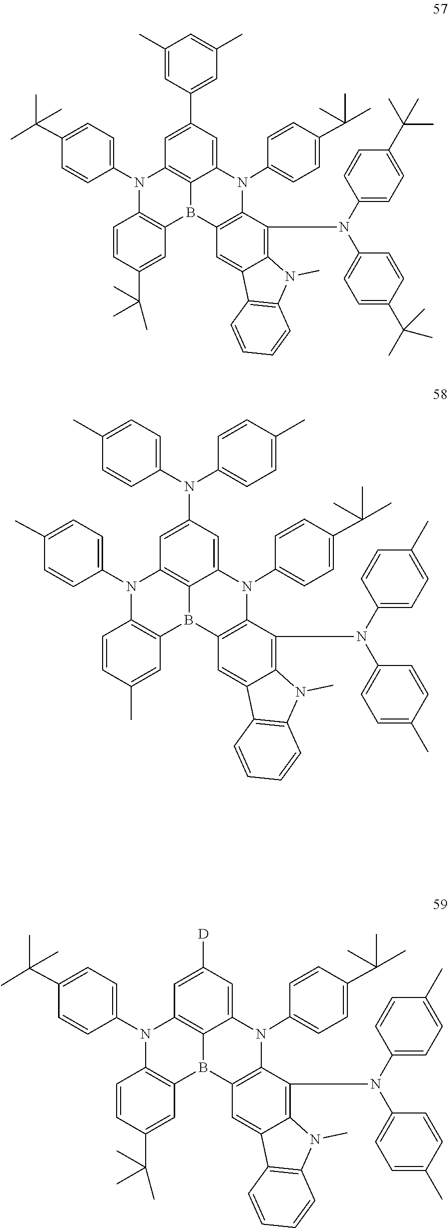

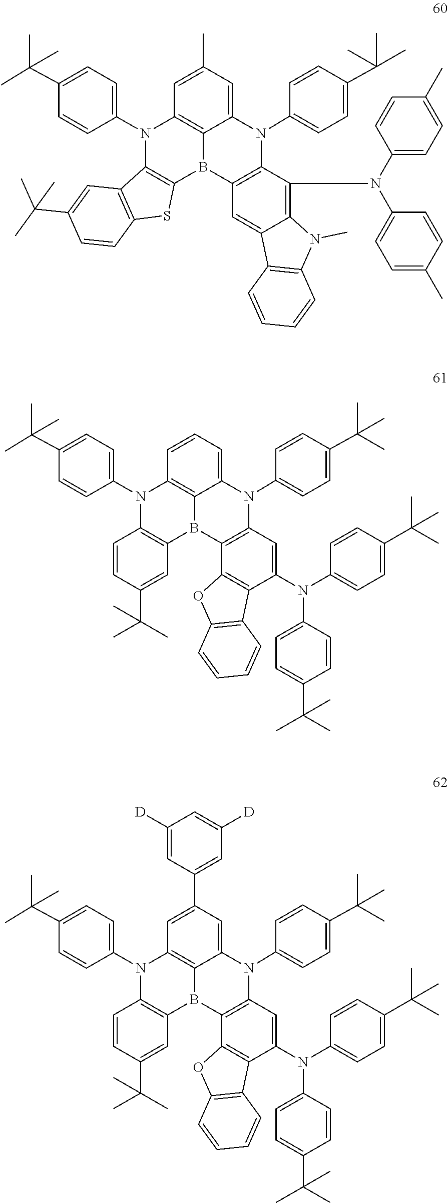

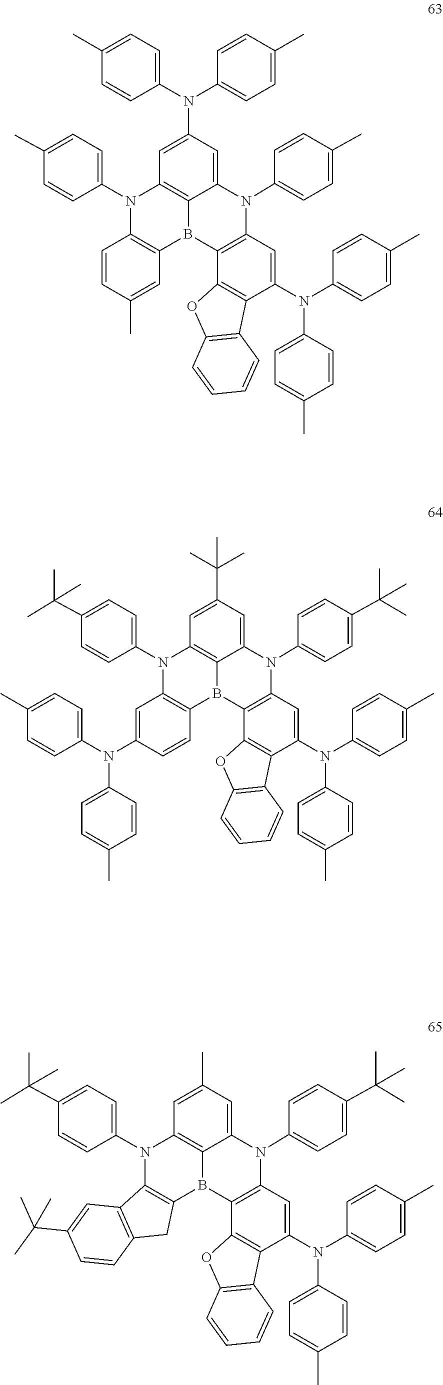

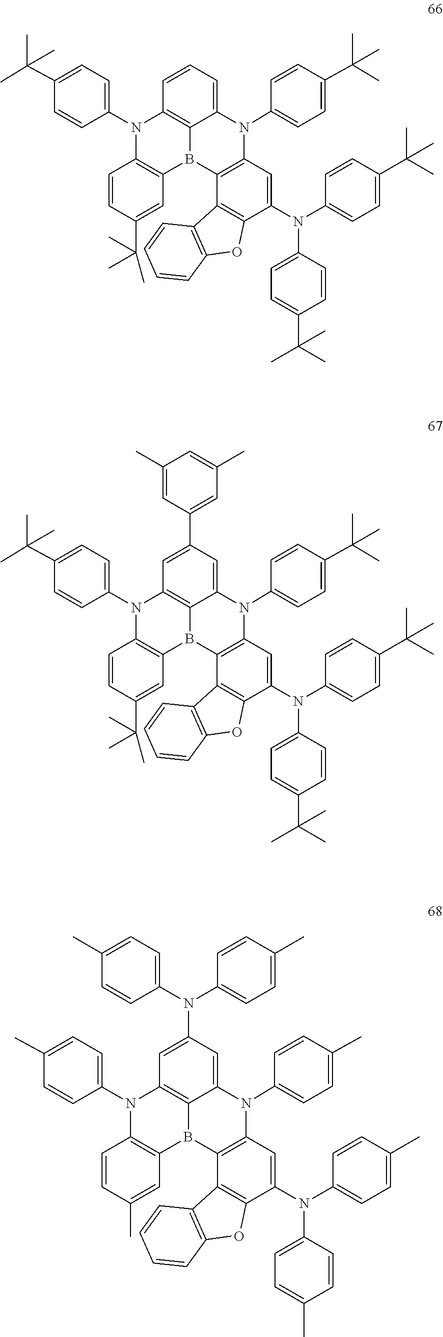

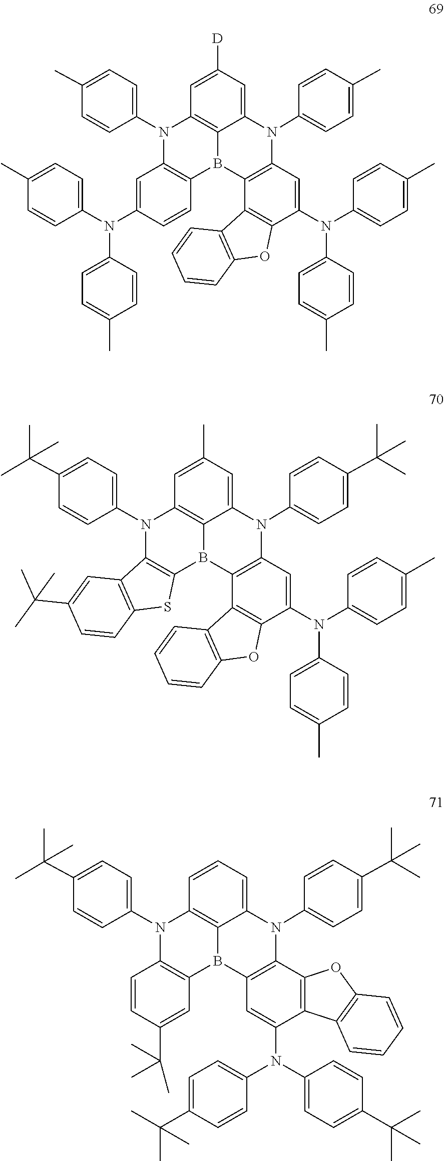

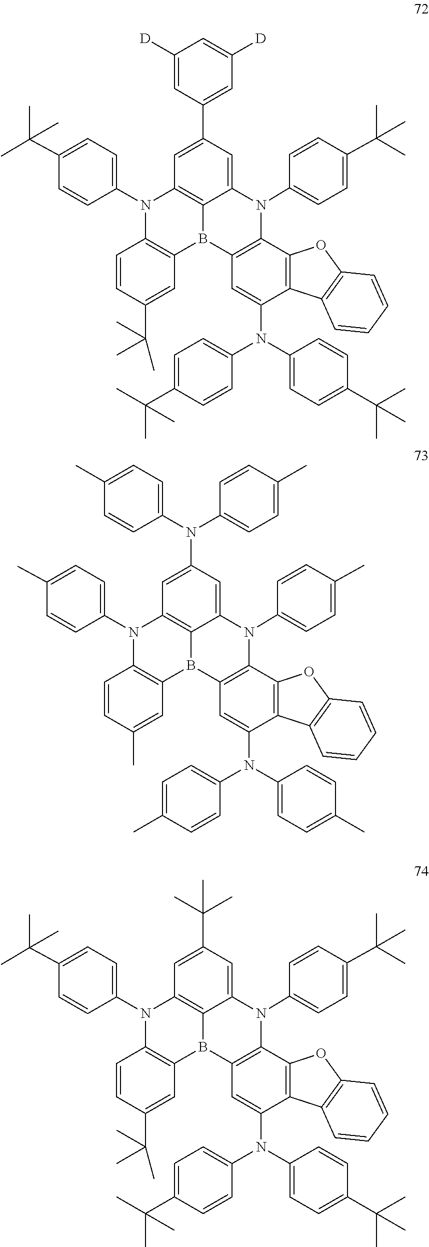

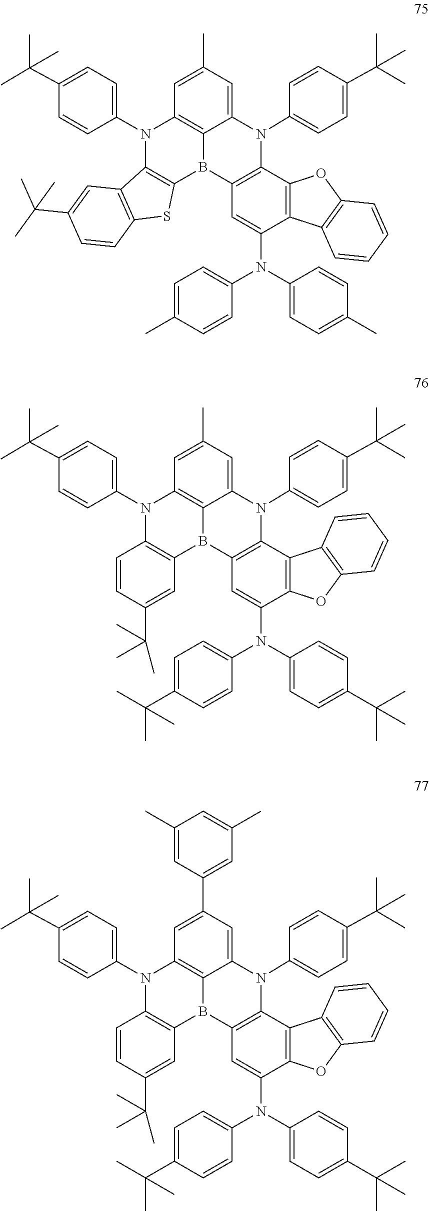

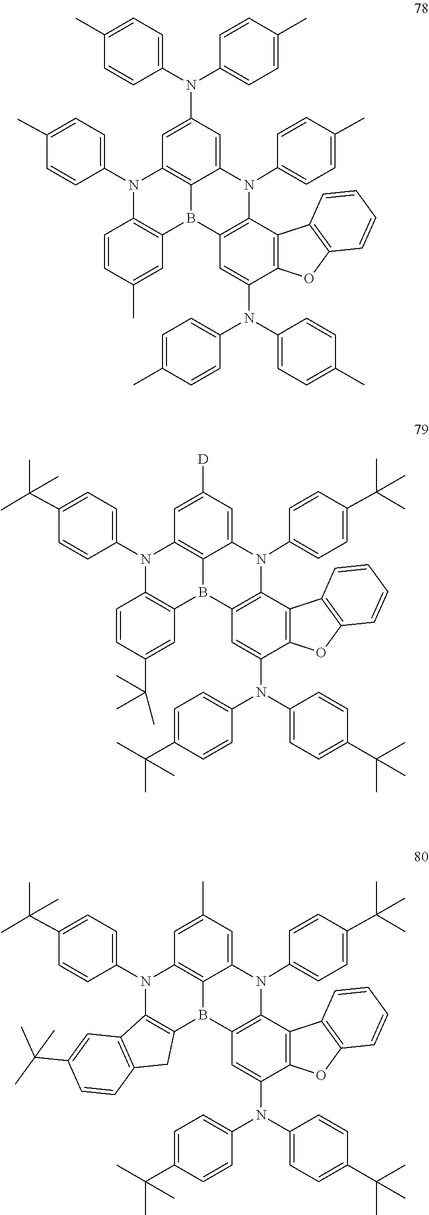

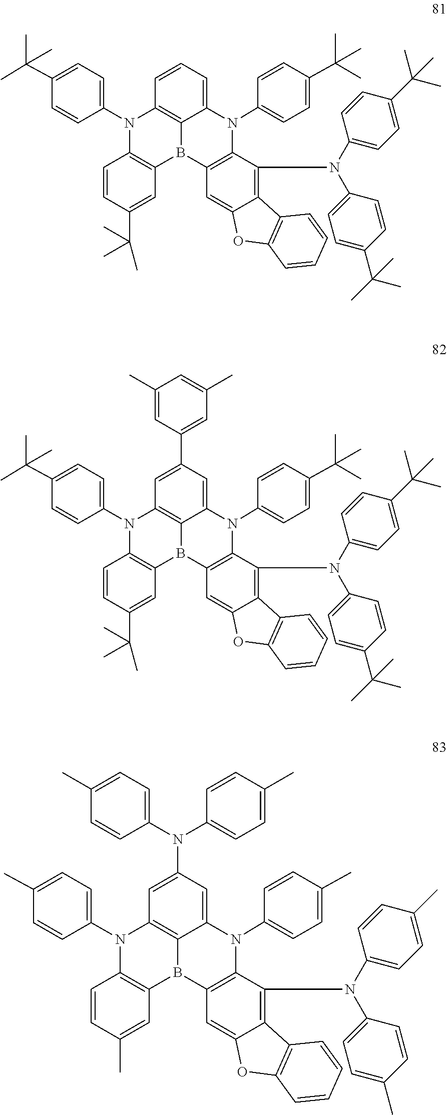

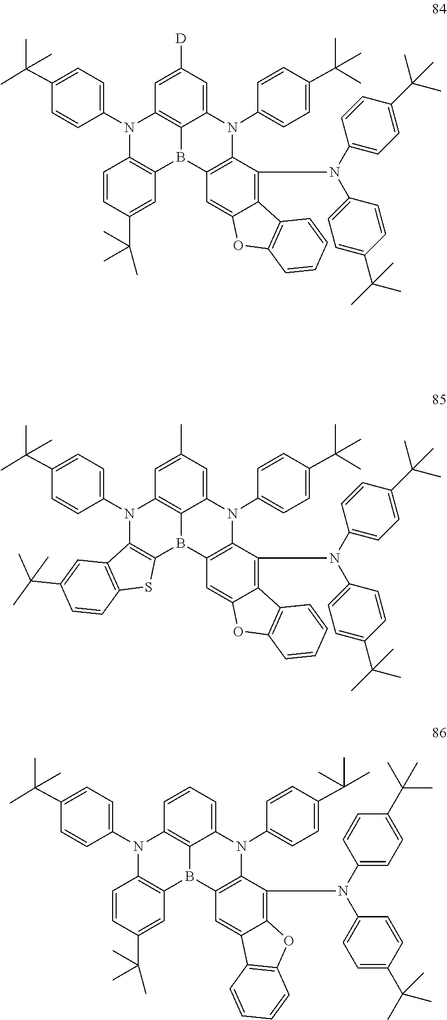

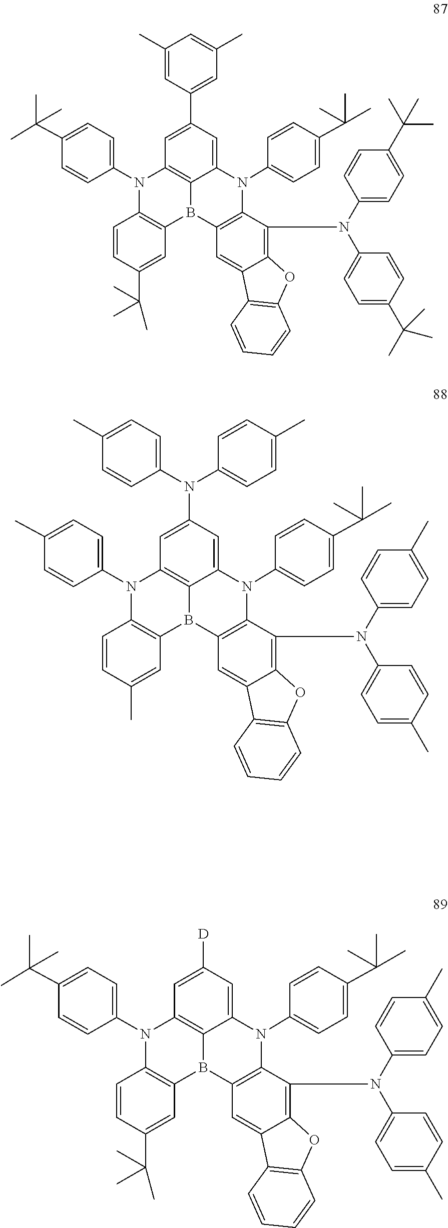

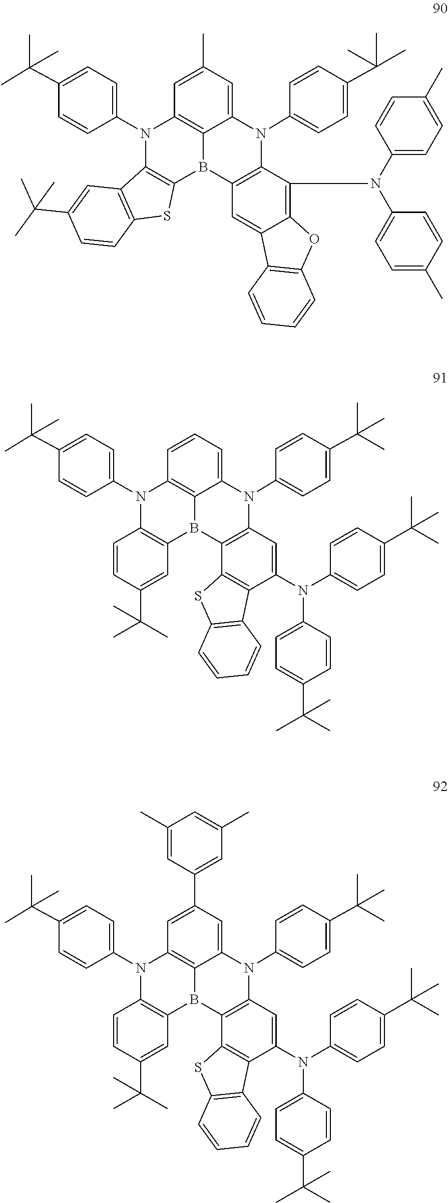

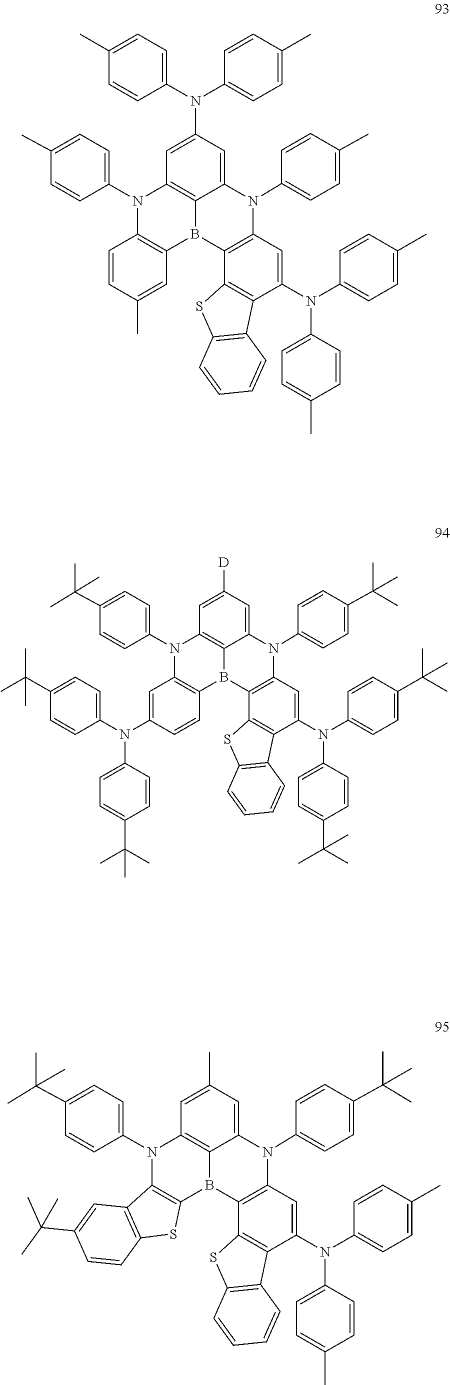

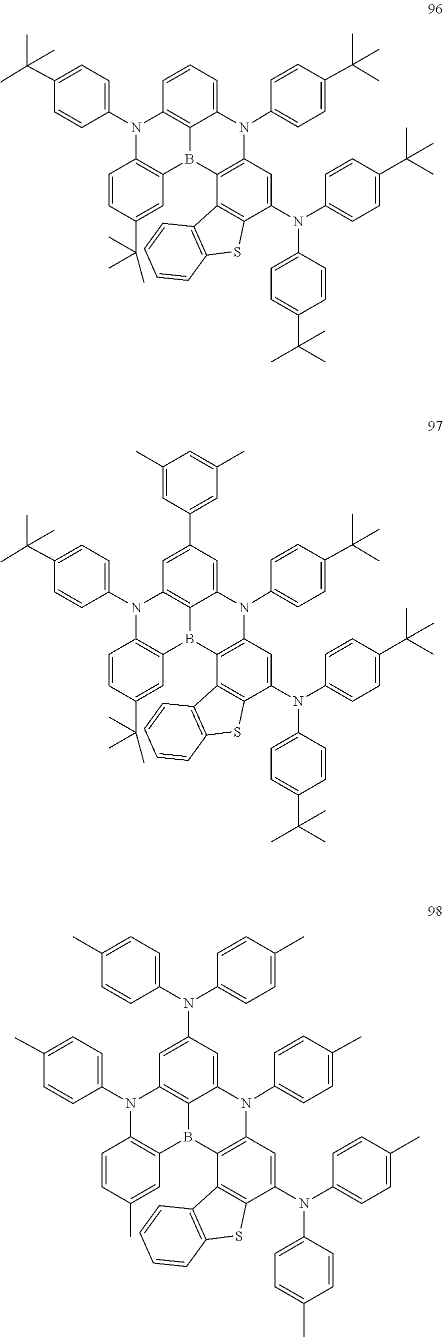

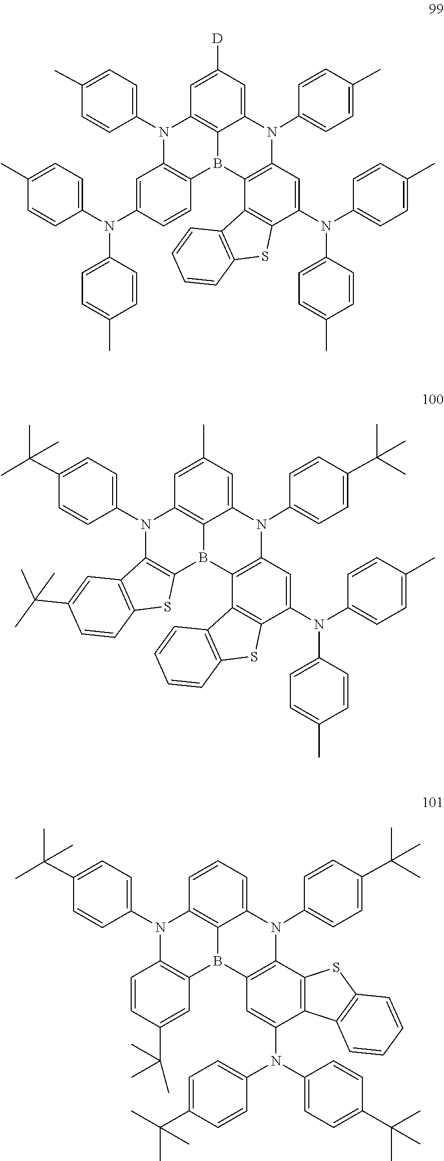

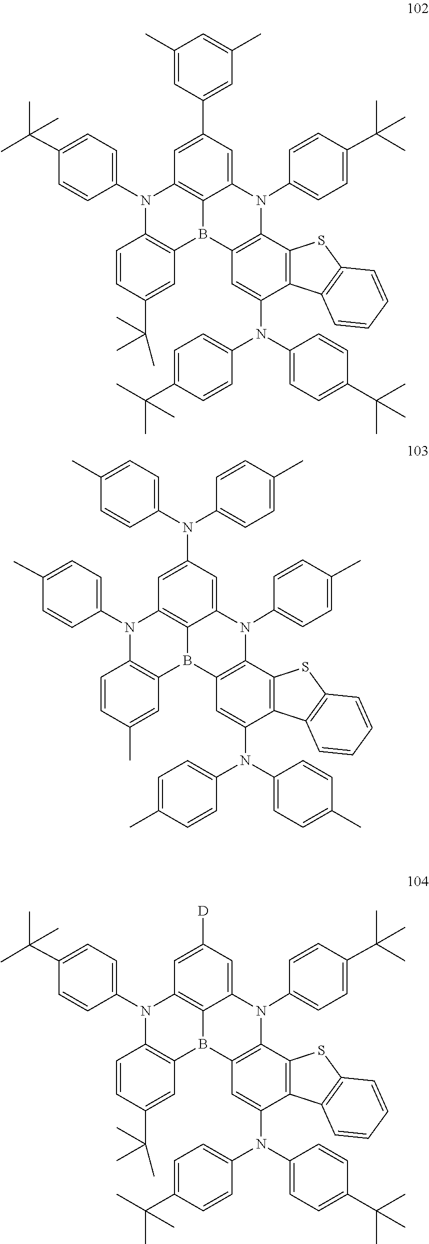

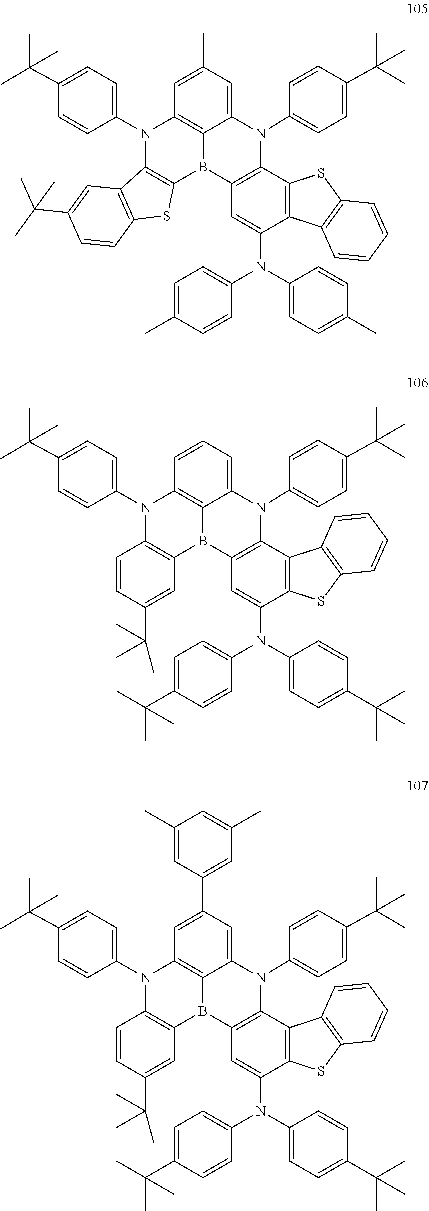

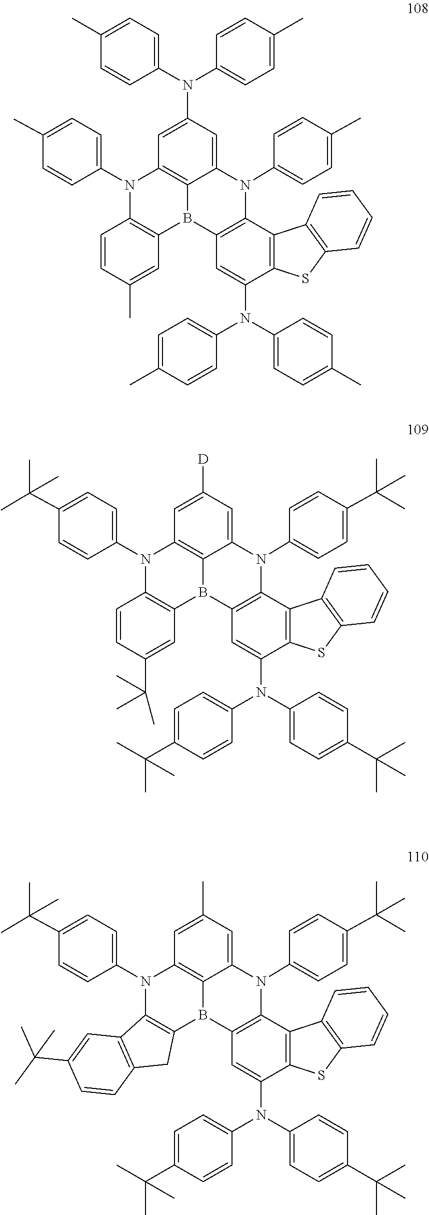

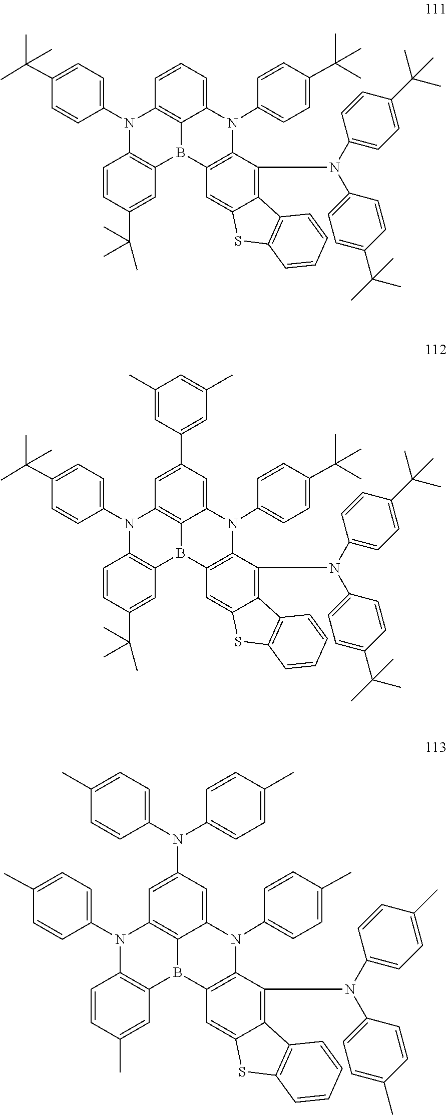

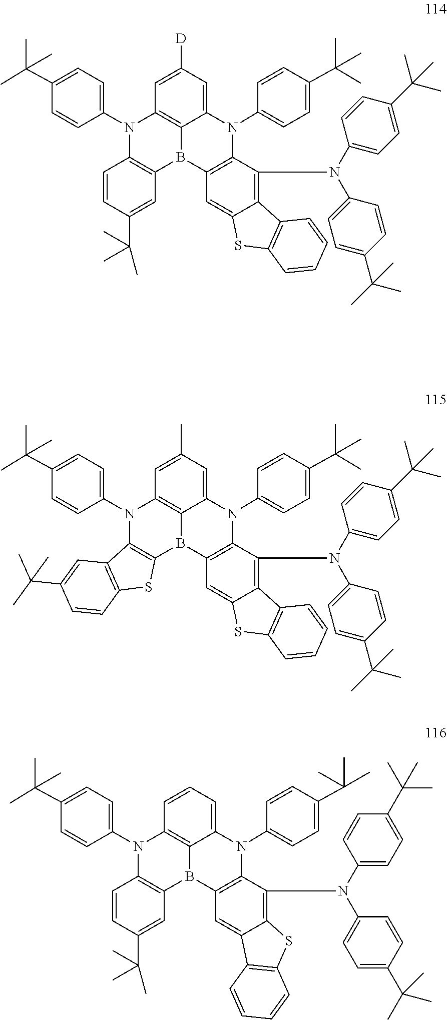

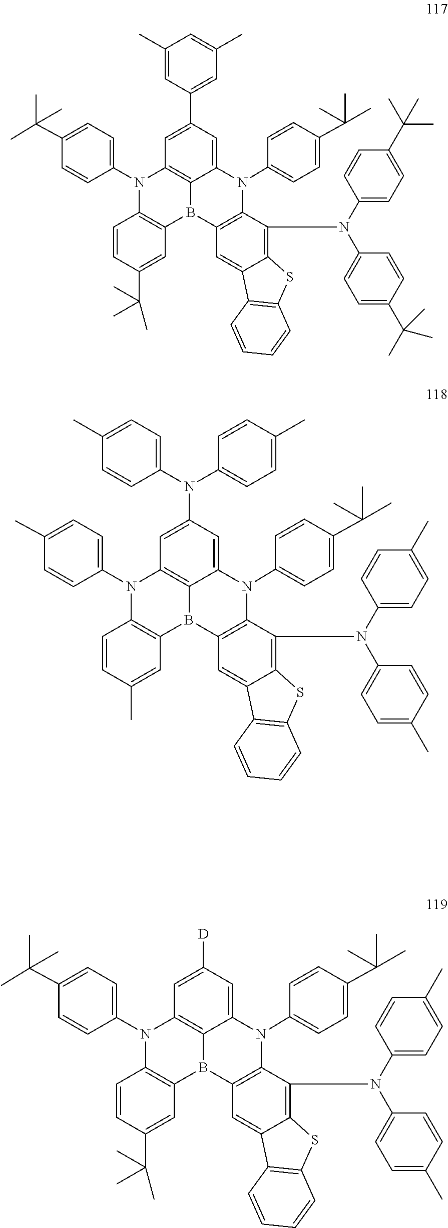

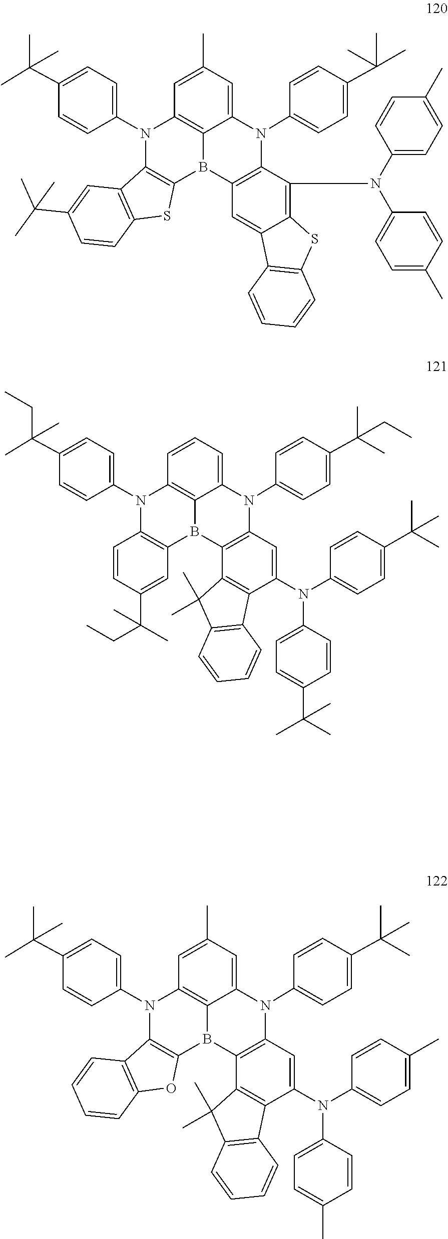

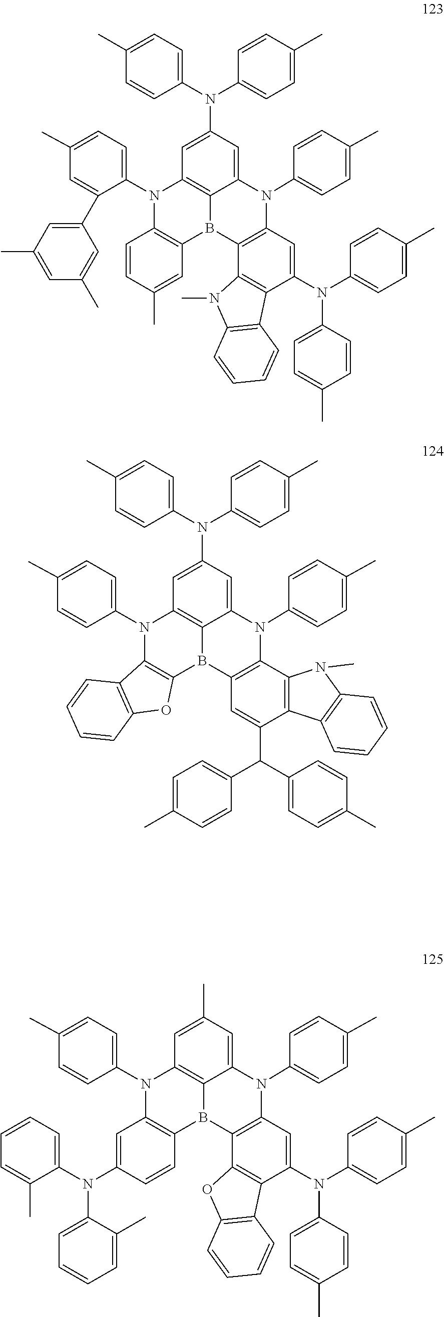

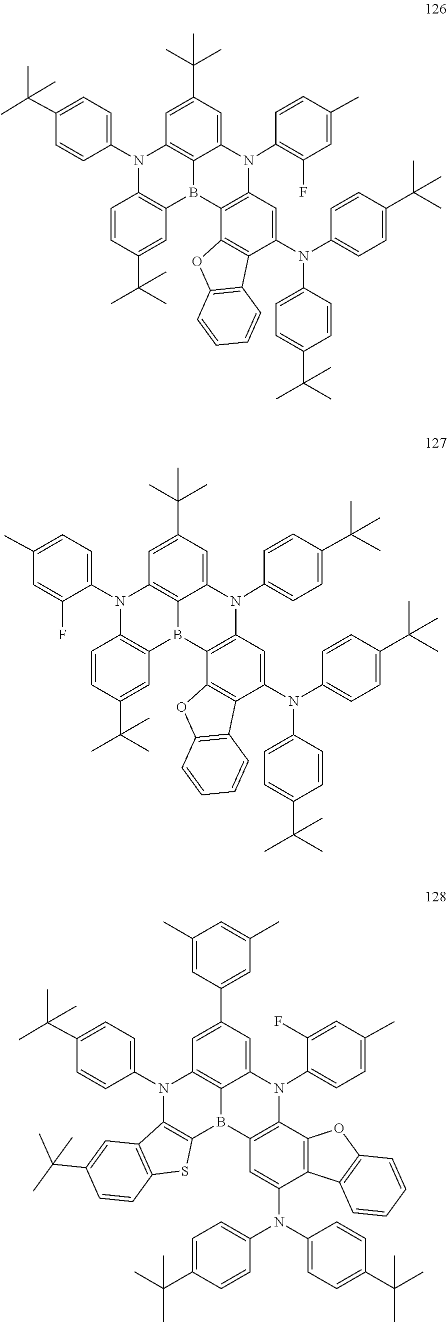

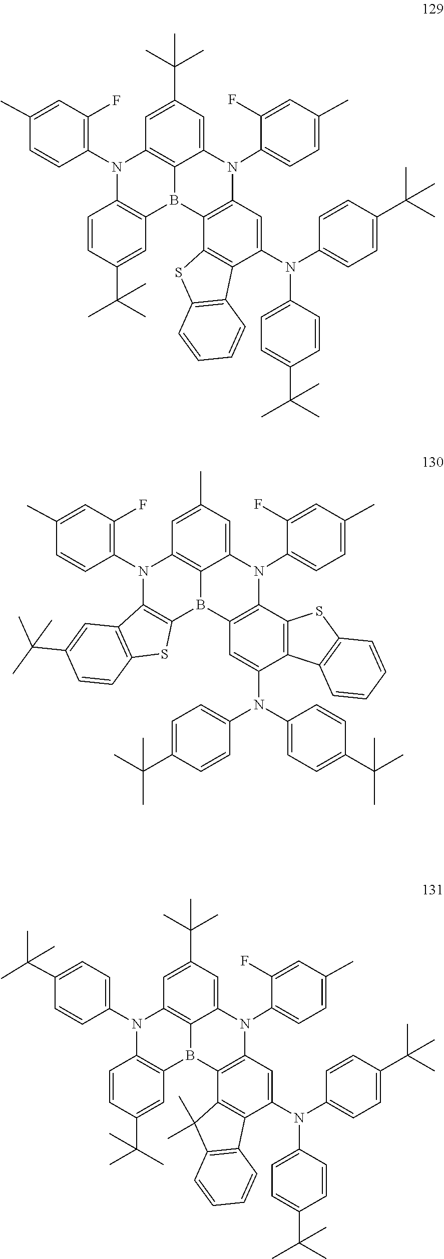

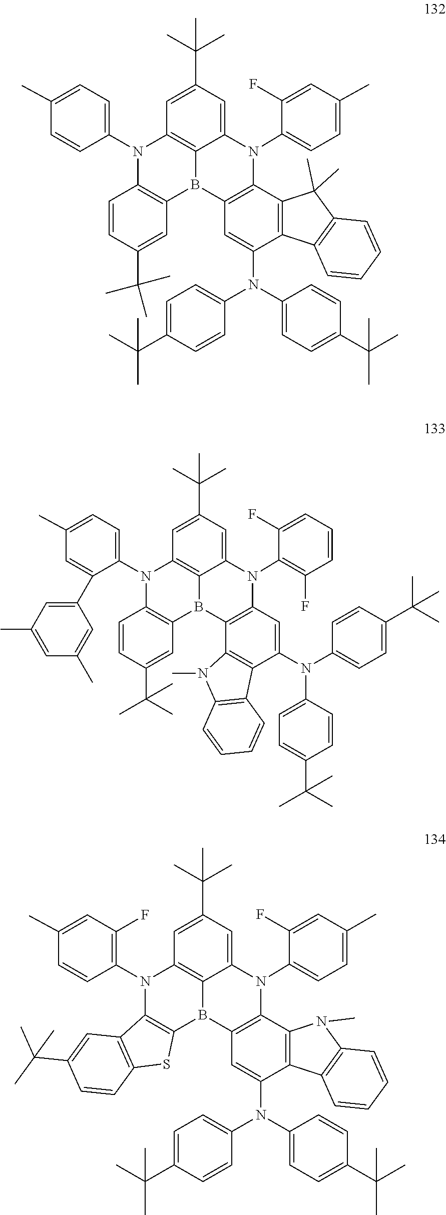

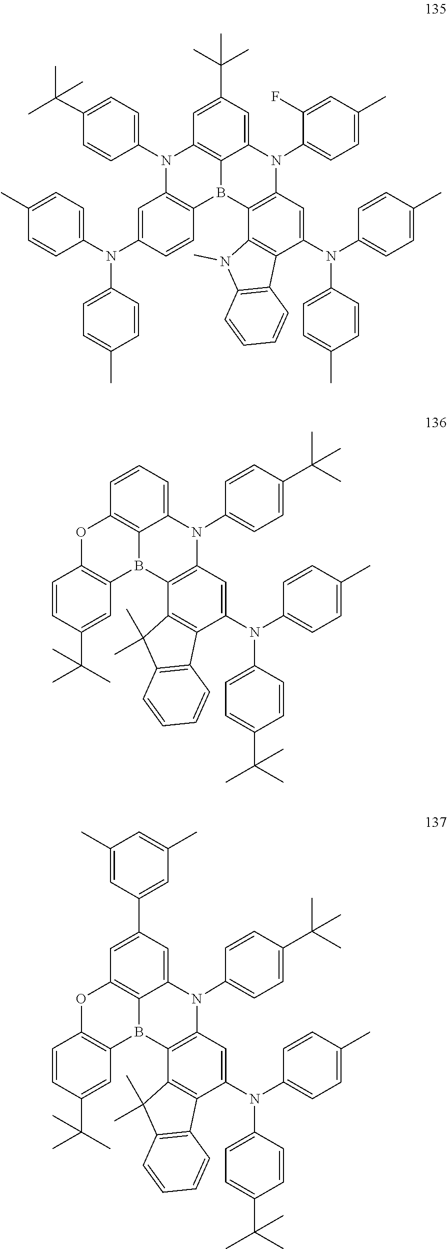

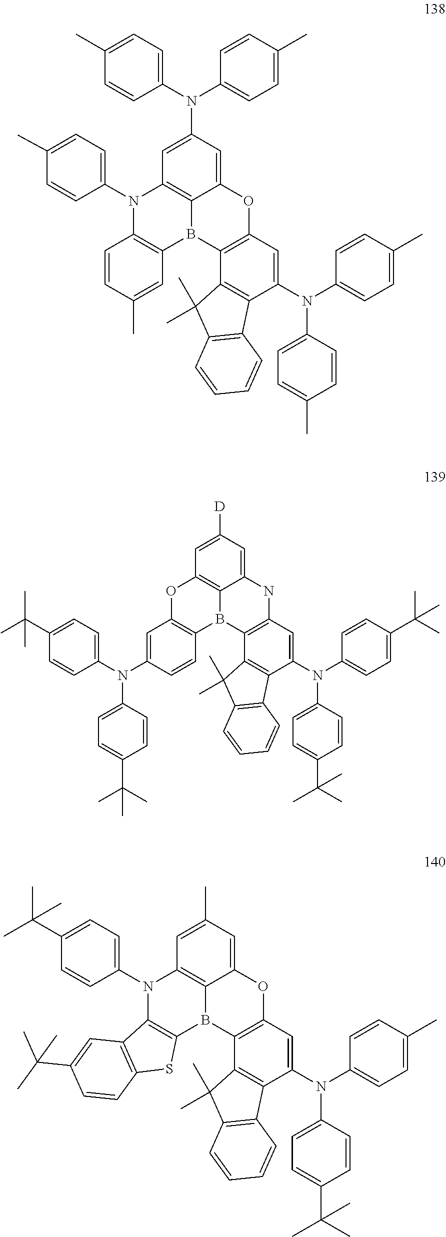

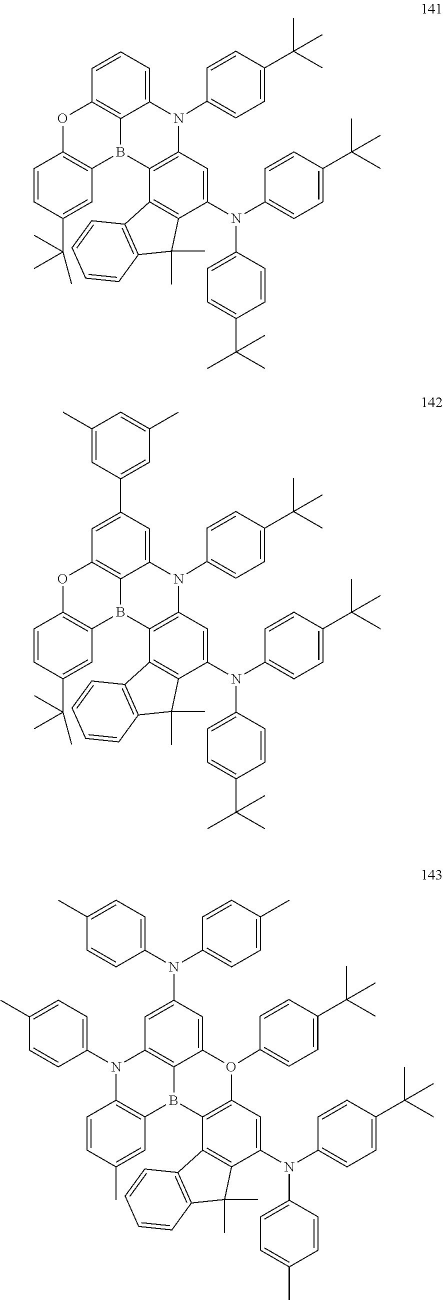

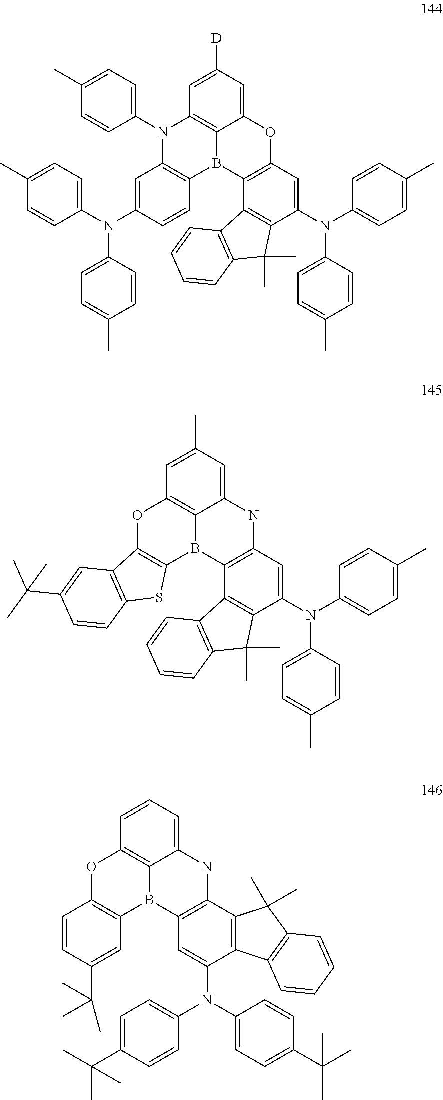

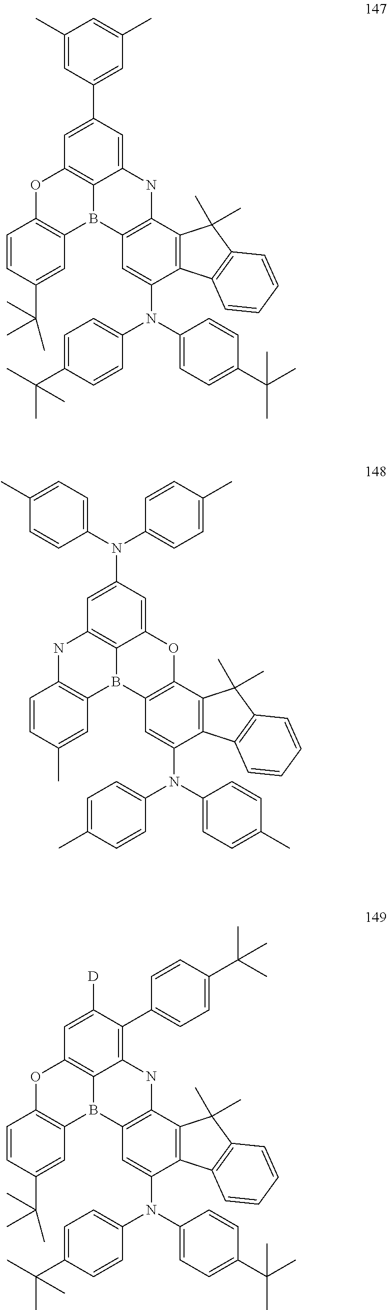

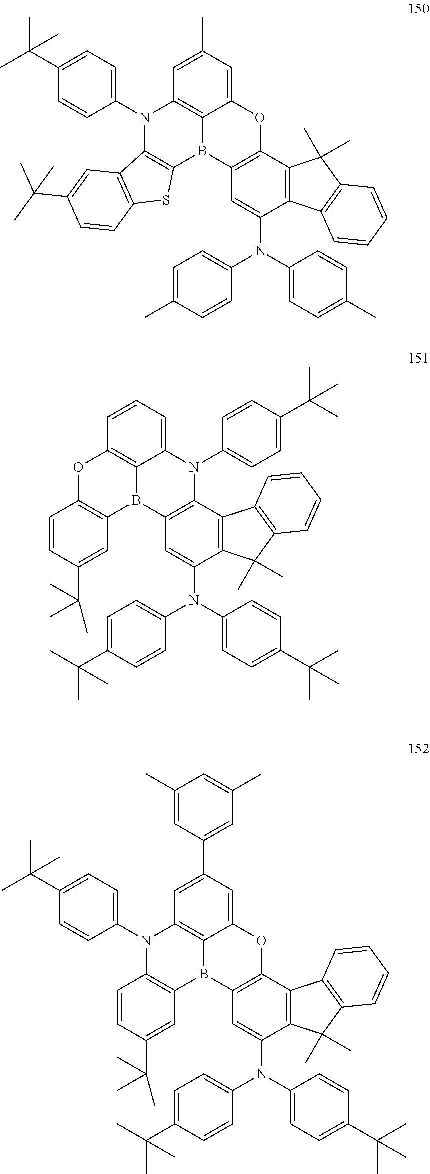

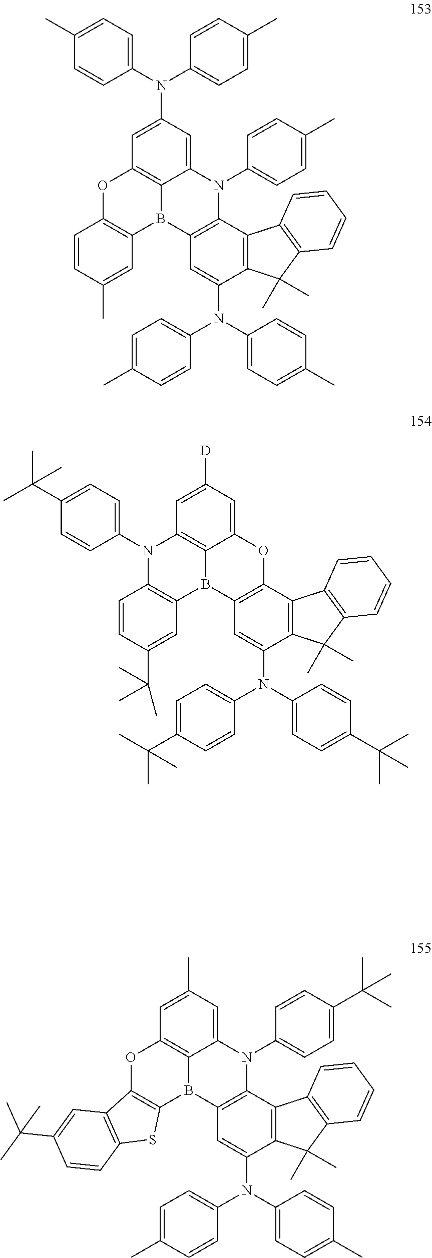

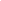

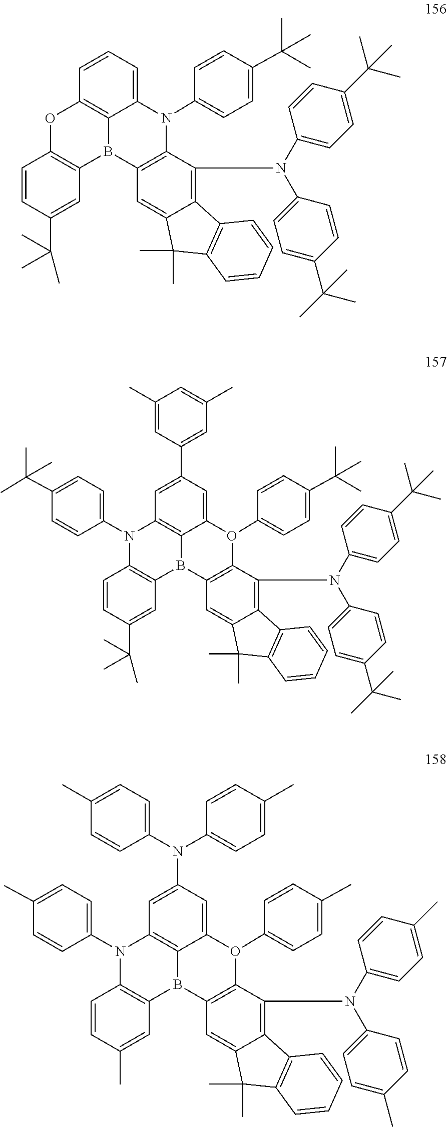

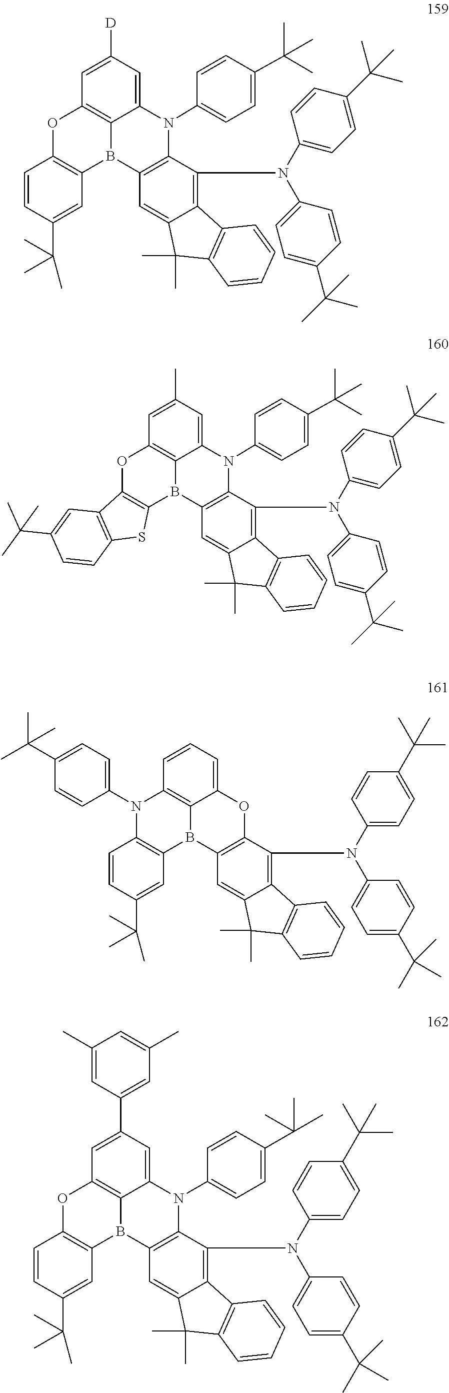

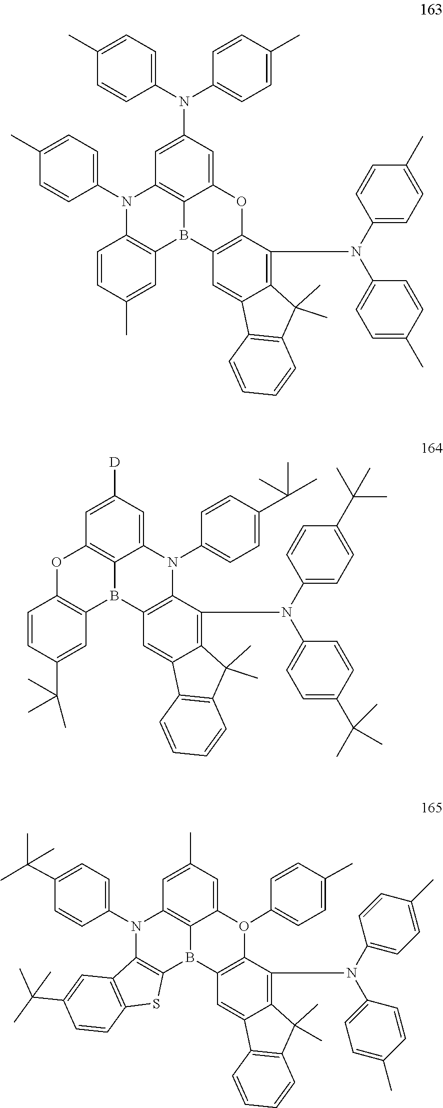

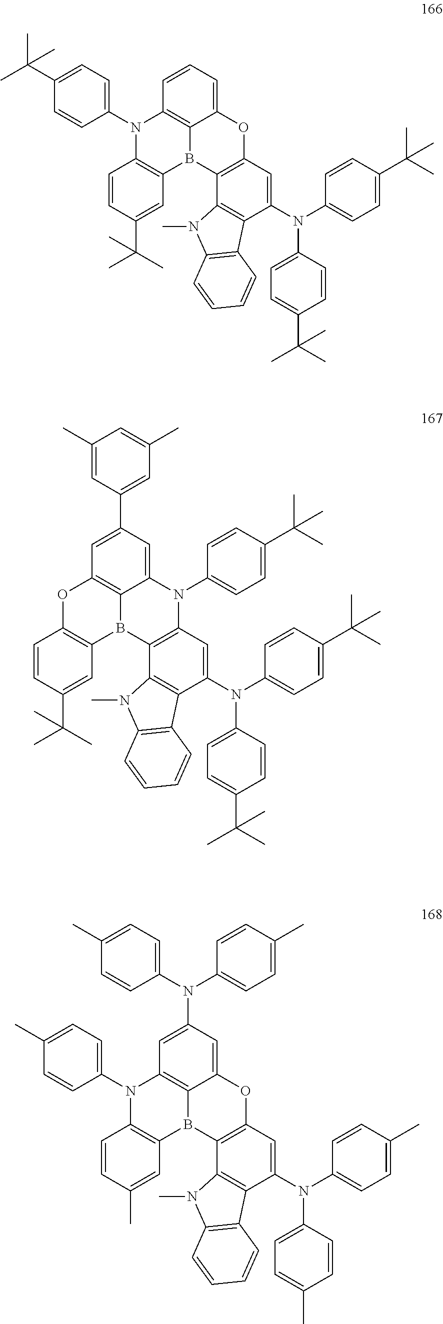

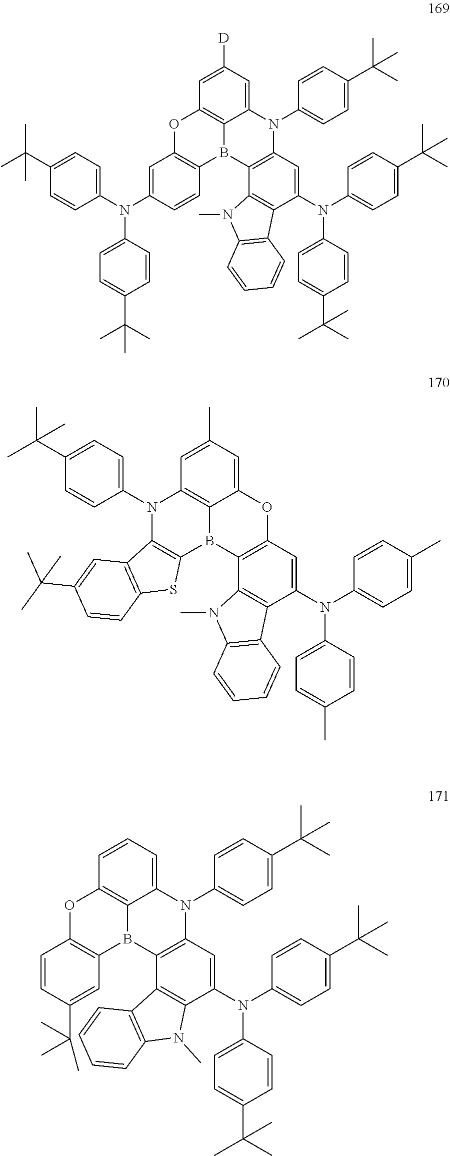

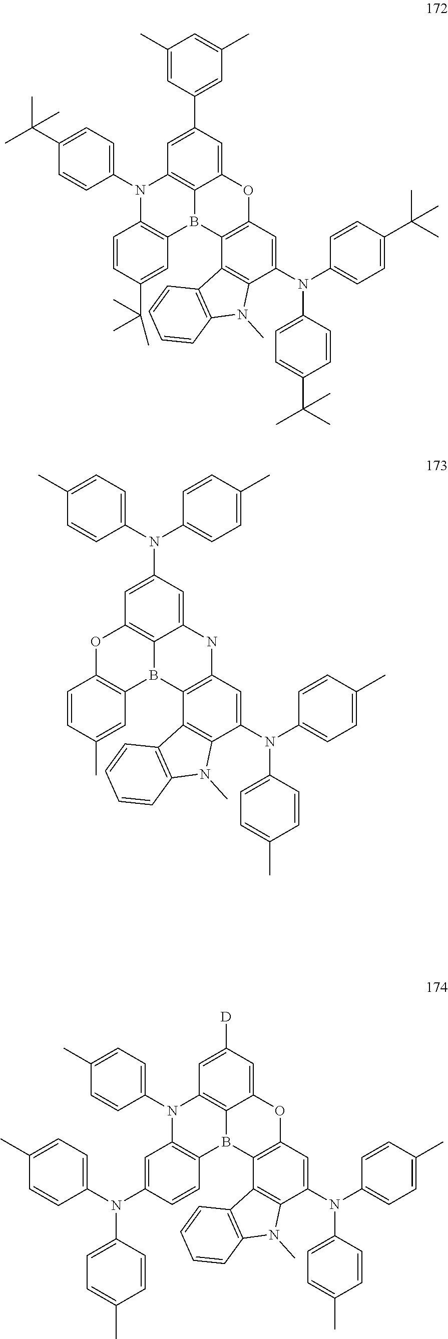

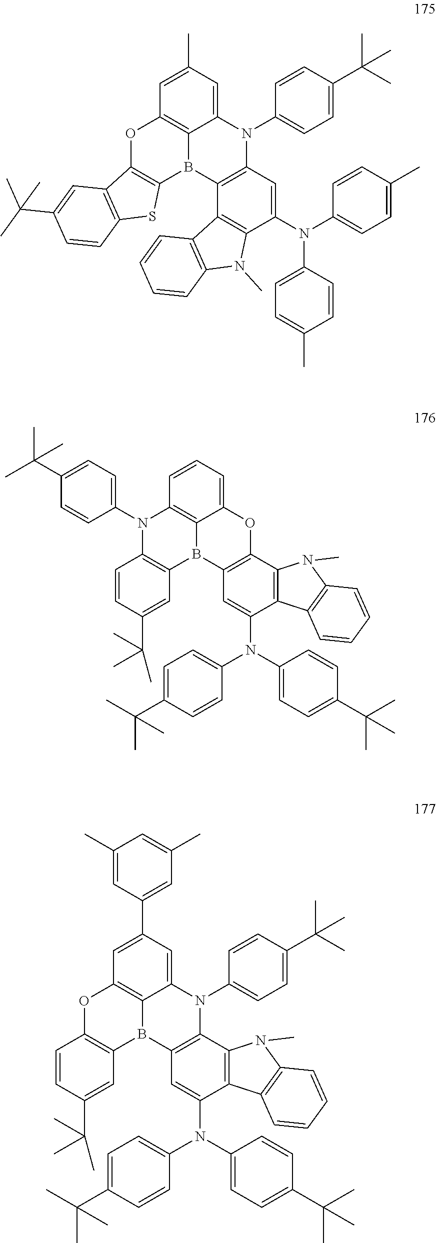

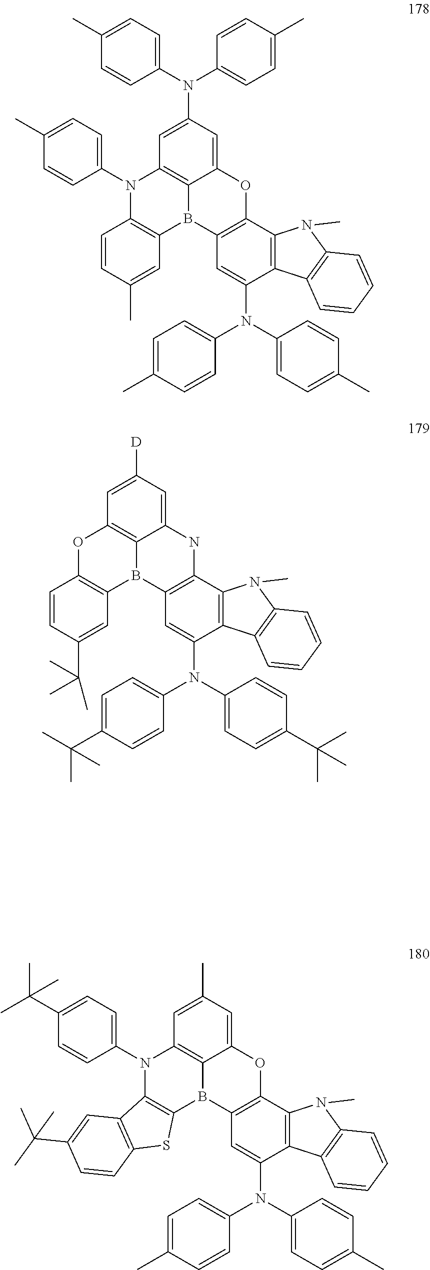

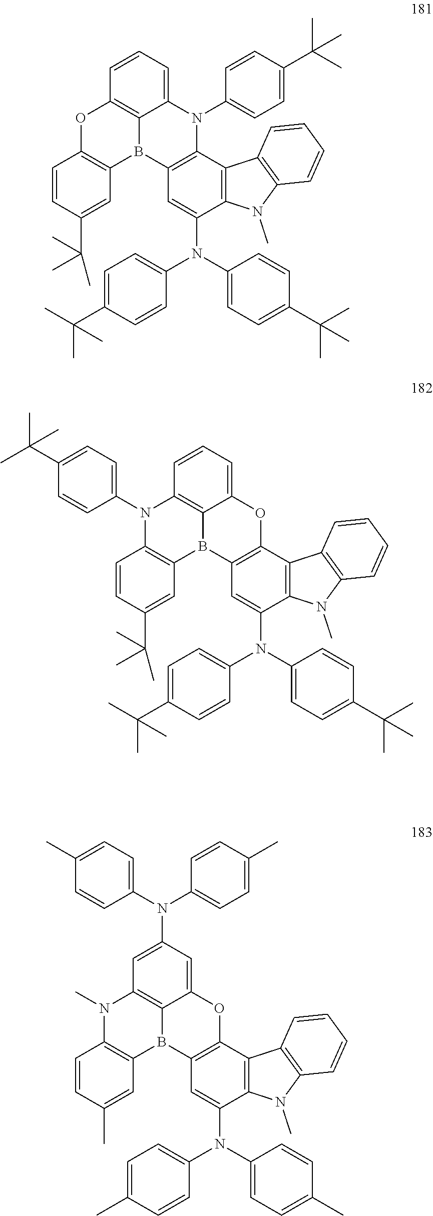

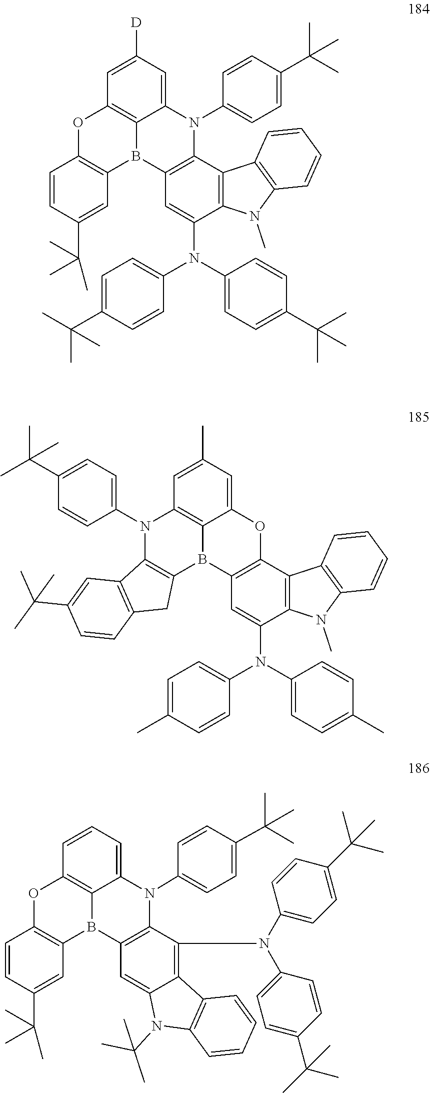

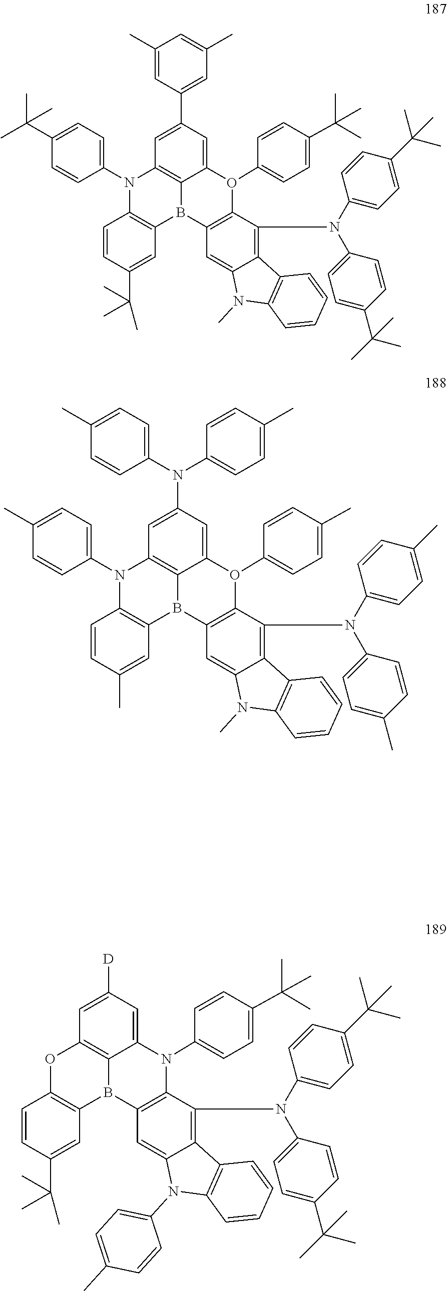

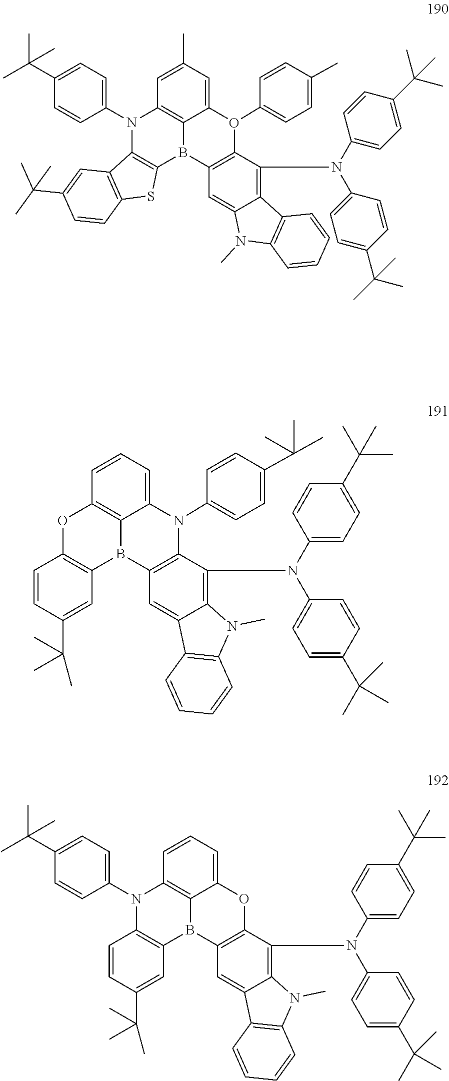

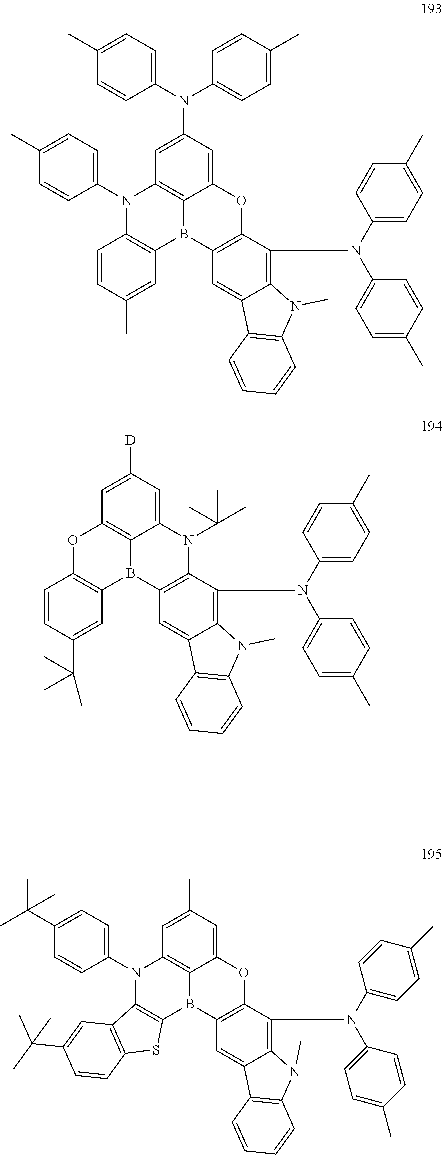

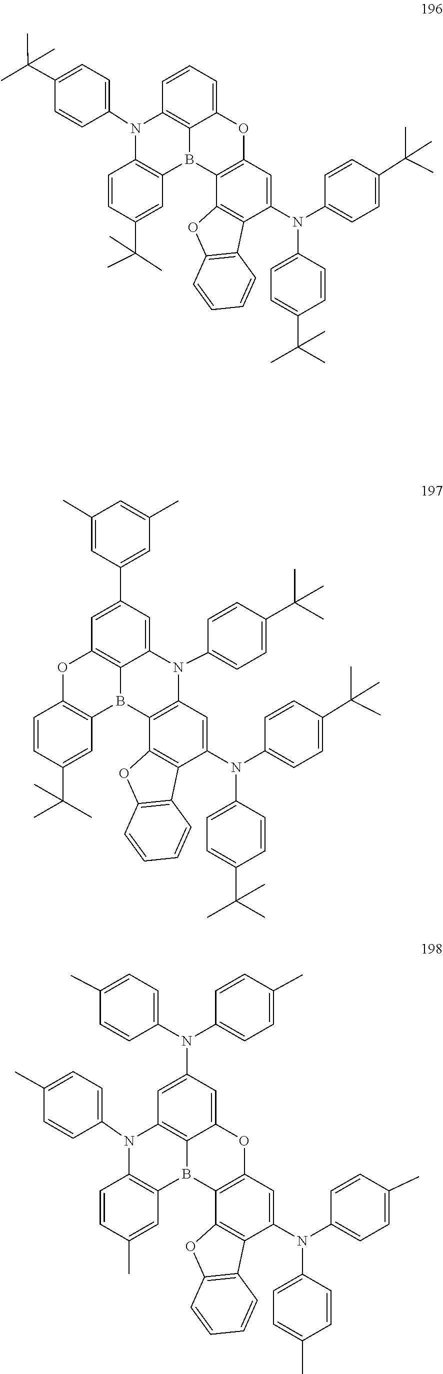

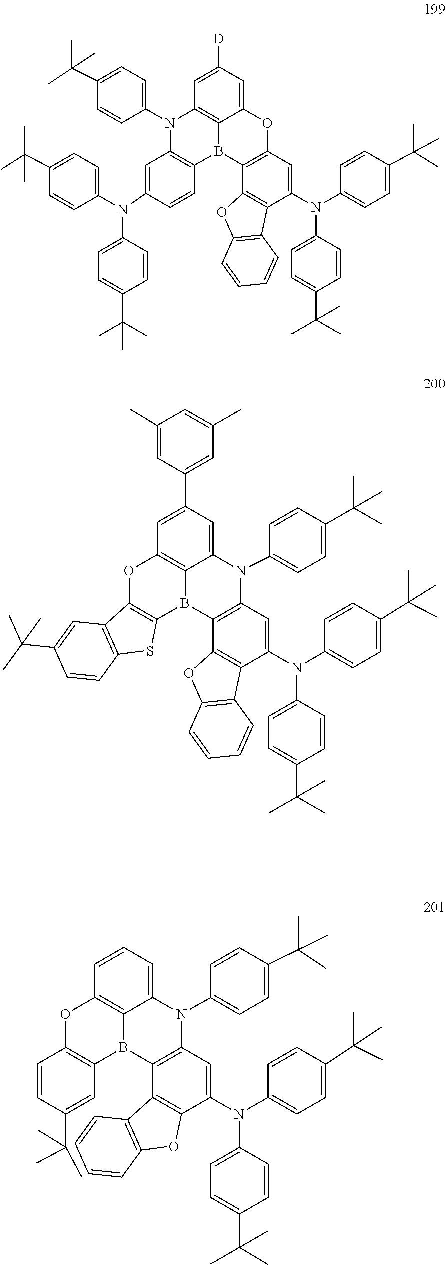

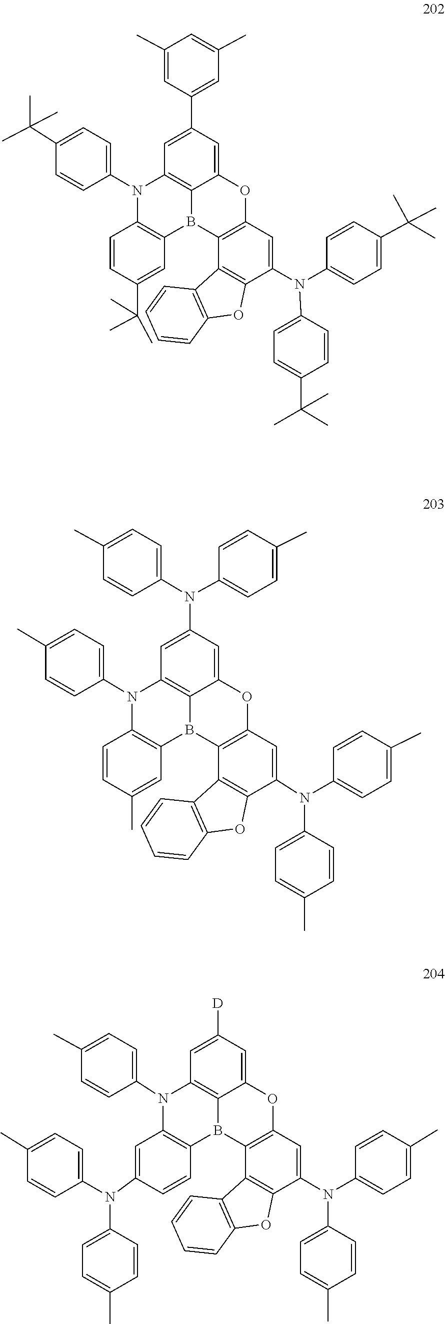

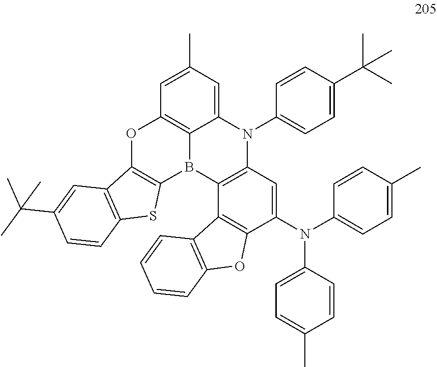 [SMILES: Cc1ccc(N(c2ccc(C)cc2)c2cc3c(c4c2oc2ccccc24)B2c4sc5ccc(C(C)(C)C)cc5c4Oc4cc(C)cc(c42)N3c2ccc(C(C)(C)C)cc2)cc1]

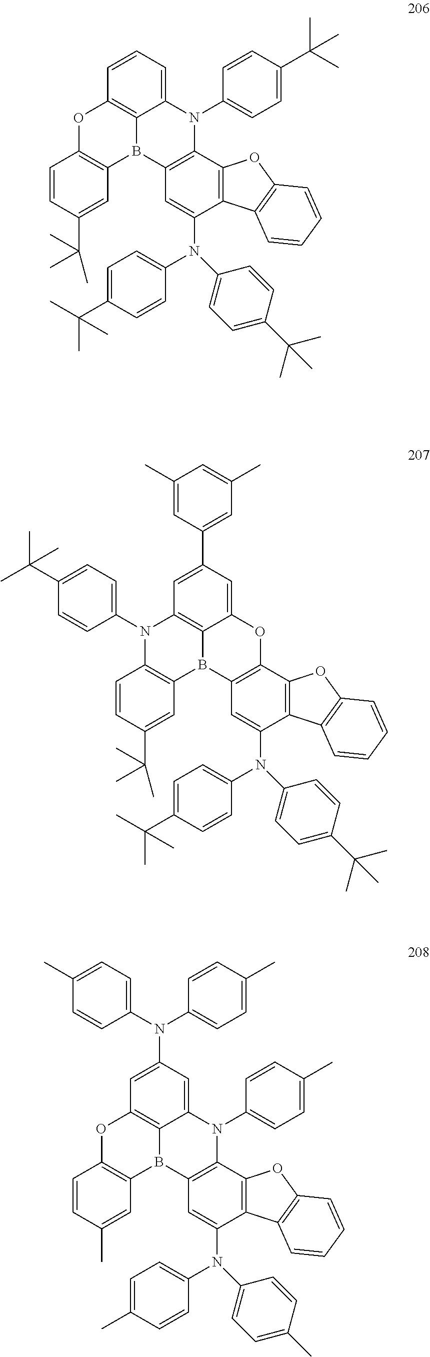

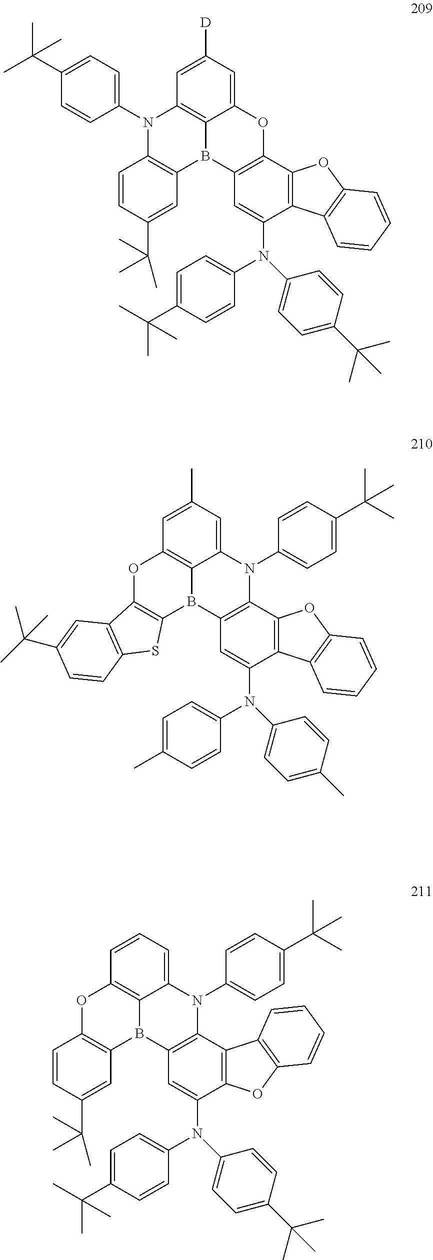 [SMILES: [2H]c1cc2c3c(c1)N(c1ccc(C(C)(C)C)cc1)c1ccc(C(C)(C)C)cc1B3c1cc(N(c3ccc(C(C)(C)C)cc3)c3ccc(C(C)(C)C)cc3)c3c(oc4ccccc43)c1O2 ; Cc1ccc(N(c2ccc(C)cc2)c2cc3c(c4oc5ccccc5c24)N(c2ccc(C(C)(C)C)cc2)c2cc(C)cc4c2B3c2sc3ccc(C(C)(C)C)cc3c2O4)cc1 ; CC(C)(C)c1ccc(N(c2ccc(C(C)(C)C)cc2)c2cc3c(c4c2oc2ccccc24)N(c2ccc(C(C)(C)C)cc2)c2cccc4c2B3c2cc(C(C)(C)C)ccc2O4)cc1]

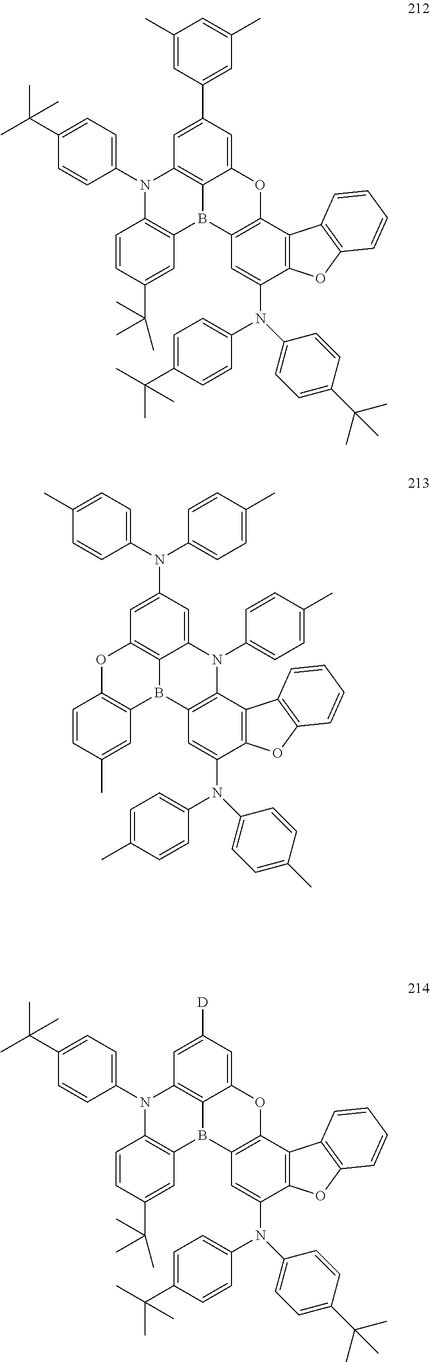 [SMILES: Cc1cc(C)cc(-c2cc3c4c(c2)N(c2ccc(C(C)(C)C)cc2)c2ccc(C(C)(C)C)cc2B4c2cc(N(c4ccc(C(C)(C)C)cc4)c4ccc(C(C)(C)C)cc4)c4oc5ccccc5c4c2O3)c1 ; Cc1ccc(N(c2ccc(C)cc2)c2cc3c4c(c2)N(c2ccc(C)cc2)c2c(cc(N(c5ccc(C)cc5)c5ccc(C)cc5)c5oc6ccccc6c25)B4c2cc(C)ccc2O3)cc1 ; [2H]c1cc2c3c(c1)N(c1ccc(C(C)(C)C)cc1)c1ccc(C(C)(C)C)cc1B3c1cc(N(c3ccc(C(C)(C)C)cc3)c3ccc(C(C)(C)C)cc3)c3oc4ccccc4c3c1O2]

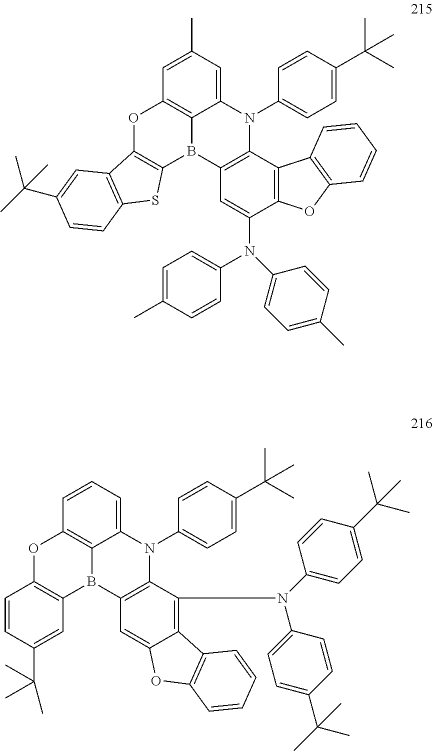 [SMILES: Cc1ccc(N(c2ccc(C)cc2)c2cc3c(c4c2oc2ccccc24)N(c2ccc(C(C)(C)C)cc2)c2cc(C)cc4c2B3c2sc3ccc(C(C)(C)C)cc3c2O4)cc1 ; CC(C)(C)c1ccc(N2c3cccc4c3B(c3cc(C(C)(C)C)ccc3O4)c3cc4oc5ccccc5c4c(N(c4ccc(C(C)(C)C)cc4)c4ccc(C(C)(C)C)cc4)c32)cc1]

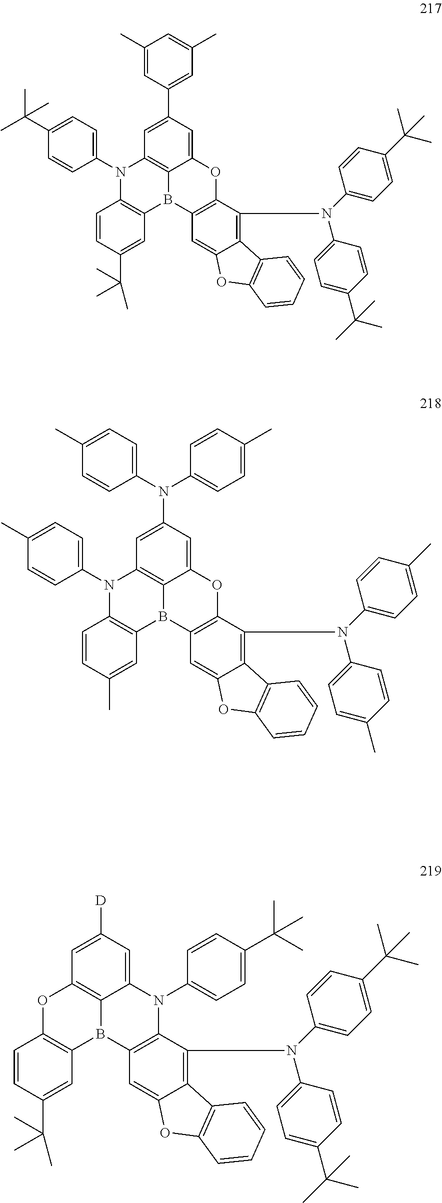

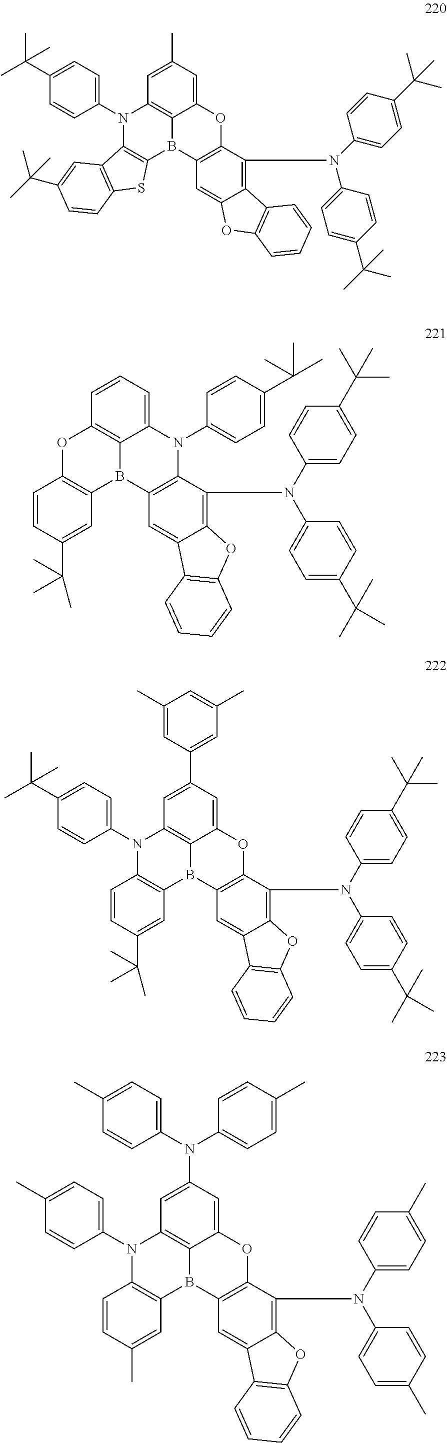

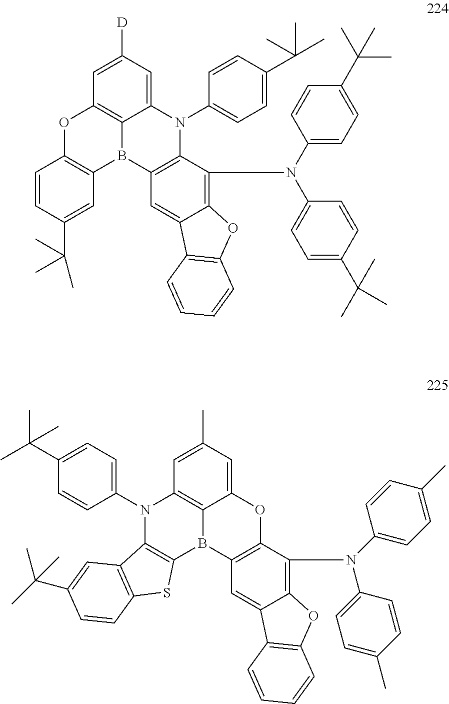

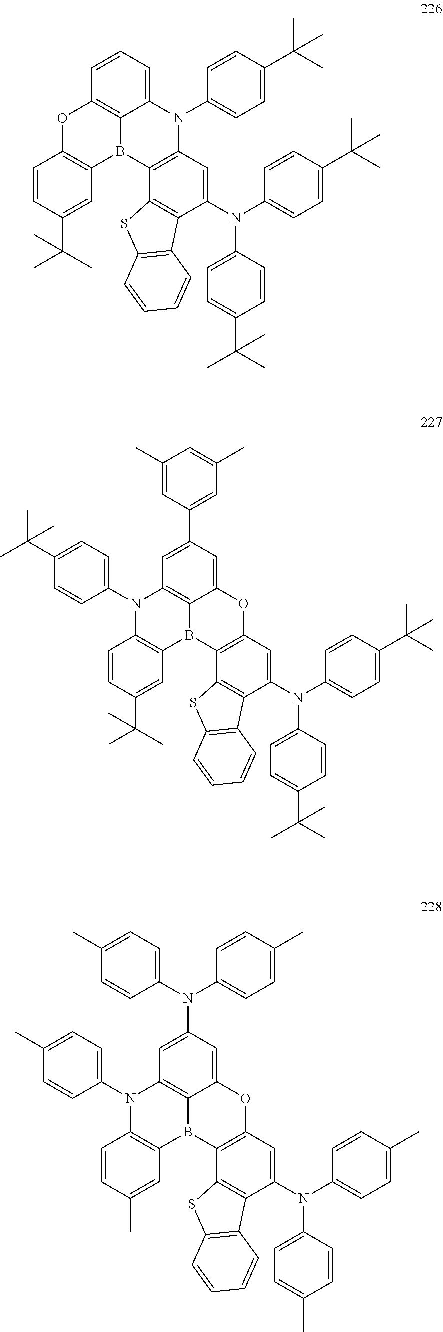

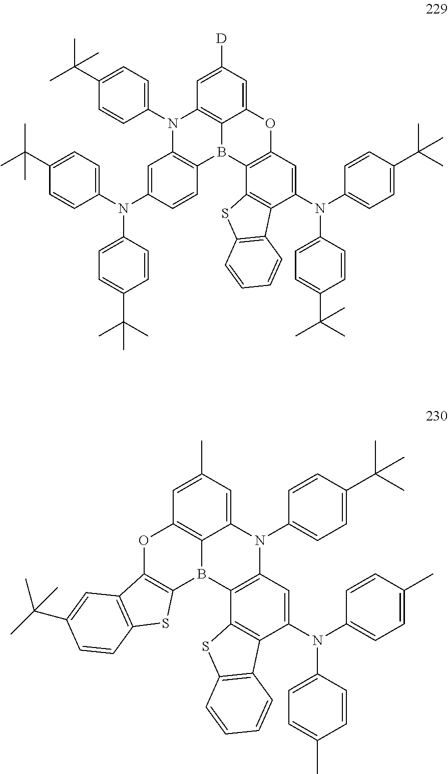

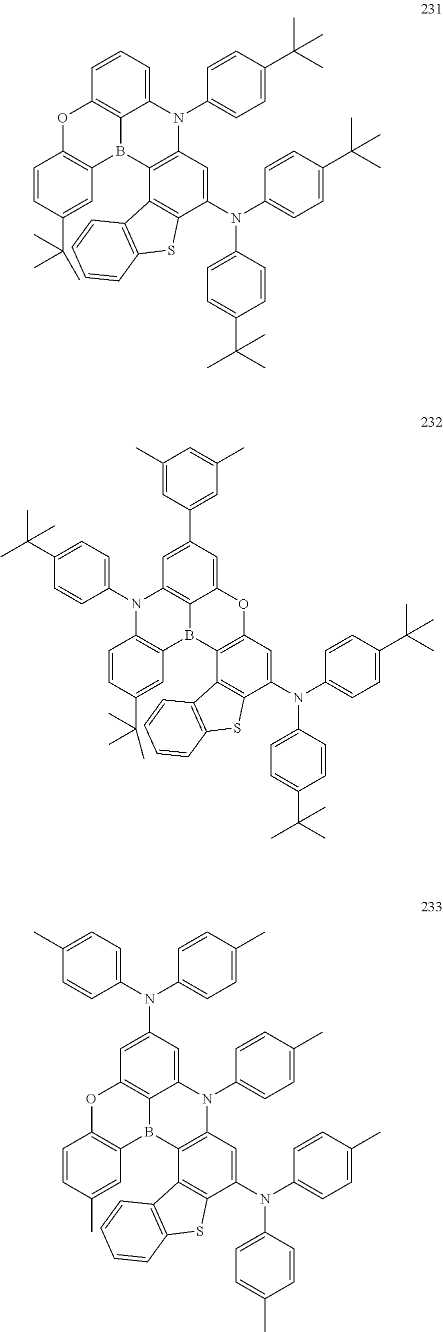

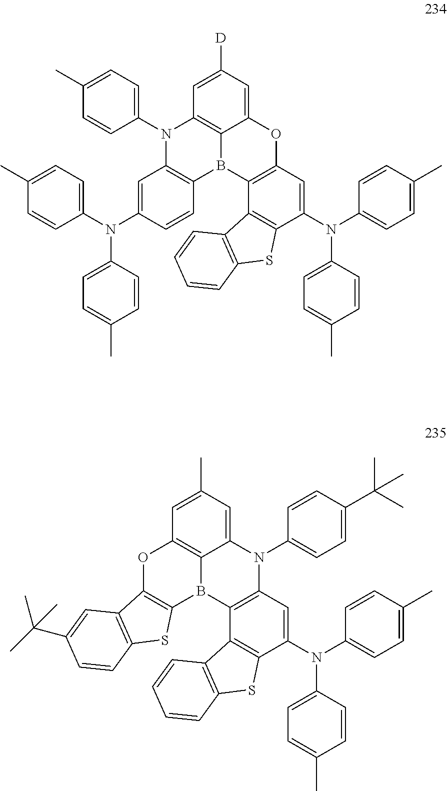

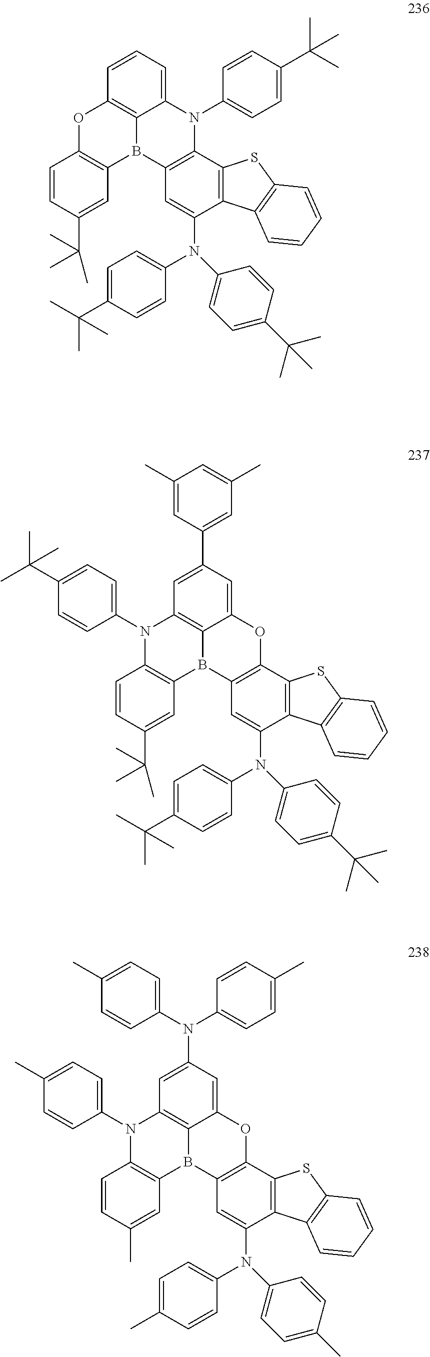

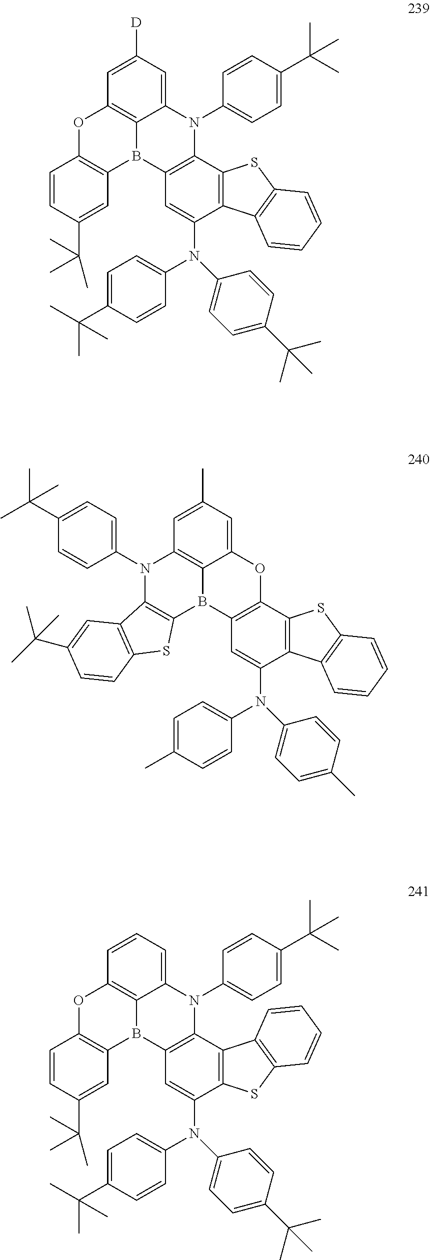

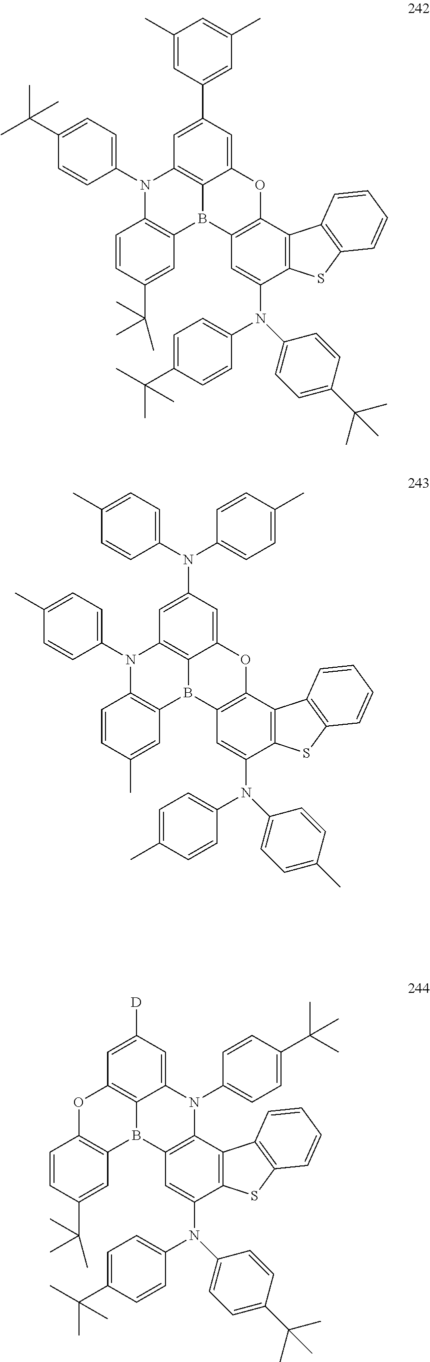 [SMILES: Cc1cc(C)cc(-c2cc3c4c(c2)N(c2ccc(C(C)(C)C)cc2)c2ccc(C(C)(C)C)cc2B4c2cc(N(c4ccc(C(C)(C)C)cc4)c4ccc(C(C)(C)C)cc4)c4sc5ccccc5c4c2O3)c1 ; Cc1ccc(N(c2ccc(C)cc2)c2cc3c4c(c2)N(c2ccc(C)cc2)c2ccc(C)cc2B4c2cc(N(c4ccc(C)cc4)c4ccc(C)cc4)c4sc5ccccc5c4c2O3)cc1 ; [2H]c1cc2c3c(c1)N(c1ccc(C(C)(C)C)cc1)c1c(cc(N(c4ccc(C(C)(C)C)cc4)c4ccc(C(C)(C)C)cc4)c4sc5ccccc5c14)B3c1cc(C(C)(C)C)ccc1O2]

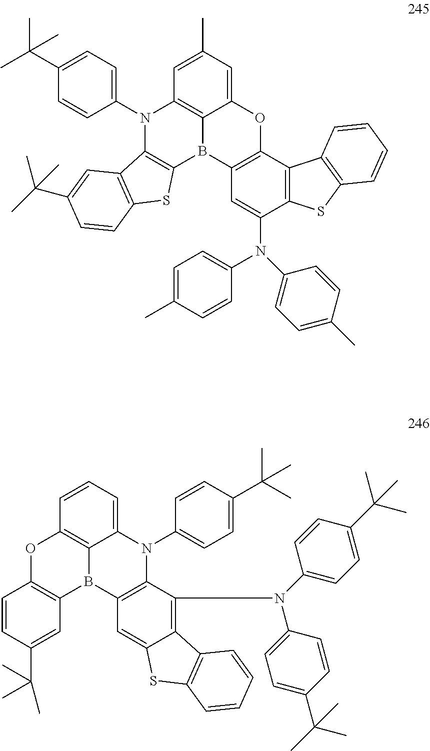 [SMILES: Cc1ccc(N(c2ccc(C)cc2)c2cc3c(c4c2sc2ccccc24)Oc2cc(C)cc4c2B3c2sc3ccc(C(C)(C)C)cc3c2N4c2ccc(C(C)(C)C)cc2)cc1 ; CC(C)(C)c1ccc(N2c3cccc4c3B(c3cc(C(C)(C)C)ccc3O4)c3cc4sc5ccccc5c4c(N(c4ccc(C(C)(C)C)cc4)c4ccc(C(C)(C)C)cc4)c32)cc1]

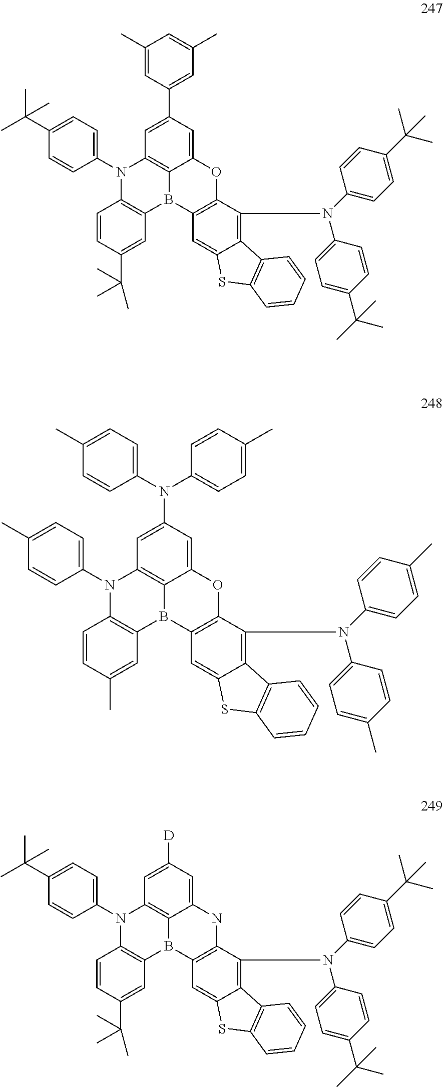

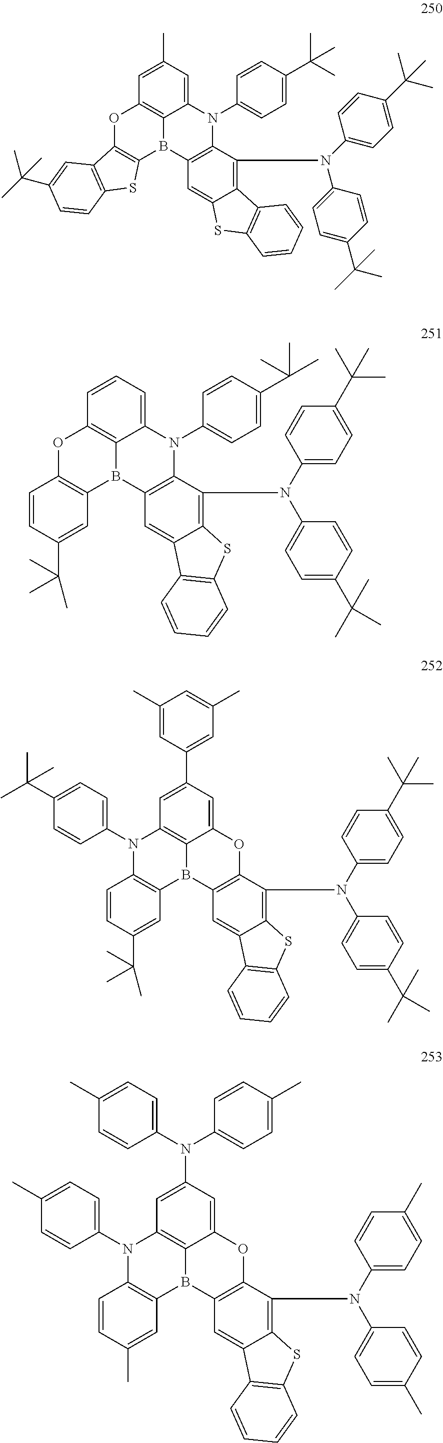

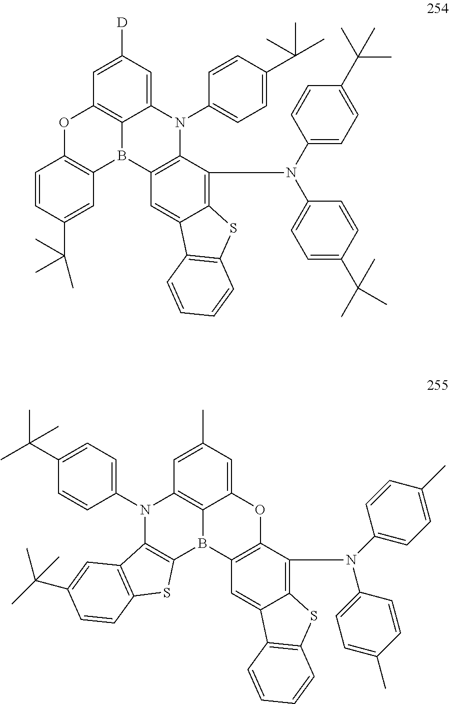

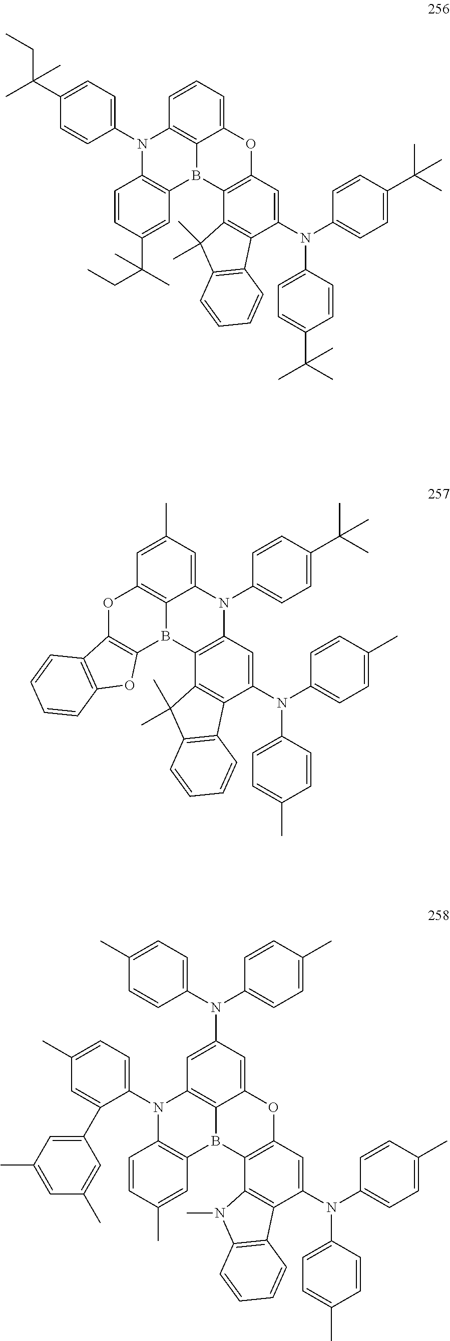

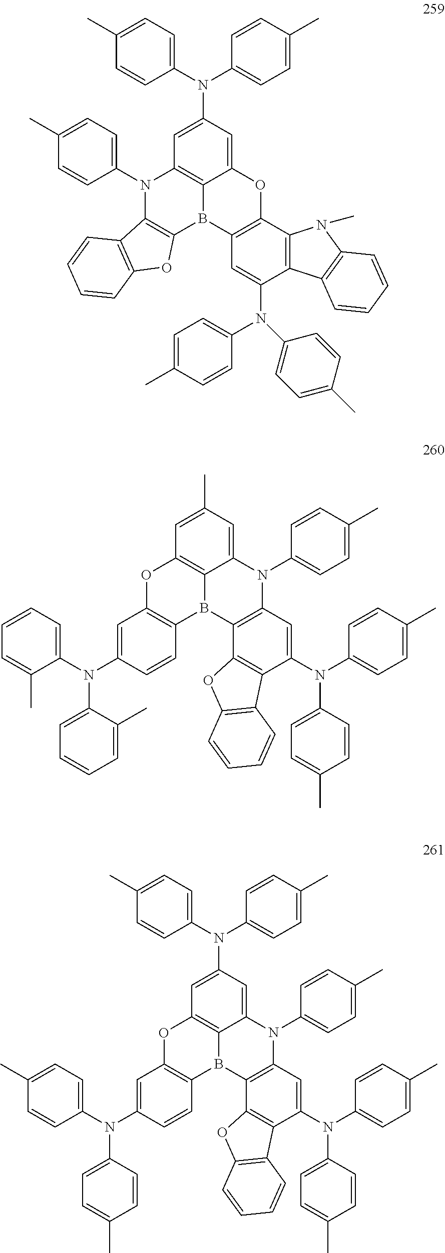

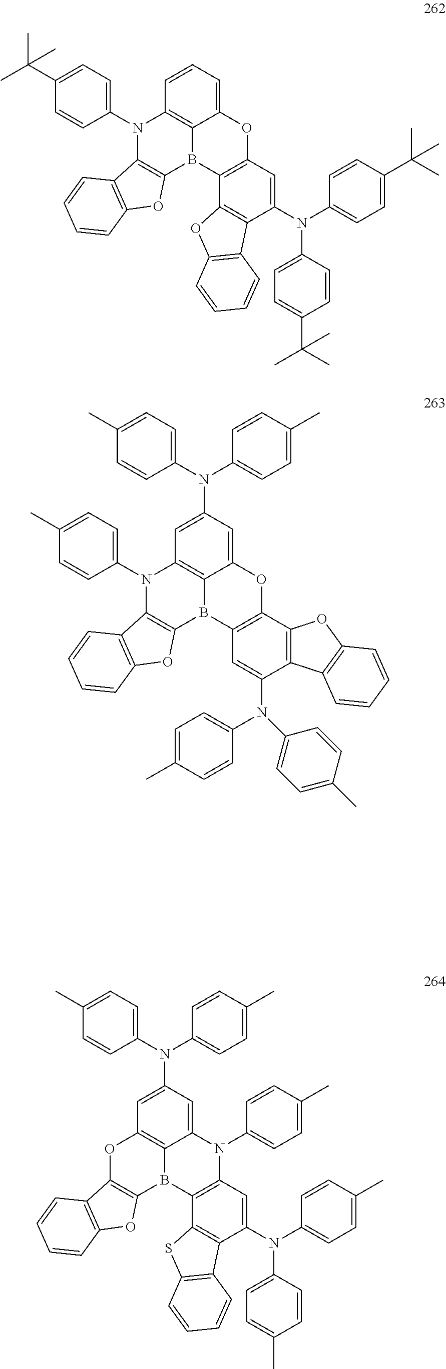

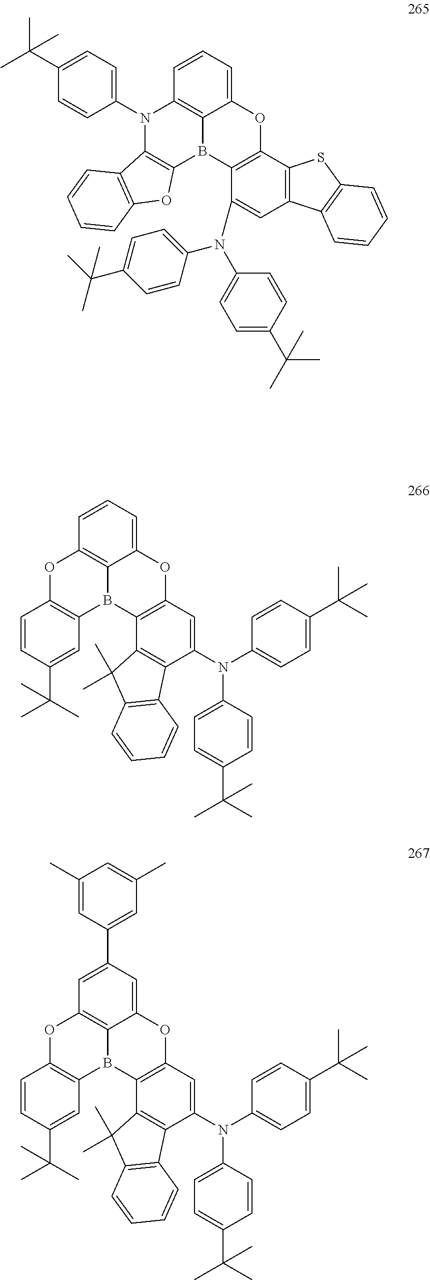 [SMILES: CC(C)(C)c1ccc(N(c2ccc(C(C)(C)C)cc2)c2cc3c(sc4ccccc43)c3c2B2c4oc5ccccc5c4N(c4ccc(C(C)(C)C)cc4)c4cccc(c42)O3)cc1 ; CC(C)(C)c1ccc(N(c2ccc(C(C)(C)C)cc2)c2cc3c(c4c2-c2ccccc2C4(C)C)B2c4cc(C(C)(C)C)ccc4Oc4cccc(c42)O3)cc1 ; Cc1cc(C)cc(-c2cc3c4c(c2)Oc2cc(N(c5ccc(C(C)(C)C)cc5)c5ccc(C(C)(C)C)cc5)c5c(c2B4c2cc(C(C)(C)C)ccc2O3)C(C)(C)c2ccccc2-5)c1]

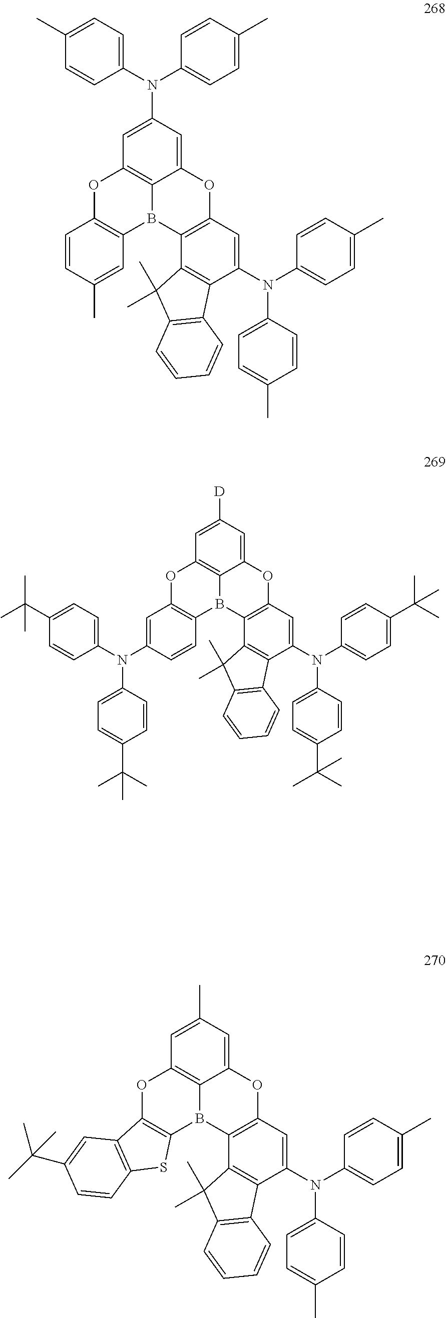

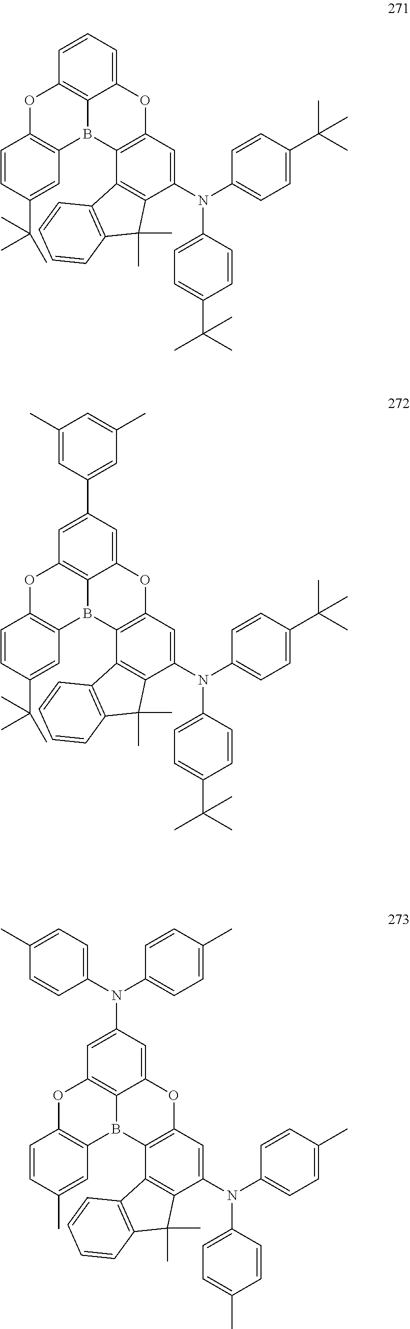

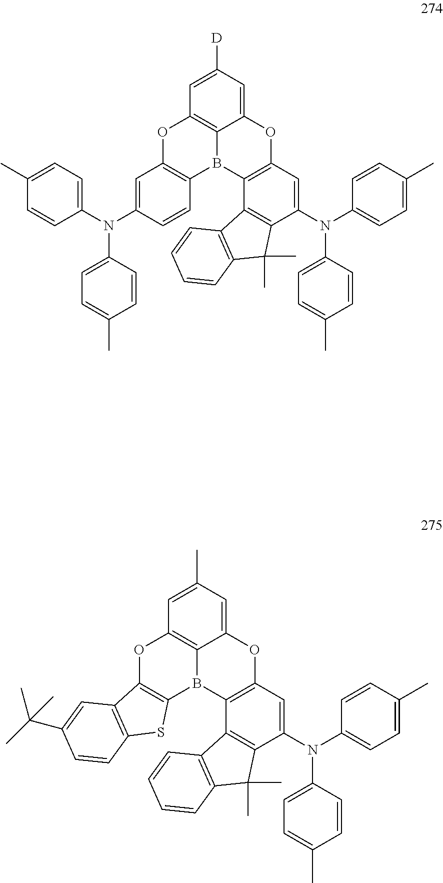

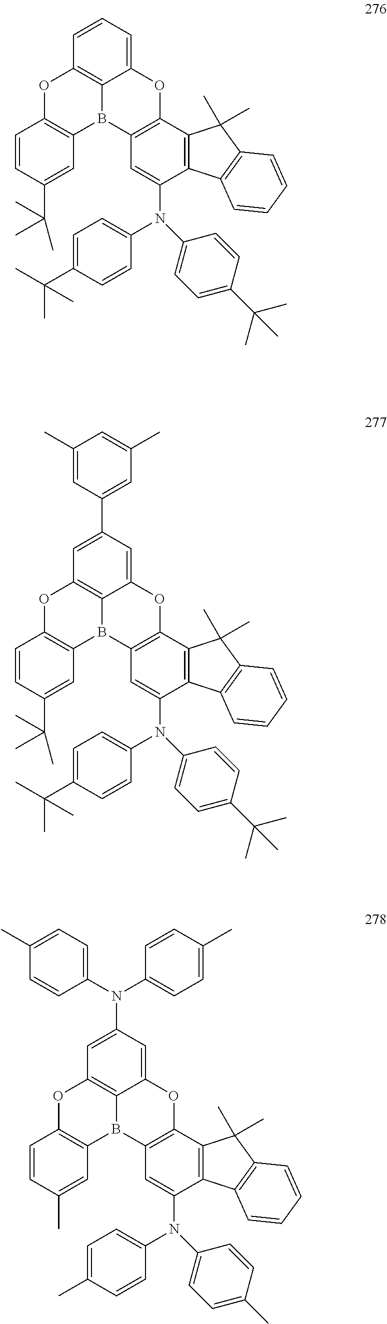 [SMILES: CC(C)(C)c1ccc(N(c2ccc(C(C)(C)C)cc2)c2cc3c(c4c2-c2ccccc2C4(C)C)Oc2cccc4c2B3c2cc(C(C)(C)C)ccc2O4)cc1 ; Cc1cc(C)cc(-c2cc3c4c(c2)Oc2c(cc(N(c5ccc(C(C)(C)C)cc5)c5ccc(C(C)(C)C)cc5)c5c2C(C)(C)c2ccccc2-5)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5c2C(C)(C)c2ccccc2-5)B4c2cc(C)ccc2O3)cc1]

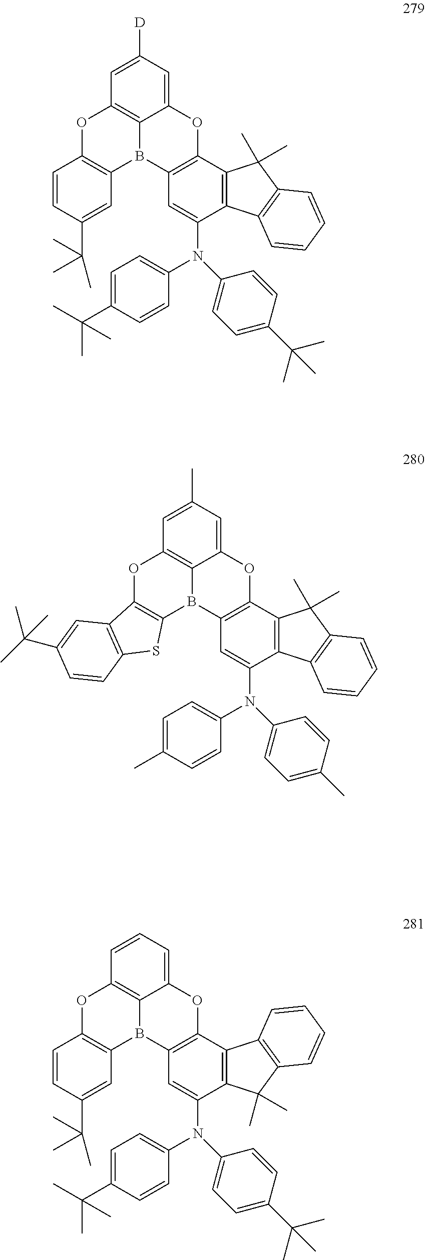 [SMILES: [2H]c1cc2c3c(c1)Oc1c(cc(N(c4ccc(C(C)(C)C)cc4)c4ccc(C(C)(C)C)cc4)c4c1C(C)(C)c1ccccc1-4)B3c1cc(C(C)(C)C)ccc1O2 ; Cc1ccc(N(c2ccc(C)cc2)c2cc3c(c4c2-c2ccccc2C4(C)C)Oc2cc(C)cc4c2B3c2sc3ccc(C(C)(C)C)cc3c2O4)cc1 ; CC(C)(C)c1ccc(N(c2ccc(C(C)(C)C)cc2)c2cc3c(c4c2C(C)(C)c2ccccc2-4)Oc2cccc4c2B3c2cc(C(C)(C)C)ccc2O4)cc1]

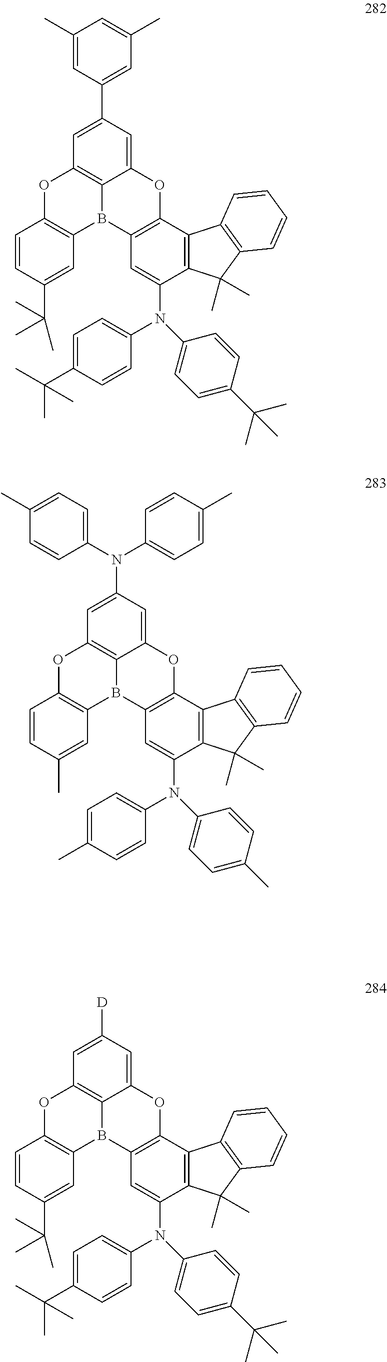 [SMILES: Cc1cc(C)cc(-c2cc3c4c(c2)Oc2c(cc(N(c5ccc(C(C)(C)C)cc5)c5ccc(C(C)(C)C)cc5)c5c2-c2ccccc2C5(C)C)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5c2-c2ccccc2C5(C)C)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4c1-c1ccccc1C4(C)C)B3c1cc(C(C)(C)C)ccc1O2]

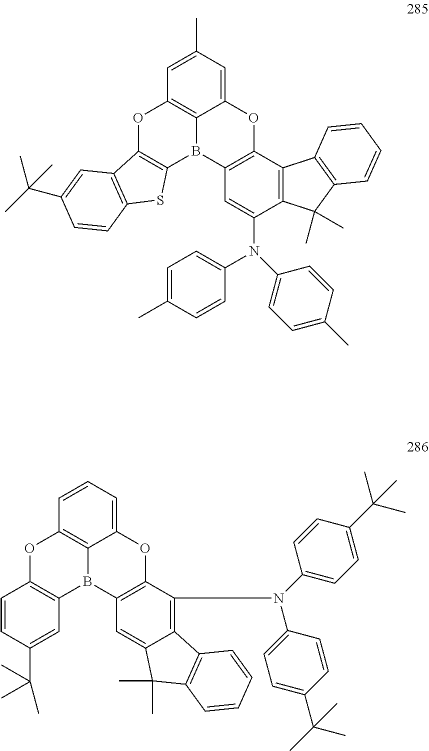 [SMILES: Cc1ccc(N(c2ccc(C)cc2)c2cc3c(c4c2C(C)(C)c2ccccc2-4)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4c2-c2ccccc2C4(C)C)B2c4cc(C(C)(C)C)ccc4Oc4cccc(c42)O3)cc1]

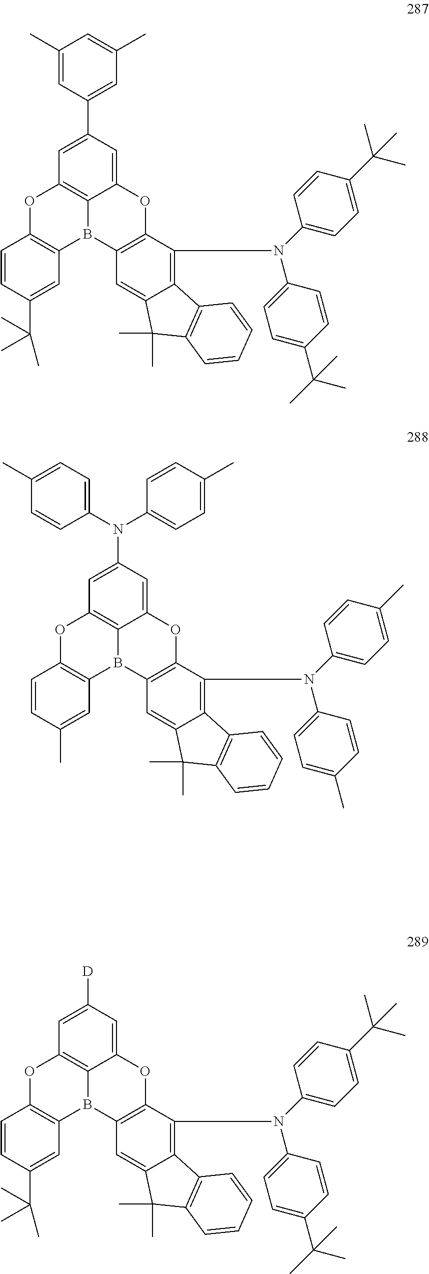

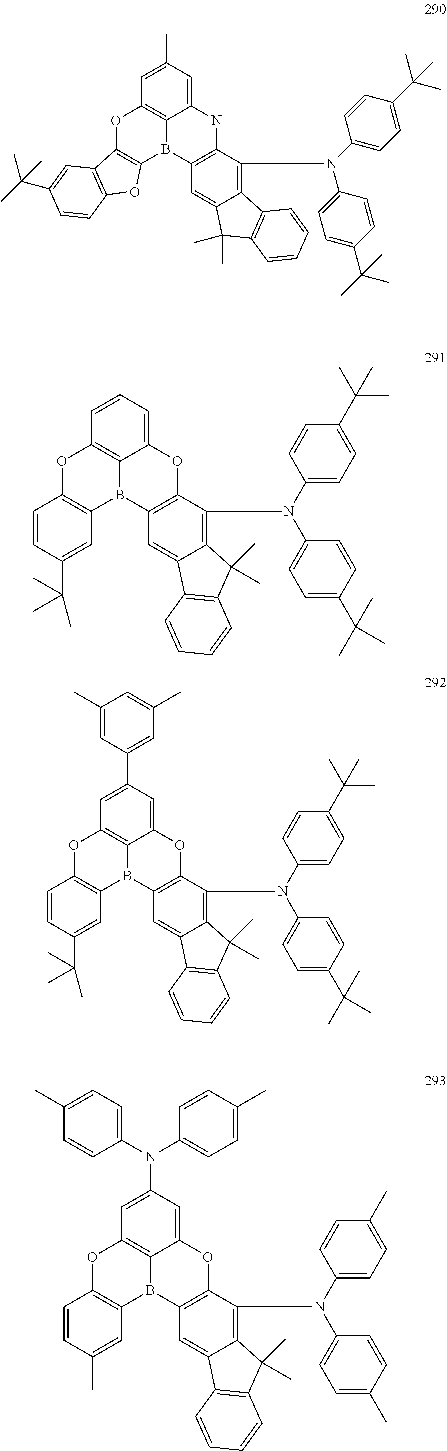

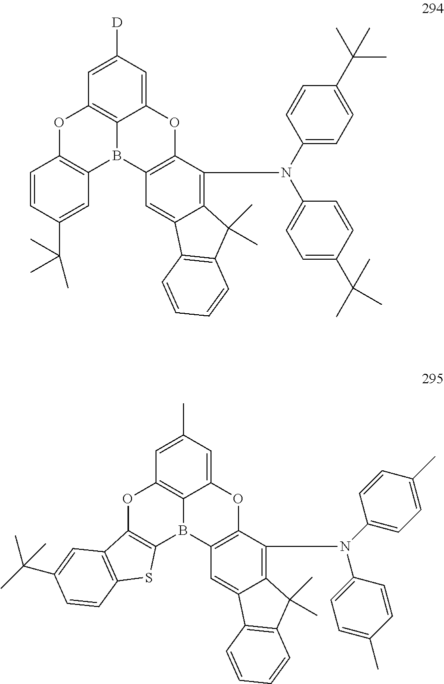

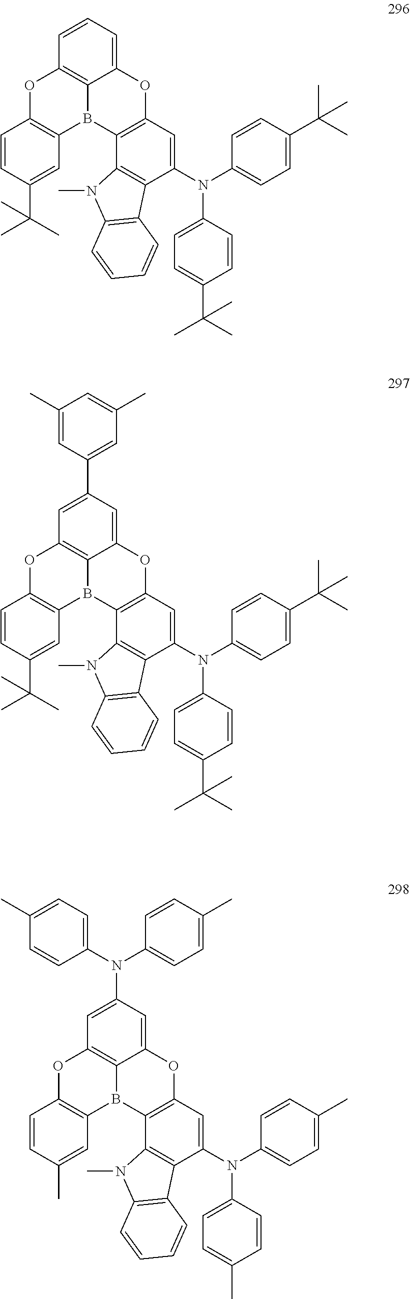

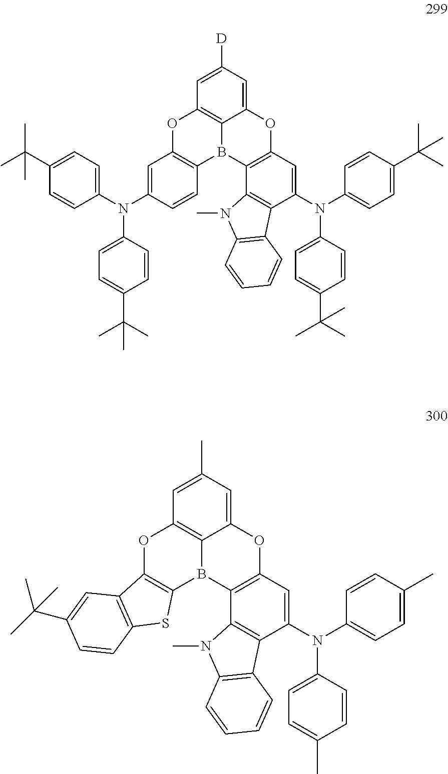

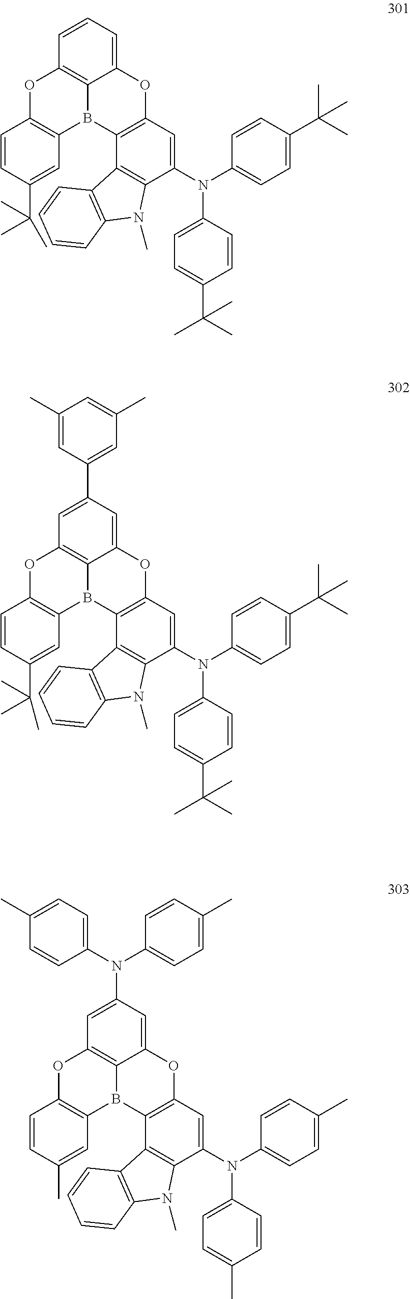

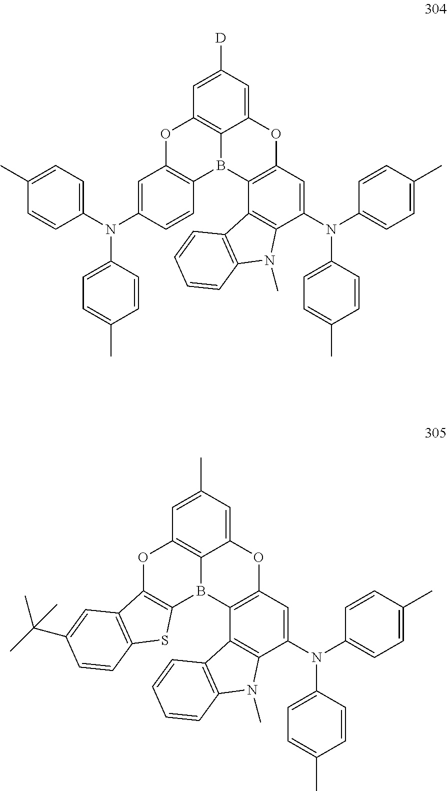

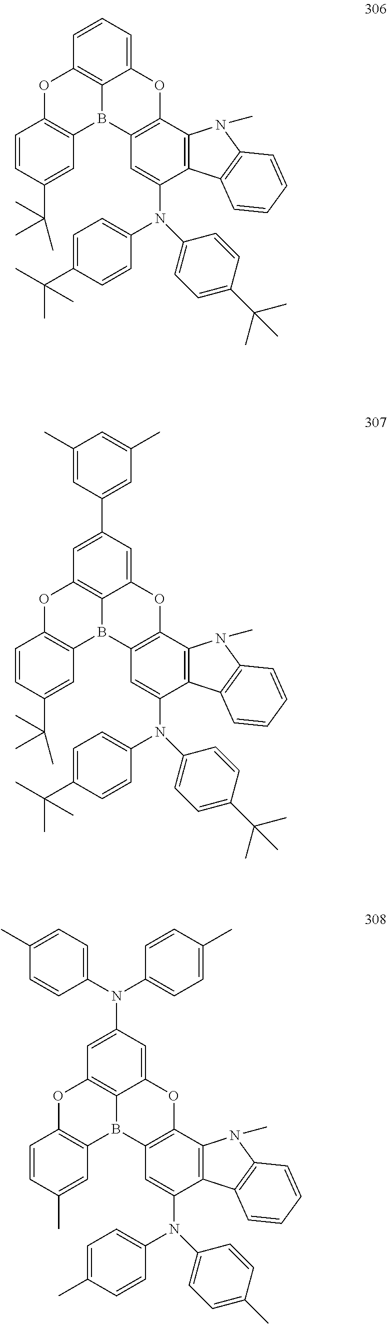 [SMILES: Cn1c2ccccc2c2c(N(c3ccc(C(C)(C)C)cc3)c3ccc(C(C)(C)C)cc3)cc3c(c21)Oc1cccc2c1B3c1cc(C(C)(C)C)ccc1O2 ; Cc1cc(C)cc(-c2cc3c4c(c2)Oc2c(cc(N(c5ccc(C(C)(C)C)cc5)c5ccc(C(C)(C)C)cc5)c5c6ccccc6n(C)c25)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5c6ccccc6n(C)c25)B4c2cc(C)ccc2O3)cc1]

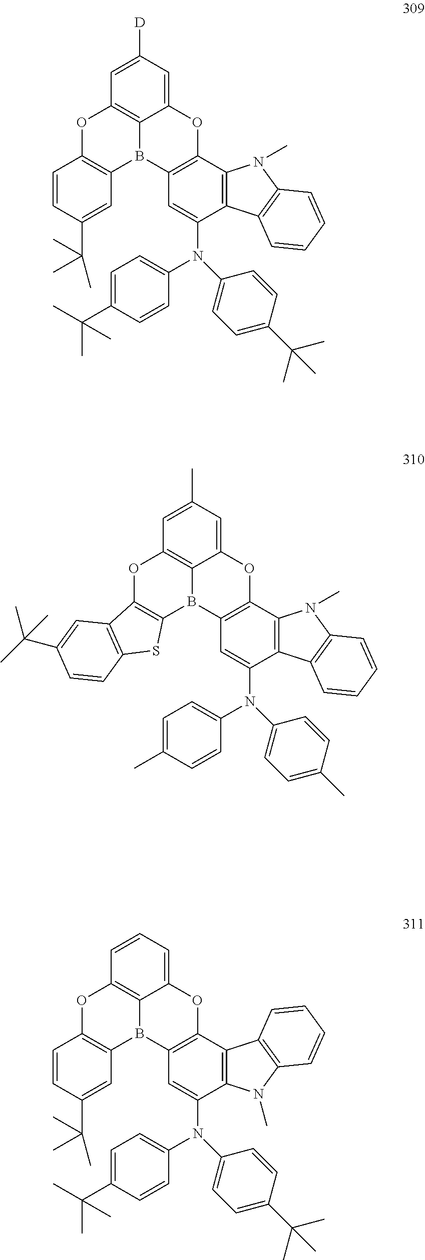 [SMILES: [2H]c1cc2c3c(c1)Oc1c(cc(N(c4ccc(C(C)(C)C)cc4)c4ccc(C(C)(C)C)cc4)c4c5ccccc5n(C)c14)B3c1cc(C(C)(C)C)ccc1O2 ; Cc1ccc(N(c2ccc(C)cc2)c2cc3c(c4c2c2ccccc2n4C)Oc2cc(C)cc4c2B3c2sc3ccc(C(C)(C)C)cc3c2O4)cc1 ; Cn1c2ccccc2c2c3c(cc(N(c4ccc(C(C)(C)C)cc4)c4ccc(C(C)(C)C)cc4)c21)B1c2cc(C(C)(C)C)ccc2Oc2cccc(c21)O3]

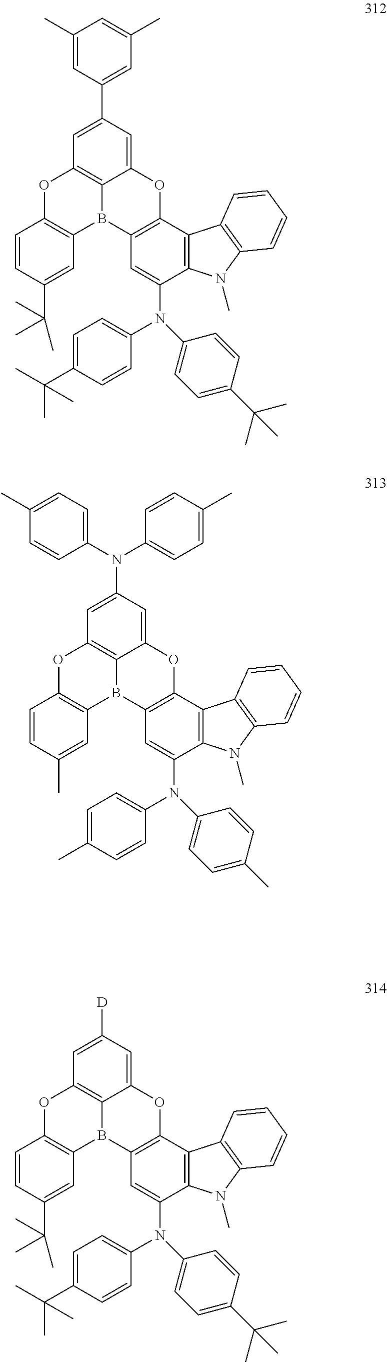 [SMILES: Cc1cc(C)cc(-c2cc3c4c(c2)Oc2c(cc(N(c5ccc(C(C)(C)C)cc5)c5ccc(C(C)(C)C)cc5)c5c2c2ccccc2n5C)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5c2c2ccccc2n5C)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4c1c1ccccc1n4C)B3c1cc(C(C)(C)C)ccc1O2]

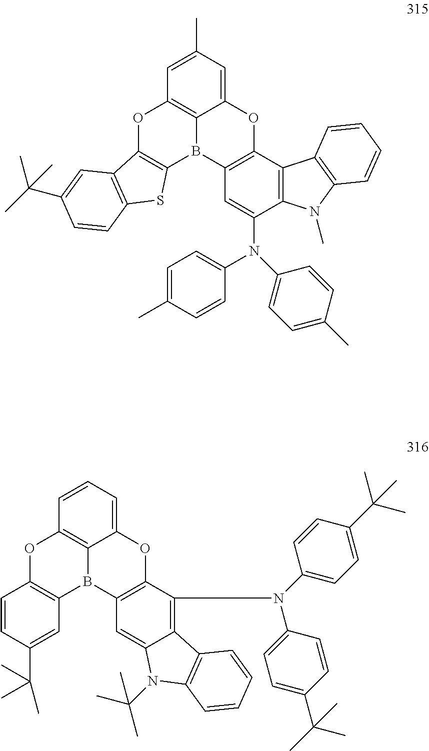 [SMILES: Cc1ccc(N(c2ccc(C)cc2)c2cc3c(c4c5ccccc5n(C)c24)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4c2c2ccccc2n4C(C)(C)C)B2c4cc(C(C)(C)C)ccc4Oc4cccc(c42)O3)cc1]

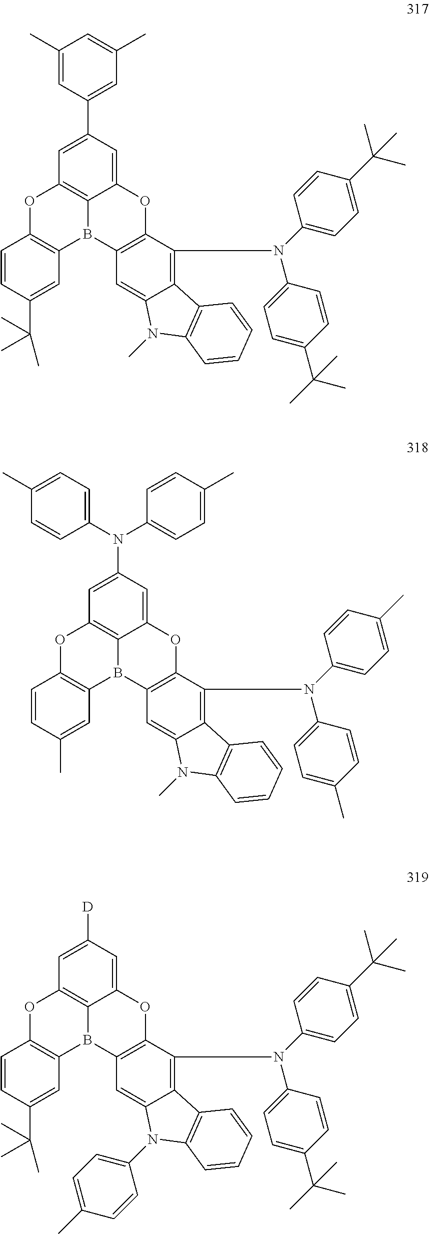

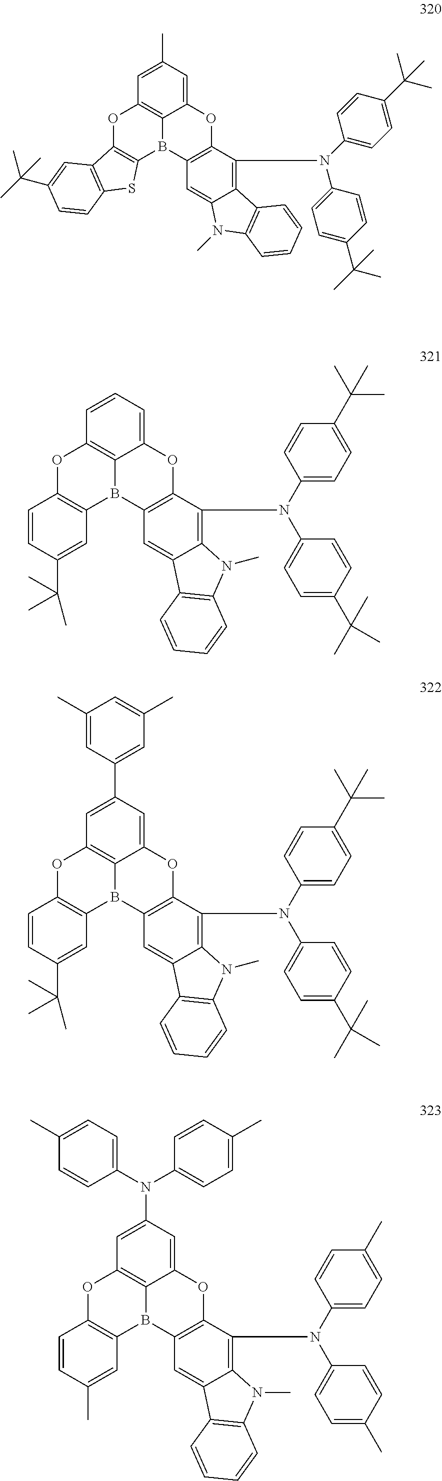

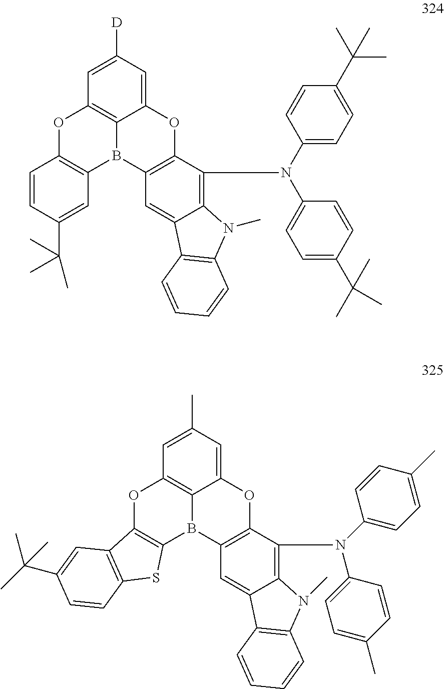

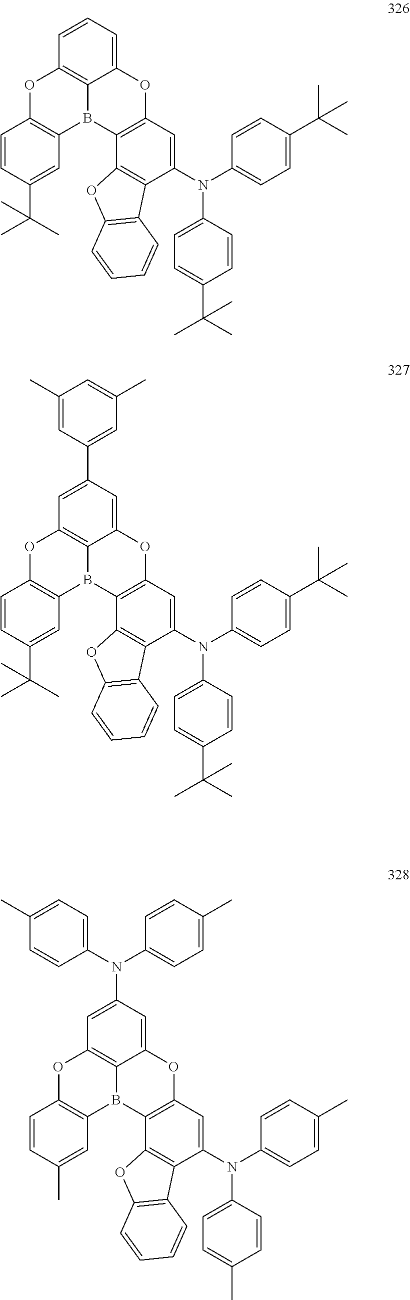

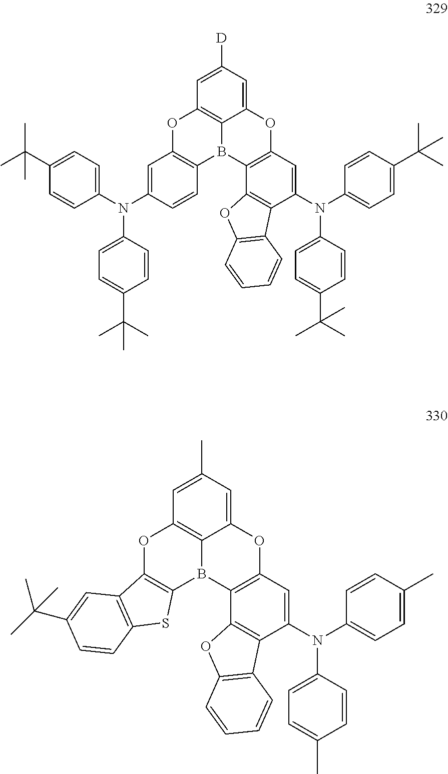

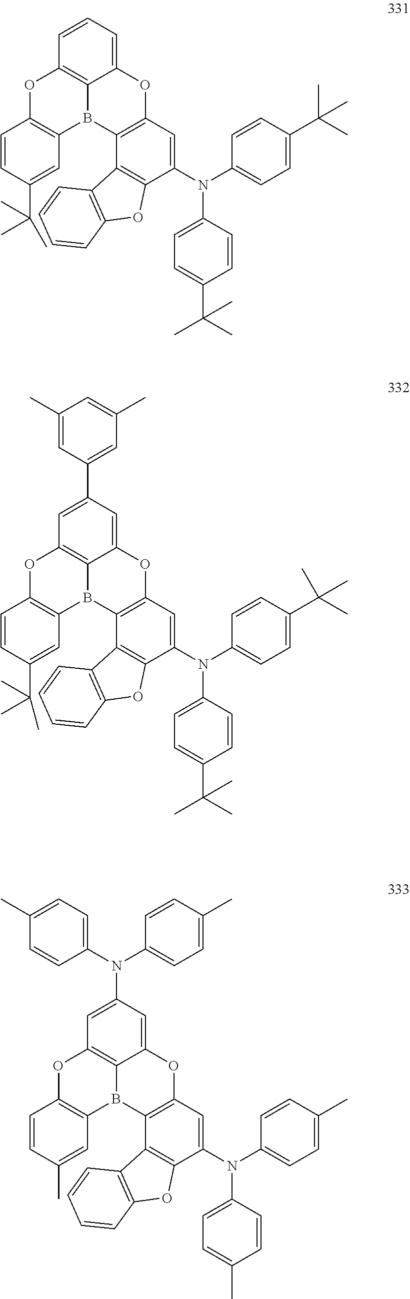

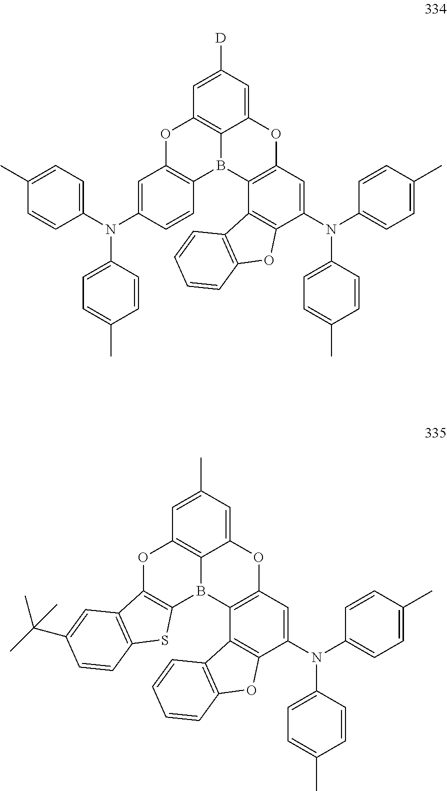

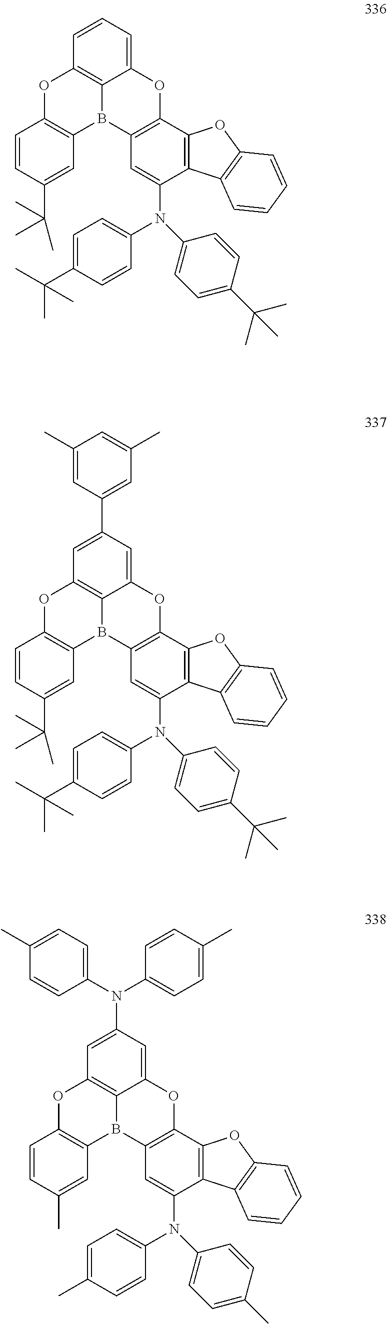 [SMILES: CC(C)(C)c1ccc(N(c2ccc(C(C)(C)C)cc2)c2cc3c(c4oc5ccccc5c24)Oc2cccc4c2B3c2cc(C(C)(C)C)ccc2O4)cc1 ; Cc1cc(C)cc(-c2cc3c4c(c2)Oc2c(cc(N(c5ccc(C(C)(C)C)cc5)c5ccc(C(C)(C)C)cc5)c5c2oc2ccccc25)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5c2oc2ccccc25)B4c2cc(C)ccc2O3)cc1]

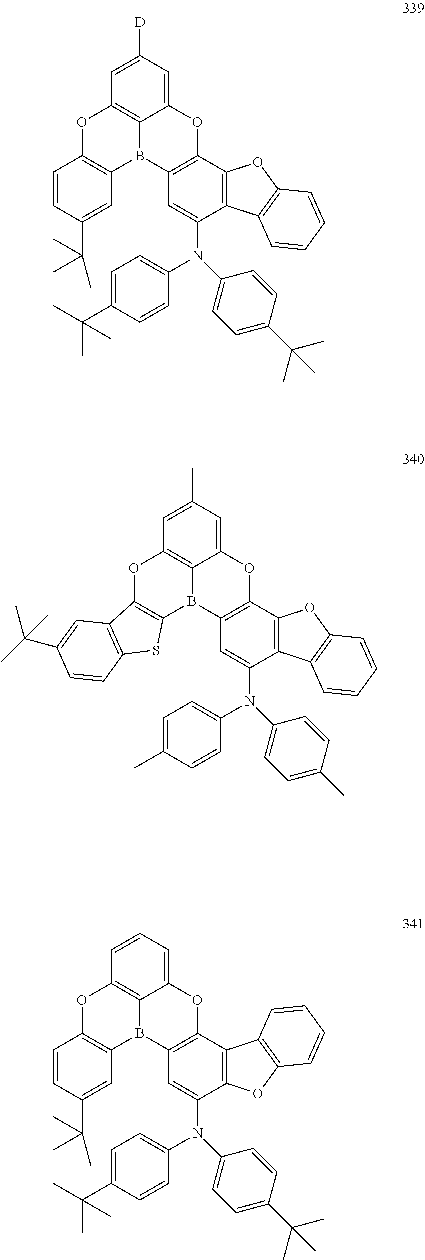 [SMILES: [2H]c1cc2c3c(c1)Oc1c(cc(N(c4ccc(C(C)(C)C)cc4)c4ccc(C(C)(C)C)cc4)c4c1oc1ccccc14)B3c1cc(C(C)(C)C)ccc1O2 ; Cc1ccc(N(c2ccc(C)cc2)c2cc3c(c4oc5ccccc5c24)Oc2cc(C)cc4c2B3c2sc3ccc(C(C)(C)C)cc3c2O4)cc1 ; CC(C)(C)c1ccc(N(c2ccc(C(C)(C)C)cc2)c2cc3c(c4c2oc2ccccc24)Oc2cccc4c2B3c2cc(C(C)(C)C)ccc2O4)cc1]

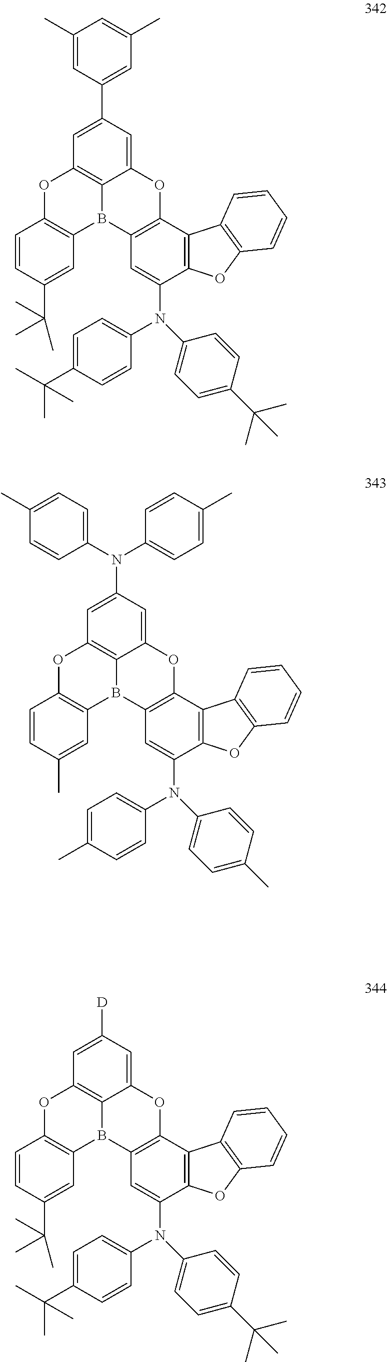 [SMILES: Cc1cc(C)cc(-c2cc3c4c(c2)Oc2c(cc(N(c5ccc(C(C)(C)C)cc5)c5ccc(C(C)(C)C)cc5)c5oc6ccccc6c25)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5oc6ccccc6c25)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4oc5ccccc5c14)B3c1cc(C(C)(C)C)ccc1O2]

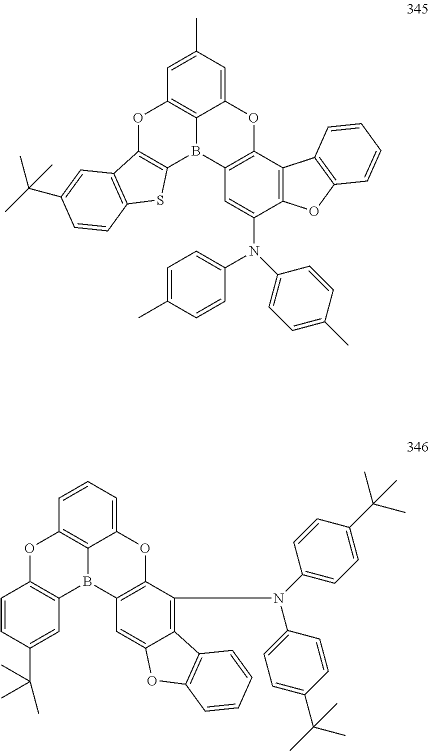 [SMILES: Cc1ccc(N(c2ccc(C)cc2)c2cc3c(c4c2oc2ccccc24)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4oc5ccccc5c24)B2c4cc(C(C)(C)C)ccc4Oc4cccc(c42)O3)cc1]

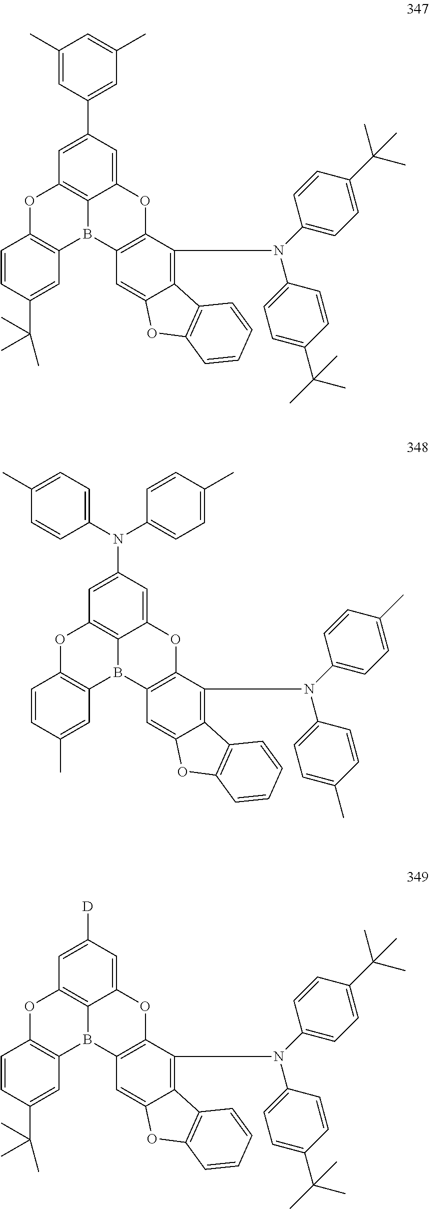

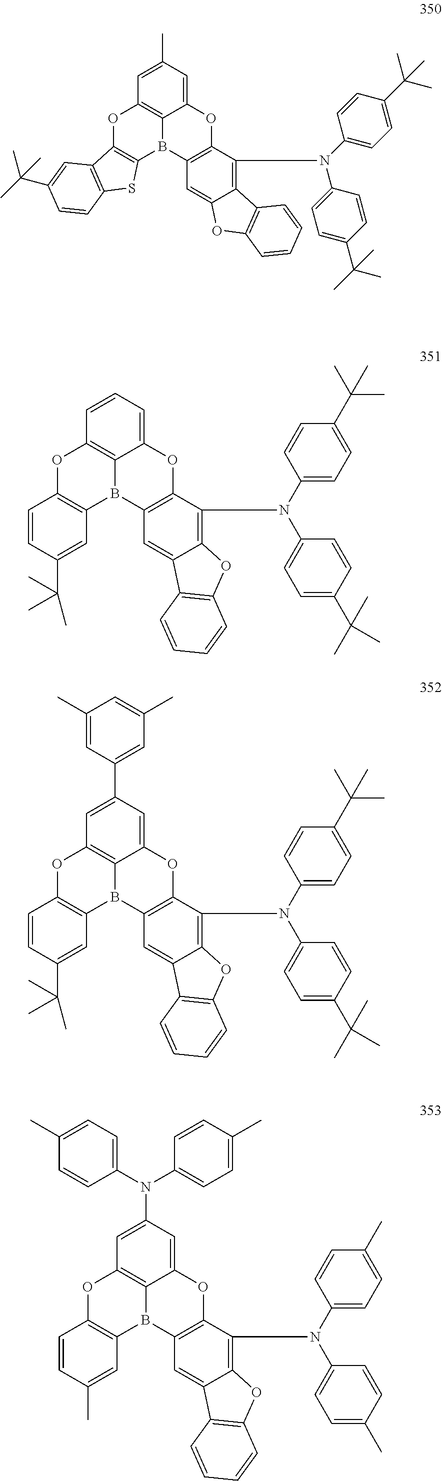

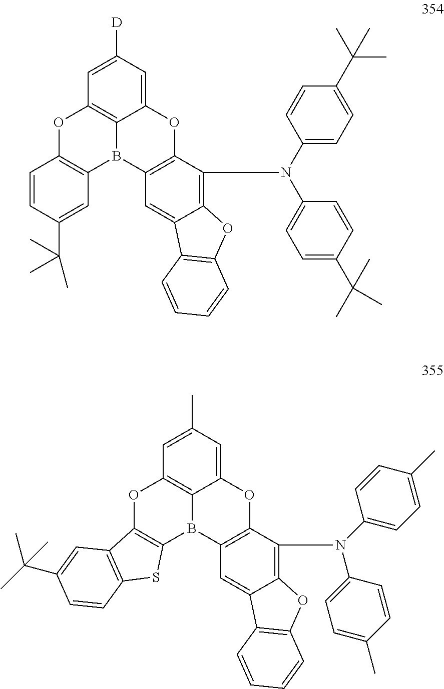

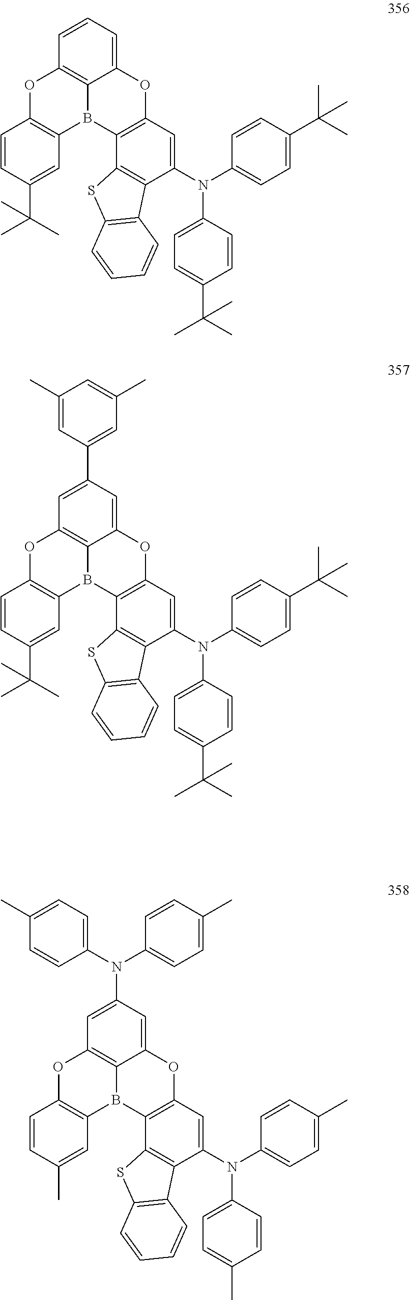

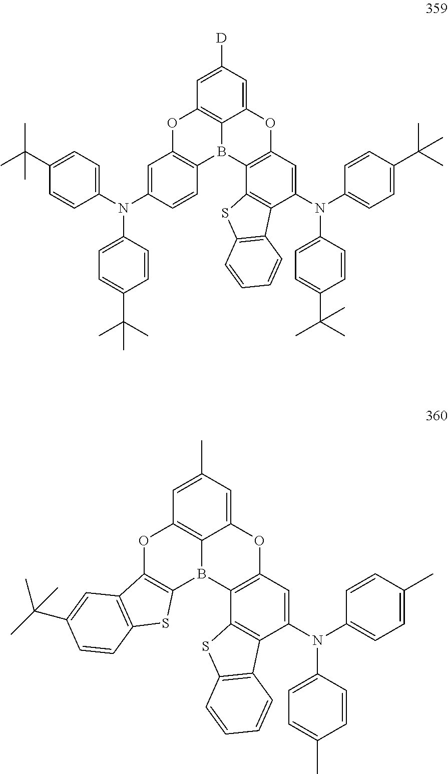

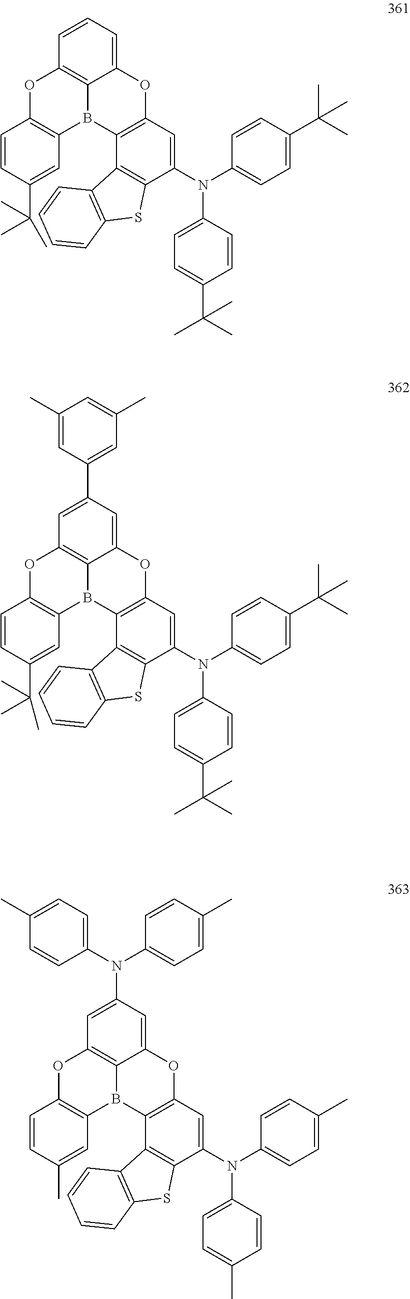

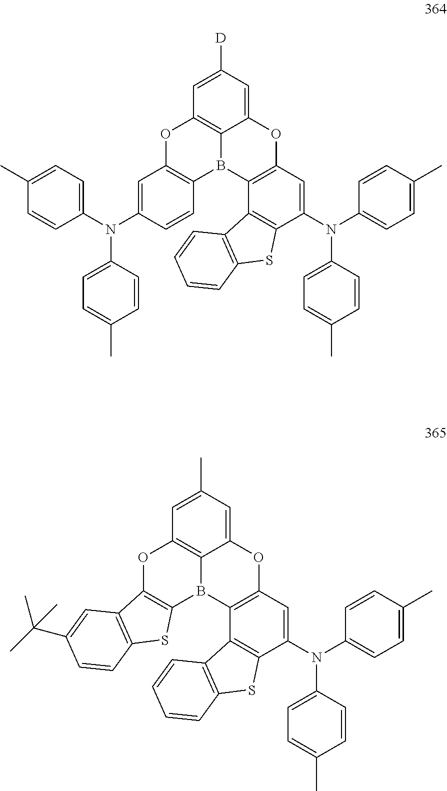

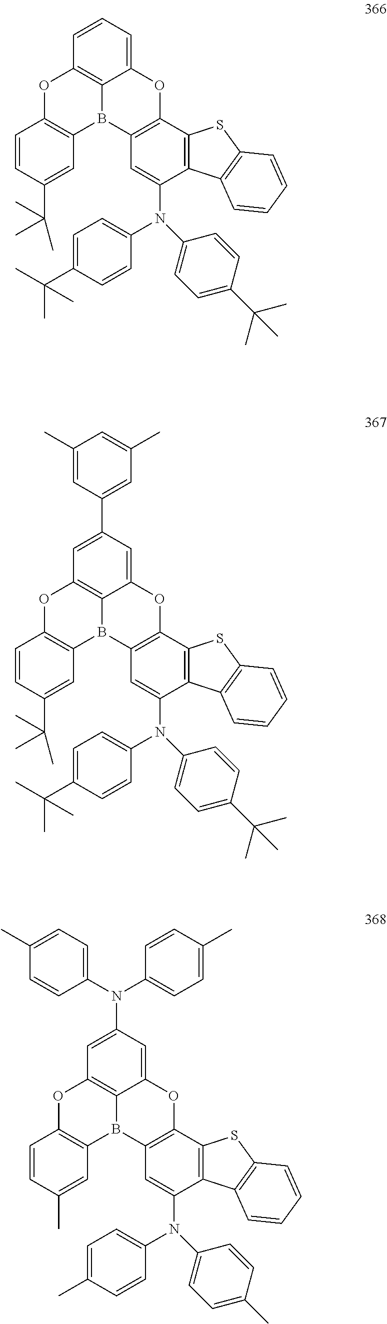 [SMILES: CC(C)(C)c1ccc(N(c2ccc(C(C)(C)C)cc2)c2cc3c(c4sc5ccccc5c24)Oc2cccc4c2B3c2cc(C(C)(C)C)ccc2O4)cc1 ; Cc1cc(C)cc(-c2cc3c4c(c2)Oc2c(cc(N(c5ccc(C(C)(C)C)cc5)c5ccc(C(C)(C)C)cc5)c5c2sc2ccccc25)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5c2sc2ccccc25)B4c2cc(C)ccc2O3)cc1]

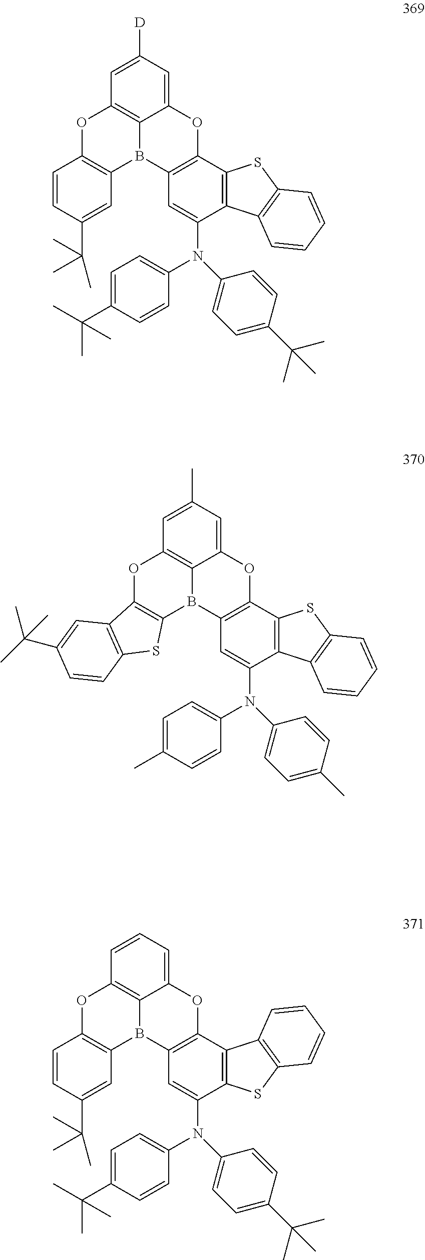 [SMILES: [2H]c1cc2c3c(c1)Oc1c(cc(N(c4ccc(C(C)(C)C)cc4)c4ccc(C(C)(C)C)cc4)c4c1sc1ccccc14)B3c1cc(C(C)(C)C)ccc1O2 ; Cc1ccc(N(c2ccc(C)cc2)c2cc3c(c4sc5ccccc5c24)Oc2cc(C)cc4c2B3c2sc3ccc(C(C)(C)C)cc3c2O4)cc1 ; CC(C)(C)c1ccc(N(c2ccc(C(C)(C)C)cc2)c2cc3c(c4c2sc2ccccc24)Oc2cccc4c2B3c2cc(C(C)(C)C)ccc2O4)cc1]

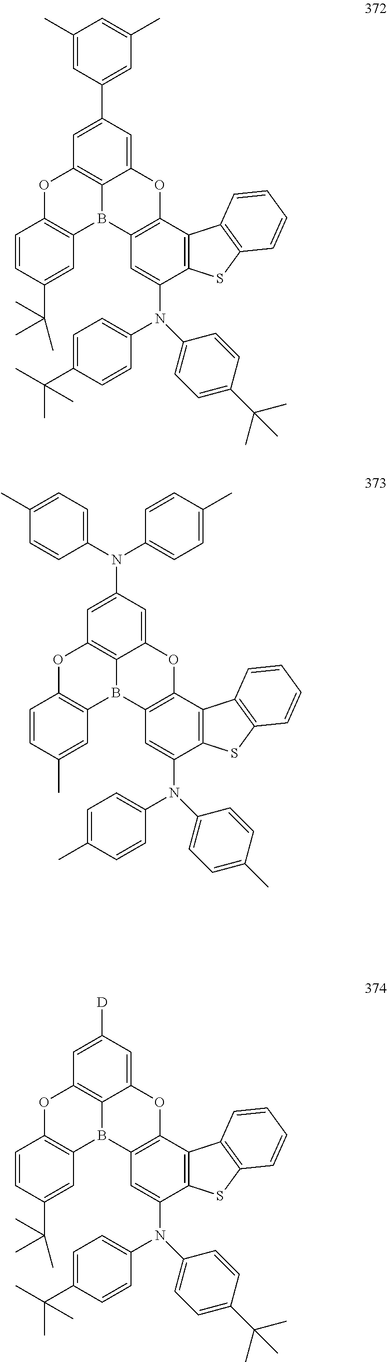 [SMILES: Cc1cc(C)cc(-c2cc3c4c(c2)Oc2c(cc(N(c5ccc(C(C)(C)C)cc5)c5ccc(C(C)(C)C)cc5)c5sc6ccccc6c25)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5sc6ccccc6c25)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4sc5ccccc5c14)B3c1cc(C(C)(C)C)ccc1O2]

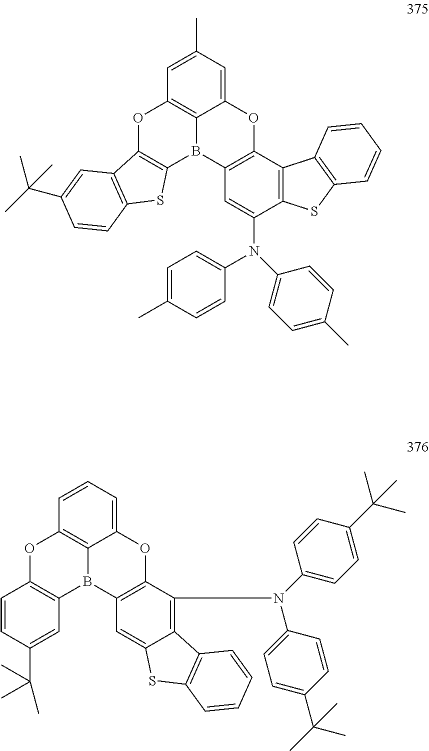 [SMILES: Cc1ccc(N(c2ccc(C)cc2)c2cc3c(c4c2sc2ccccc24)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4sc5ccccc5c24)B2c4cc(C(C)(C)C)ccc4Oc4cccc(c42)O3)cc1]

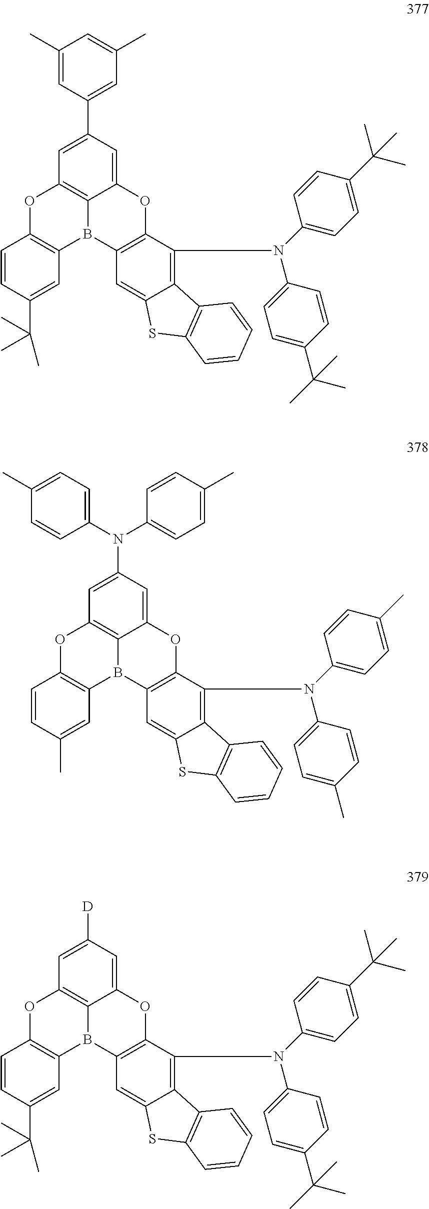

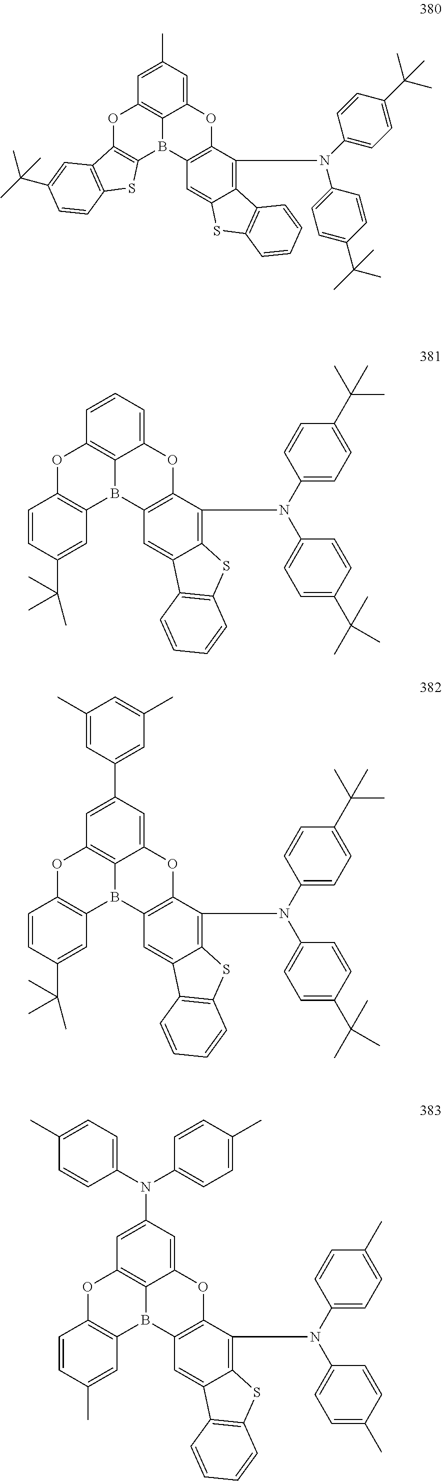

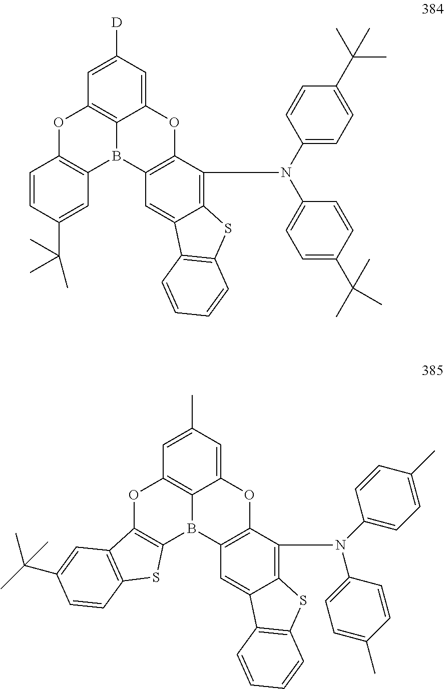

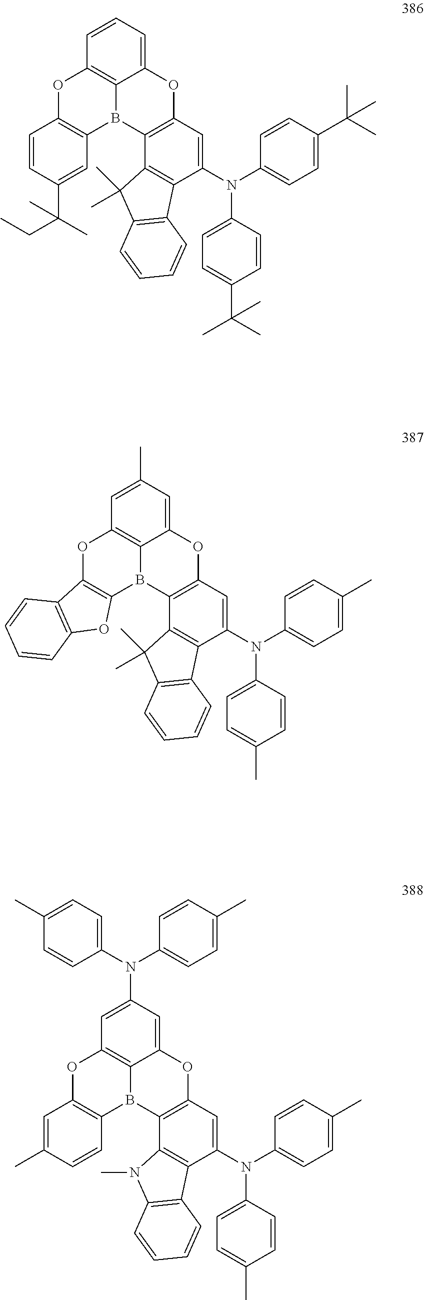

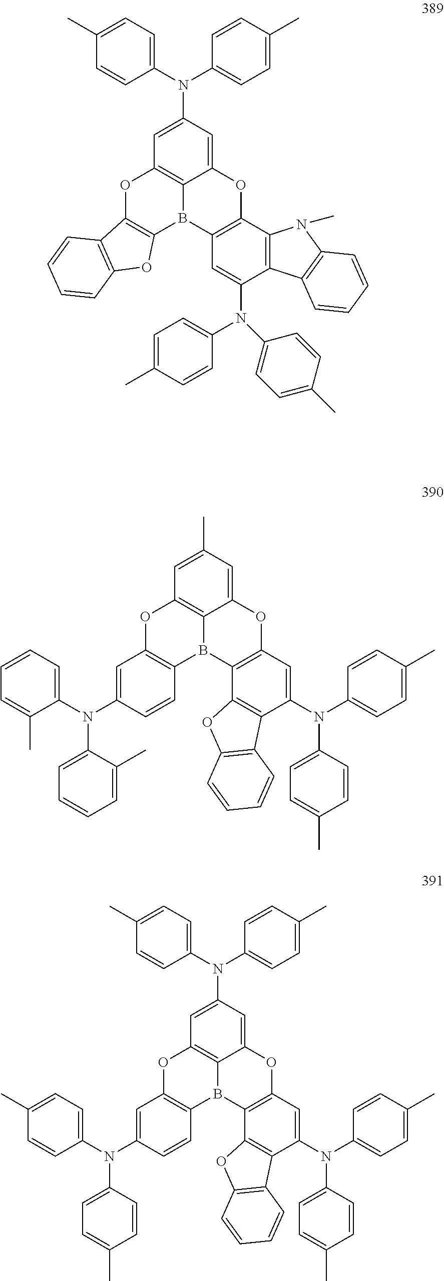

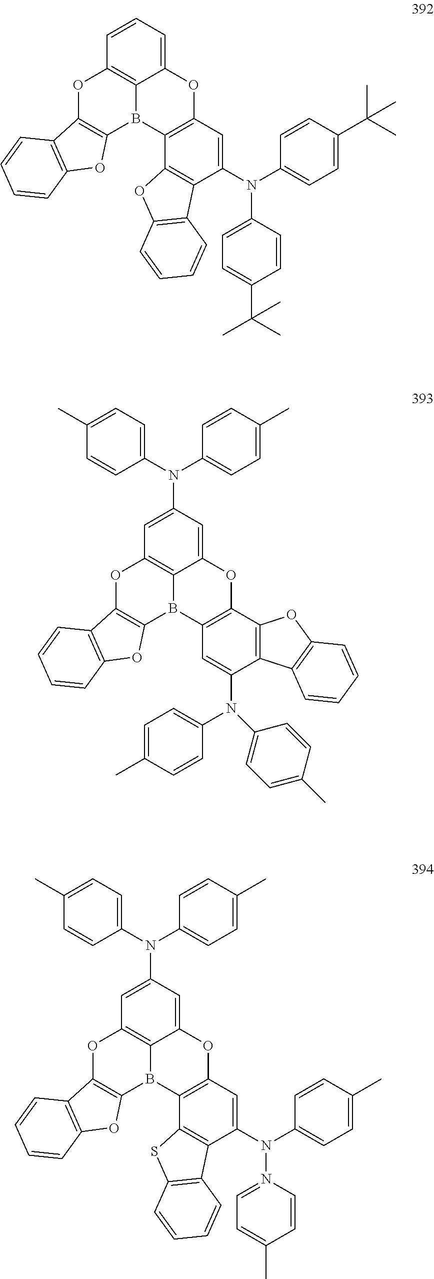

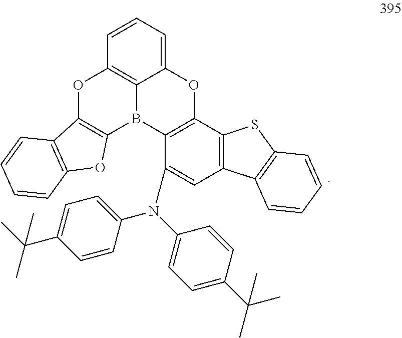 [SMILES: CC(C)(C)c1ccc(N(c2ccc(C(C)(C)C)cc2)c2cc3c(sc4ccccc43)c3c2B2c4oc5ccccc5c4Oc4cccc(c42)O3)cc1]

The present disclosure further provides a light-emitting component, which includes

a pair of electrodes including a first electrode and a second electrode; and

an organic functional layer disposed between the first electrode and the second electrode;

wherein, a material of the organic functional layer includes one or more organic compounds mentioned above.

Preferably, the organic functional layer at least includes a light-emitting layer, the light-emitting layer includes a host material and a guest material, and the guest material includes one or more organic compounds mentioned above.

Preferably, in the light-emitting layer, a mass ratio of the host material to the guest material ranges from 99:1 to 70:30.

The present disclosure further provides a display panel, which includes the light-emitting component mentioned above.

The organic compound of the present disclosure can enhance conjugated effect and resonance effect of materials applied into the light-emitting component by having a heterocyclic group and an amino group at a same time. Therefore, material performances can be improved, a luminous efficiency of the light-emitting component can be improved, and a light-emitting service life of the light-emitting component can be extended.

### DESCRIPTION OF DRAWINGS

The accompanying figures to be used in the description of embodiments of the present disclosure or prior art will be described in brief to illustrate the technical solutions of the embodiments or the prior art more clearly. The accompanying figures described below are only part of the embodiments of the present disclosure, from which those skilled in the art can derive further figures without making any inventive efforts.

The figure is a schematic structural diagram of a light-emitting component according to an embodiment of the present disclosure.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure. In addition, it should be understood that the specific embodiments described herein are only used to illustrate and explain the disclosure, and are not used to limit the disclosure. In the present disclosure, in the case of no explanation to the contrary, the orientation words used such as “on” and “under” usually refer to upper and lower directions of the device in actual use or working state, and specifically the directions in the drawings; and “inside” and “outside” refer to the outline of the device. In the present disclosure, “optionally”, “optional”, and “option” refer to optional, that is, it may be “with” or “without” any one of two side-by-side solutions. If a technical solution has multiple “options”, if there is no special description, and there is no contradiction or mutual restriction, each “option” is independent. In the present disclosure, the technical features described in an open-ended manner include closed-ended technical solutions composed of the listed features, as well as open-ended technical solutions including the listed features.

In the present disclosure, aryl groups, aromatic groups, and aromatic ring systems have the same meaning and may be interchanged. An “aryl group, aromatic group, or aromatic ring system” refers to an aromatic hydrocarbon group derived from an aromatic ring compound by removing one hydrogen atom, which may be a monocyclic aryl group, a fused-ring aryl group, or a polycyclic aryl group. For polycyclic ring species, at least one is an aromatic ring system. For example, a “substituted or unsubstituted aryl group having 6 to 40 ring atoms” refers to an aryl group containing 6 to 40 ring atoms, preferably, a substituted or unsubstituted aryl group having 6 to 30 ring atoms, more preferably, a substituted or unsubstituted aryl group having 6 to 18 ring atoms, and even more preferably, an aryl group having 6 to 14 ring atoms and further substituted on the aryl group. Suitable examples include but are not limited to: a phenyl group, a biphenyl group, a terphenyl group, a naphthyl group, an anthracenyl group, a phenanthryl group, a fluoranthenyl group, a triphenylene group, a pyrenyl group, a perylene group, a naphthacenyl group, a fluorenyl group, a perylene group, an acenaphthyl group, and derivatives thereof. It can be understood that groups in which a plurality of aromatic groups being interrupted by short non-aromatic units (for example, less than 10% of non-hydrogen atoms, such as C, N, or O are also ones of the aryl groups, such as an acenaphthyl group, a fluorenyl group, 9,9-diarylfluorene, triarylamine, and diarylether are also included in the definition of aryl groups.

In the present disclosure, heteroaryl groups, heteroaromatic groups, and heteroaromatic ring systems have the same meaning and may be interchanged. A “heteroaryl group, heteroaromatic group, or heteroaromatic ring system” refers to that on the basis of an aryl group, at least one carbon atom is replaced by a non-carbon atom, which may be an N atom, an O atom, or an S atom. For example, a “substituted or unsubstituted heteroaryl group having 5 to 40 ring atoms” refers to a heteroaryl group containing 5 to 40 ring atoms, preferably, a substituted or unsubstituted heteroaryl group having 6 to 30 ring atoms, more preferably, a substituted or unsubstituted heteroaryl group having 6 to 18 ring atoms, and even more preferably, a heteroaryl group having 6 to 14 ring atoms and further substituted on the heteroaryl group. Suitable examples include but are not limited to: a thienyl group, a furyl group, a pyrrolyl group, an imidazolyl group, a triazolyl group, a diazolyl group, a pyridyl group, a bipyridyl group, a pyrimidinyl group, a triazinyl group, an acridinyl group, a pyridazinyl group, a pyrazinyl group, a quinolinyl group, a quinazolinyl group, a quinoxalinyl group, a phthalazinyl group, a pyridopyrimidinyl group, a pyridopyrazinyl group, a pyrazinopyrazinyl group, an isoquinolinyl group, an indolyl group, a carbazolyl group, a benzothienyl group, a benzofuranyl group, a pyrroloimidazolyl group, a pyrrolopyrrolyl group, a thienopyrrolyl group, a thienothienyl group, a furanopyrrolyl group, a furanofuryl group, a thienofuranyl group, a benzisoxazolyl group, a benzisothiazolyl group, a benzimidazolyl group, an isoquinolinyl group, an o-diazonaphthyl group, a phenanthridinyl group, a perimidinyl group, a quinazolinone group, a dibenzothienyl group, a dibenzofuranyl group, and derivatives thereof.

In the present disclosure, “substituted” means that one or more hydrogen atoms in a substituted group is replaced by a substituent group. When a same substituent appears multiple times, it may be independently selected from different groups. For example, if a general formula contains multiple R, then each R may be independently selected from different groups. In the examples of the present disclosure, “substituted or unsubstituted” means that a defined group may or may not be substituted. When the defined group is substituted, it is understood that the defined group may be substituted with one or more substituents R. Each substituent R may be selected from, but is not limited to, a deuterium atom, a cyano group, an isocyano group, a nitro group, halogen, an alkyl group having 1 to 20 carbon atoms, a heterocyclic group having 3 to 20 ring atoms, an aromatic group having 6 to 20 ring atoms, a heteroaromatic group having 5 to 20 ring atoms, —NR′R″, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, and a trifluoromethyl group; and the above groups may also be substituted with an acceptable substituent in the art. It can be understood that R′ and R″ of —NR′R″ are independently selected from but are not limited to: H, a deuterium atom, a cyano group, an isocyano group, a nitro group, halogen, an alkyl group having 1 to 10 carbon atoms, a heterocyclic group having 3 to 20 ring atoms, an aromatic group having 6 to 20 ring atoms, and a heteroaromatic group having 5 to 20 ring atoms. Preferably, R may be selected from, but is not limited to, a deuterium atom, a cyano group, an isocyano group, a nitro group, halogen, an alkyl group having 1 to 10 carbon atoms, a heterocyclic group having 3 to 10 ring atoms, an aromatic group having 6 to 20 ring atoms, a heteroaromatic group having 5 to 20 ring atoms, -NR′R″, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, and a trifluoromethyl group; and the above groups may also be substituted with an acceptable substituent in the art.

In the present disclosure, an “amino group” refers to a derivative of amines, which has a structural feature of —NR′R″, wherein, the definitions of R′ and R″ are same as above.

In the present disclosure, “number of ring atoms” means a number of atoms that are bonded to each other and constitute a ring of a structural compound (such as a monocyclic compound, a fused ring compound, a cross-linked compound, a carbocyclic compound, and a heterocyclic compound). When the ring is substituted by a substituent, atoms of the substituent are not included in the ring atoms. The same applies to the “number of ring atoms” described below unless otherwise specified. For example, the number of ring atoms of a benzene ring is 6, the number of ring atoms of a naphthalene ring is 10, and the number of ring atoms of a thienyl group is 5.

In the present disclosure, “*” attached to a single bond indicates a linkage site or a fused site. When the linkage site is not specified in the group, it means that any optional linkage site in the group may be as the linkage site. When multiple substituents with a same symbol are on a same group, the substituents may be the same or different from each other. For example,

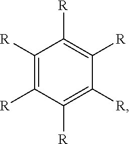

the six R on the benzene ring may be the same or different from each other. A single bond to which a substituent is attached extending through a corresponding ring structure, indicates that the substituent may be attached to an optional position on the ring structure. For example, in

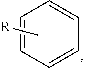

R is connected to any optional linkage site on the benzene ring.

At present, since light-emitting materials used in OLED components have low luminous efficiency, stability, and lifespan, the performance of OLED components is difficult to improve.

An embodiment of the present disclosure provides an organic compound, which has a structure shown as general formula (1):

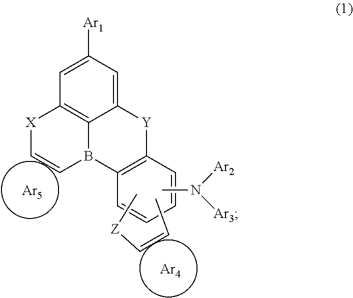

wherein, Z is selected from CR₁R₂NR₃, O, or S;

X and Y are each independently selected from O or NR4;

R₁ to R₄ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms;

R₁ and R₂ are connected in a ring or independent of each other;

Ar₁ is selected from H, D, a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms;

Ar₂ and Ar₃ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms; and

Ar₄ and Ar₅ are each independently selected from a substituted or unsubstituted aromatic group with 6 to 30 carbon atoms or a substituted or unsubstituted heteroaromatic group with 5 to 30 carbon atoms.

The organic compound of the present disclosure can enhance conjugated effect and resonance effect of materials applied into the light-emitting component by having a heterocyclic group and an amino group at a same time. Therefore, material performances can be improved, a luminous efficiency of the light-emitting component can be improved, and a light-emitting service life of the light-emitting component can be extended.

In some embodiments, the organic compound has a structure shown as general formula (2), general formula (3), general formula (4), general formula (5), general formula (6), or general formula (7):

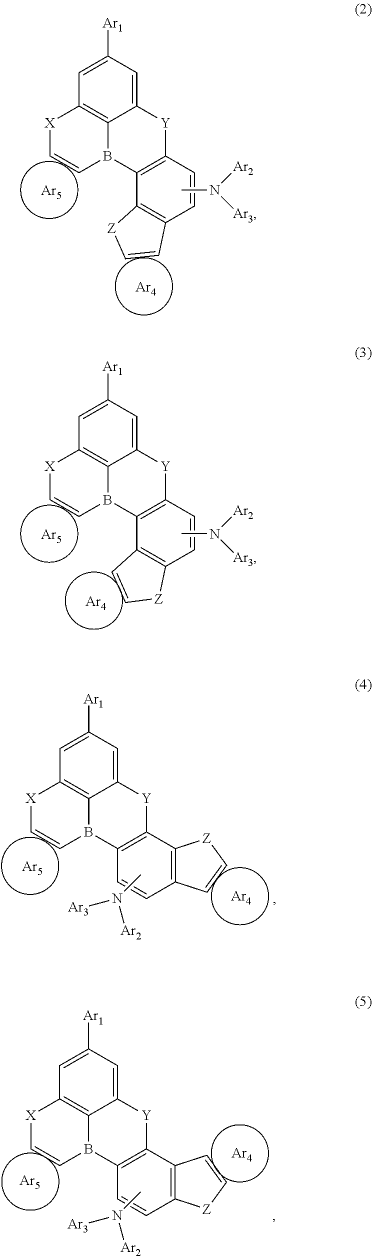

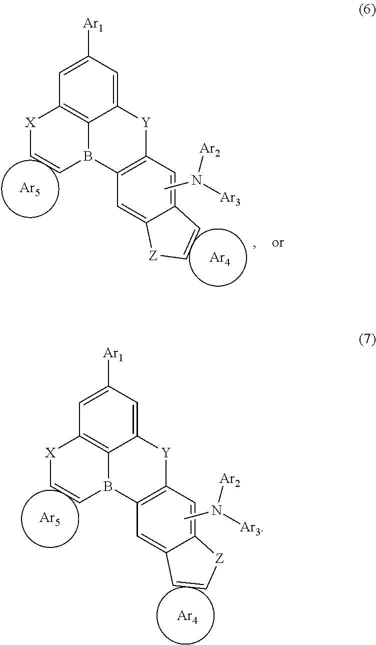

In some embodiments, the organic compound has a structure shown as general formula (8), general formula (9), general formula (10), general formula (11), general formula (12), or general formula (13):

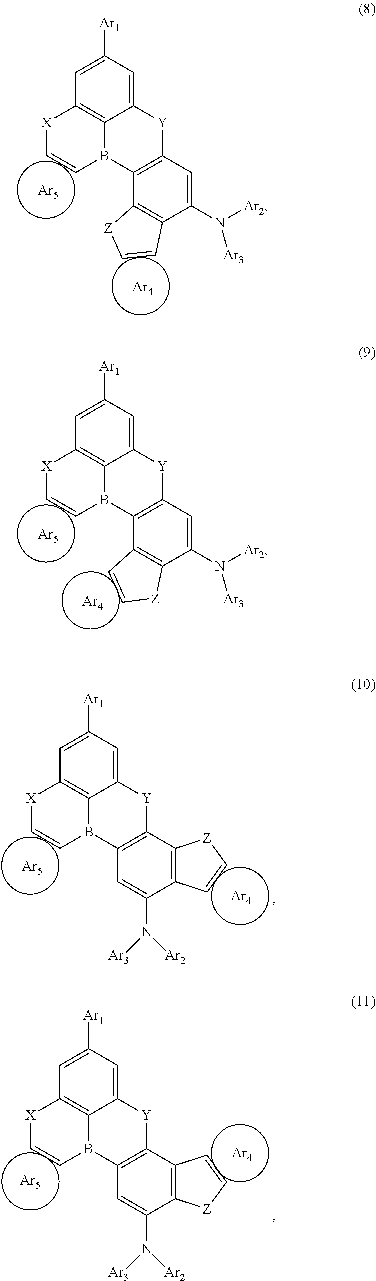

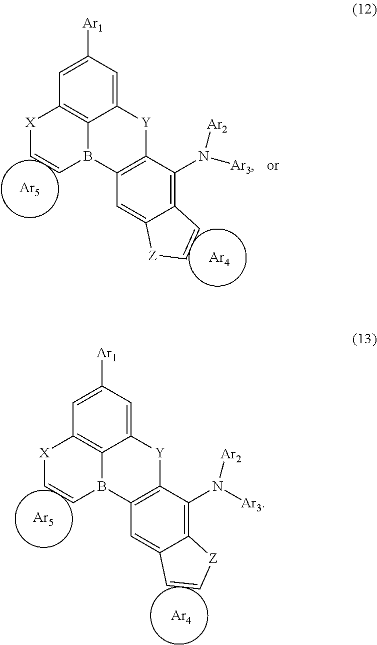

In some embodiments, the organic compound has a structure shown as general formula (14):

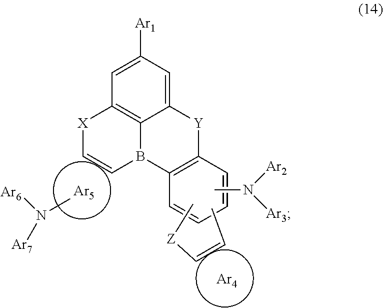

wherein, Ar₆ and Ar₇ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms.

In some embodiments, the organic compound has a structure shown as general formula (15):

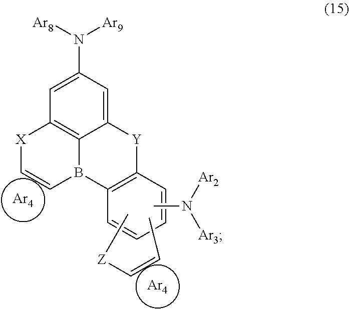

wherein, Ar₈ and Ar₉ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms.

In the above embodiments, Z is selected from CR₁R₂, O, or S,

X and Y are each independently selected from O or NR₄, and X and Y are not O at a same time; and

R₁ to R₄ are each independently selected from a substituted or unsubstituted alkyl group with 1 to 12 carbon atoms, a substituted or unsubstituted aromatic group with 6 to 20 carbon atoms, or a substituted or unsubstituted heteroaromatic group with 5 to 20 carbon atoms. Wherein, preferably, R₁ to R₄ are each independently selected from a substituted or unsubstituted alkyl group with 1 to 8 carbon atoms, a substituted or unsubstituted aromatic group with 6 to 15 carbon atoms, or a substituted or unsubstituted heteroaromatic group with 5 to 15 carbon atoms. Preferably, R₁ and R₂ are independently selected from a methyl group or a substituted or unsubstituted phenyl group; and R₄ is selected from a methyl group, a substituted or unsubstituted phenyl group, a substituted or unsubstituted naphthyl group, a substituted or unsubstituted dibenzofuryl group, a substituted or unsubstituted dibenzothienyl group, a substituted or unsubstituted fluorenyl group, or a substituted or unsubstituted carbazolyl group.

In the above embodiments, Ar₁ is selected from H, D, a substituted or unsubstituted alkyl group with 1 to 12 carbon atoms, a substituted or unsubstituted aromatic group with 6 to 20 carbon atoms, or a substituted or unsubstituted heteroaromatic group with 5 to 20 carbon atoms. Wherein, preferably, Ar₁ is selected from H, D, a substituted or unsubstituted alkyl group with 1 to 8 carbon atoms, a substituted or unsubstituted aromatic group with 6 to 15 carbon atoms, or a substituted or unsubstituted heteroaromatic group with 5 to 15 carbon atoms. More preferably, Ar₁ is selected from H, D, a methyl group, an isopropyl group, a tert-butyl group, a tert-amyl group, a substituted or unsubstituted phenyl group, a substituted or unsubstituted naphthyl group, a substituted or unsubstituted dibenzofuryl group, a substituted or unsubstituted dibenzothienyl group, a substituted or unsubstituted fluorenyl group, a substituted or unsubstituted carbazolyl group, or an amino group.

In the above embodiments, Ar₂ and Ar₃ are each independently selected from a substituted or unsubstituted alkyl group with 1 to 12 carbon atoms, a substituted or unsubstituted aromatic group with 6 to 20 carbon atoms, or a substituted or unsubstituted heteroaromatic group with 5 to 20 carbon atoms. Preferably, Ar₂ and Ar₃ are each independently selected from a substituted or unsubstituted alkyl group with 1 to 8 carbon atoms, a substituted or unsubstituted aromatic group with 6 to 15 carbon atoms, or a substituted or unsubstituted heteroaromatic group with 5 to 15 carbon atoms. More preferably, Ar₂ and Ar₃ are independently selected from a substituted or unsubstituted phenyl group, a substituted or unsubstituted naphthyl group, a substituted or unsubstituted triphenyl group, a substituted or unsubstituted dibenzofuryl group, a substituted or unsubstituted dibenzothienyl group, a substituted or unsubstituted fluorenyl group, a substituted or unsubstituted carbazolyl group, or a methyl group.

Ar₄ and Ar₅ are each independently selected from a substituted or unsubstituted aromatic group with 6 to 20 carbon atoms or a substituted or unsubstituted heteroaromatic group with 5 to 20 carbon atoms. Preferably, Ar₄ and Ar₅ are each independently selected from a substituted or unsubstituted aromatic group with 6 to 15 carbon atoms or a substituted or unsubstituted heteroaromatic group with 5 to 15 carbon atoms. More preferably, Ar₄ and Ar₅ are independently selected from a substituted or unsubstituted phenyl group, a substituted or unsubstituted naphthyl group, a substituted or unsubstituted triphenyl group, a substituted or unsubstituted dibenzofuryl group, a substituted or unsubstituted dibenzothienyl group, a substituted or unsubstituted fluorenyl group, or a substituted or unsubstituted carbazolyl group.

In some embodiments, the organic compound is one selected from following compounds:

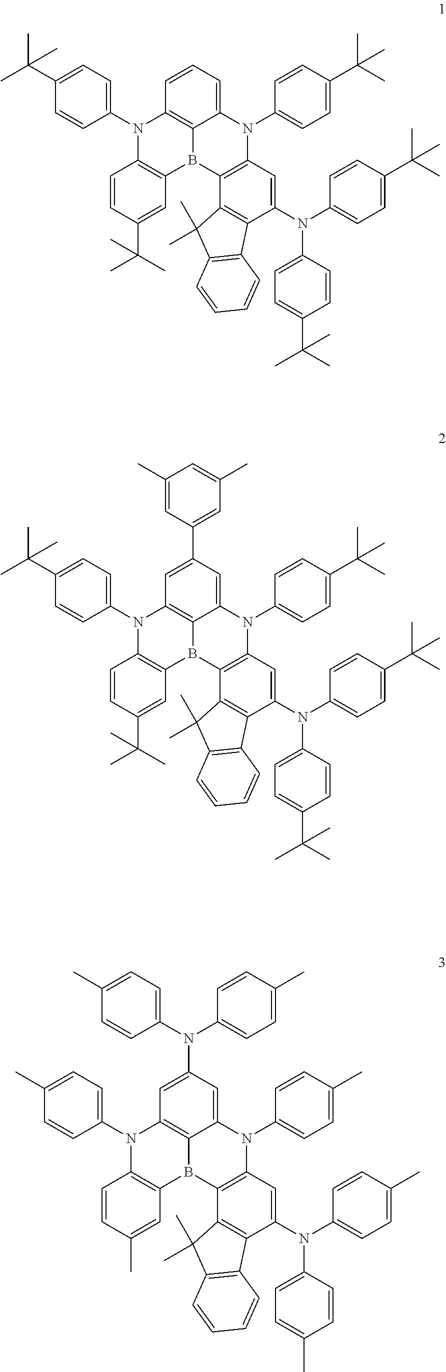

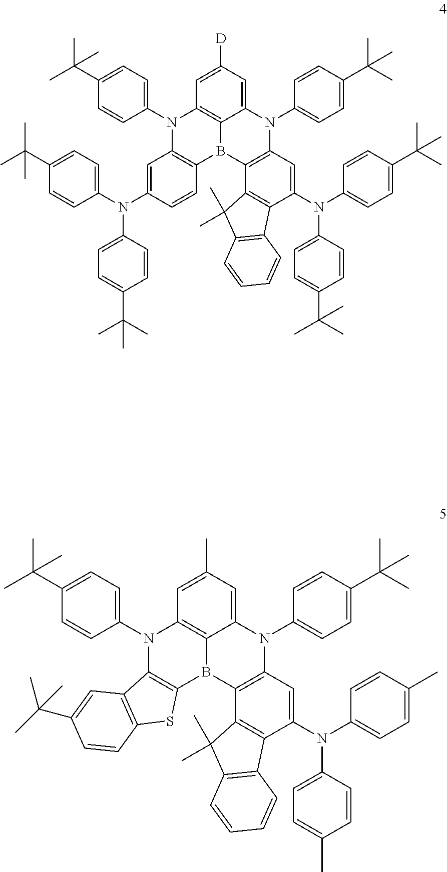

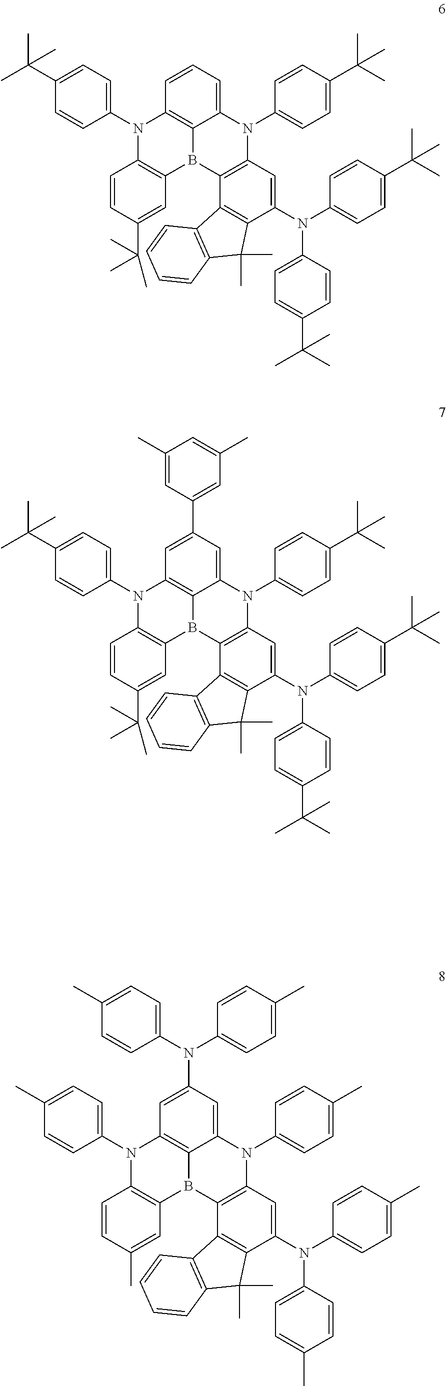

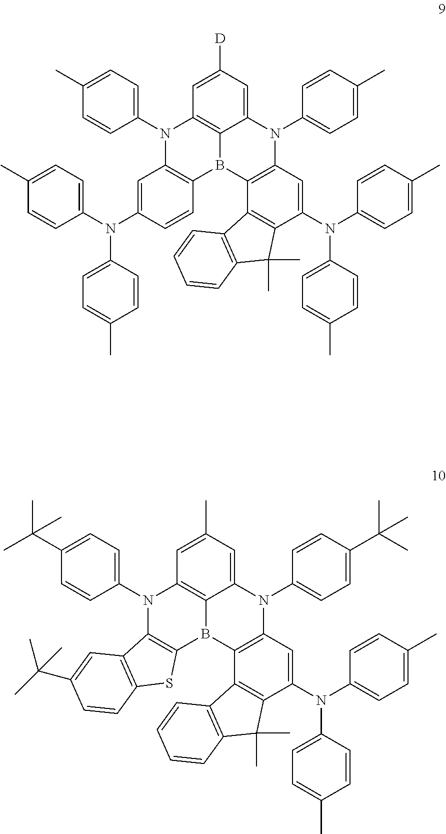

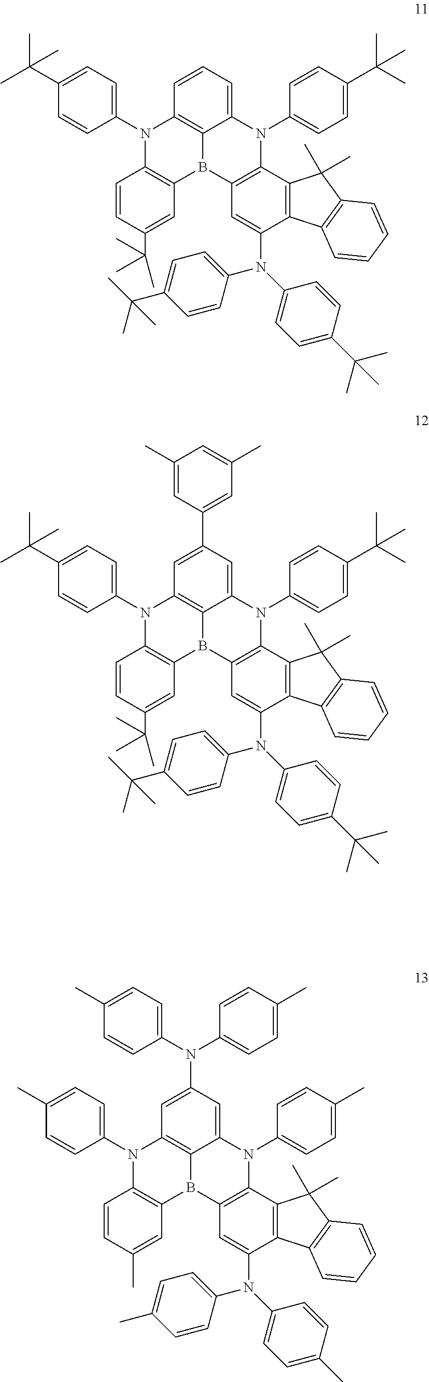

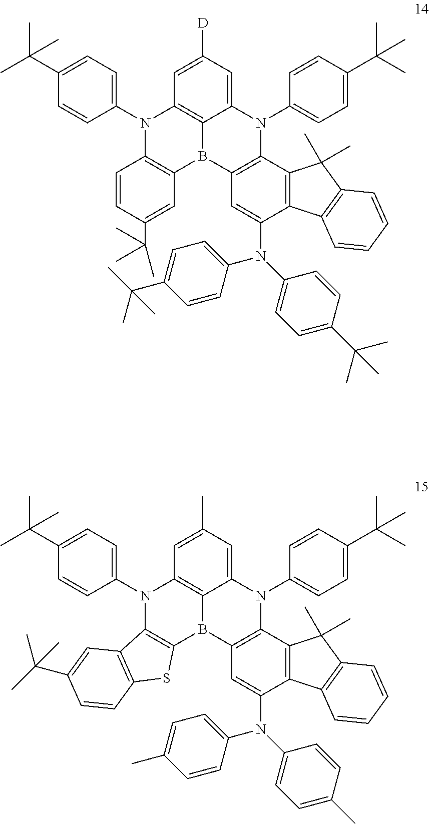

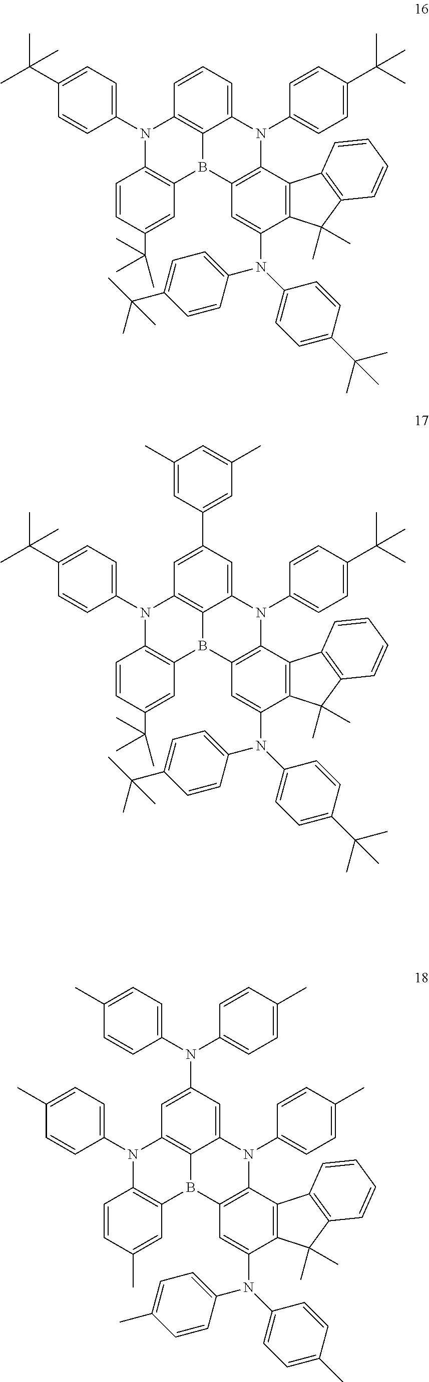

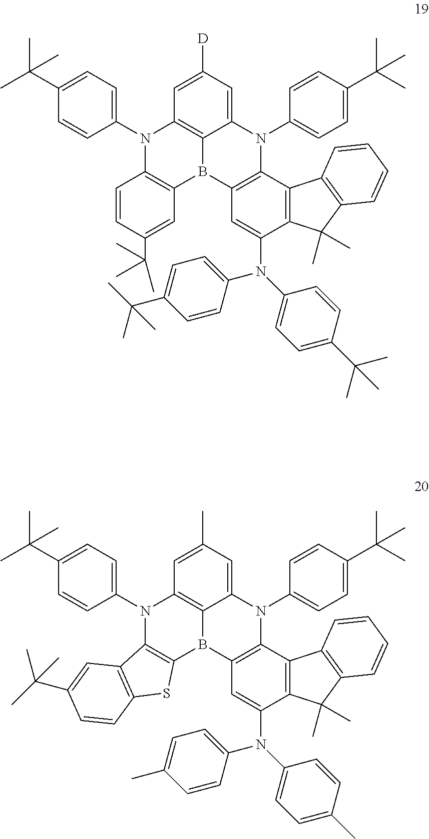

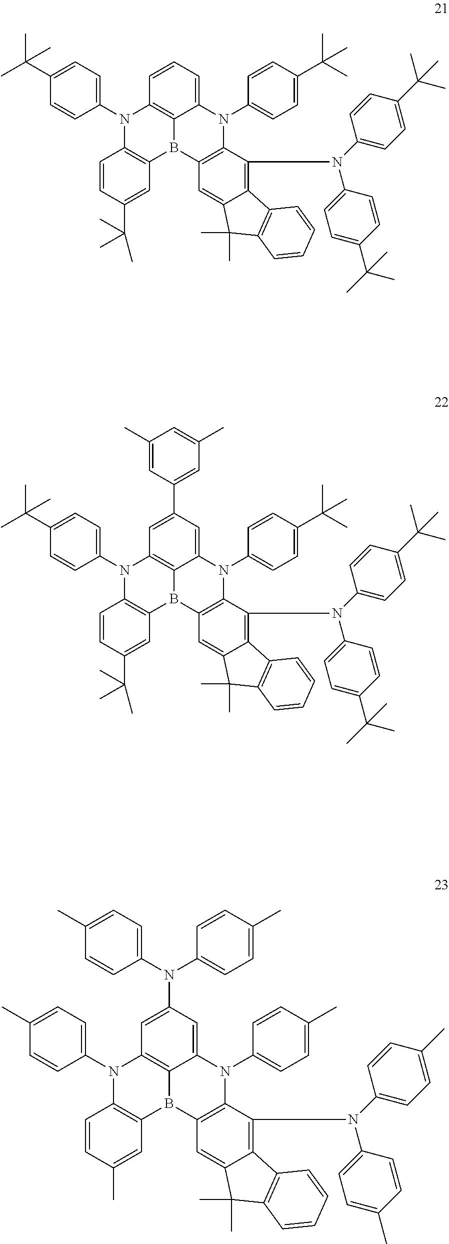

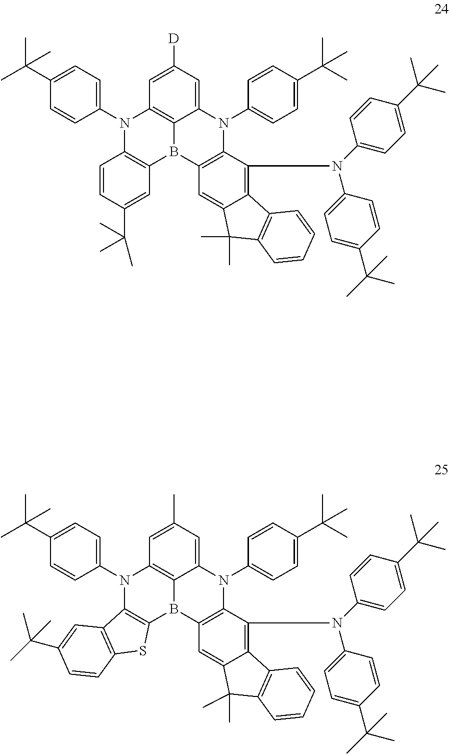

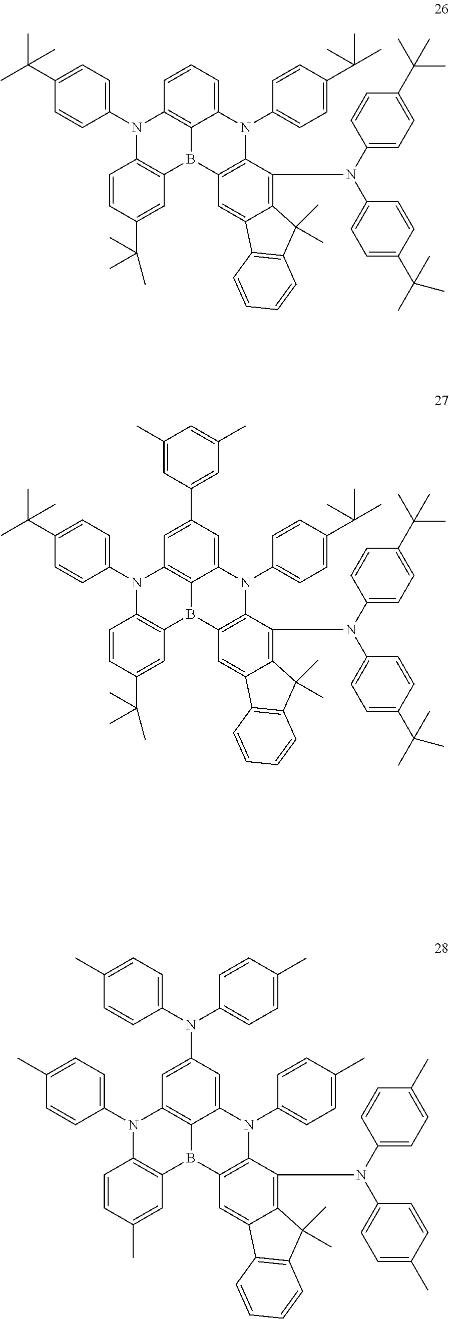

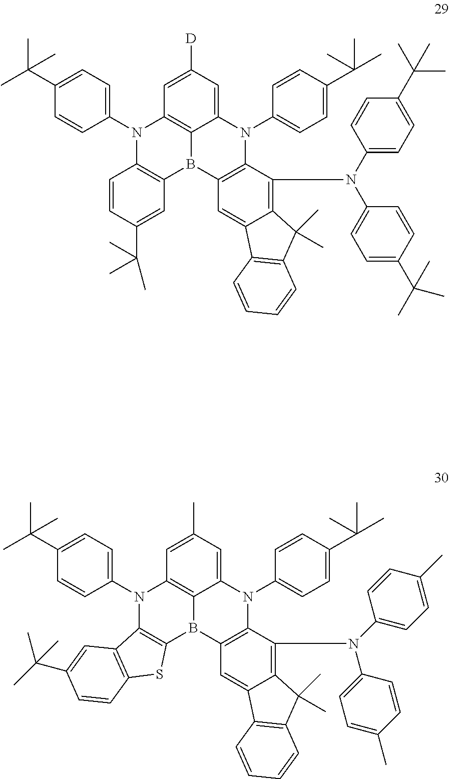

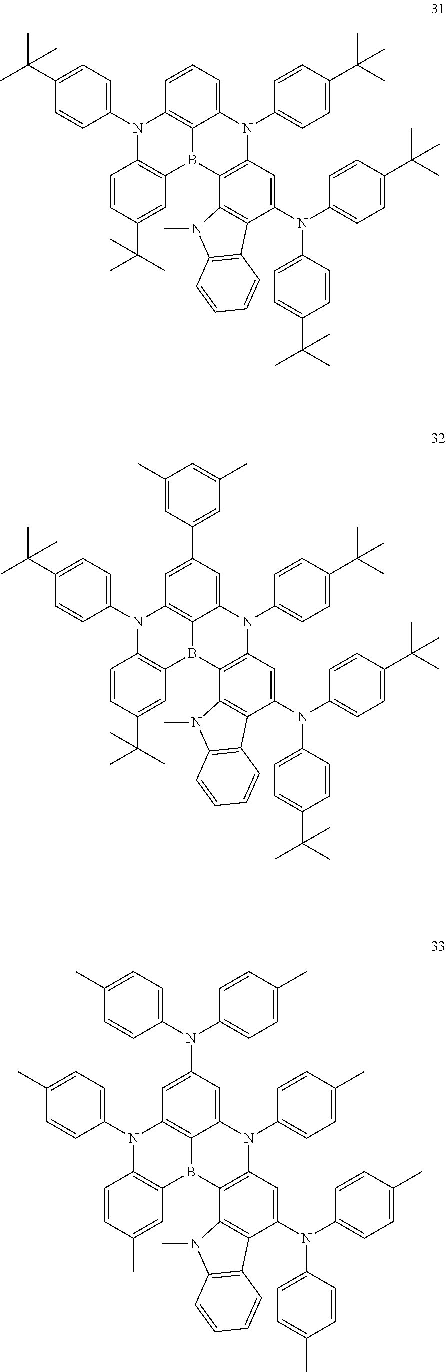

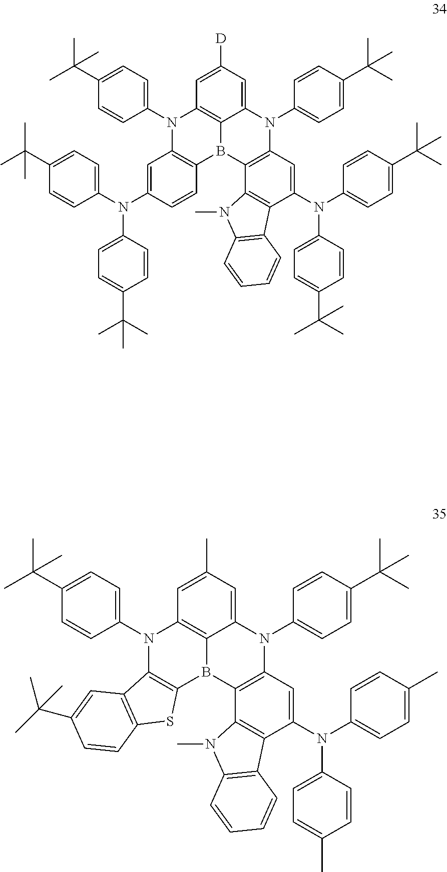

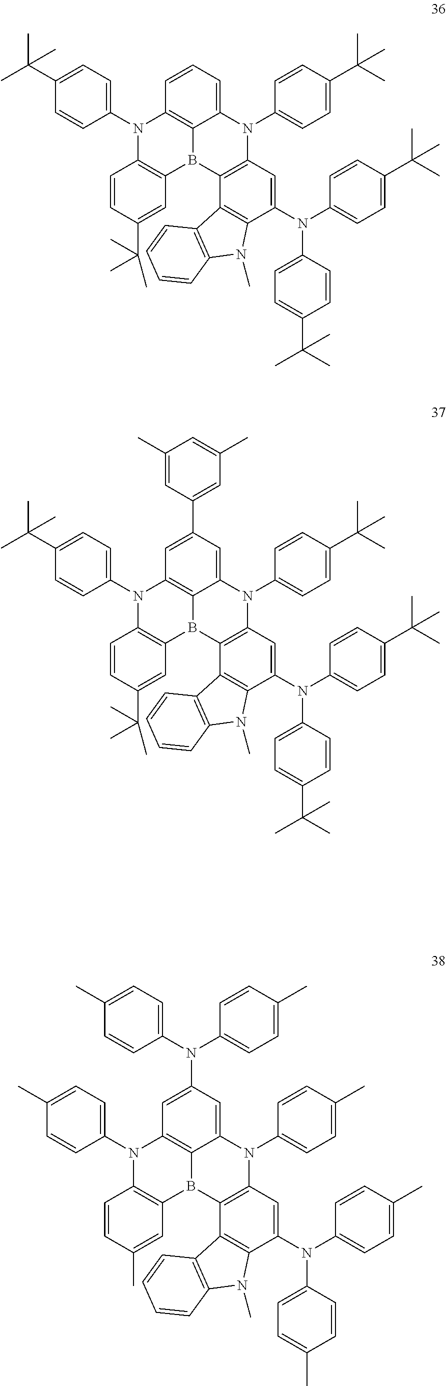

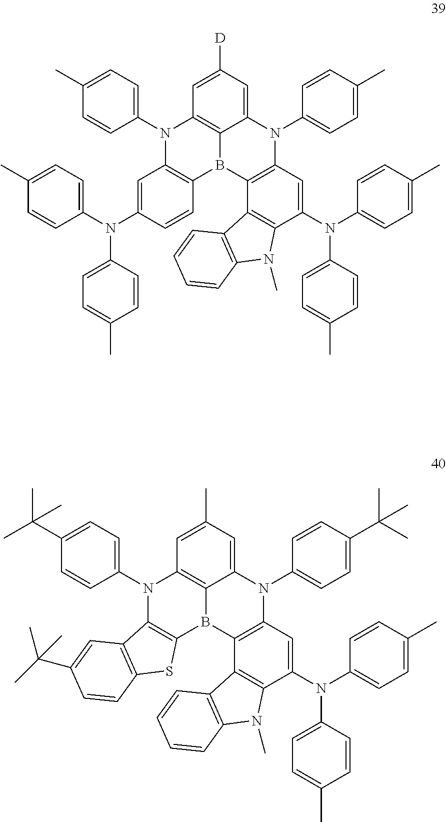

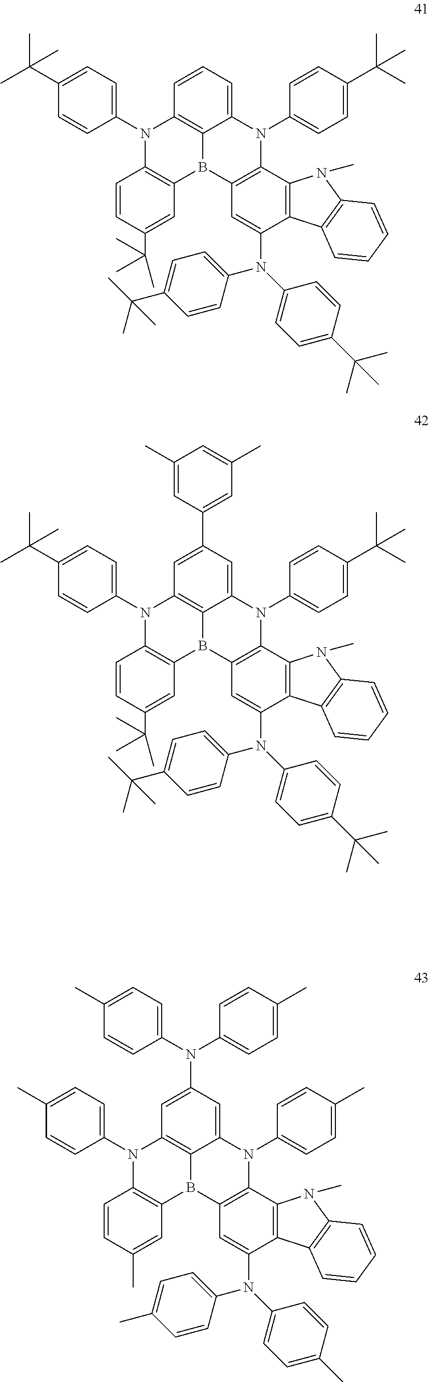

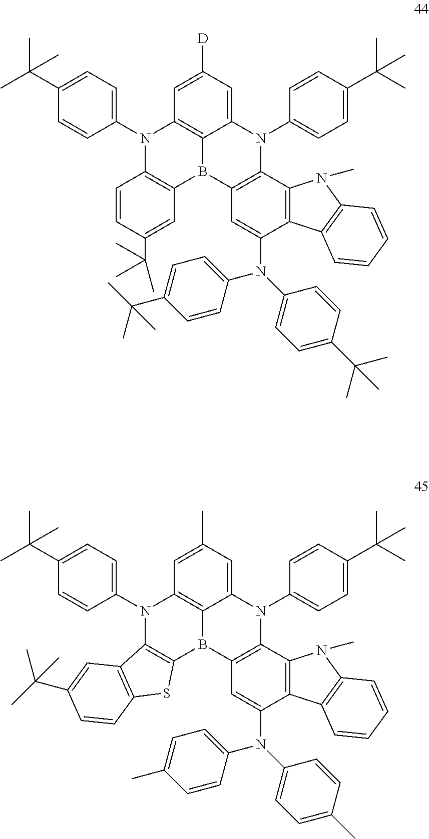

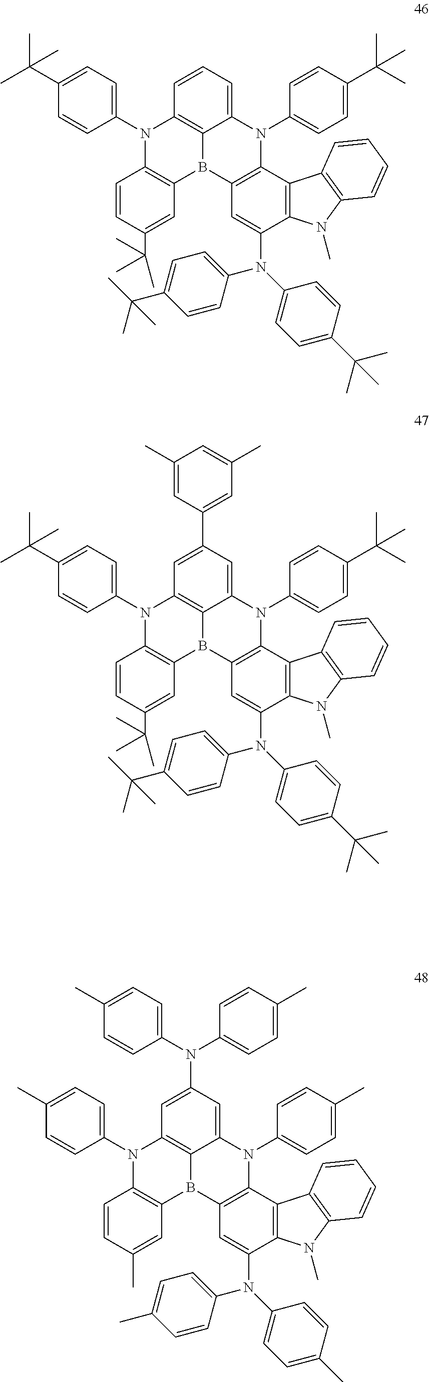

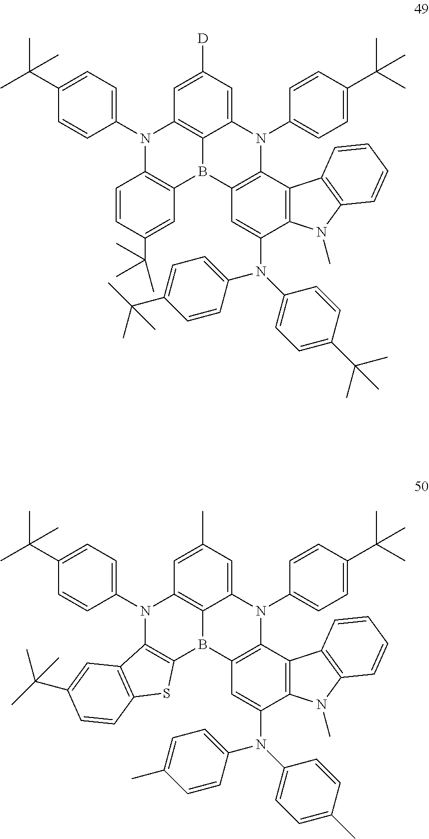

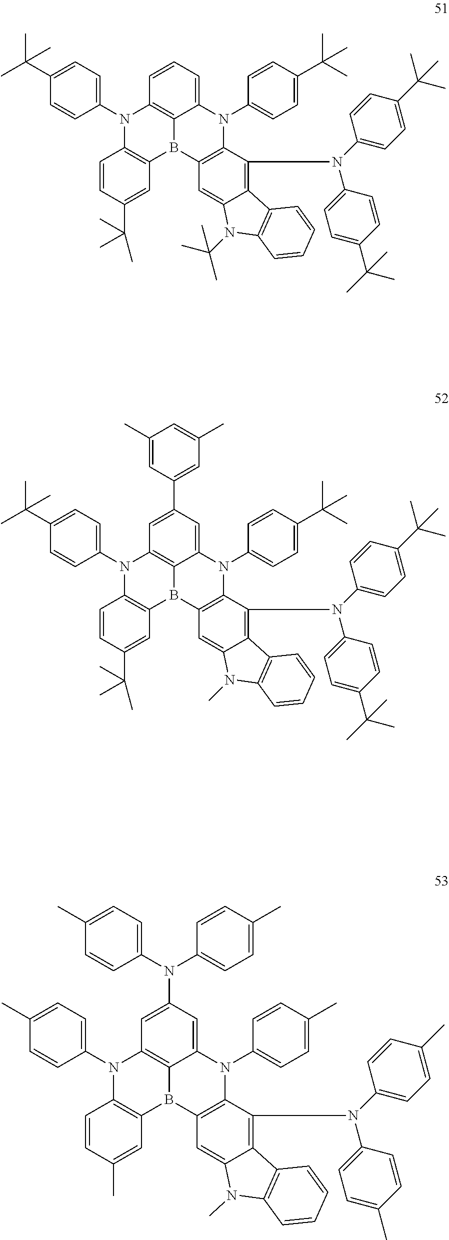

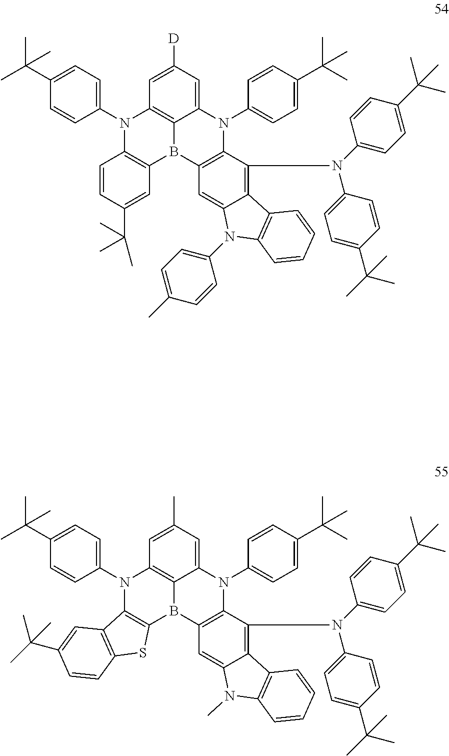

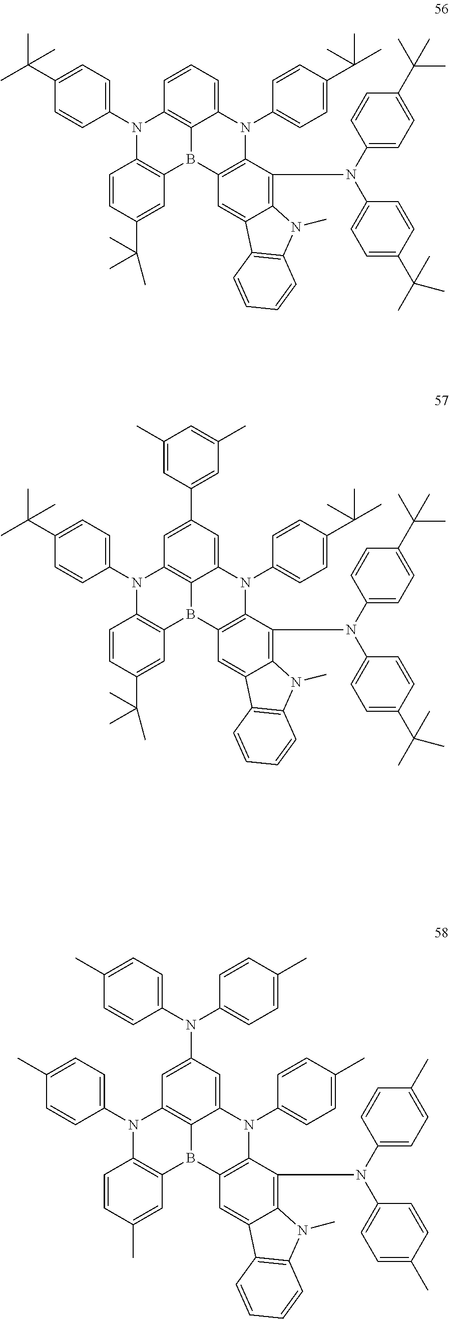

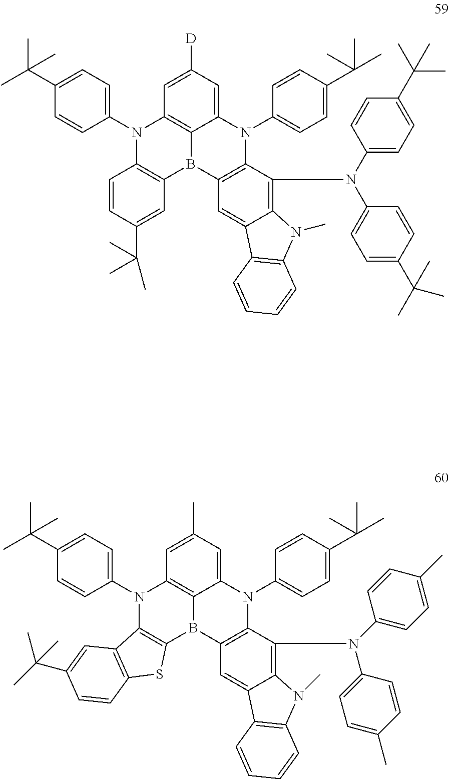

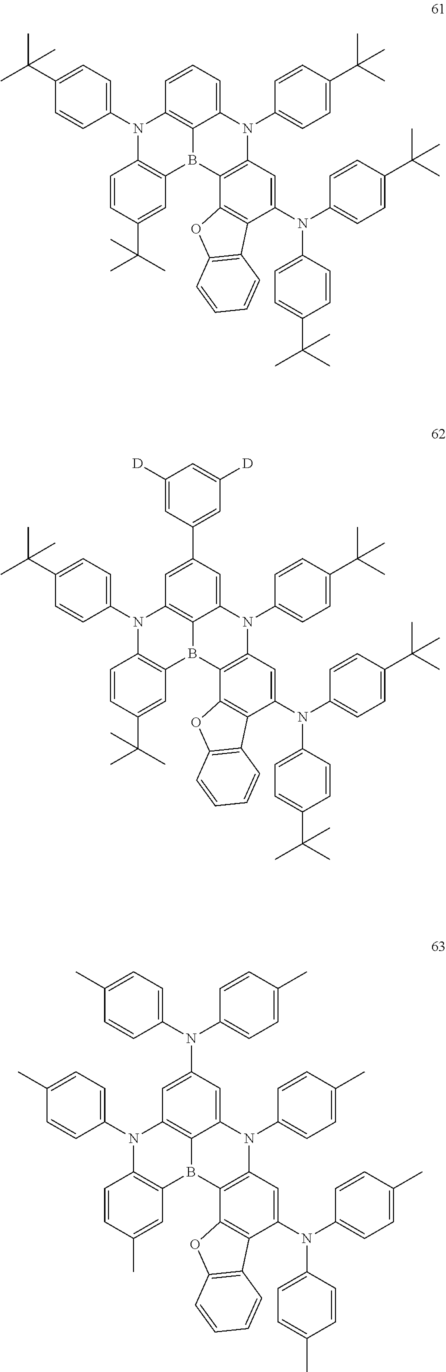

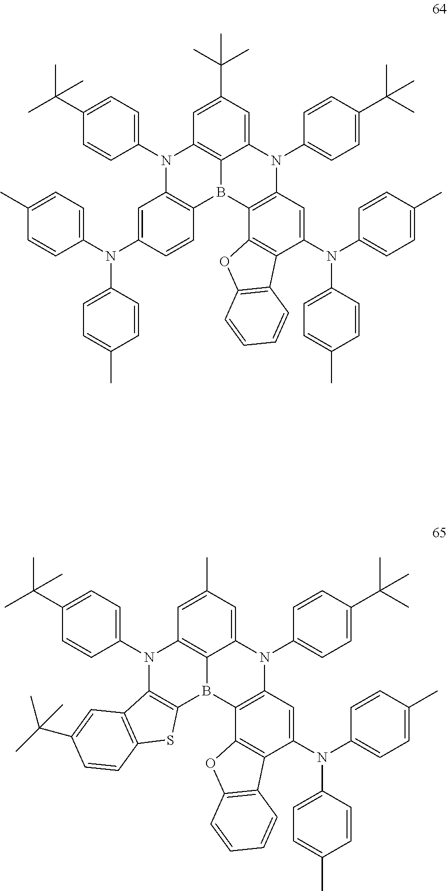

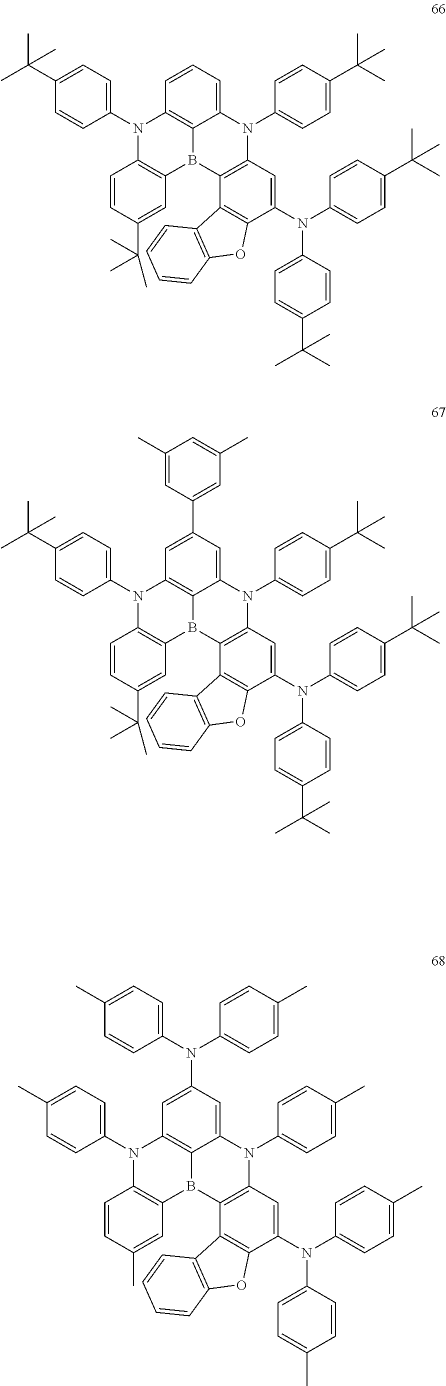

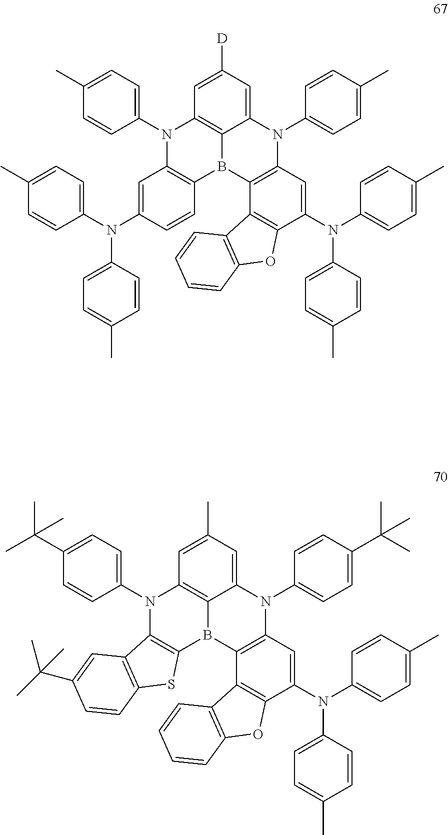

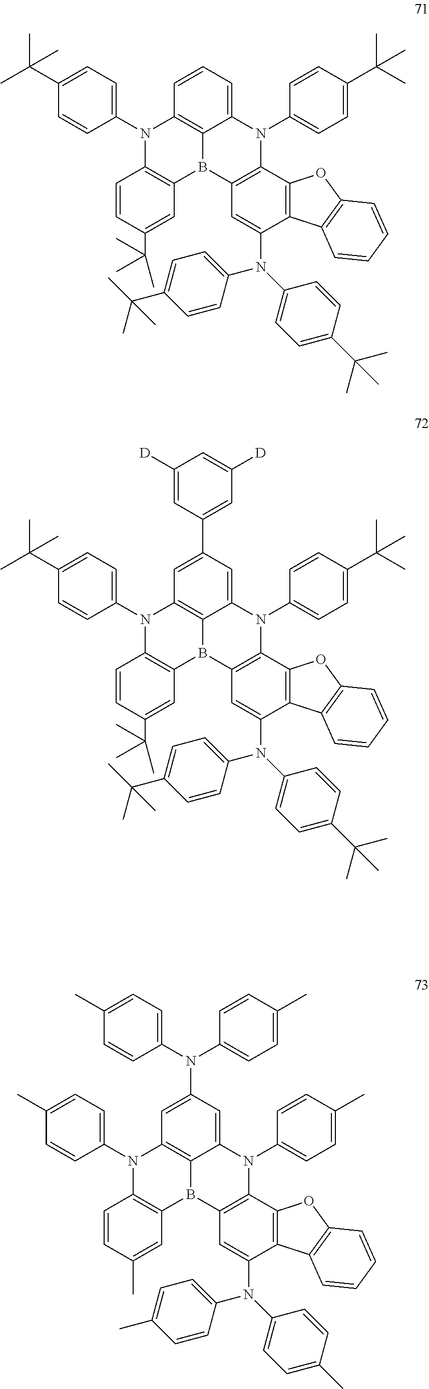

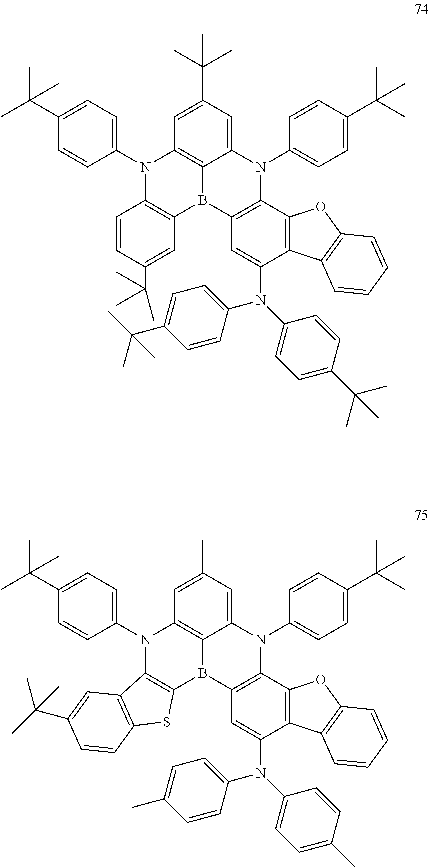

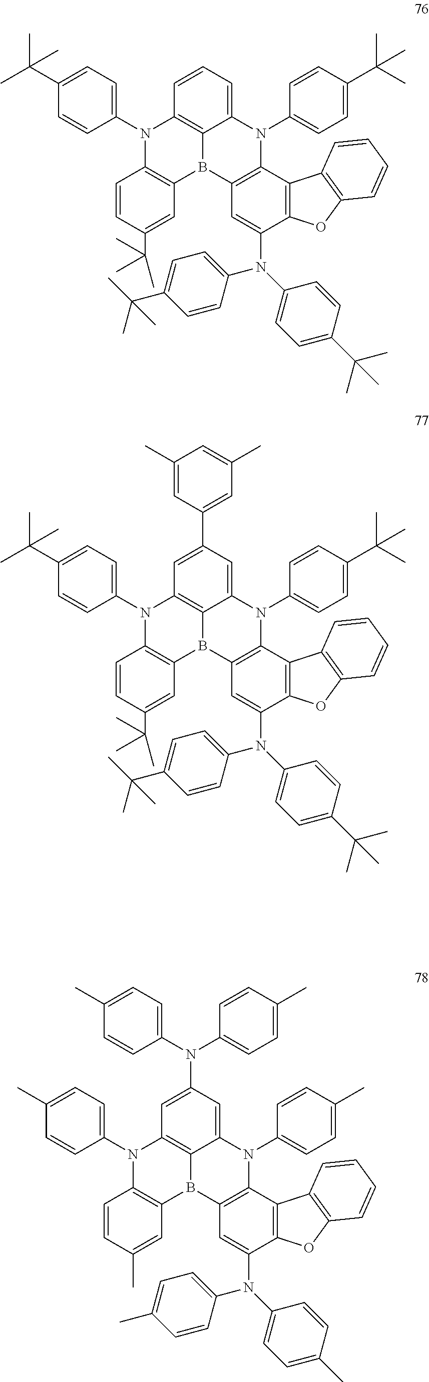

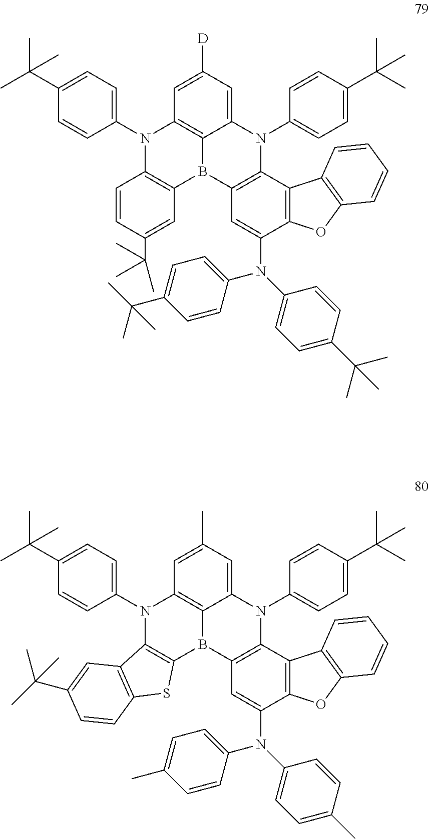

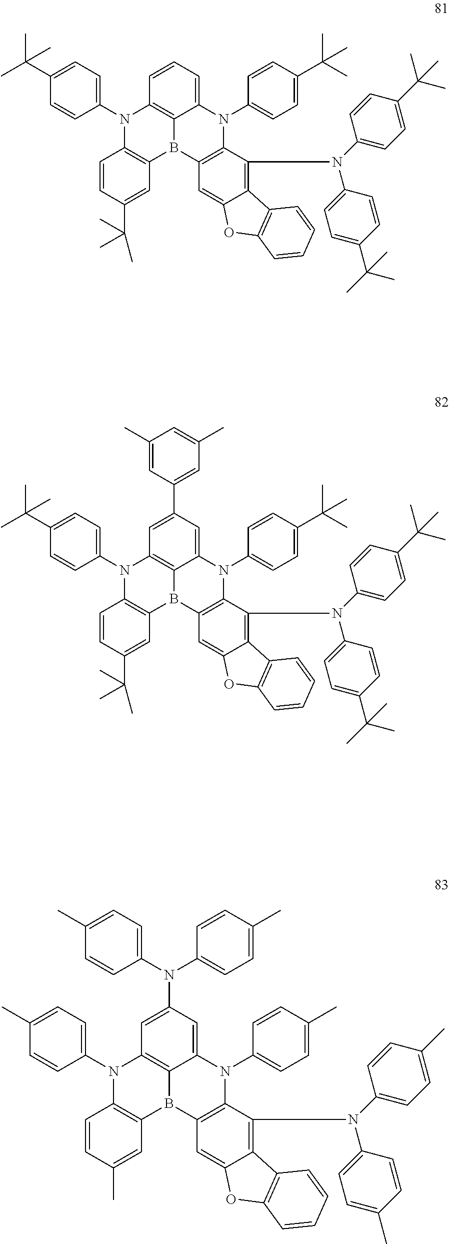

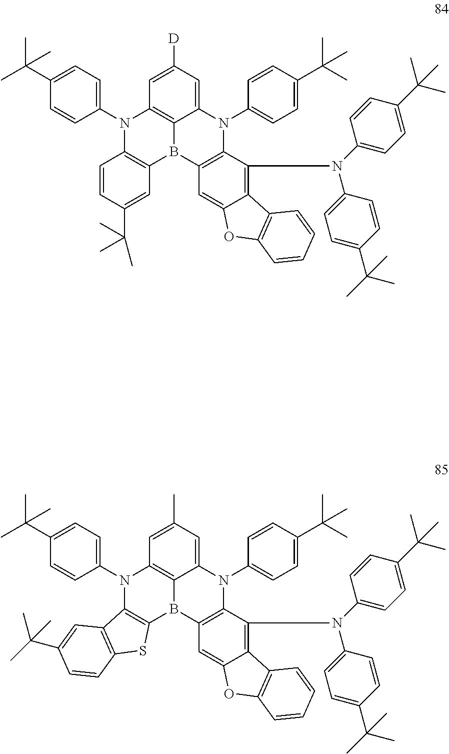

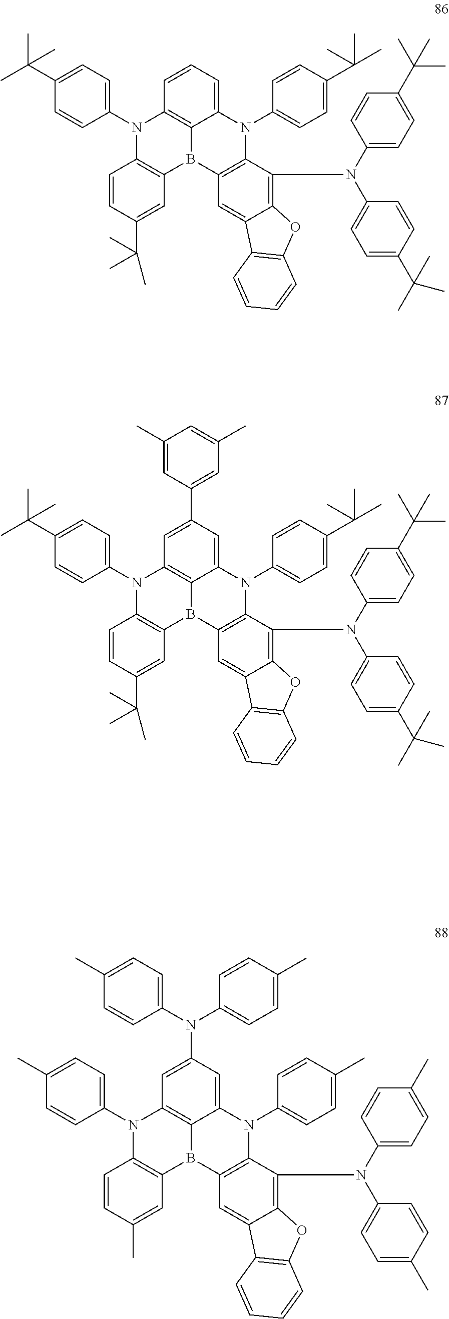

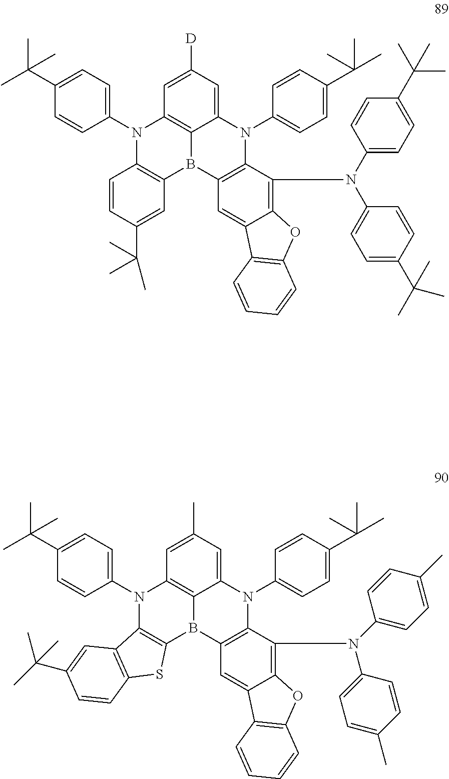

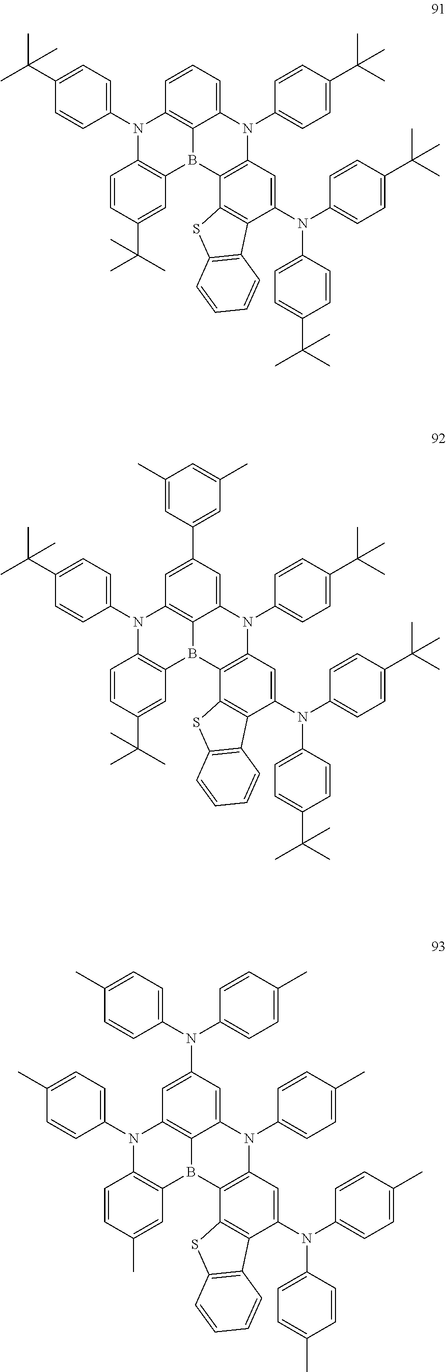

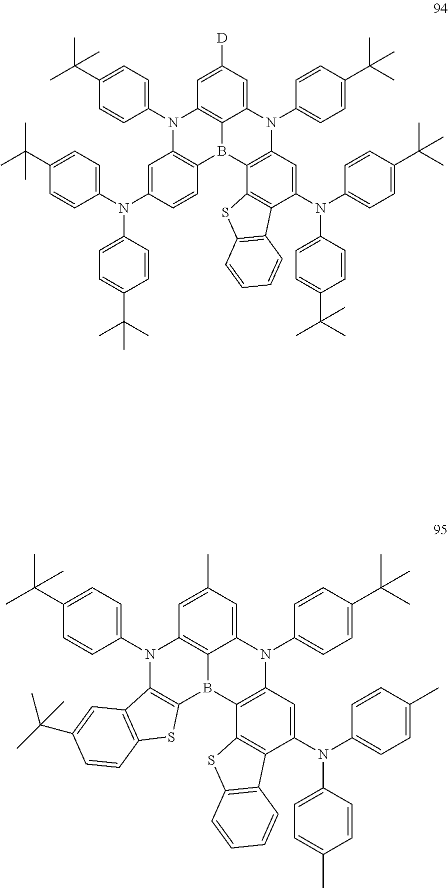

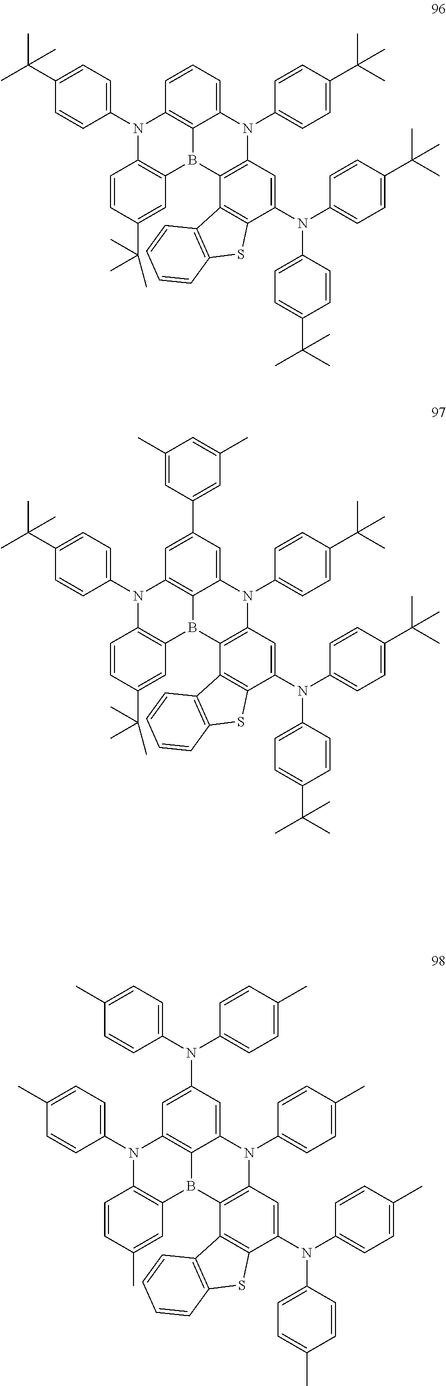

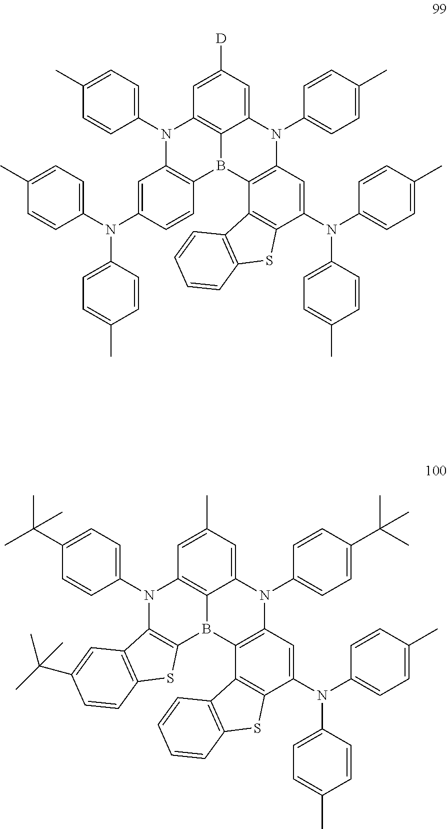

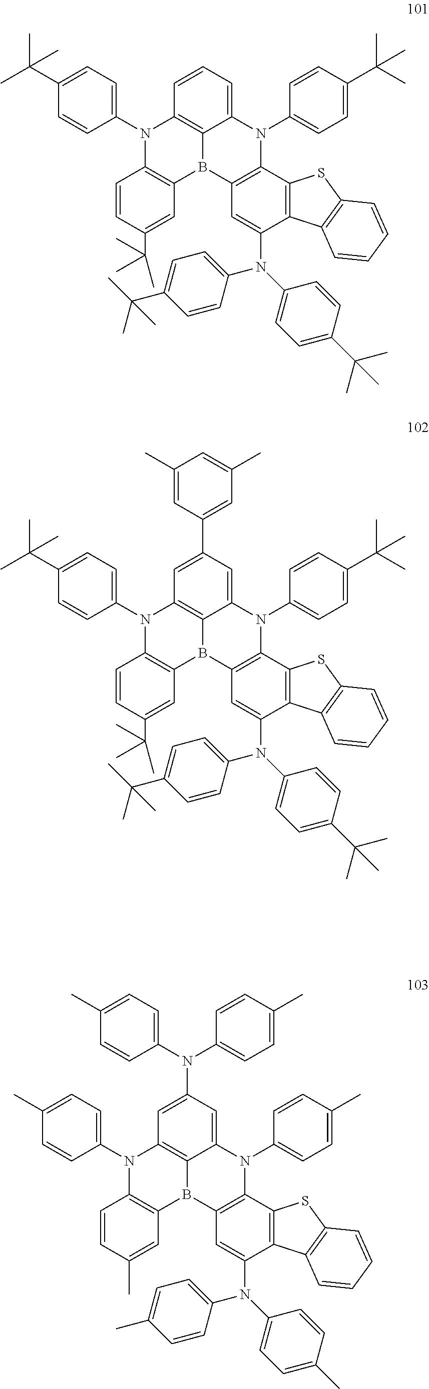

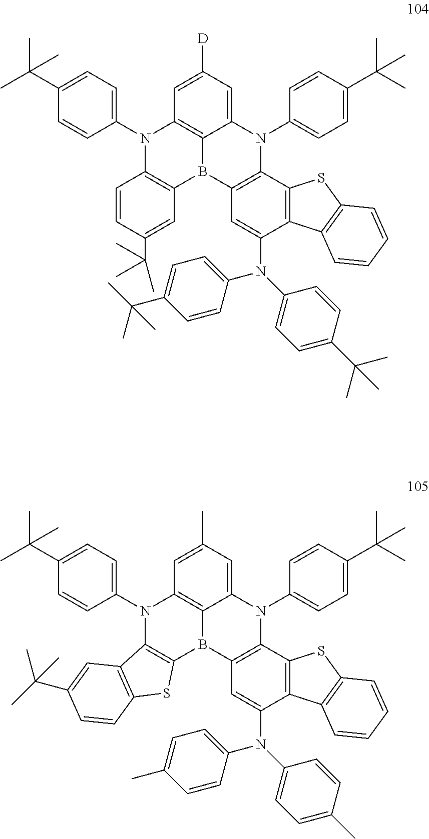

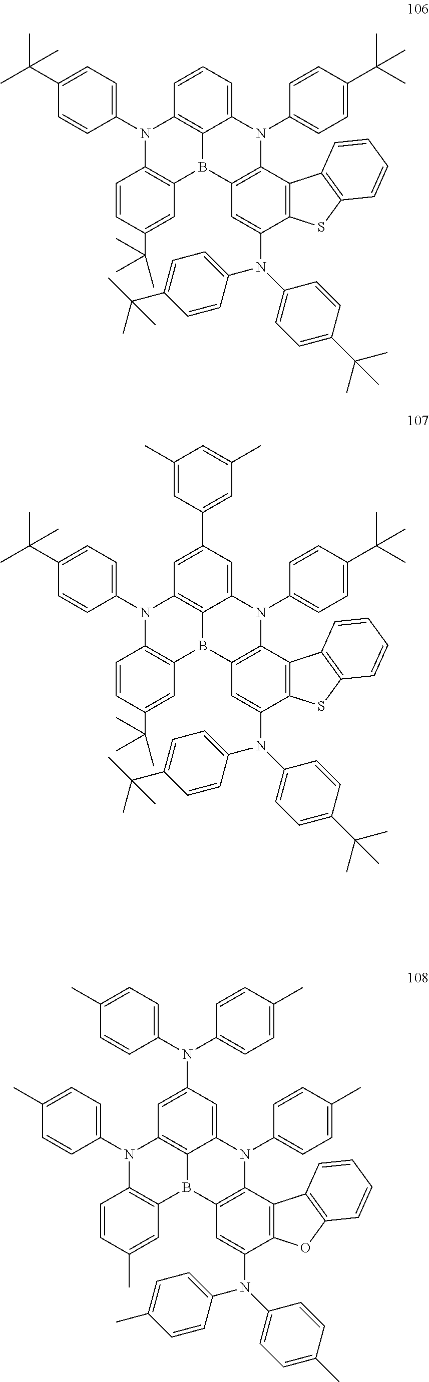

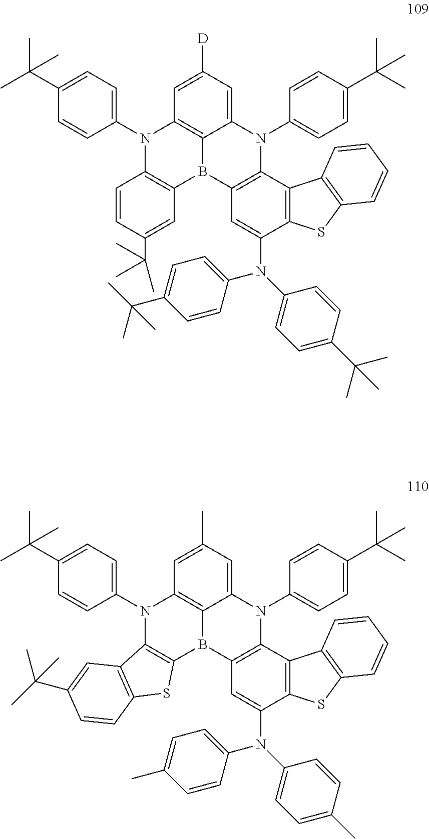

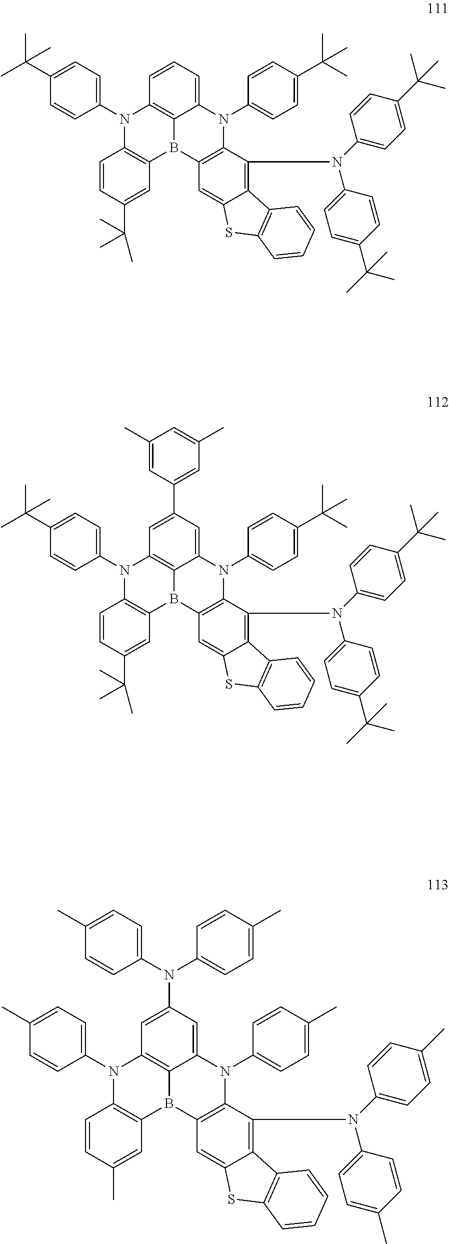

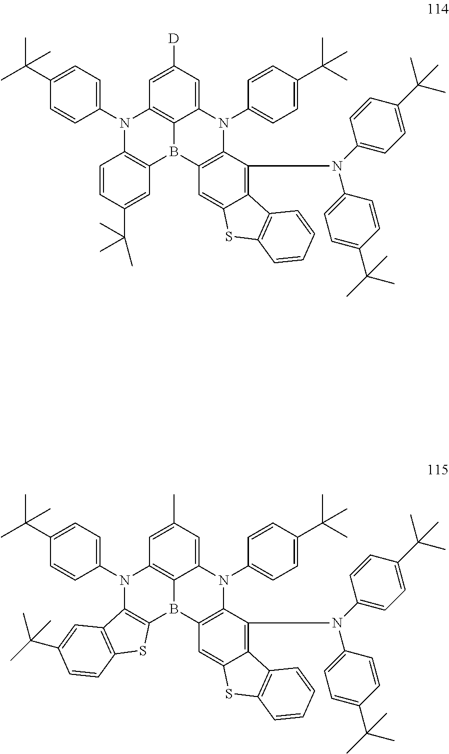

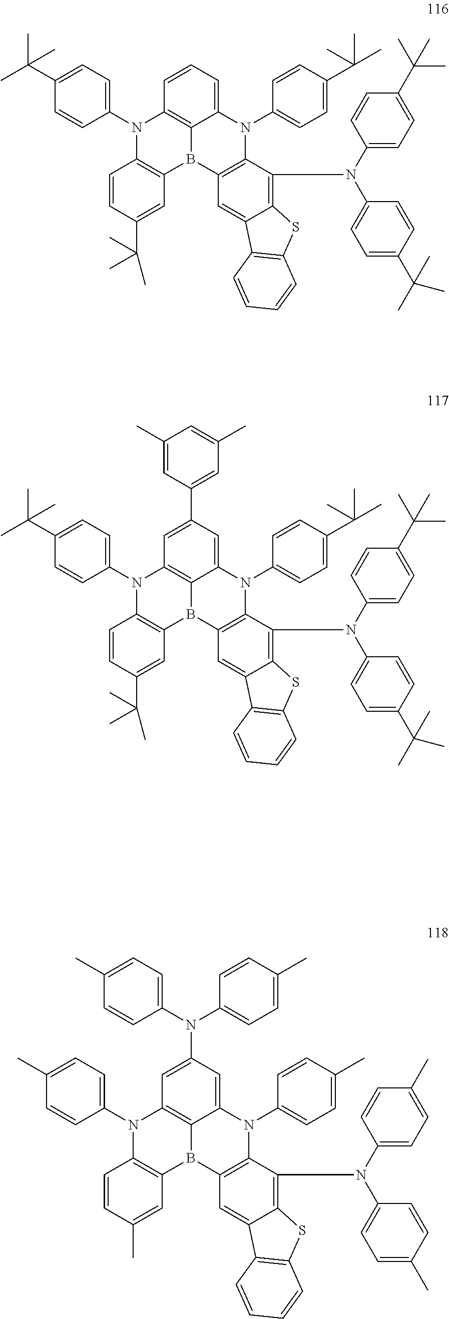

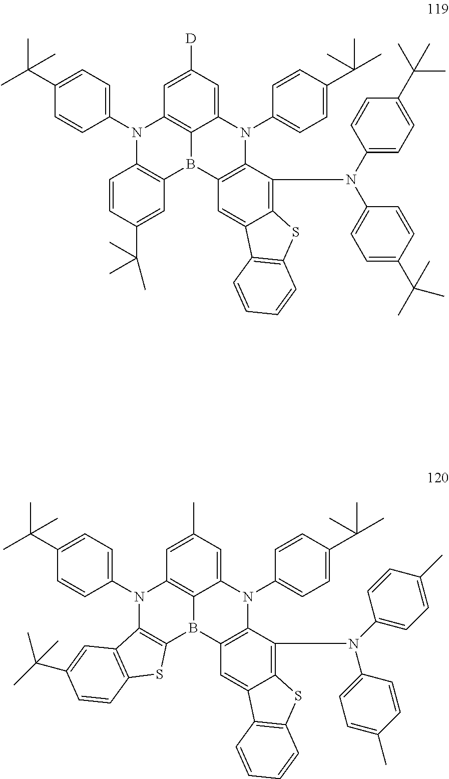

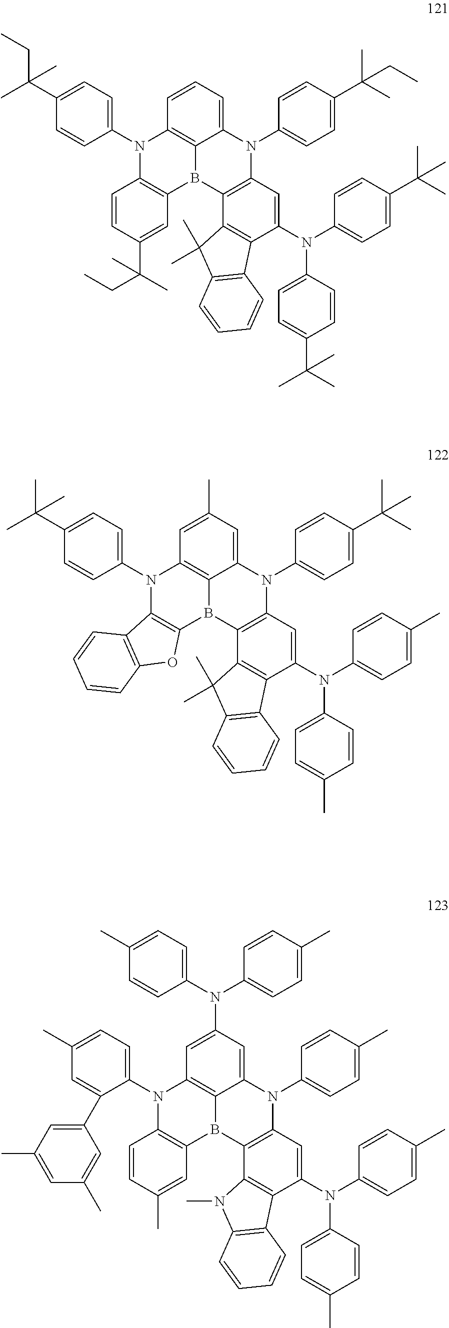

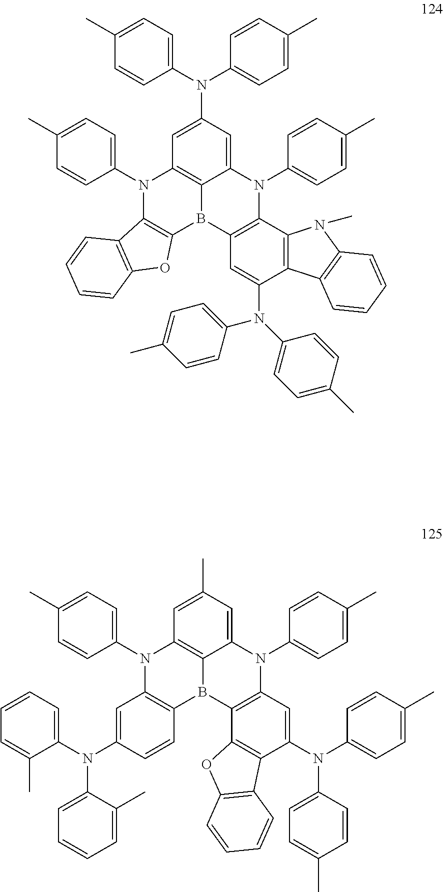 [SMILES: Cc1ccc(N(c2ccc(C)cc2)c2cc3c4c(c2)N(c2ccc(C)cc2)c2c(cc(N(c5ccc(C)cc5)c5ccc(C)cc5)c5c6ccccc6n(C)c25)B4c2oc4ccccc4c2N3c2ccc(C)cc2)cc1 ; Cc1ccc(N2c3cc(N(c4ccccc4C)c4ccccc4C)ccc3B3c4c2cc(C)cc4N(c2ccc(C)cc2)c2cc(N(c4ccc(C)cc4)c4ccc(C)cc4)c4c(oc5ccccc54)c23)cc1]

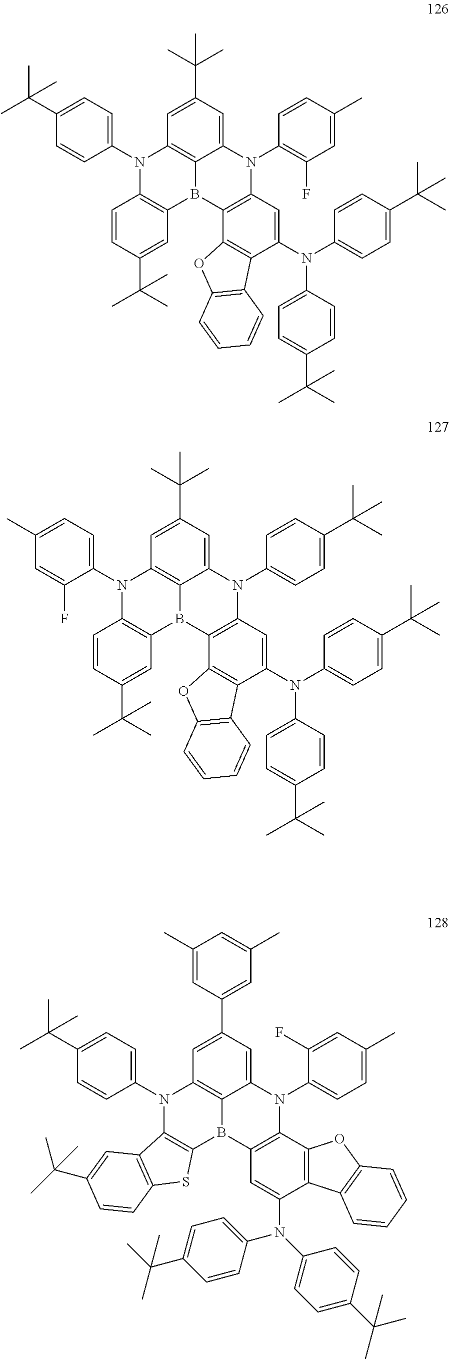

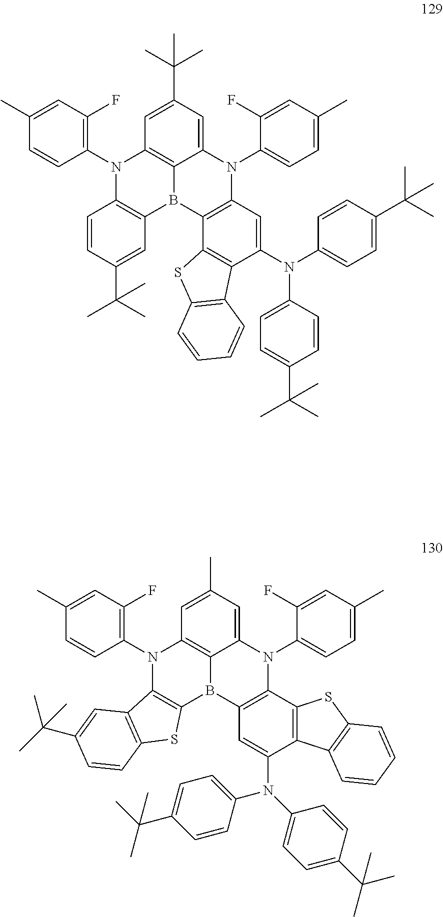

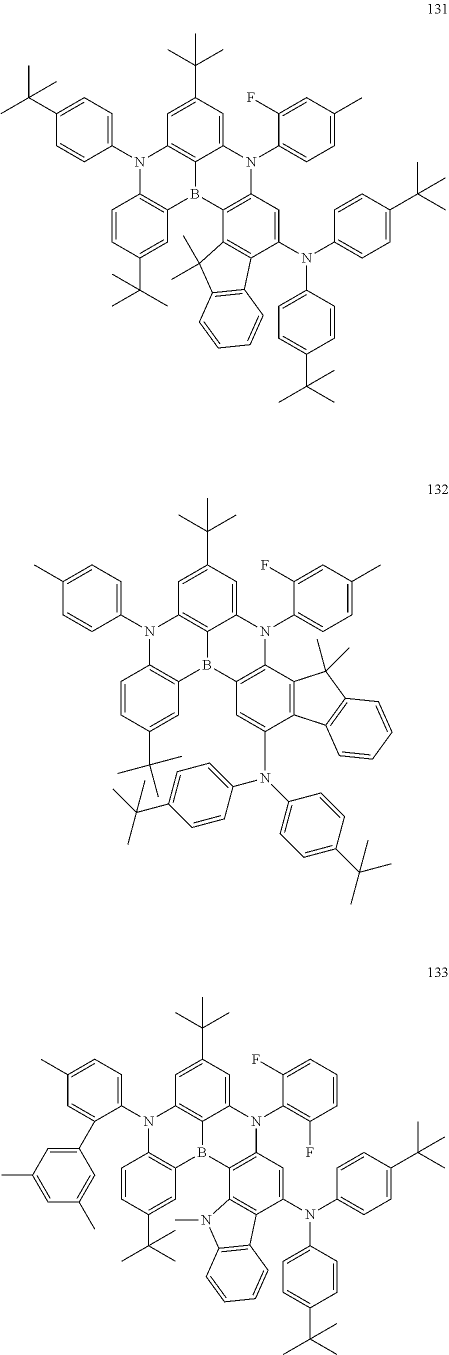

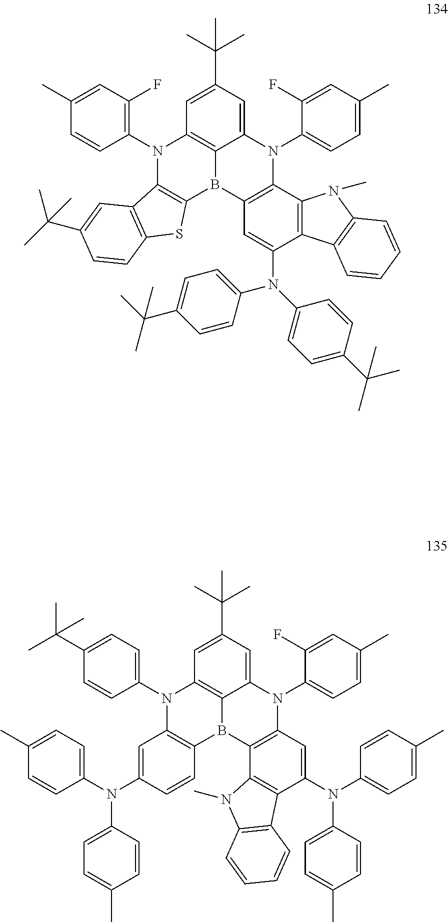

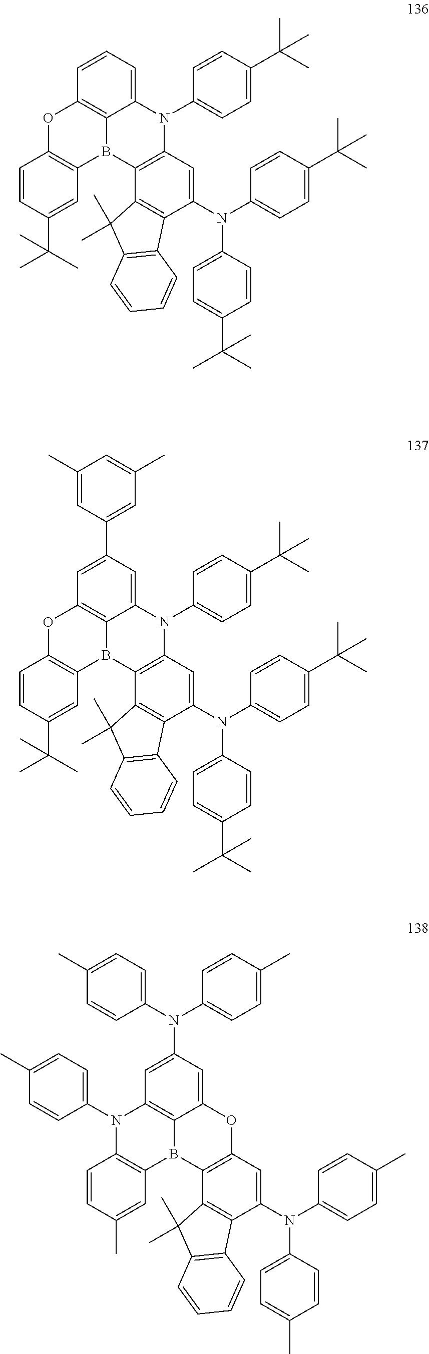

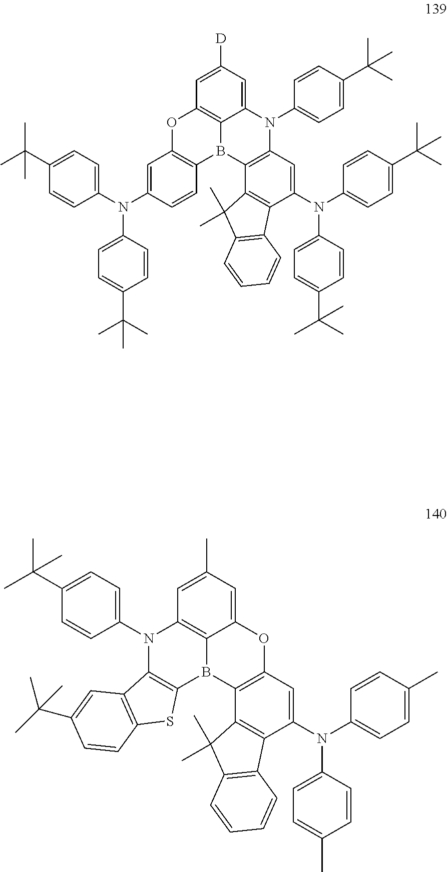

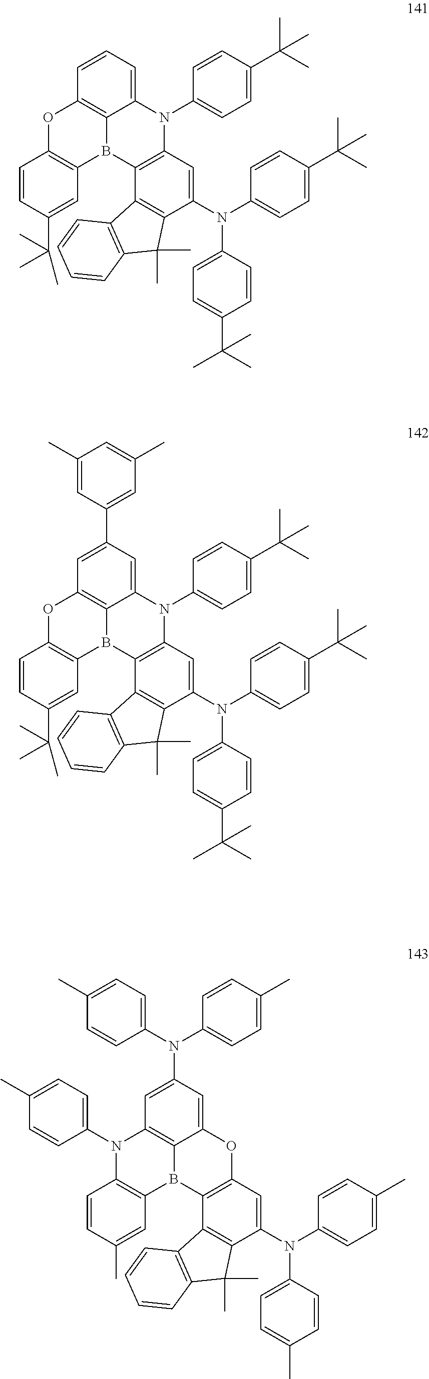

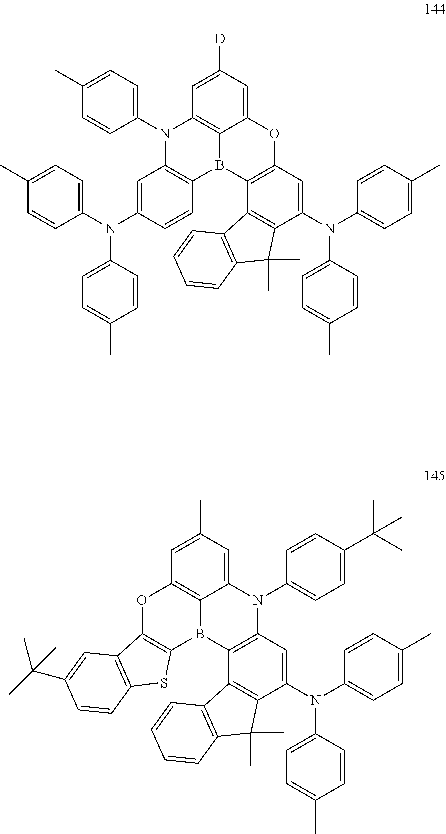

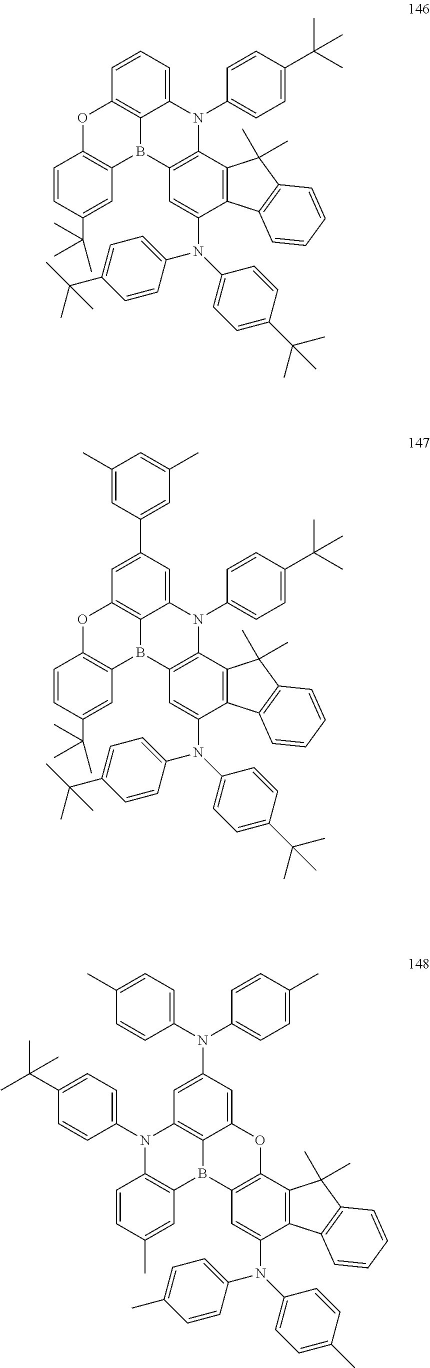

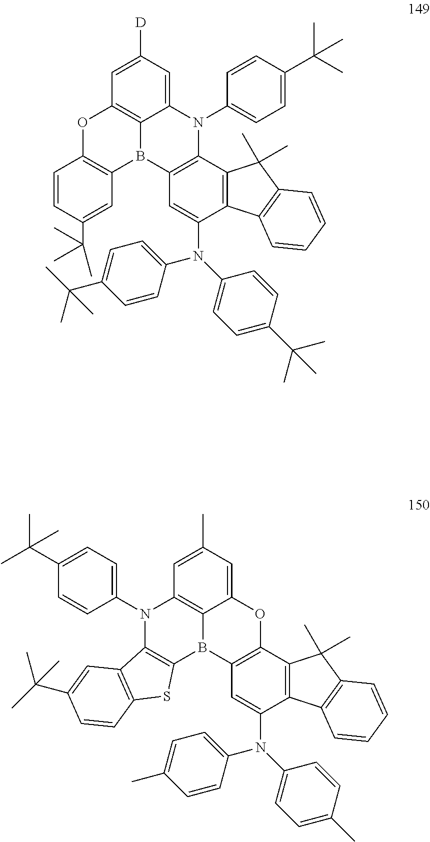

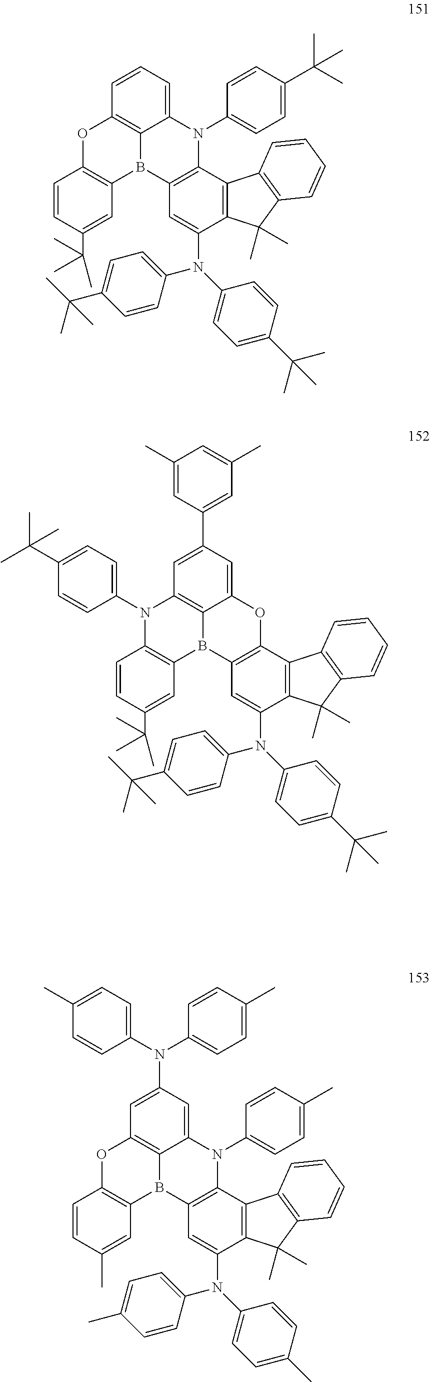

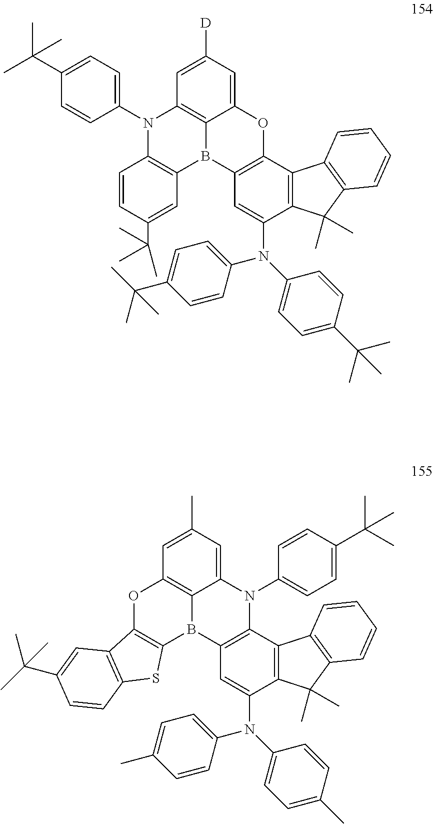 [SMILES: [2H]c1cc2c3c(c1)N(c1ccc(C(C)(C)C)cc1)c1ccc(C(C)(C)C)cc1B3c1cc(N(c3ccc(C(C)(C)C)cc3)c3ccc(C(C)(C)C)cc3)c3c(c1O2)-c1ccccc1C3(C)C ; Cc1ccc(N(c2ccc(C)cc2)c2cc3c(c4c2C(C)(C)c2ccccc2-4)N(c2ccc(C(C)(C)C)cc2)c2cc(C)cc4c2B3c2sc3ccc(C(C)(C)C)cc3c2O4)cc1]

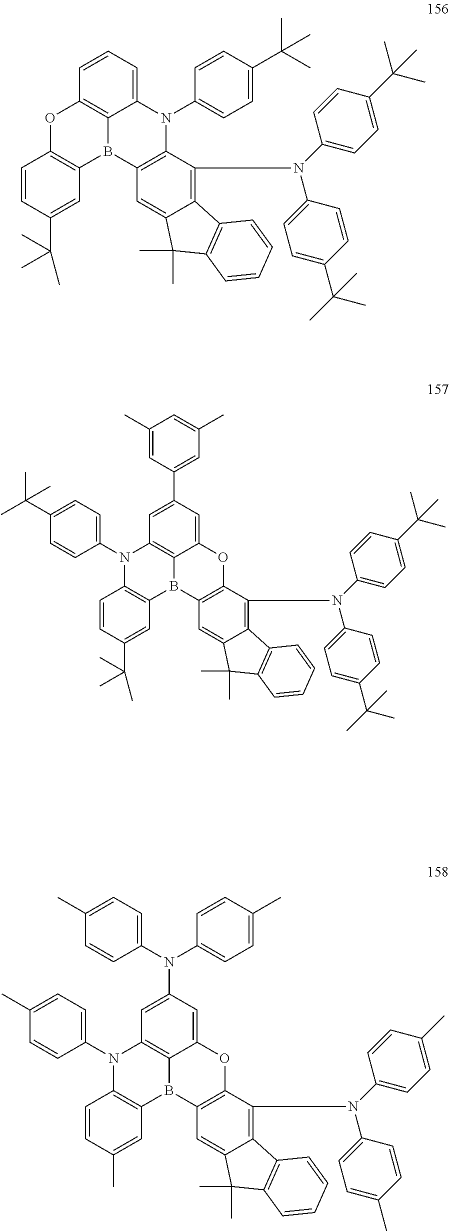

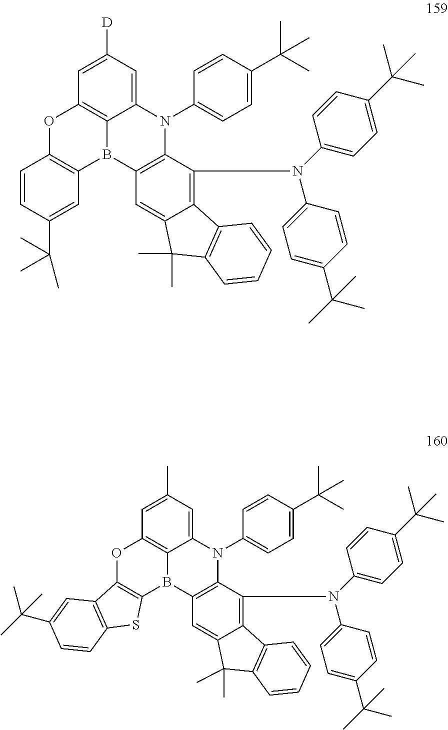

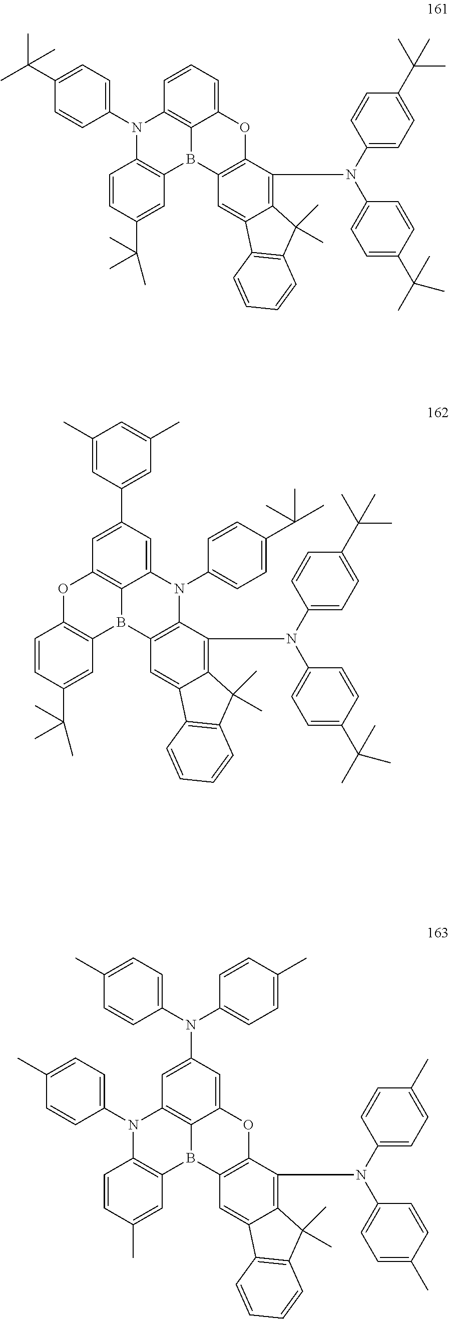

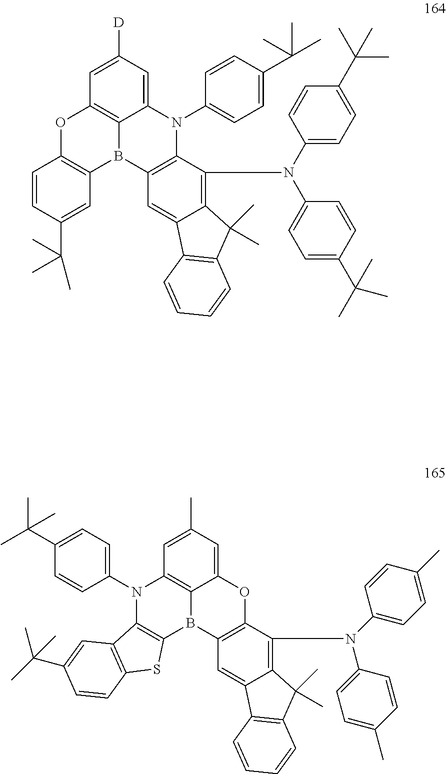

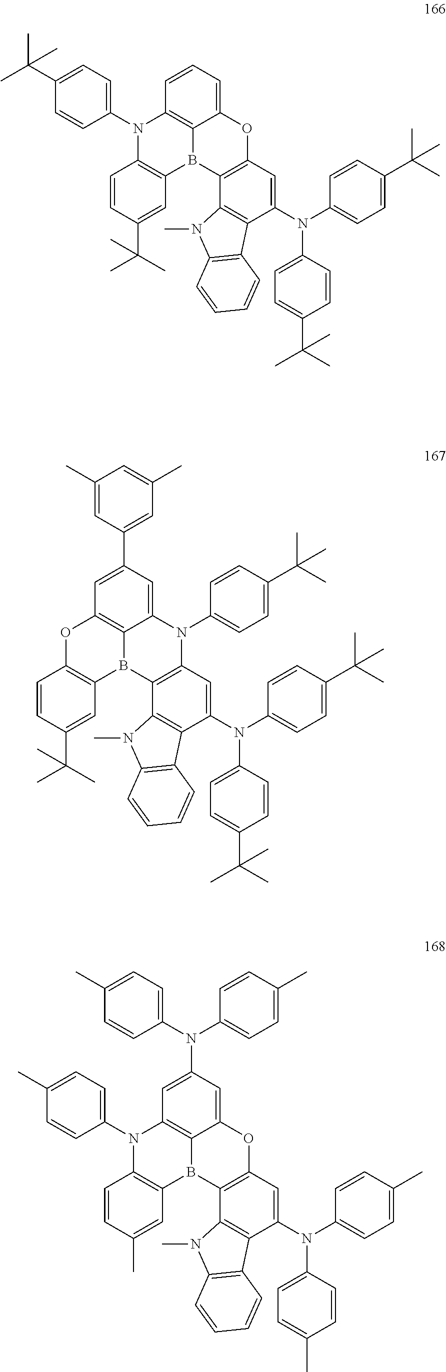

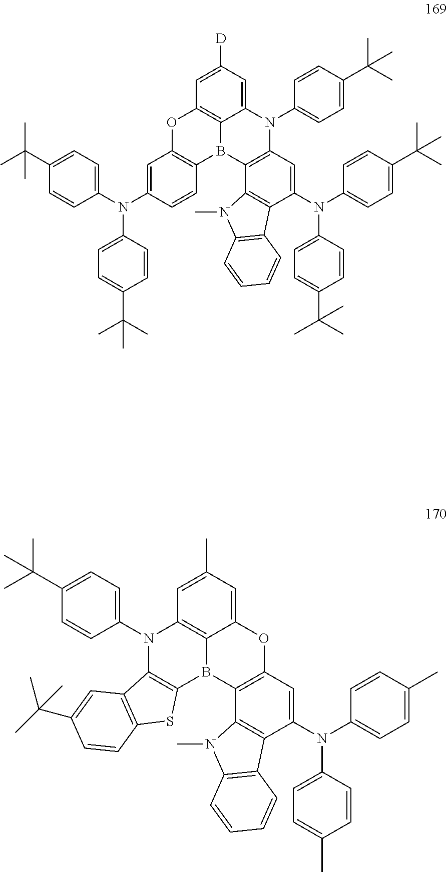

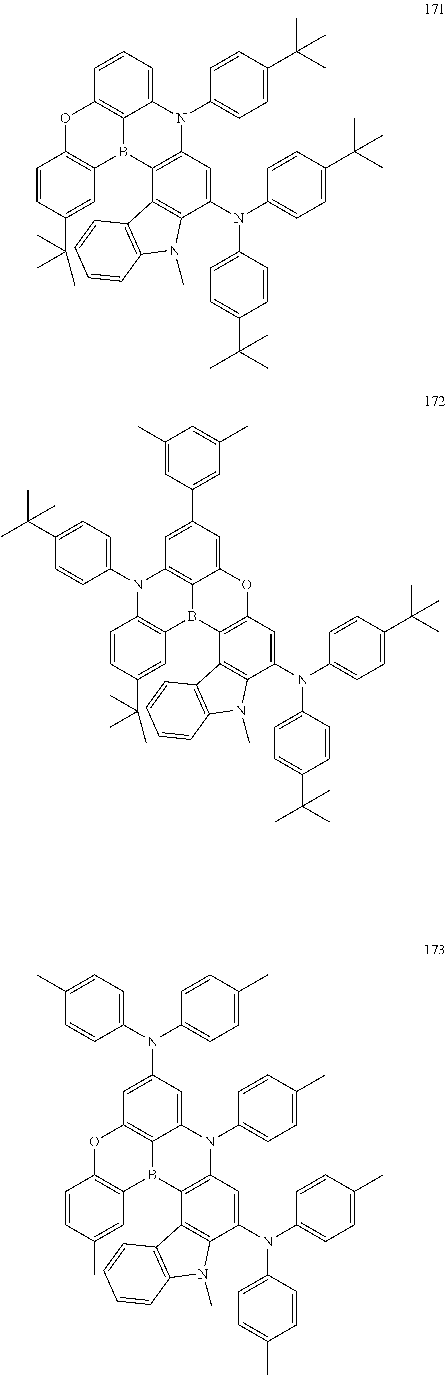

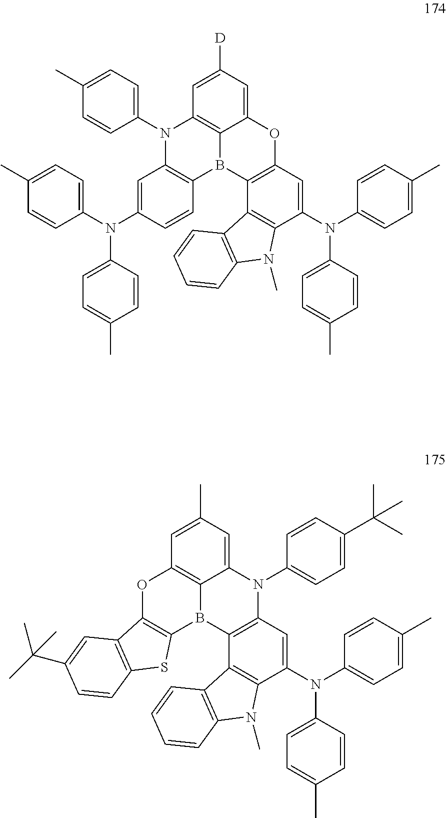

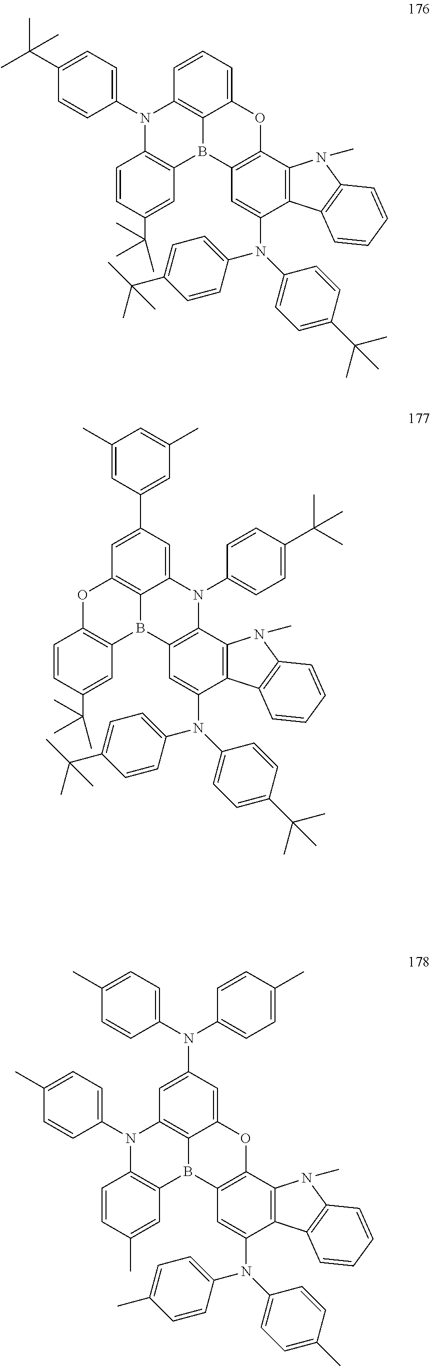

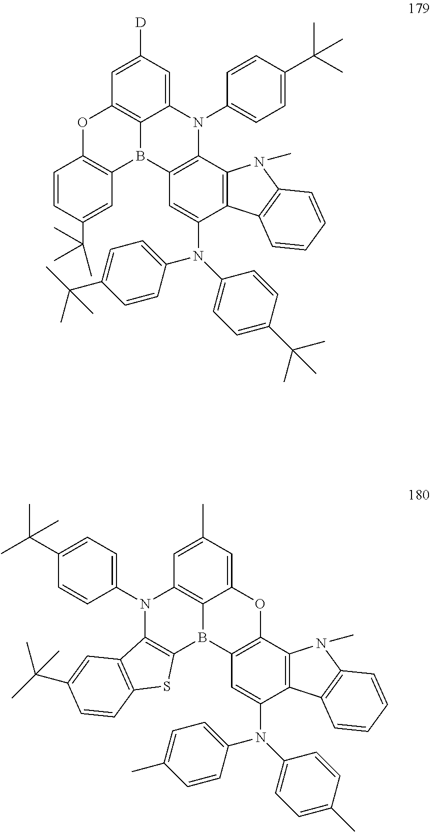

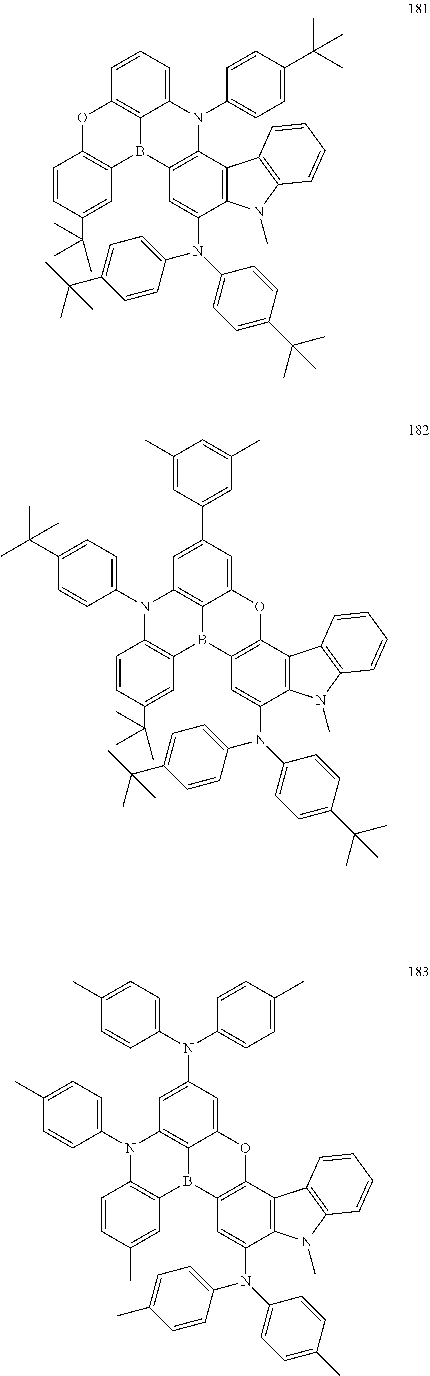

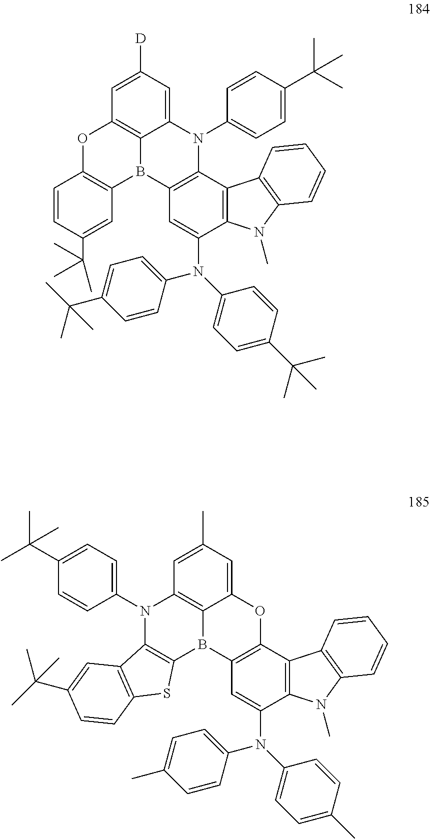

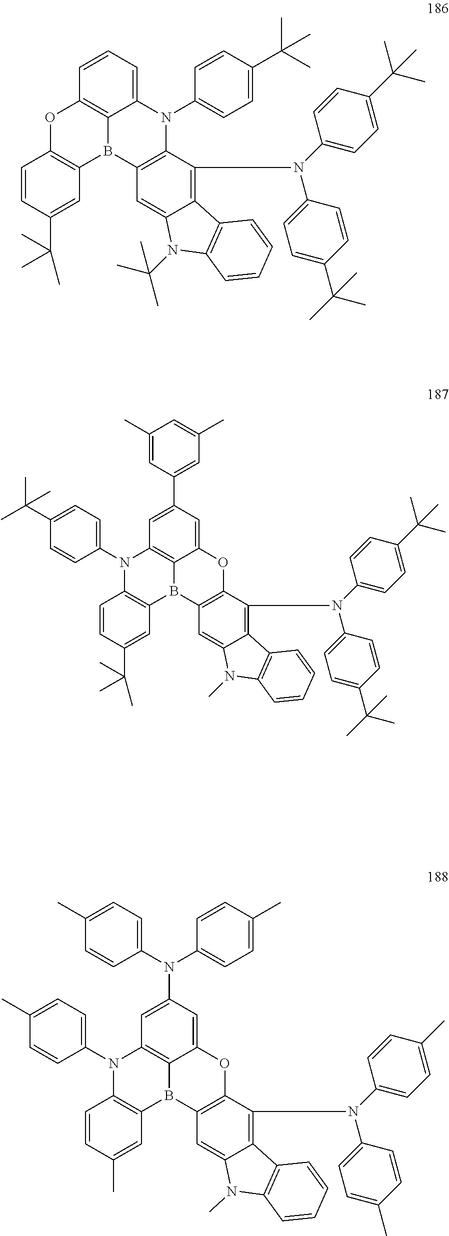

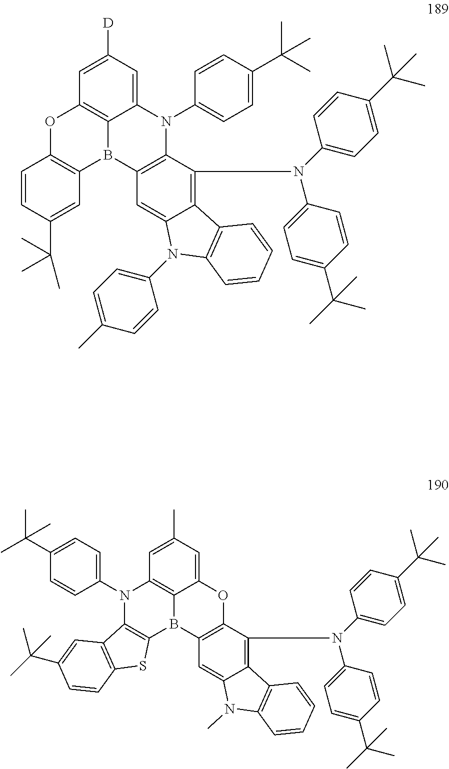

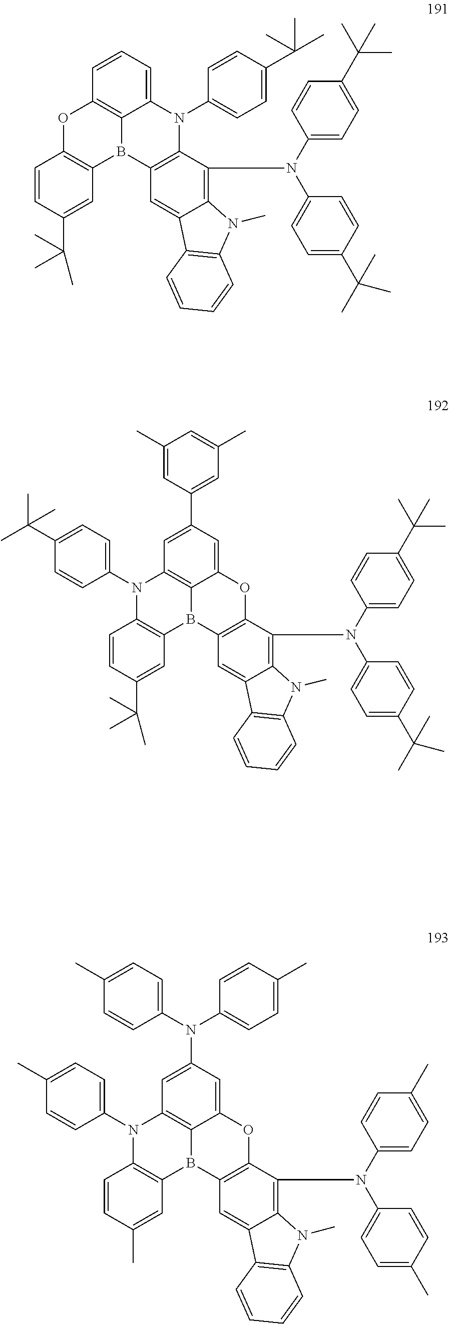

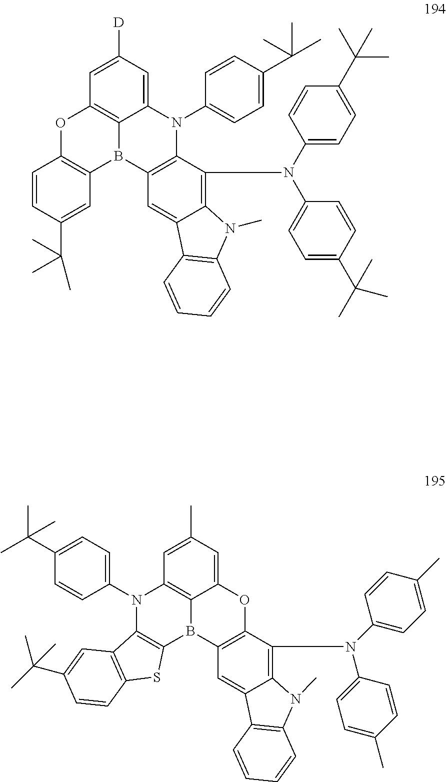

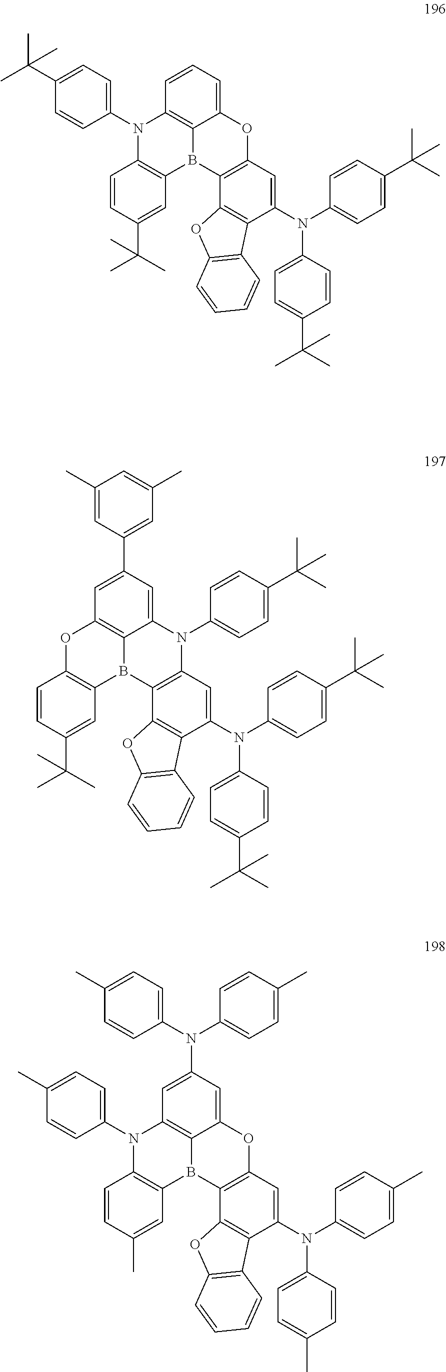

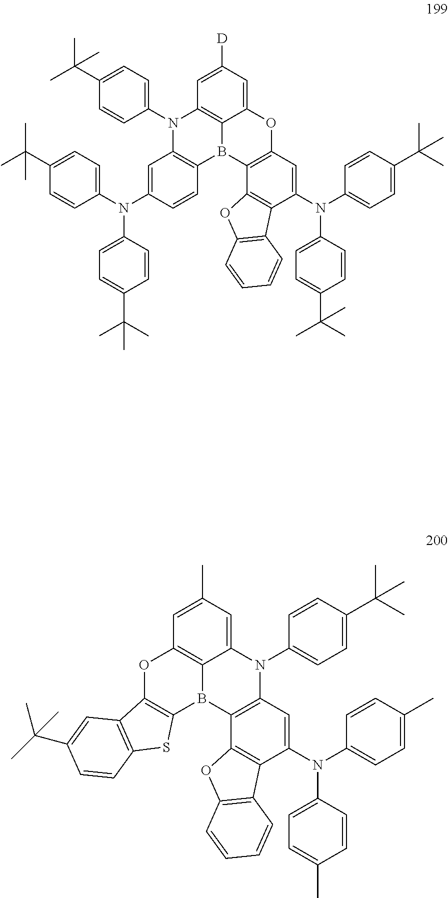

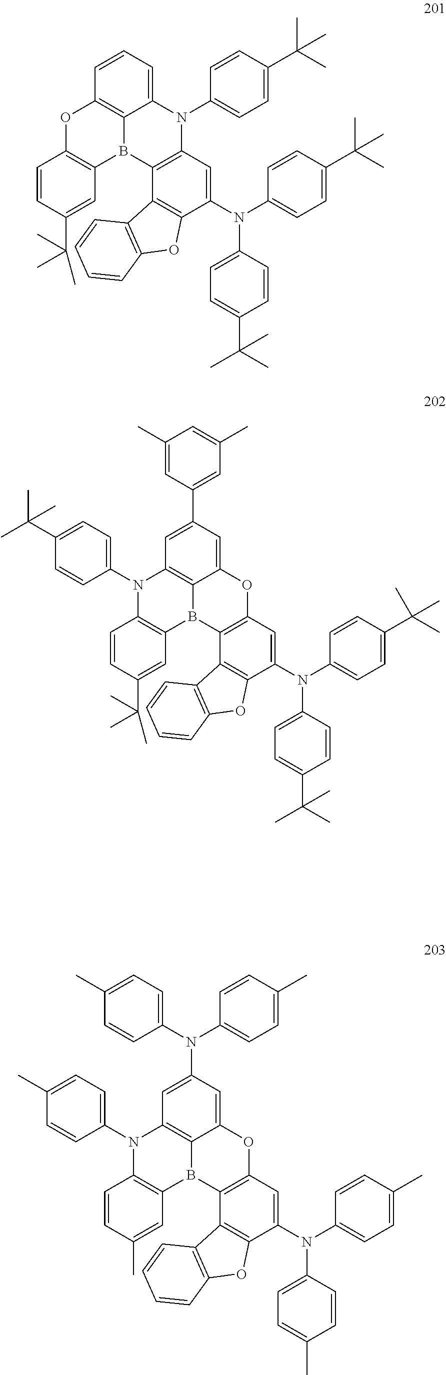

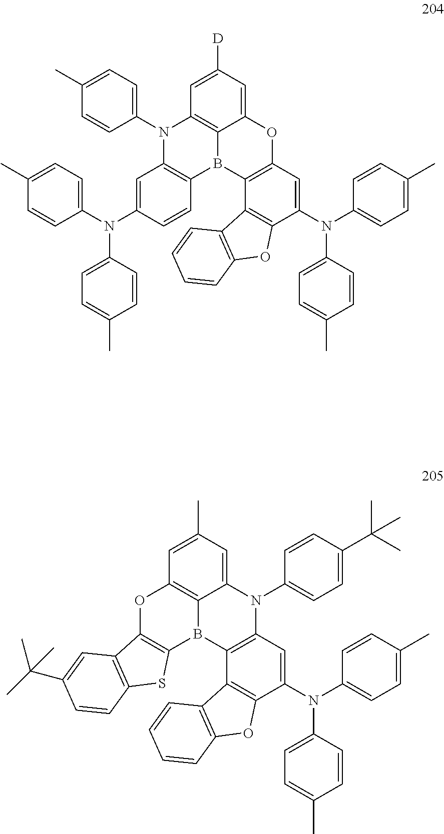

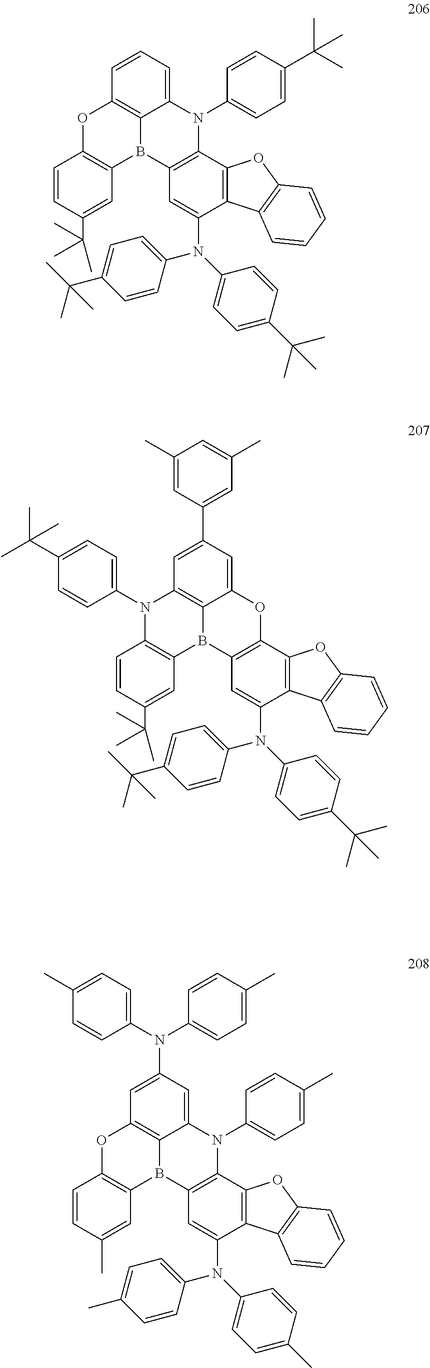

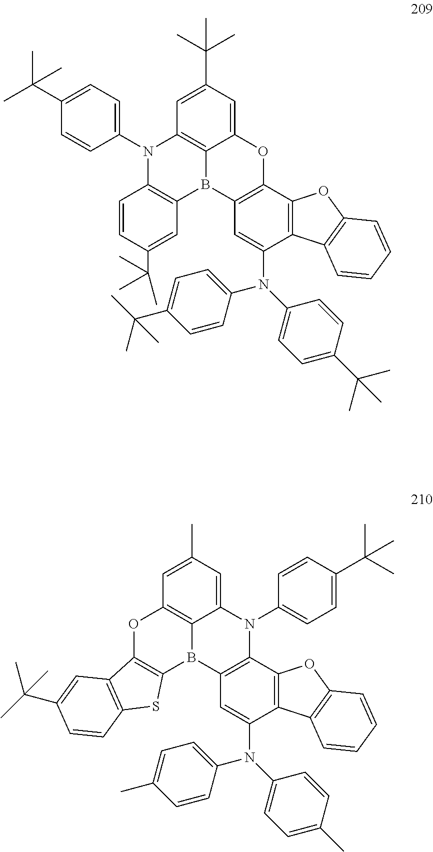 [SMILES: CC(C)(C)c1ccc(N2c3ccc(C(C)(C)C)cc3B3c4cc(N(c5ccc(C(C)(C)C)cc5)c5ccc(C(C)(C)C)cc5)c5c(oc6ccccc65)c4Oc4cc(C(C)(C)C)cc2c43)cc1 ; Cc1ccc(N(c2ccc(C)cc2)c2cc3c(c4oc5ccccc5c24)N(c2ccc(C(C)(C)C)cc2)c2cc(C)cc4c2B3c2sc3ccc(C(C)(C)C)cc3c2O4)cc1]

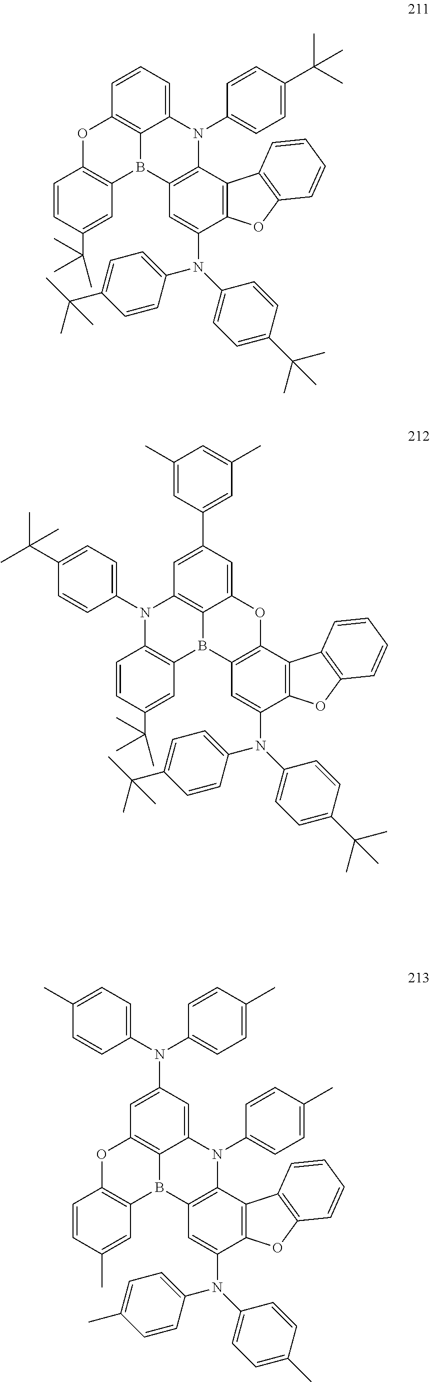

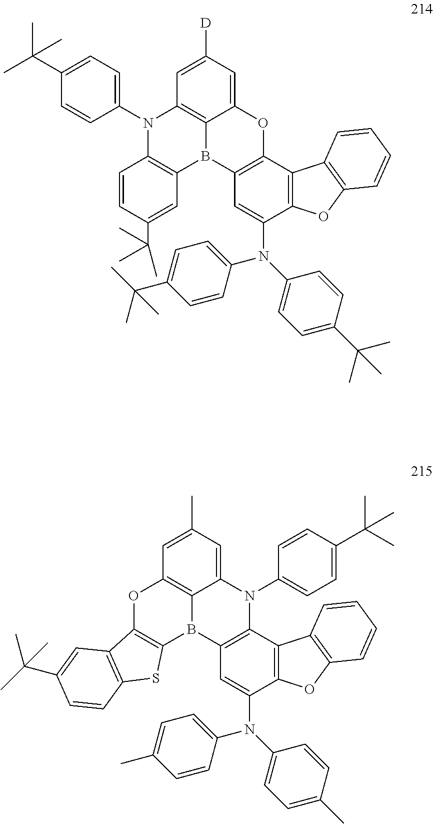 [SMILES: [2H]c1cc2c3c(c1)N(c1ccc(C(C)(C)C)cc1)c1ccc(C(C)(C)C)cc1B3c1cc(N(c3ccc(C(C)(C)C)cc3)c3ccc(C(C)(C)C)cc3)c3oc4ccccc4c3c1O2 ; Cc1ccc(N(c2ccc(C)cc2)c2cc3c(c4c2oc2ccccc24)N(c2ccc(C(C)(C)C)cc2)c2cc(C)cc4c2B3c2sc3ccc(C(C)(C)C)cc3c2O4)cc1]

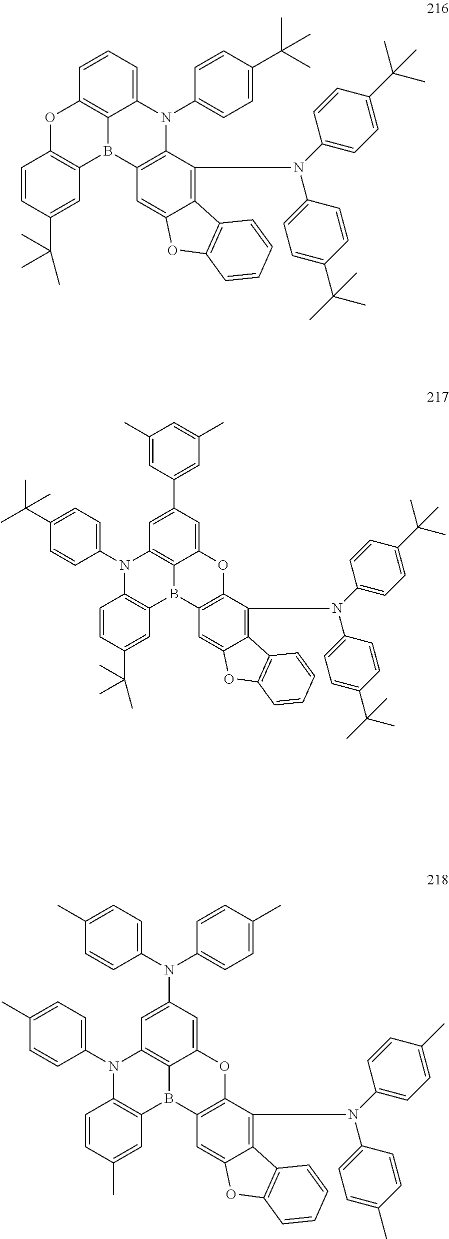

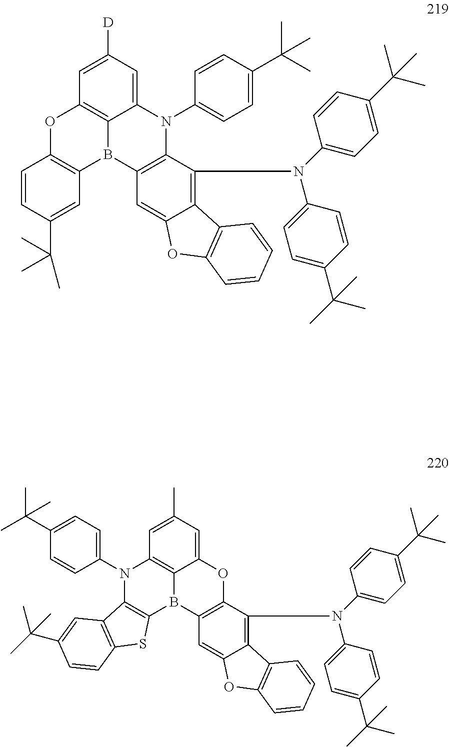

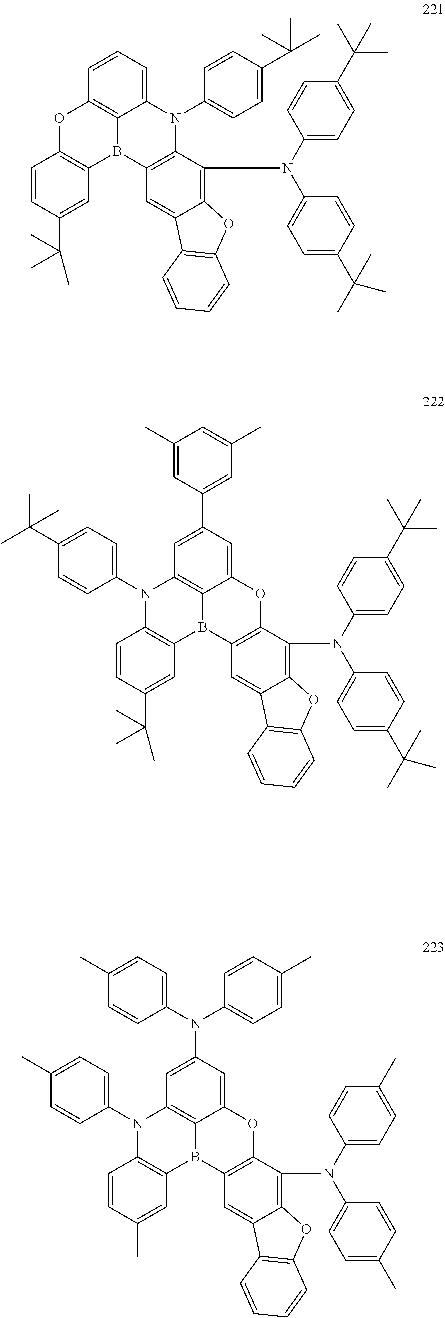

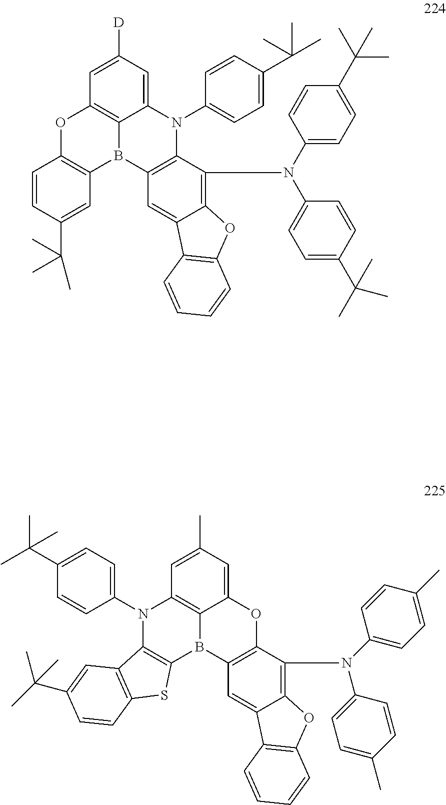

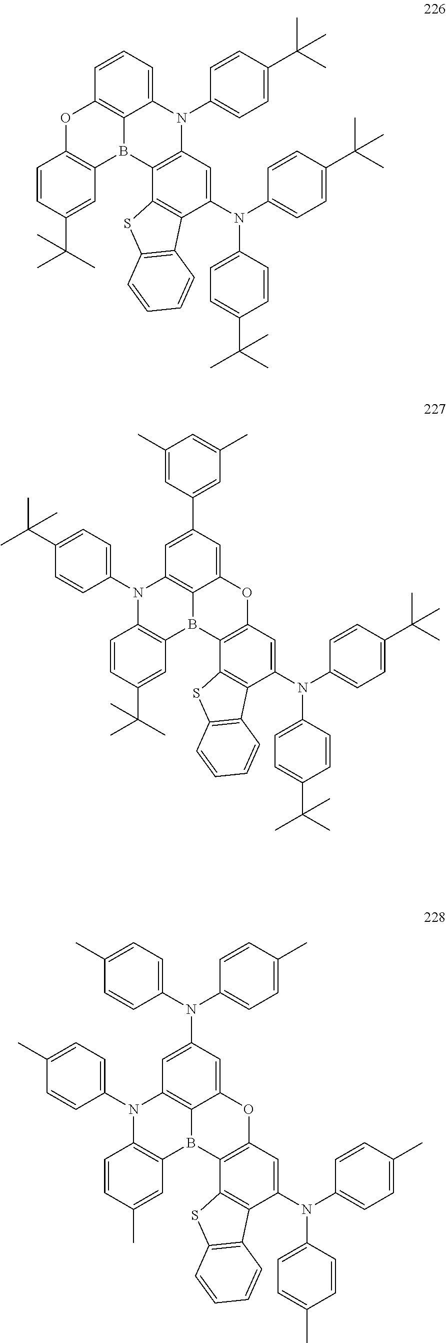

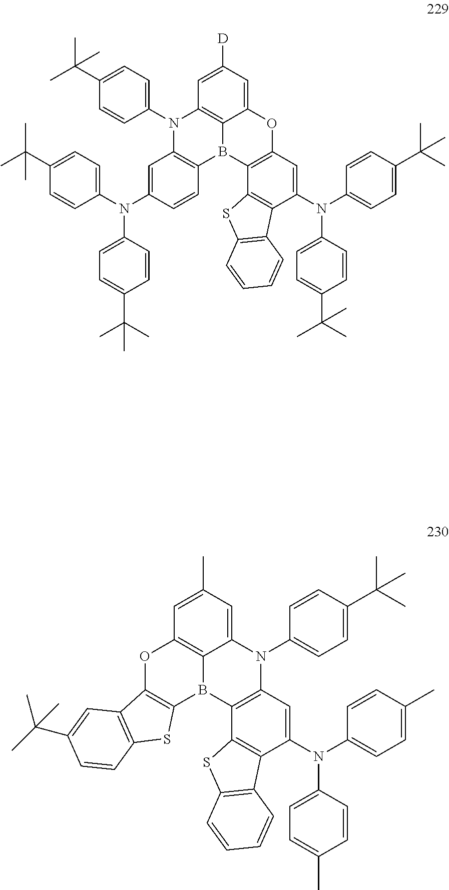

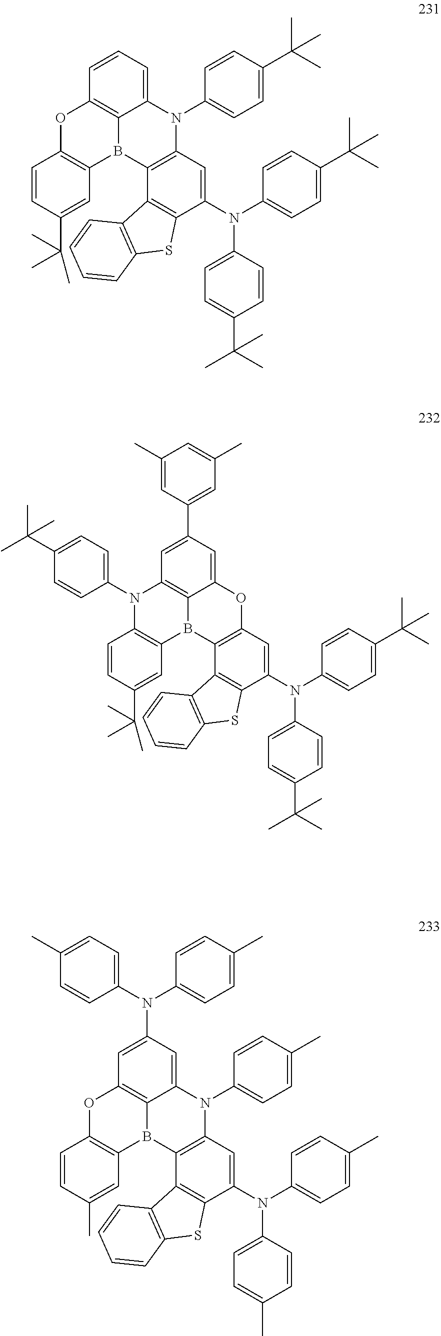

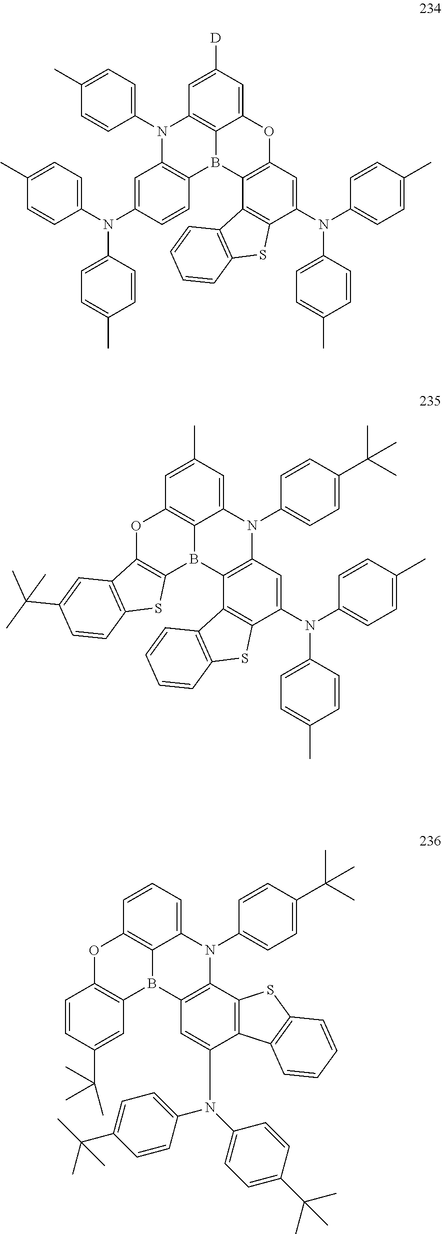

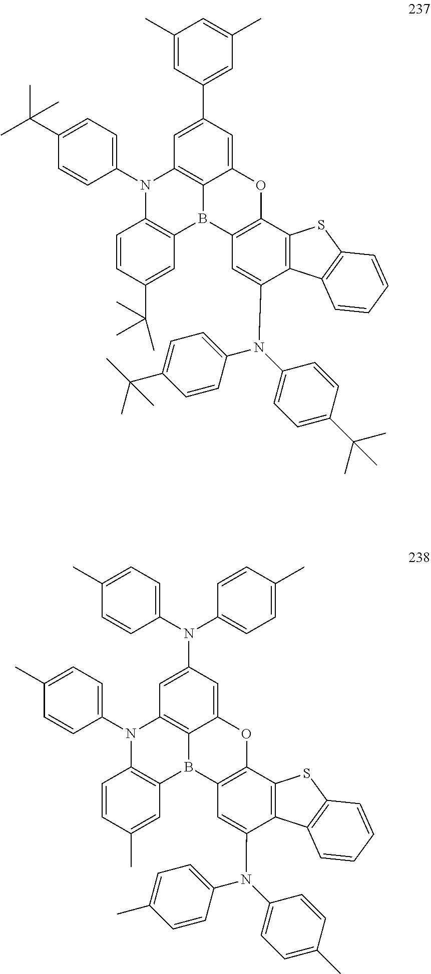 [SMILES: Cc1cc(C)cc(-c2cc3c4c(c2)N(c2ccc(C(C)(C)C)cc2)c2ccc(C(C)(C)C)cc2B4c2cc(N(c4ccc(C(C)(C)C)cc4)c4ccc(C(C)(C)C)cc4)c4c(sc5ccccc54)c2O3)c1 ; Cc1ccc(N(c2ccc(C)cc2)c2cc3c4c(c2)N(c2ccc(C)cc2)c2ccc(C)cc2B4c2cc(N(c4ccc(C)cc4)c4ccc(C)cc4)c4c(sc5ccccc54)c2O3)cc1]

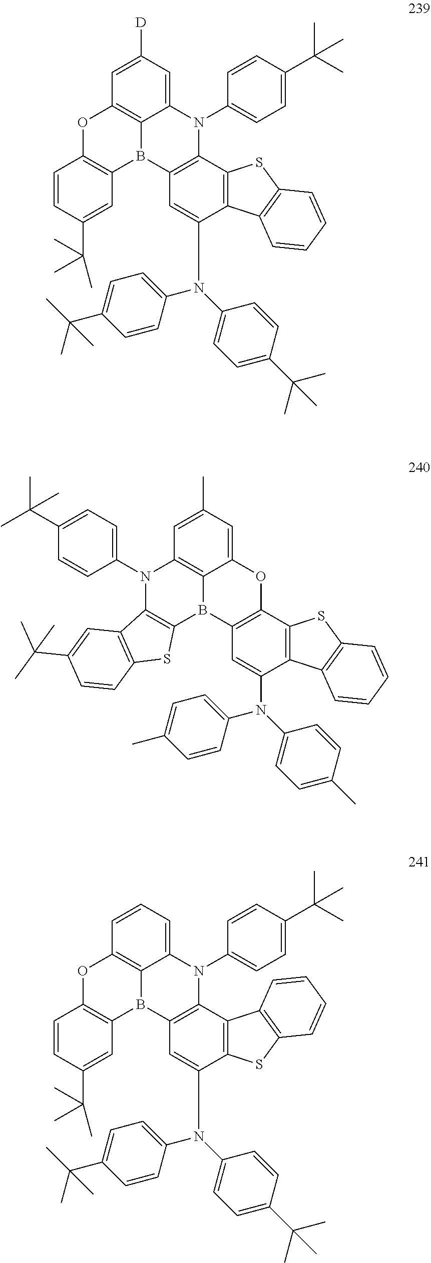

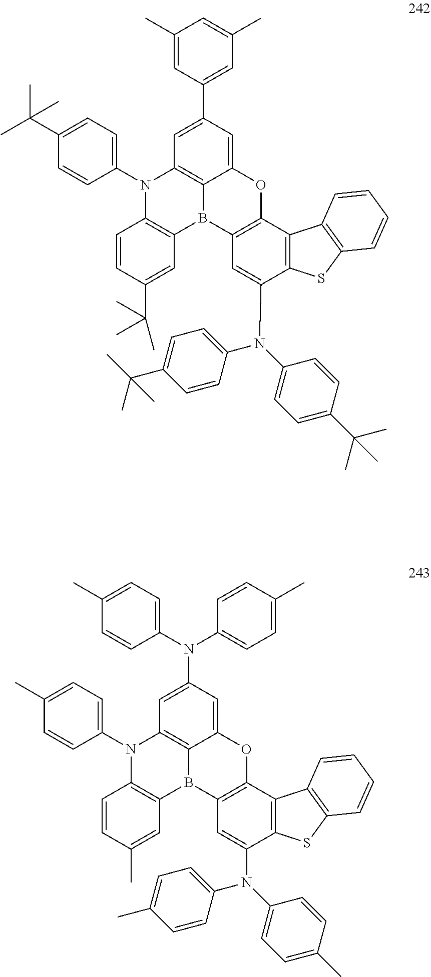 [SMILES: Cc1cc(C)cc(-c2cc3c4c(c2)N(c2ccc(C(C)(C)C)cc2)c2ccc(C(C)(C)C)cc2B4c2cc(N(c4ccc(C(C)(C)C)cc4)c4ccc(C(C)(C)C)cc4)c4sc5ccccc5c4c2O3)c1 ; Cc1ccc(N(c2ccc(C)cc2)c2cc3c4c(c2)N(c2ccc(C)cc2)c2ccc(C)cc2B4c2cc(N(c4ccc(C)cc4)c4ccc(C)cc4)c4sc5ccccc5c4c2O3)cc1]

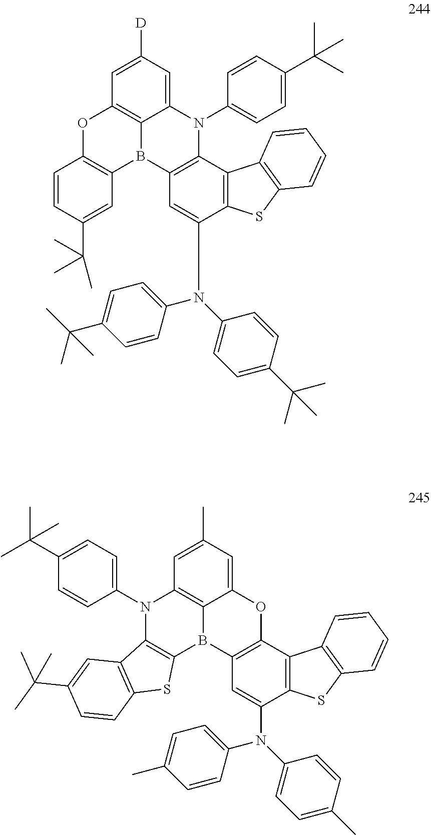

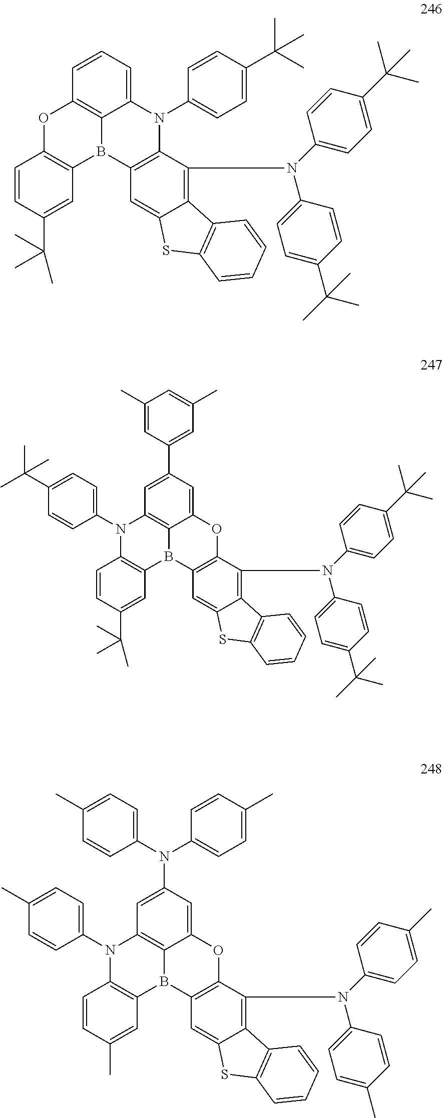

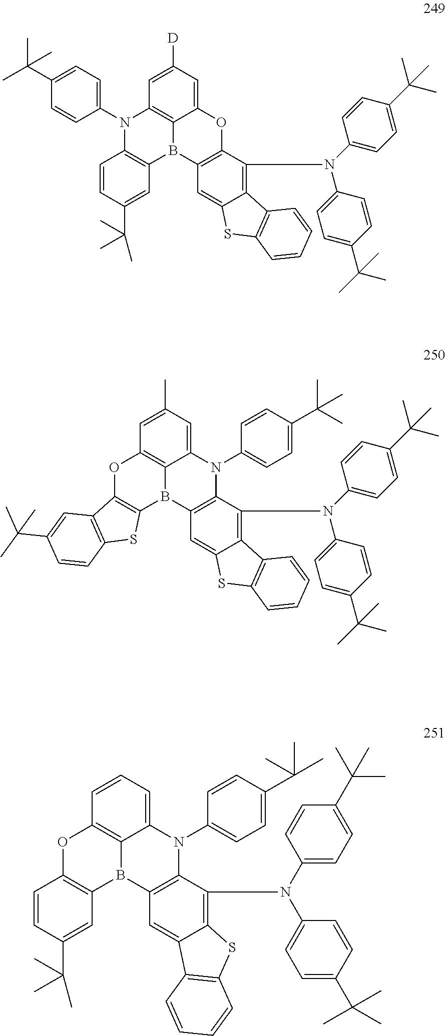

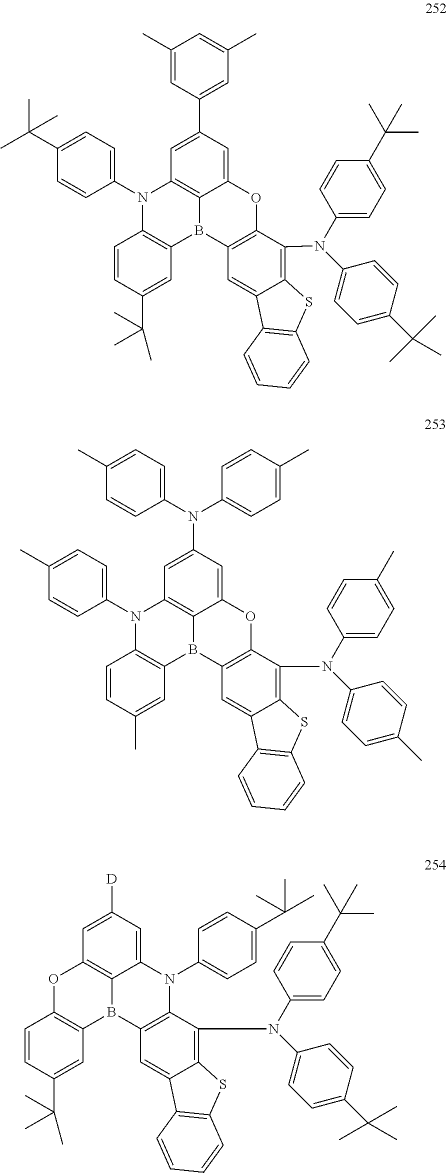

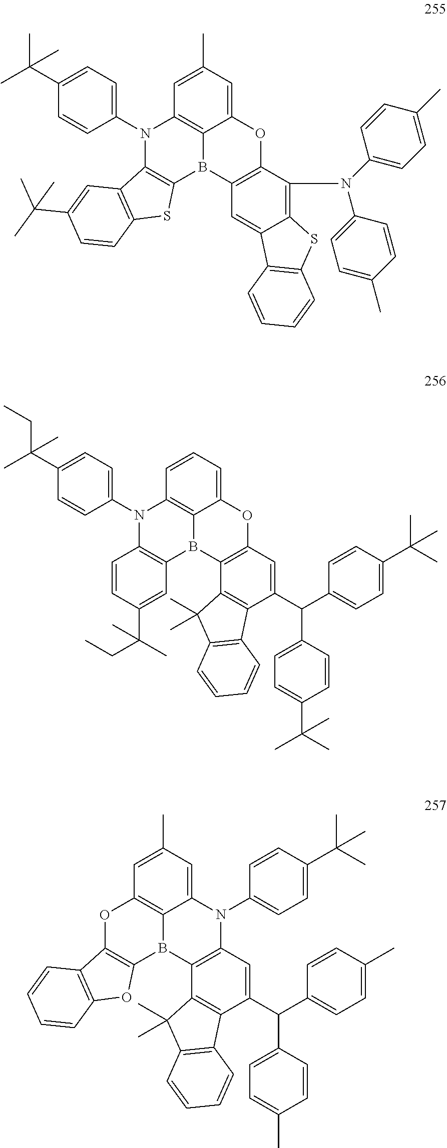

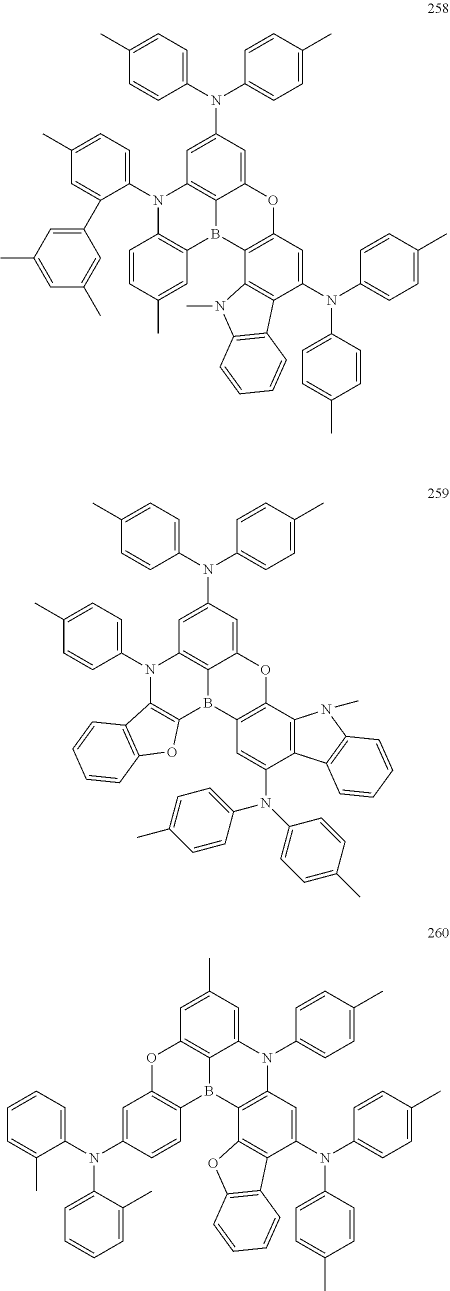

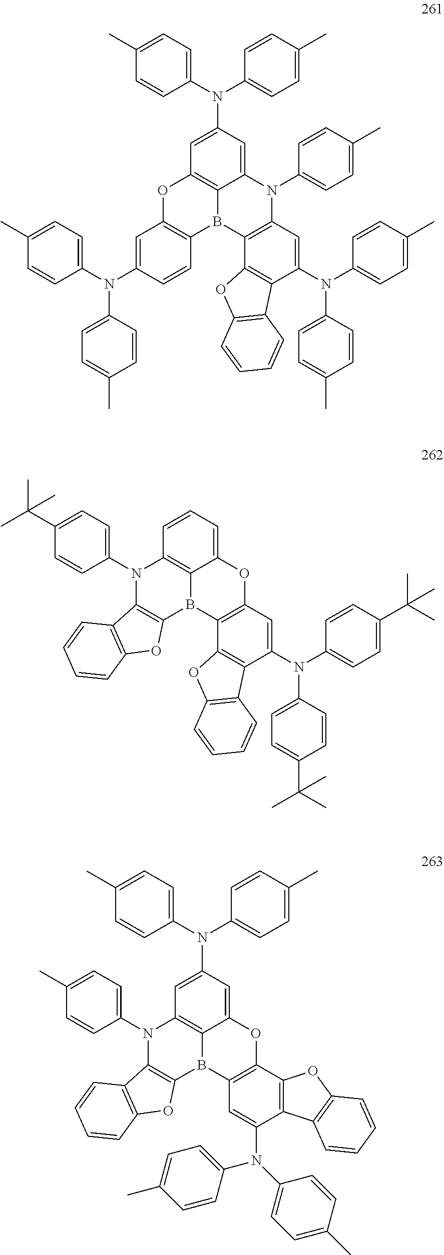

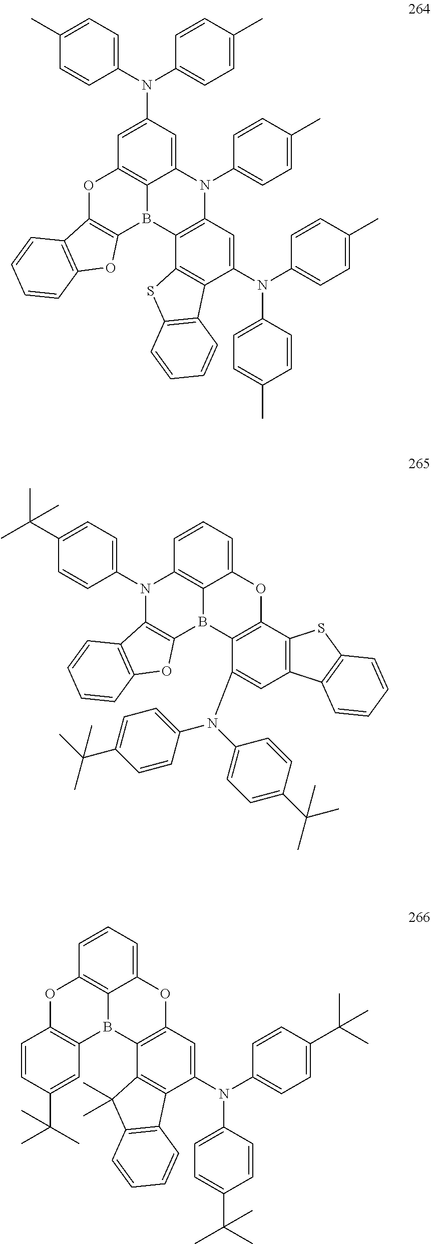

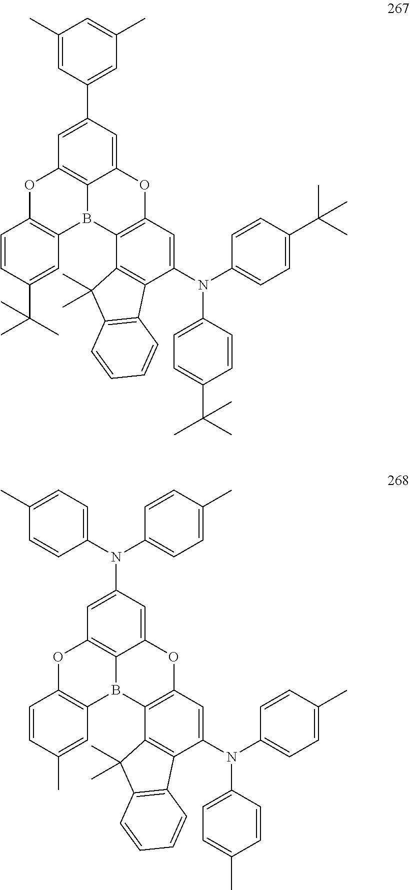

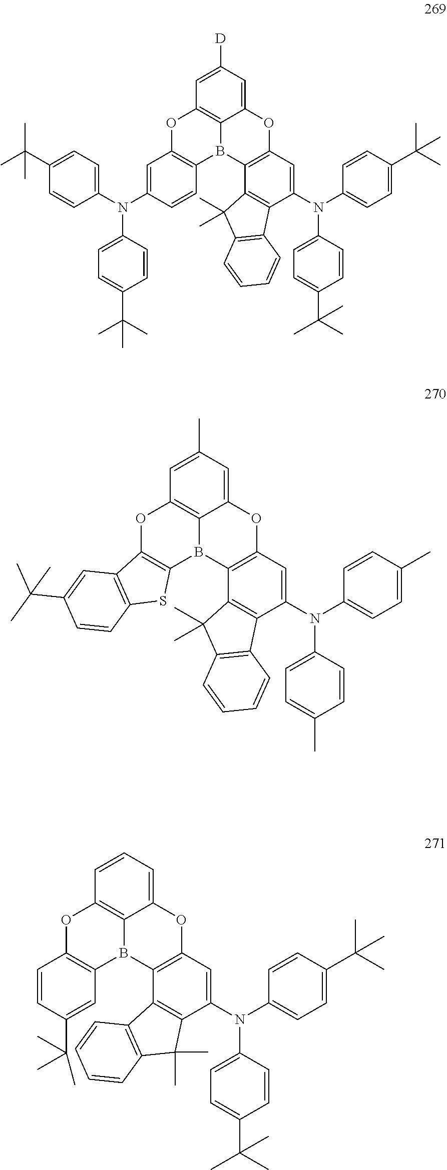

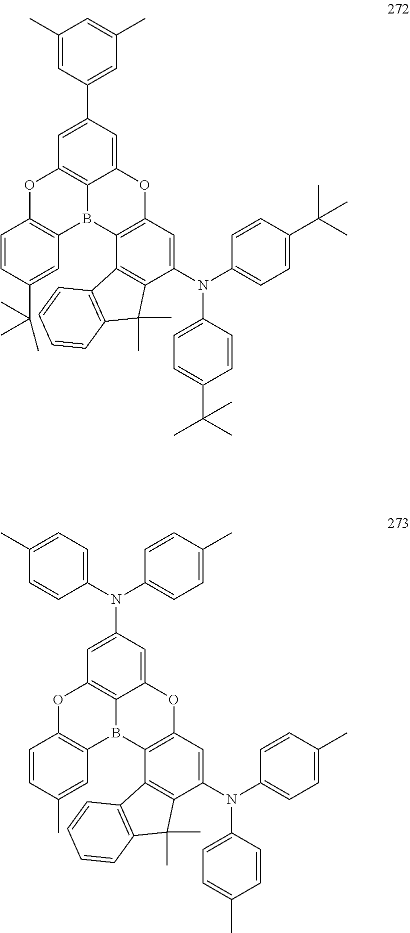

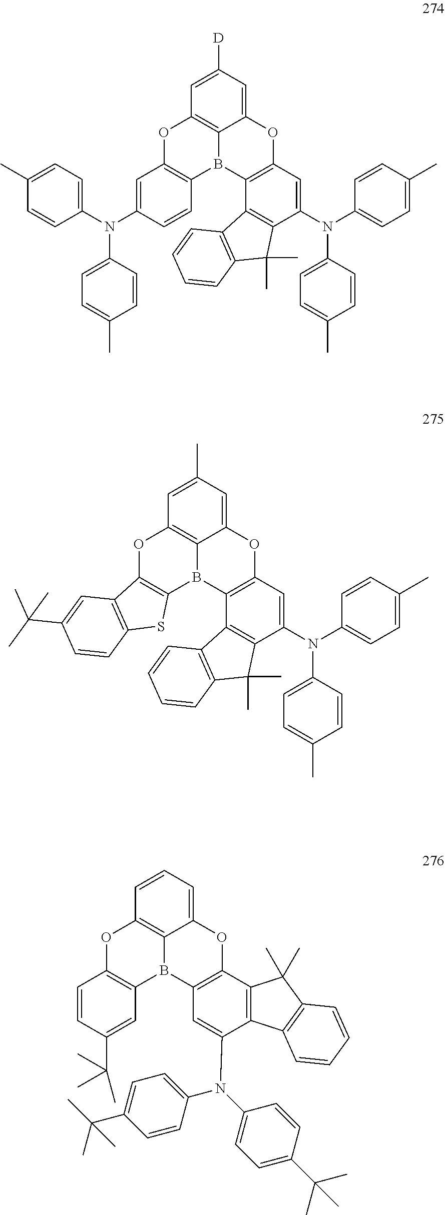

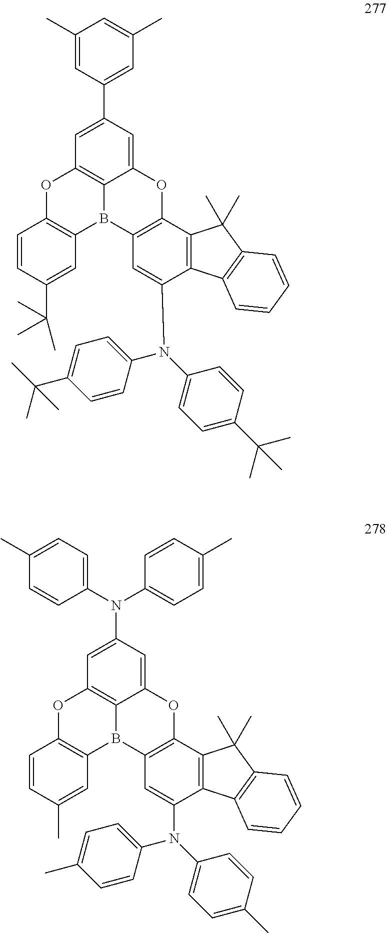

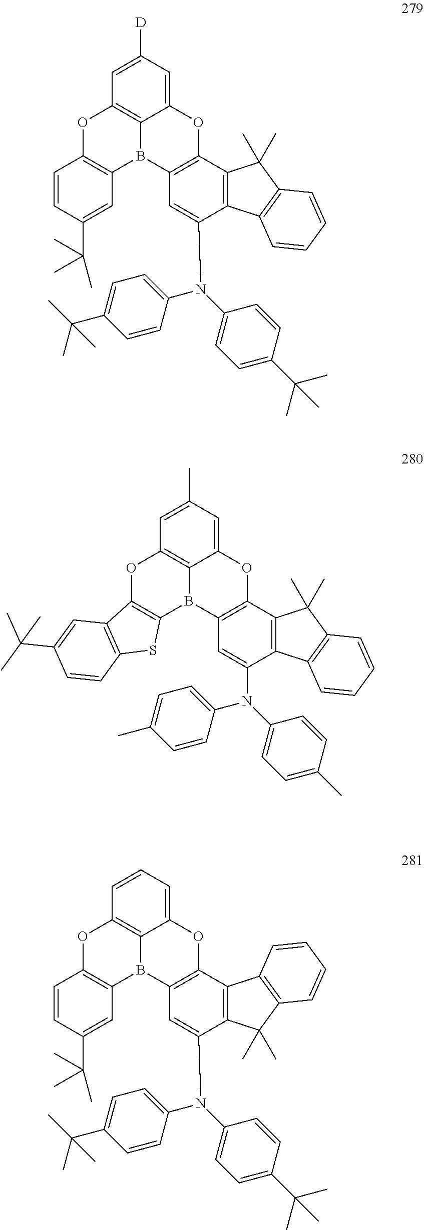

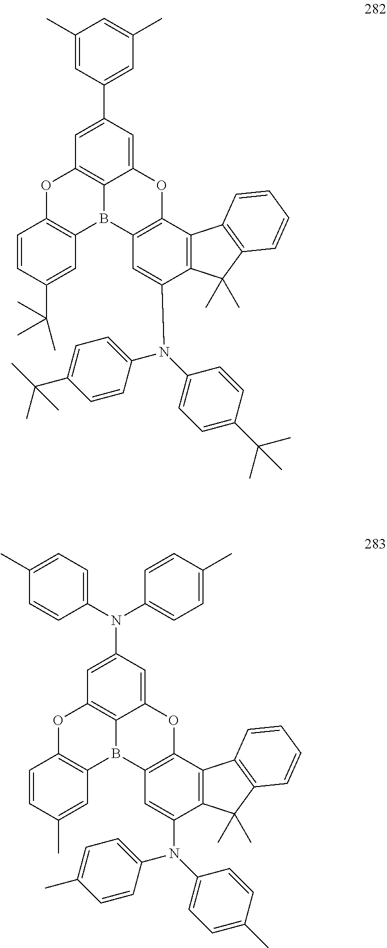

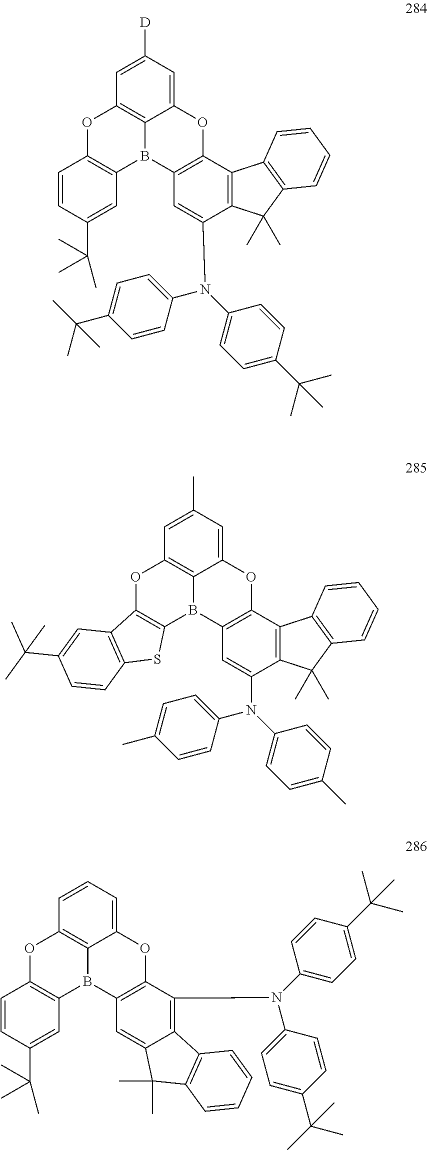

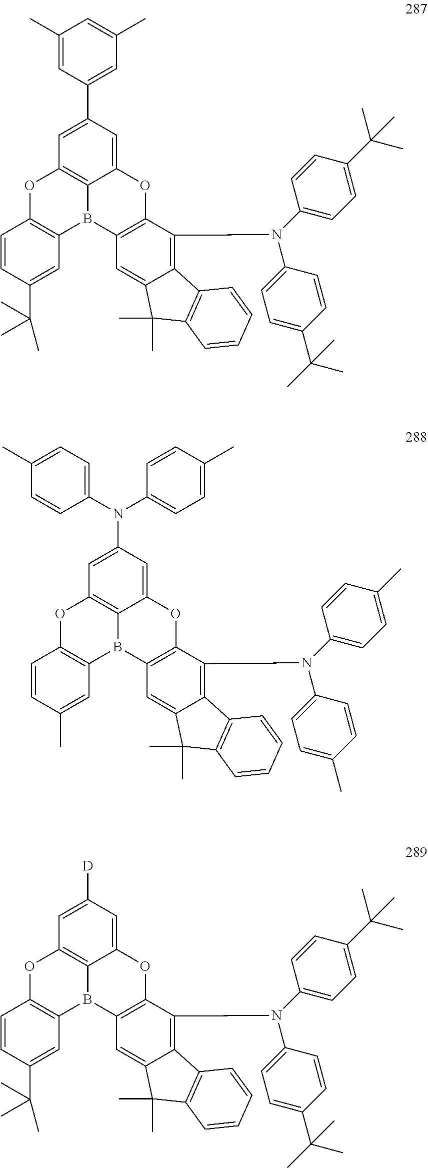

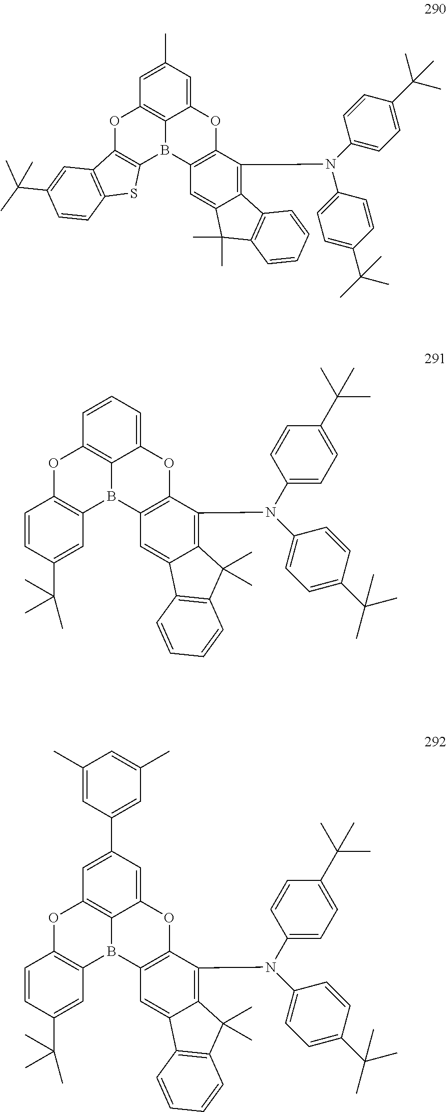 [SMILES: Cc1cc2c3c(c1)Oc1c(sc4ccc(C(C)(C)C)cc14)B3c1cc3c(c(N(c4ccc(C(C)(C)C)cc4)c4ccc(C(C)(C)C)cc4)c1O2)-c1ccccc1C3(C)C ; CC(C)(C)c1ccc(N(c2ccc(C(C)(C)C)cc2)c2c3c(cc4c2C(C)(C)c2ccccc2-4)B2c4cc(C(C)(C)C)ccc4Oc4cccc(c42)O3)cc1 ; Cc1cc(C)cc(-c2cc3c4c(c2)Oc2c(cc5c(c2N(c2ccc(C(C)(C)C)cc2)c2ccc(C(C)(C)C)cc2)C(C)(C)c2ccccc2-5)B4c2cc(C(C)(C)C)ccc2O3)c1]

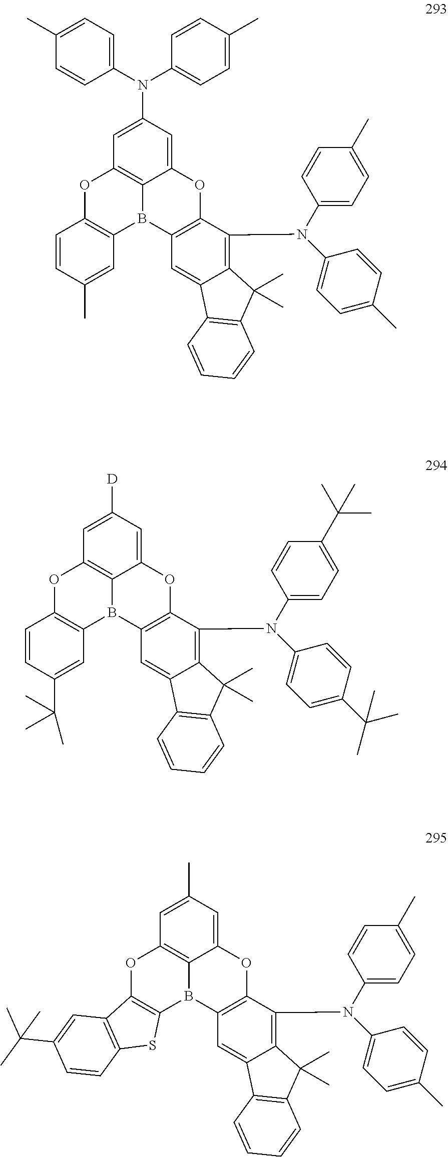

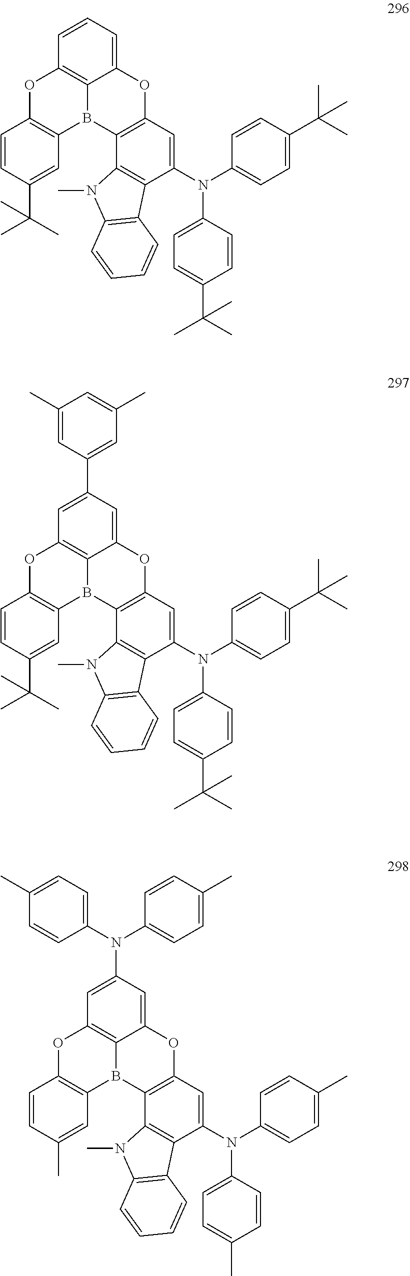

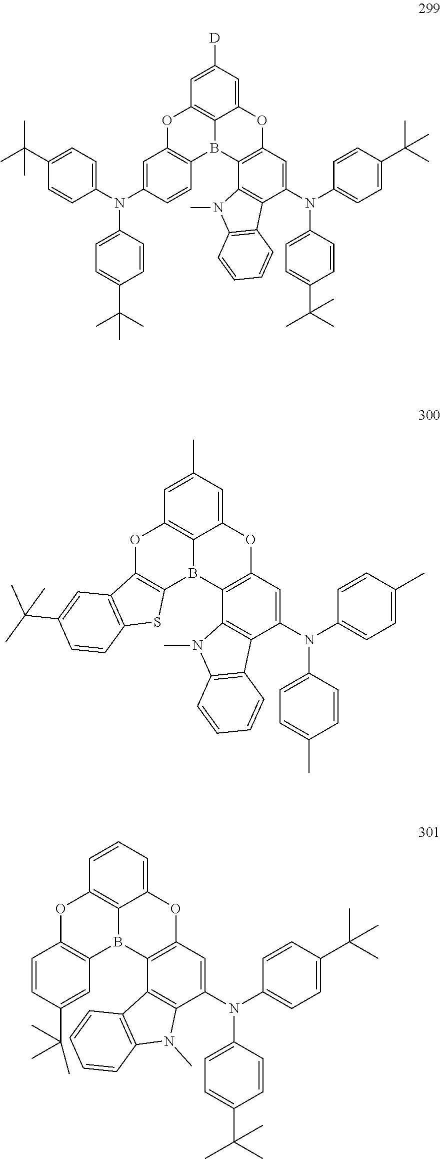

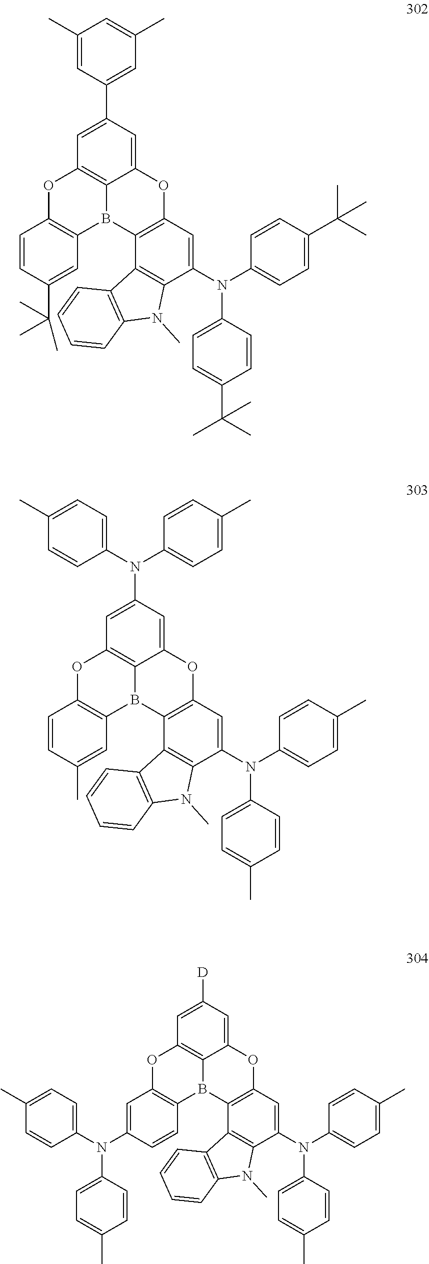

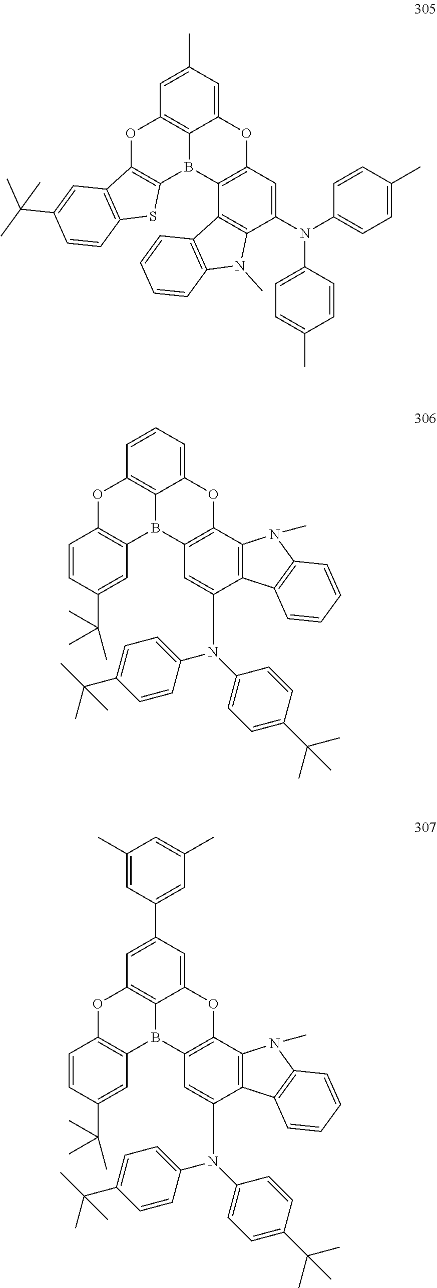

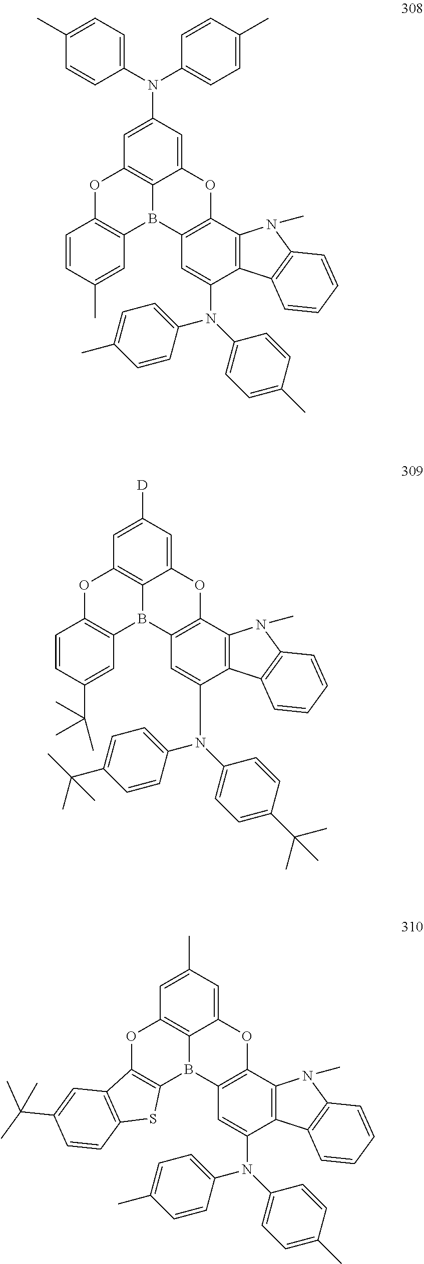 [SMILES: Cc1ccc(N(c2ccc(C)cc2)c2cc3c4c(c2)Oc2c(cc(N(c5ccc(C)cc5)c5ccc(C)cc5)c5c6ccccc6n(C)c25)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4c5ccccc5n(C)c14)B3c1cc(C(C)(C)C)ccc1O2 ; Cc1ccc(N(c2ccc(C)cc2)c2cc3c(c4c2c2ccccc2n4C)Oc2cc(C)cc4c2B3c2sc3ccc(C(C)(C)C)cc3c2O4)cc1]

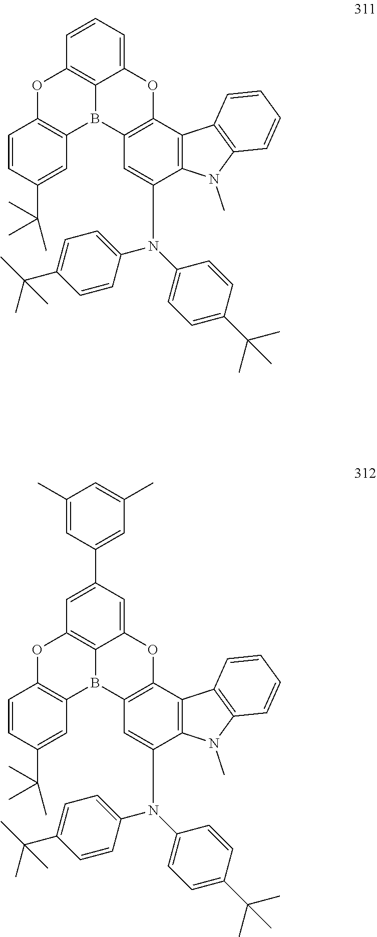 [SMILES: Cn1c2ccccc2c2c3c(cc(N(c4ccc(C(C)(C)C)cc4)c4ccc(C(C)(C)C)cc4)c21)B1c2cc(C(C)(C)C)ccc2Oc2cccc(c21)O3 ; Cc1cc(C)cc(-c2cc3c4c(c2)Oc2c(cc(N(c5ccc(C(C)(C)C)cc5)c5ccc(C(C)(C)C)cc5)c5c2c2ccccc2n5C)B4c2cc(C(C)(C)C)ccc2O3)c1]

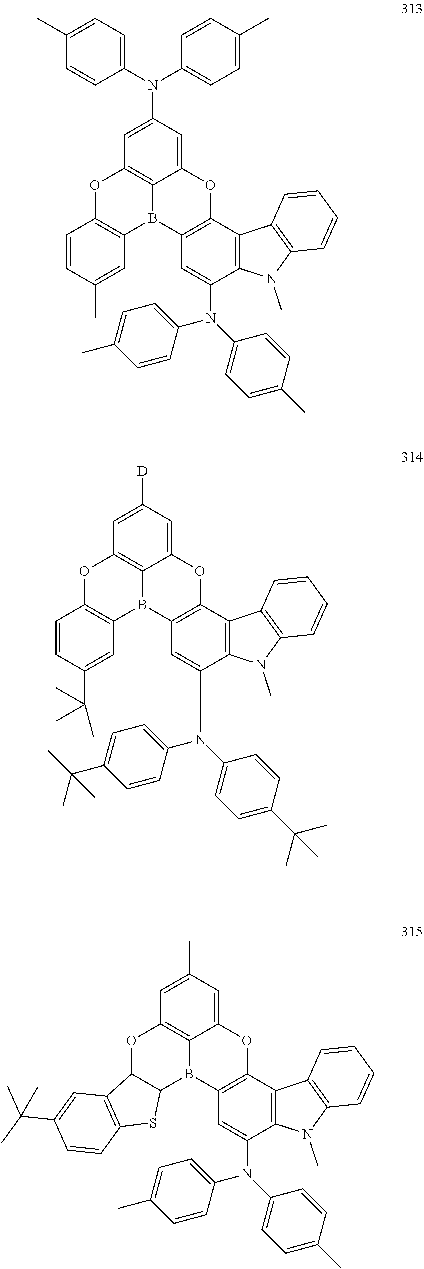 [SMILES: Cc1ccc(N(c2ccc(C)cc2)c2cc3c4c(c2)Oc2c(cc(N(c5ccc(C)cc5)c5ccc(C)cc5)c5c2c2ccccc2n5C)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4c1c1ccccc1n4C)B3c1cc(C(C)(C)C)ccc1O2 ; Cc1ccc(N(c2ccc(C)cc2)c2cc3c(c4c5ccccc5n(C)c24)Oc2cc(C)cc4c2B3C2Sc3ccc(C(C)(C)C)cc3C2O4)cc1]

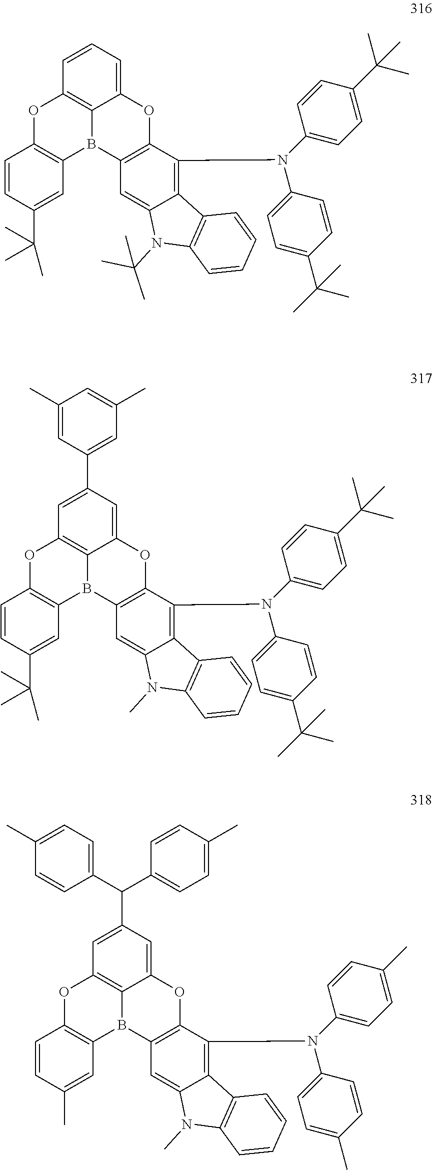

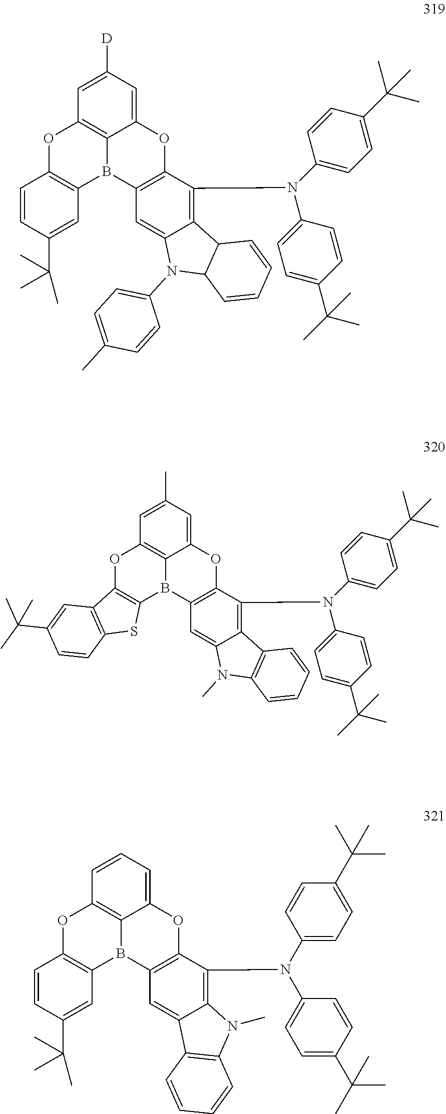

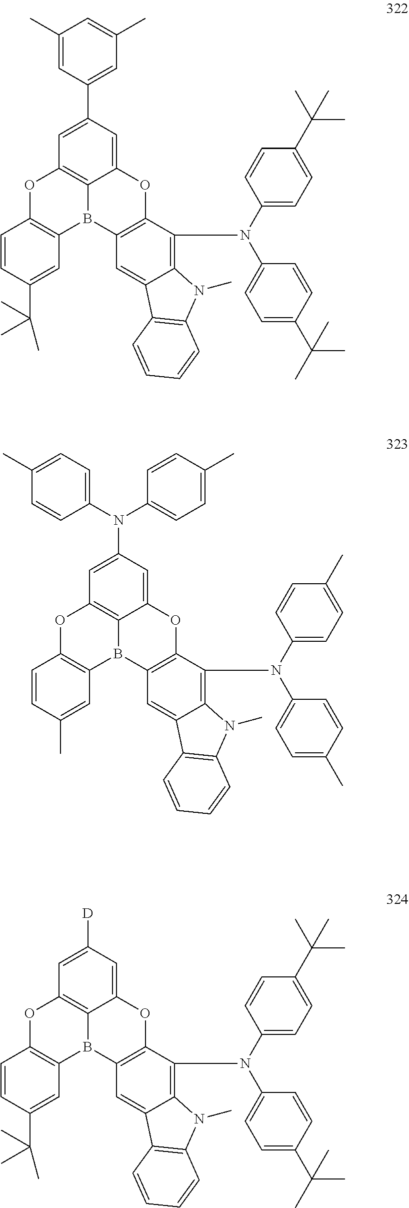

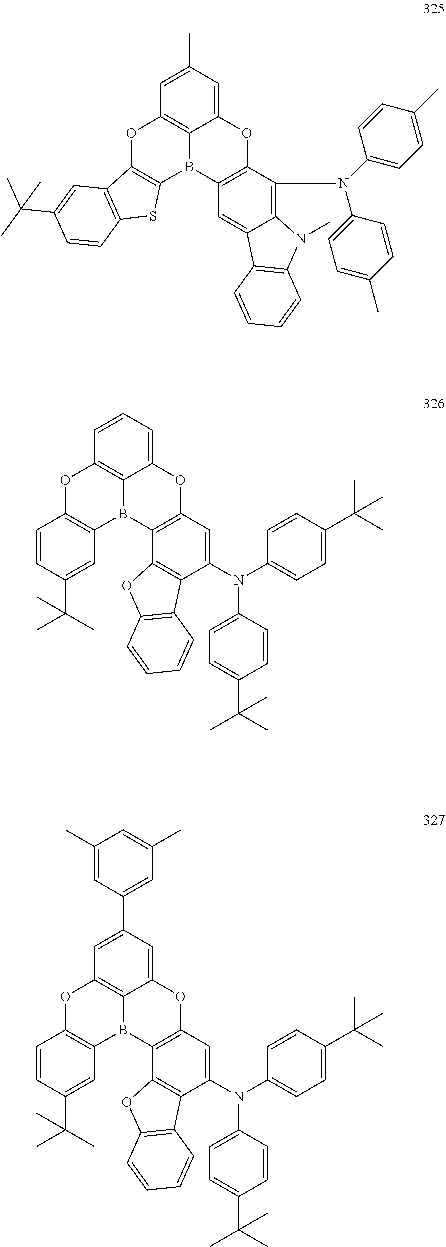 [SMILES: Cc1ccc(N(c2ccc(C)cc2)c2c3c(cc4c5ccccc5n(C)c24)B2c4sc5ccc(C(C)(C)C)cc5c4Oc4cc(C)cc(c42)O3)cc1 ; CC(C)(C)c1ccc(N(c2ccc(C(C)(C)C)cc2)c2cc3c(c4oc5ccccc5c24)B2c4cc(C(C)(C)C)ccc4Oc4cccc(c42)O3)cc1 ; Cc1cc(C)cc(-c2cc3c4c(c2)Oc2cc(N(c5ccc(C(C)(C)C)cc5)c5ccc(C(C)(C)C)cc5)c5c(oc6ccccc65)c2B4c2cc(C(C)(C)C)ccc2O3)c1]

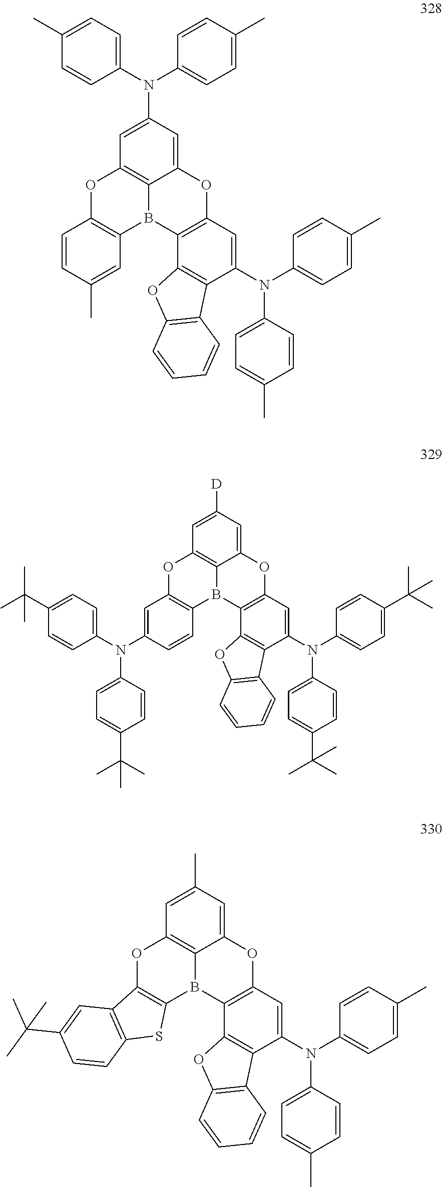

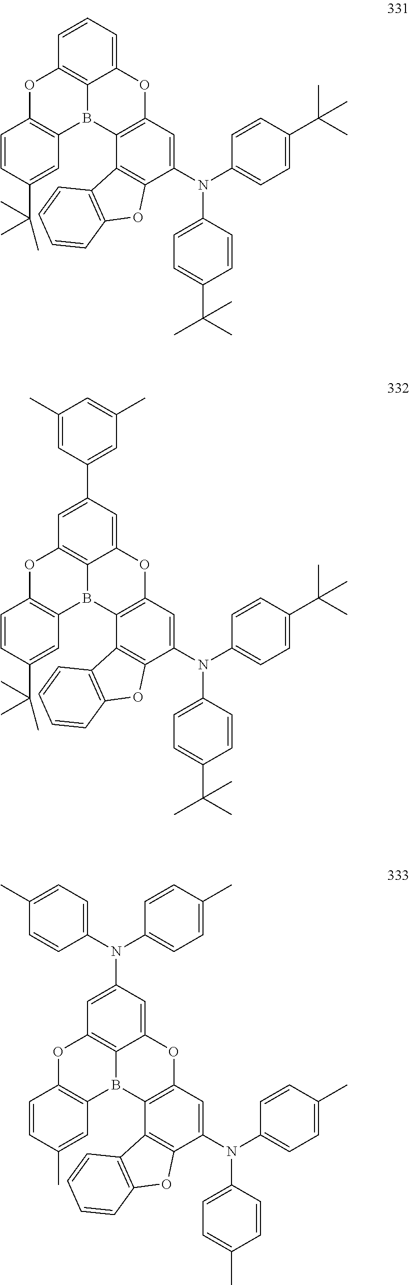

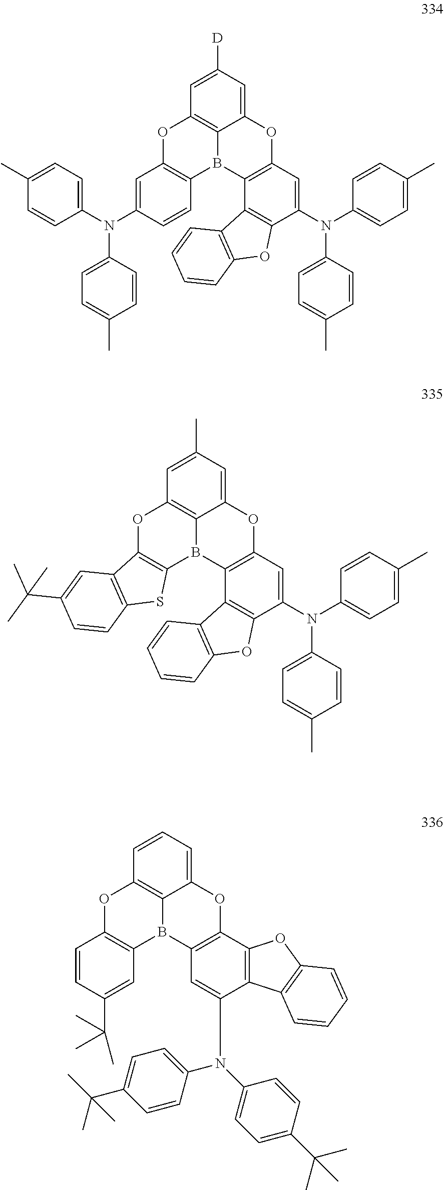

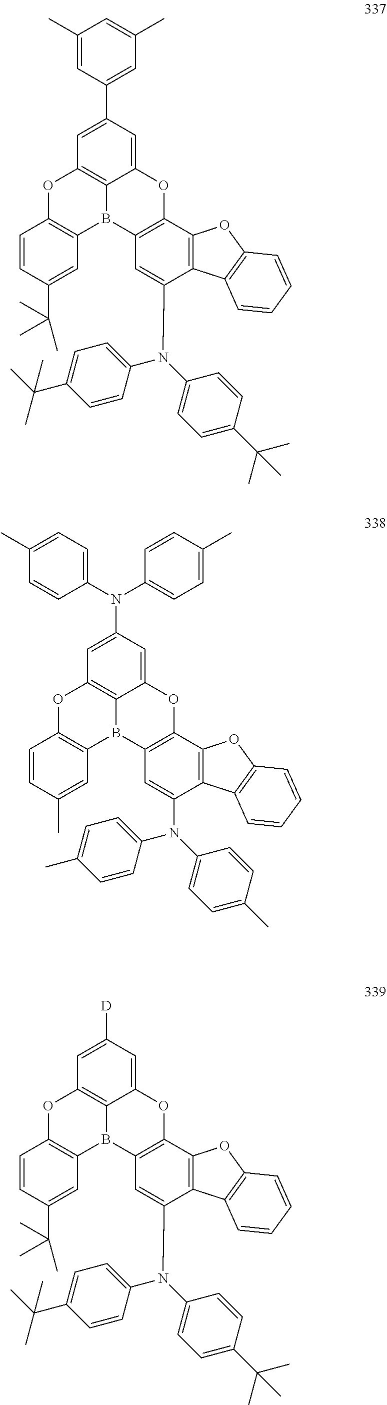 [SMILES: Cc1cc(C)cc(-c2cc3c4c(c2)Oc2c(cc(N(c5ccc(C(C)(C)C)cc5)c5ccc(C(C)(C)C)cc5)c5c2oc2ccccc25)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5c2oc2ccccc25)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4c1oc1ccccc14)B3c1cc(C(C)(C)C)ccc1O2]

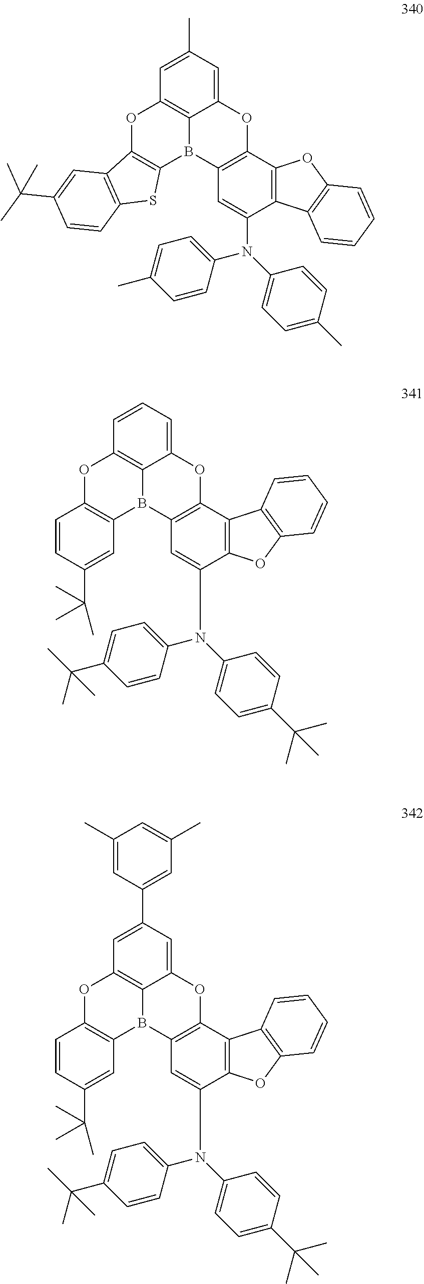 [SMILES: Cc1ccc(N(c2ccc(C)cc2)c2cc3c(c4oc5ccccc5c24)Oc2cc(C)cc4c2B3c2sc3ccc(C(C)(C)C)cc3c2O4)cc1 ; CC(C)(C)c1ccc(N(c2ccc(C(C)(C)C)cc2)c2cc3c(c4c2oc2ccccc24)Oc2cccc4c2B3c2cc(C(C)(C)C)ccc2O4)cc1 ; Cc1cc(C)cc(-c2cc3c4c(c2)Oc2c(cc(N(c5ccc(C(C)(C)C)cc5)c5ccc(C(C)(C)C)cc5)c5oc6ccccc6c25)B4c2cc(C(C)(C)C)ccc2O3)c1]

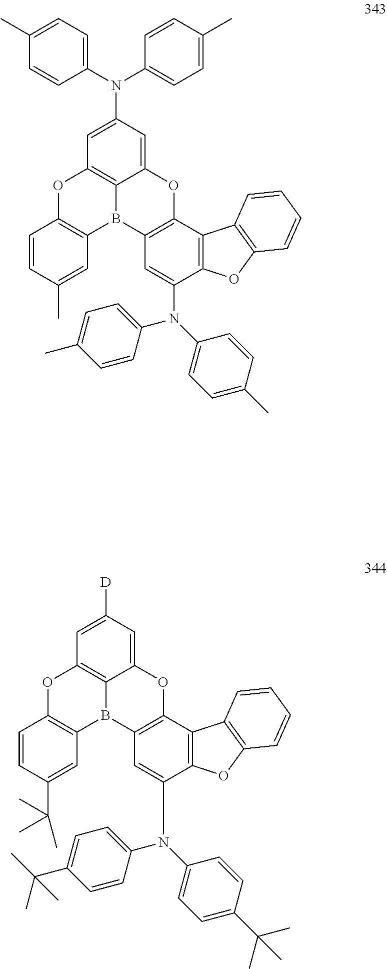 [SMILES: Cc1ccc(N(c2ccc(C)cc2)c2cc3c4c(c2)Oc2c(cc(N(c5ccc(C)cc5)c5ccc(C)cc5)c5oc6ccccc6c25)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4oc5ccccc5c14)B3c1cc(C(C)(C)C)ccc1O2]

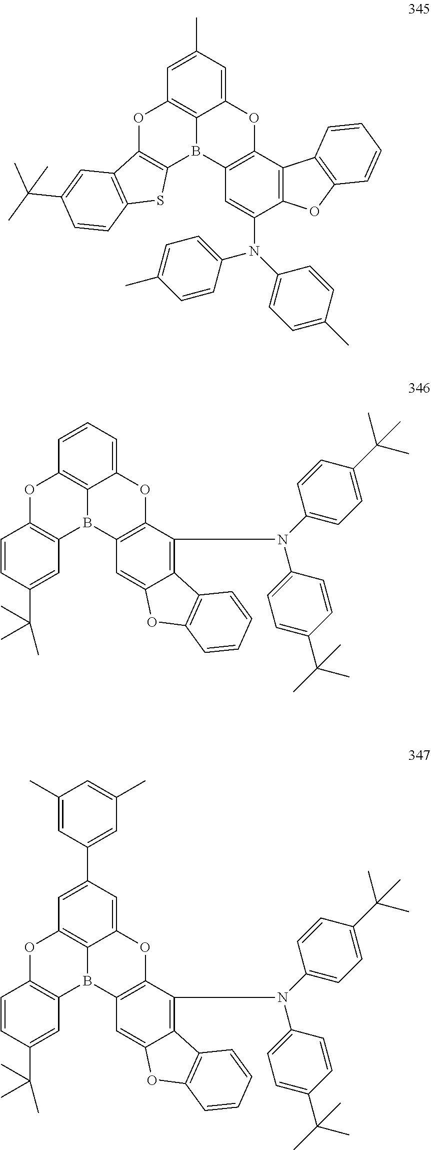 [SMILES: Cc1ccc(N(c2ccc(C)cc2)c2cc3c(c4c2oc2ccccc24)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4oc5ccccc5c24)B2c4cc(C(C)(C)C)ccc4Oc4cccc(c42)O3)cc1 ; Cc1cc(C)cc(-c2cc3c4c(c2)Oc2c(cc5oc6ccccc6c5c2N(c2ccc(C(C)(C)C)cc2)c2ccc(C(C)(C)C)cc2)B4c2cc(C(C)(C)C)ccc2O3)c1]

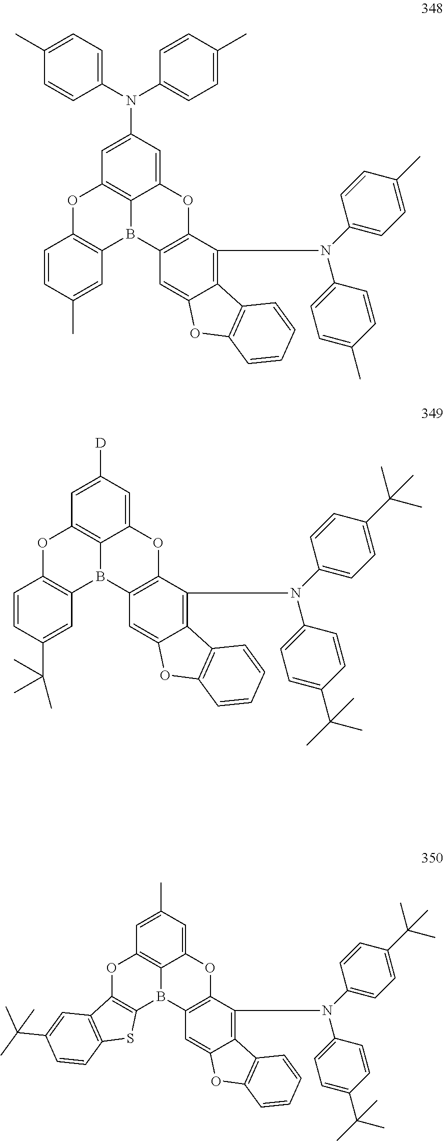

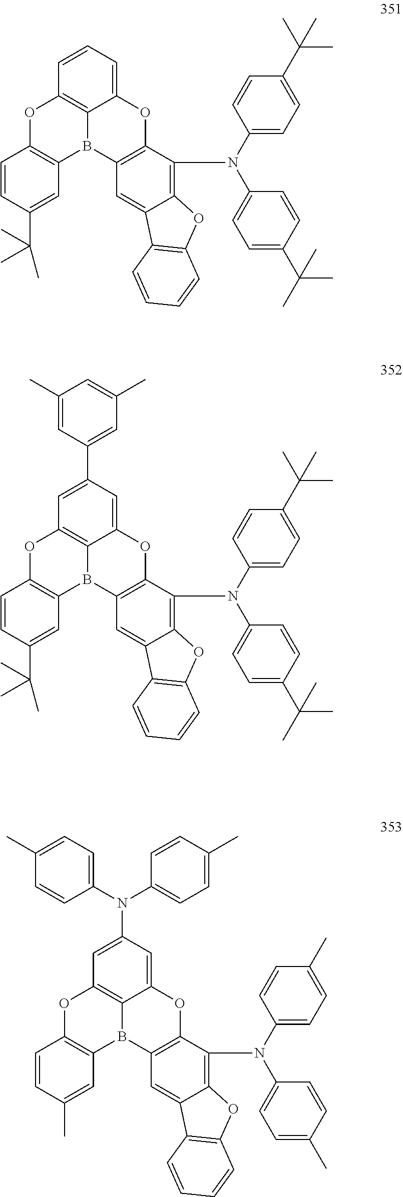

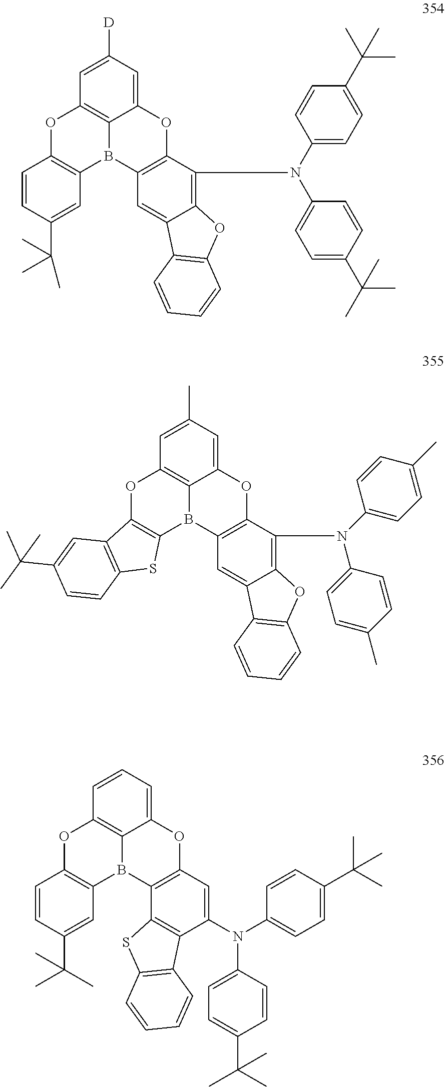

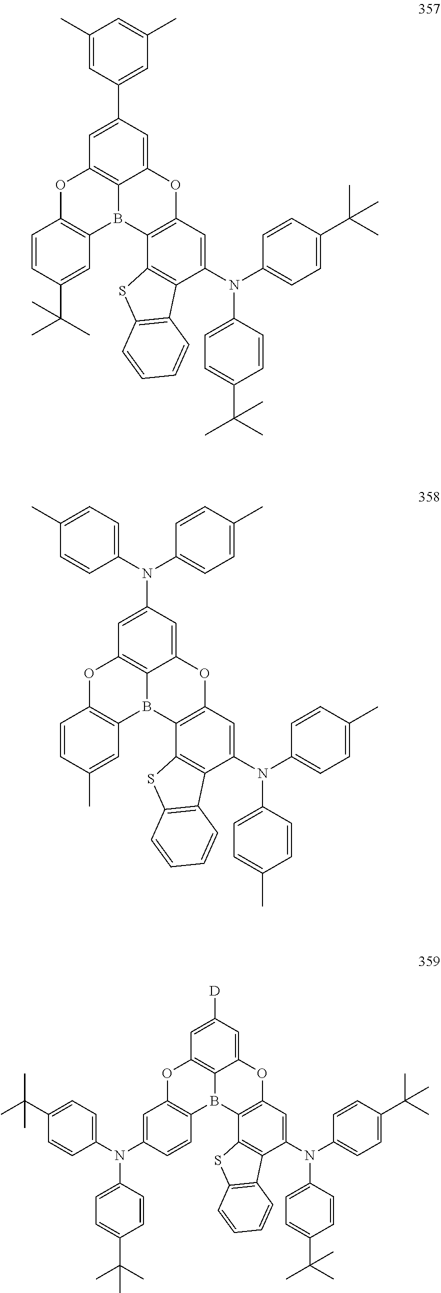

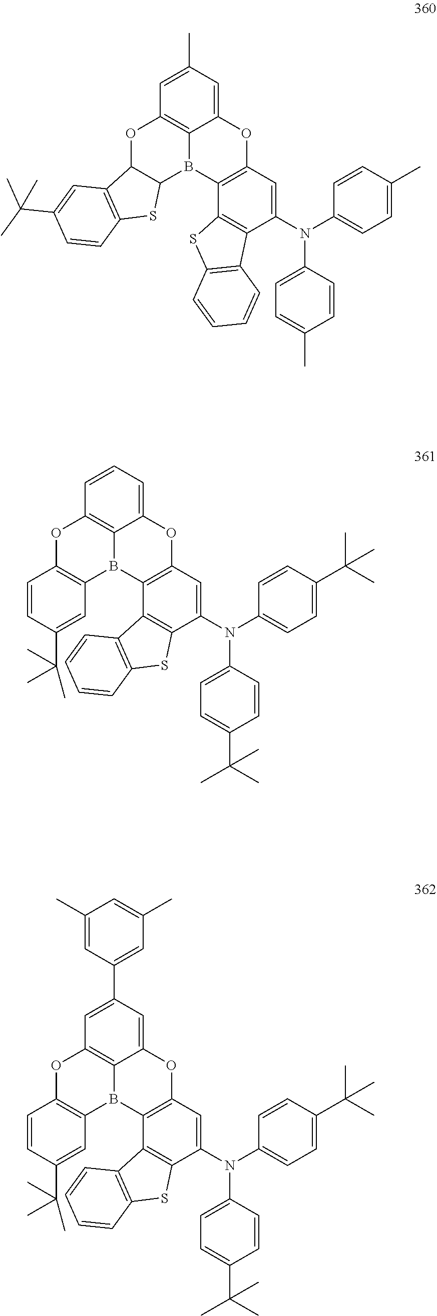 [SMILES: Cc1ccc(N(c2ccc(C)cc2)c2cc3c(c4sc5ccccc5c24)B2c4c(cc(C)cc4OC4c5cc(C(C)(C)C)ccc5SC24)O3)cc1 ; CC(C)(C)c1ccc(N(c2ccc(C(C)(C)C)cc2)c2cc3c(c4c2sc2ccccc24)B2c4cc(C(C)(C)C)ccc4Oc4cccc(c42)O3)cc1 ; Cc1cc(C)cc(-c2cc3c4c(c2)Oc2cc(N(c5ccc(C(C)(C)C)cc5)c5ccc(C(C)(C)C)cc5)c5sc6ccccc6c5c2B4c2cc(C(C)(C)C)ccc2O3)c1]

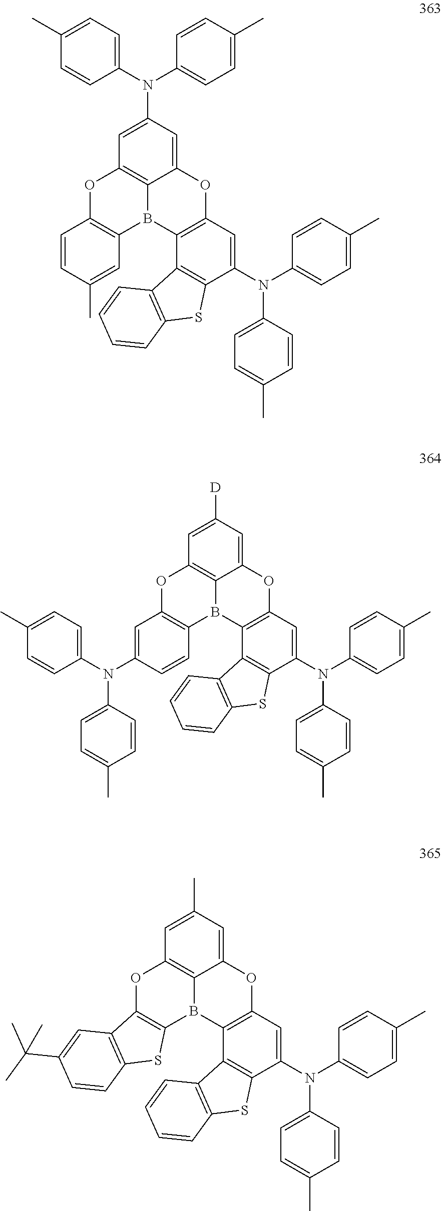

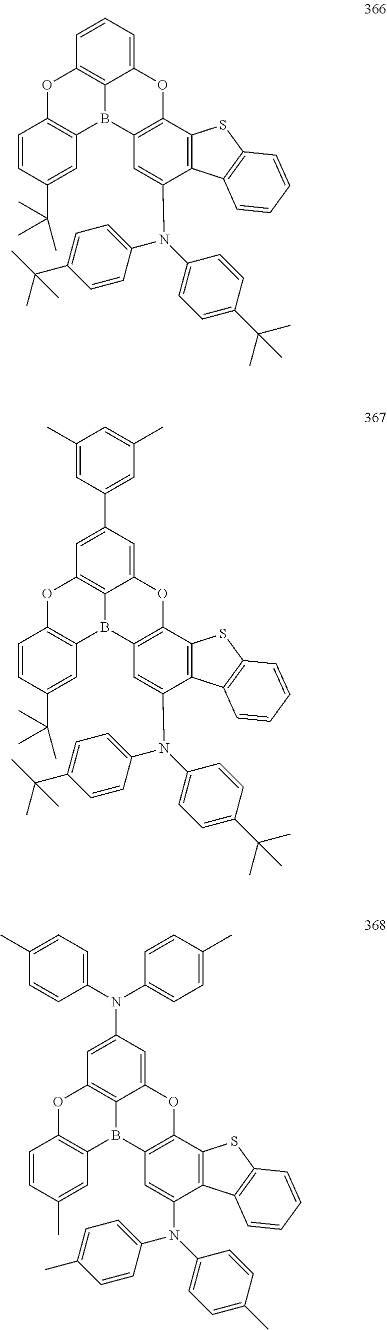

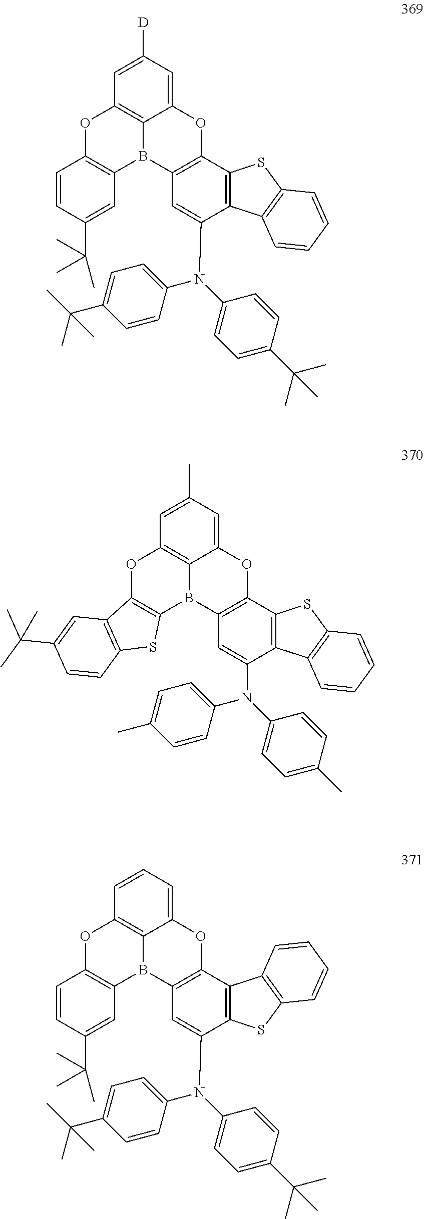 [SMILES: [2H]c1cc2c3c(c1)Oc1c(cc(N(c4ccc(C(C)(C)C)cc4)c4ccc(C(C)(C)C)cc4)c4c1sc1ccccc14)B3c1cc(C(C)(C)C)ccc1O2 ; Cc1ccc(N(c2ccc(C)cc2)c2cc3c(c4sc5ccccc5c24)Oc2cc(C)cc4c2B3c2sc3ccc(C(C)(C)C)cc3c2O4)cc1 ; CC(C)(C)c1ccc(N(c2ccc(C(C)(C)C)cc2)c2cc3c(c4c2sc2ccccc24)Oc2cccc4c2B3c2cc(C(C)(C)C)ccc2O4)cc1]

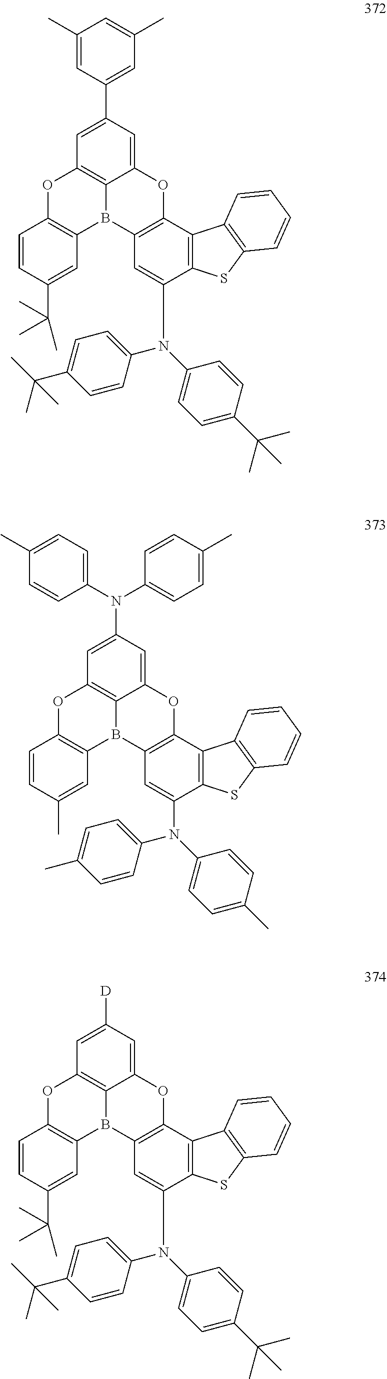 [SMILES: Cc1cc(C)cc(-c2cc3c4c(c2)Oc2c(cc(N(c5ccc(C(C)(C)C)cc5)c5ccc(C(C)(C)C)cc5)c5sc6ccccc6c25)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5sc6ccccc6c25)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4sc5ccccc5c14)B3c1cc(C(C)(C)C)ccc1O2]

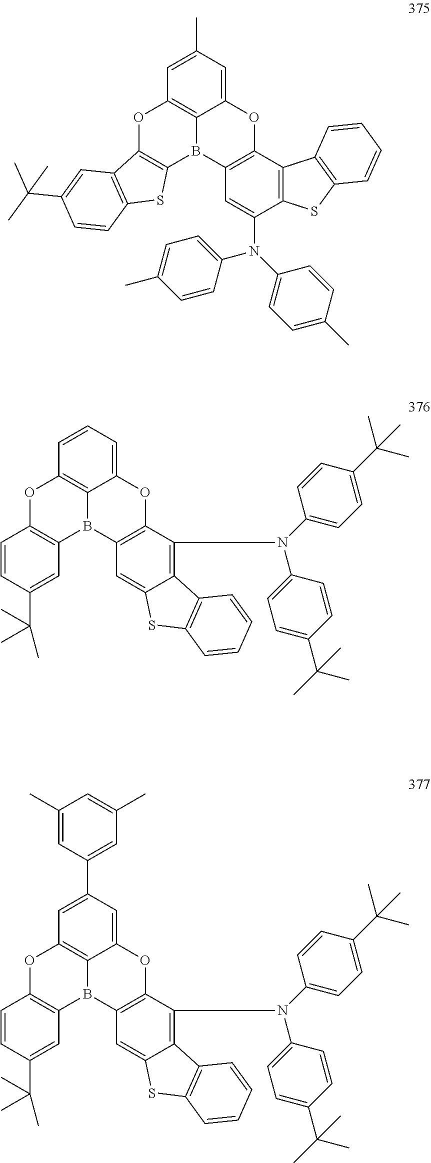 [SMILES: Cc1ccc(N(c2ccc(C)cc2)c2cc3c(c4c2sc2ccccc24)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4sc5ccccc5c24)B2c4cc(C(C)(C)C)ccc4Oc4cccc(c42)O3)cc1 ; Cc1cc(C)cc(-c2cc3c4c(c2)Oc2c(cc5sc6ccccc6c5c2N(c2ccc(C(C)(C)C)cc2)c2ccc(C(C)(C)C)cc2)B4c2cc(C(C)(C)C)ccc2O3)c1]

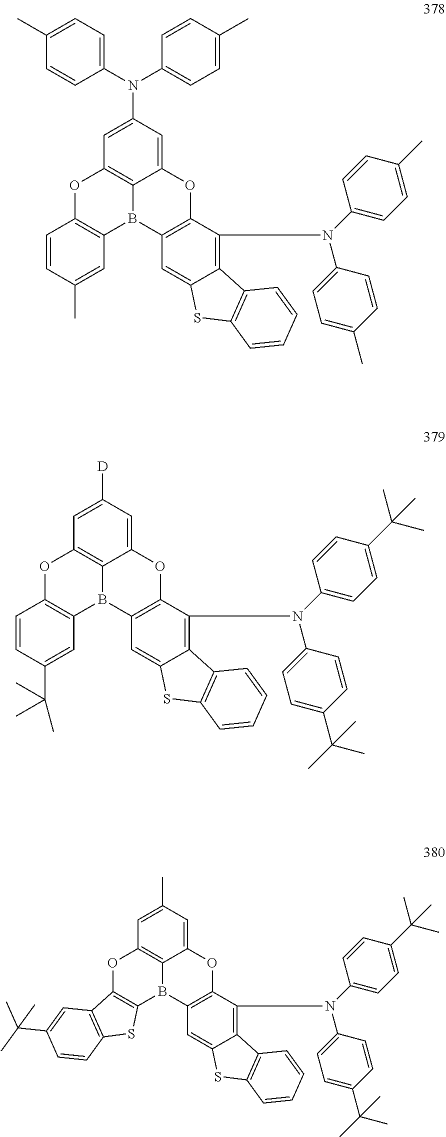

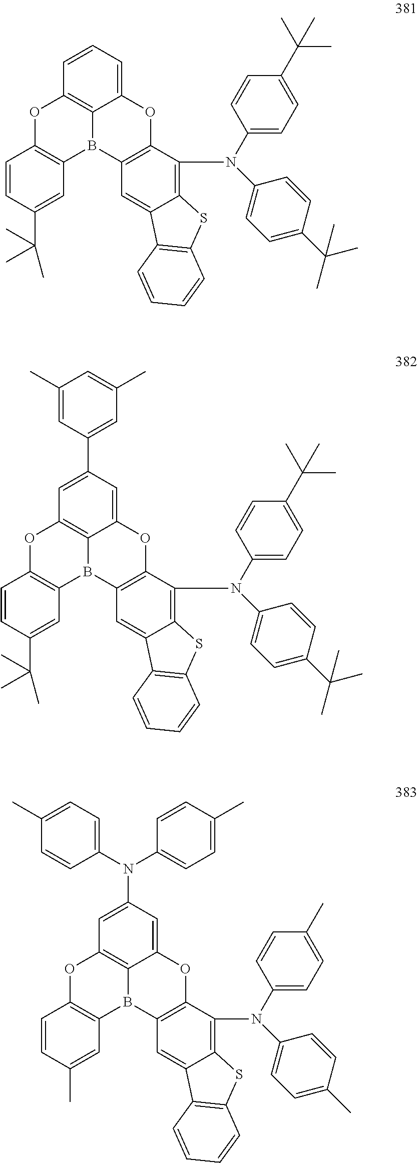

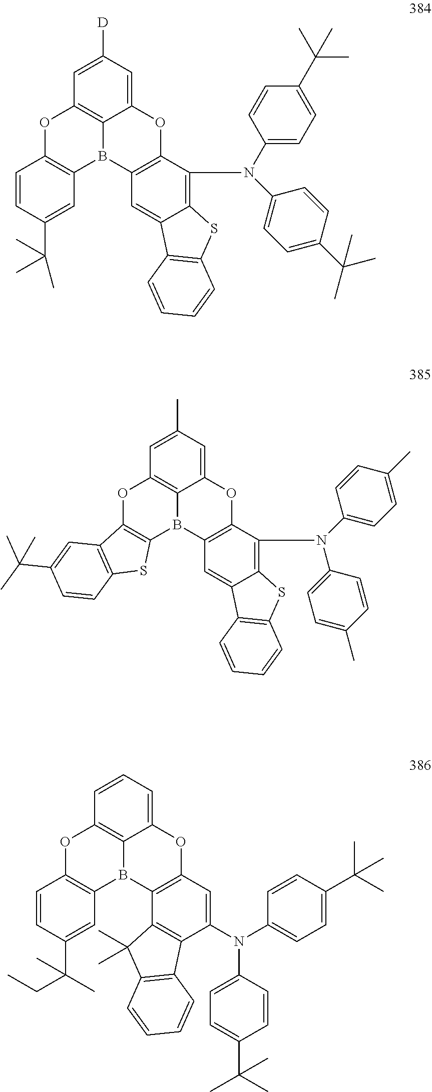

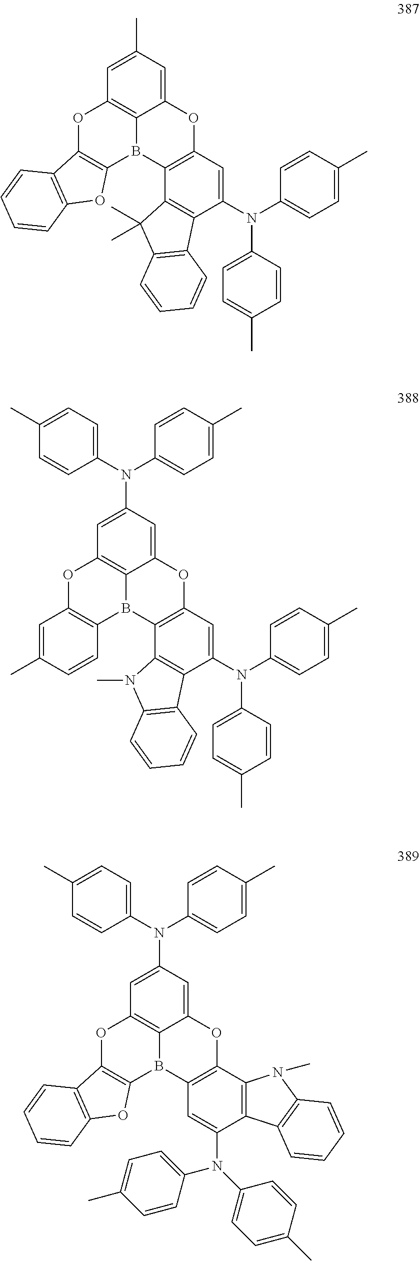

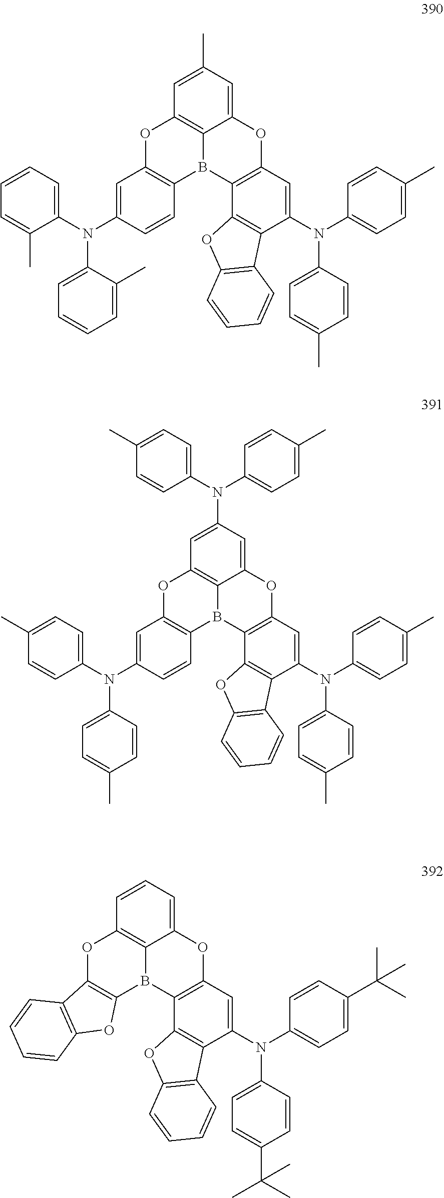

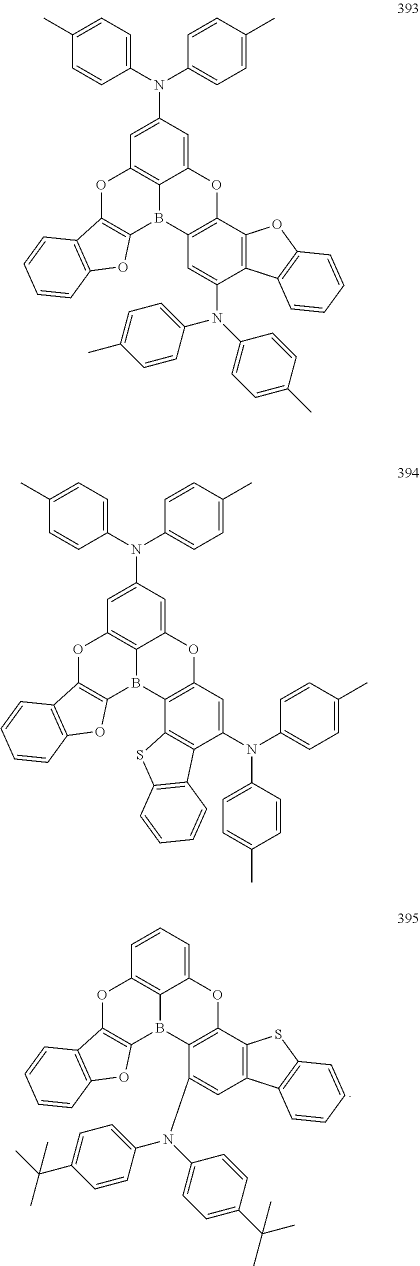

The organic compound provided in the embodiment of the present disclosure effectively suppresses the vibrational relaxation caused by the vibration and rotation of organic compound molecules by a heterocyclic group connecting to an aromatic ring and heteroaromatic rings forming larger conjugated systems and larger rigid planes, thereby improving the luminous efficiency and thermal stability thereof. In addition, the introduction of the amino group further enhances the conjugation and resonance effect of the organic compound and improves the performance of the organic compound. Therefore, the luminous efficiency of a light-emitting component which uses the organic compound can be improved, and the light-emitting service life of the light-emitting component can also be extended.

The present disclosure further provides a light-emitting component, which includes: a pair of electrodes including a first electrode 101 and a second electrode 102; and an organic functional layer 103 disposed between the first electrode 101 and the second electrode 102; wherein, a material of the organic functional layer 103 includes one or more organic compounds mentioned above. The first electrode 101 may be an anode, and the second electrode 102 may be a cathode.

In some embodiments, the light-emitting component may be organic-light emitting diodes (OLEDs), organic photovoltaic cells (OPV), organic light-emitting cells (OLEEC), organic field effect transistors (OFET), organic light-emitting field effect transistors, organic lasers, organic spintronic devices, organic sensors, or organic plasmon-emitting diodes, etc., and is preferably the organic-light emitting diodes (OLEDs), the organic light-emitting cells (OLEEC), or the organic light-emitting field effect transistors.

In some embodiments, the light-emitting component may be used in various electronic devices, such as display panels, lighting devices, light sources, etc.

In some embodiments, the organic functional layer 103 may be a single layer, at this time, the organic functional layer 103 is a mixture layer, and the mixture layer includes a first compound and a second compound. The first compound is selected from one or more of the above-mentioned organic compounds. The second compound is selected from one or more of hole injection materials, hole transport materials, electron transport materials, hole blocking materials, light-emitting guest materials, light-emitting host materials, or organic dyes.

When the second compound is selected from one or more of the hole injection materials, the hole transport materials, the electron transport materials, the hole blocking materials, the light-emitting host materials, or the organic dyes, a mass ratio of the first compound to the second compound ranges from 1:99 to 30:70, and preferably, from 1:99 to 10:90.

When the second compound is the light-emitting guest materials, the mass ratio of the first compound to the second compound ranges from 99:1 to 70:30, and preferably, from 99:1 to 90:10.

In some embodiments, the organic functional layer 103 may include multiple layers. When the organic functional layer 103 is a multi-layer, the organic functional layer 103 at least includes a light-emitting layer 107. Preferably, the organic functional layer 103 includes a hole injection layer 104, a hole transport layer 105, a light-emitting layer 107, an electron blocking layer 106, an electron injection layer 109, an electron transport layer 108, or a hole blocking layer.

In some embodiments, the anode is an electrode that injects holes, and the anode can inject the holes into the organic functional layer 103. For example, the anode injects the holes into the hole injection layer, the hole transport layer, or the light-emitting layer. The anode may include at least one of a conductive metal, a conductive metal oxide, or a conductive polymer. Preferably, an absolute value of a difference between a work function of the anode and a highest occupied molecular orbital (HOMO) energy level or valence band energy level of a light-emitting material in the light-emitting layer or a p-type semiconductor material as the hole injection layer, the hole transport layer, or the electron blocking layer is less than 0.5 eV, preferably less than 0.3 eV, and more preferably less than 0.2 eV. Anode materials include but are not limited to at least one of Al, Cu, Au, Ag, Mg, Fe, Co, Ni, Mn, Pd, Pt, indium tin oxide (ITO), or aluminum-doped zinc oxide (AZO), or other suitable and known anode materials that can be readily selected for use by those of ordinary skill in the art. The anode materials may be deposited using any suitable techniques, such as a suitable physical vapor deposition method, which includes radio frequency magnetron sputtering, vacuum thermal evaporation, electron beam (e-beam), etc. In some embodiments, the anode may be patterned. For example, patterned ITO conductive substrates are commercially available and can be used to fabricate devices of the present disclosure.

In some embodiments, the cathode is an electrode that injects electrons, and the cathode can inject the electrons into the organic functional layer. For example, the cathode injects the electrons into the electron injection layer, the electron transport layer, or the light-emitting layer. The cathode may include at least one of a conductive metal or a conductive metal oxide. Preferably, an absolute value of a difference between a work function of the cathode and a lowest unoccupied molecular orbital (LUMO) energy level or valence band energy level of a light-emitting material in the light-emitting layer or an n-type semiconductor material as the electron injection layer, the electron transport layer, or the hole blocking layer is less than 0.5 eV, preferably less than 0.3 eV, and more preferably less than 0.2 eV. All materials that may be used as cathodes for organic electronic devices are possible as cathode materials for the device of the present disclosure. The cathode materials include but are not limited to at least one of Al, Au, Ag, Ca, Ba, Mg, LiF/Al, MgAg alloy, BaF₂/Al, Cu, Fe, Co, Ni, Mn, Pd, Pt, or ITO. The cathode materials may be deposited using any suitable techniques, such as a suitable physical vapor deposition method, which includes radio frequency magnetron sputtering, vacuum thermal evaporation, electron beam (e-beam), etc.

In some embodiments, the hole injection layer 104 is used to promote holes injected from the anode to the light-emitting layer 107, and the hole injection layer 104 includes hole injection materials. The hole injection materials are materials that can accept holes injected from the positive electrode at a low voltage. Preferably, the HOMO energy level of the hole injection materials is between the work function of the anode materials and the HOMO energy level of a functional material of a film layer that accepts holes and away from the anode (such as hole transport materials of the hole transport layer). The hole injection materials include but are not limited to at least one of metalloporphyrin, oligothiophene, arylamine-based organic materials, hexaazatriphenylene hexacarbonitrile-based organic materials, quinacridone-based organic materials, perylene-based organic materials, anthraquinone, or polyaniline-based or polythiophene-based conductive polymers.

In some embodiments, the hole transport layer 105 can be used to transport holes to the light-emitting layer 107, and the hole transport layer 105 includes a hole transport material that receives the holes transported from the anode or the hole injection layer and transfers the holes to the light-emitting layer. The hole transport material is a material having high hole mobility known in the art. The hole transport material may include but is not limited to at least one of arylamine-based organic materials, conductive polymers, or block copolymers having both conjugated and non-conjugated moieties.

In some embodiments, the electron transport layer 108 is used to transport electrons, and the electron transport layer 108 includes an electron transport material that receives electrons injected from the negative electrode and transfers the electrons to the light-emitting layer 107. The electron transport material is a material having high electron mobility known in the art. The electron transport material may include but is not limited to at least one of Al complex of 8-hydroxyquinoline, Alq3 complex, organic free radical compounds, metal complexes of hydroxyl flavonoids, 8-Hydroxyquinoline lithium (Liq), or benzimidazole-based compounds.

In some embodiments, the electron injection layer 109 is used for injecting electrons, and the electron injection layer 109 includes an electron injection material. Preferably, the electron injection material has an ability to transport electrons, has an effect of injecting electrons from the negative electrode, has an excellent effect of injecting electrons into the light-emitting layer 107 or the light-emitting material, has an ability to prevent excitons generated by the light-emitting layer 107 from moving to the hole injection layer, and has an excellent ability to form thin films. The electron injection material includes but is not limited to at least one of 8-Hydroxyquinoline lithium (Liq), fluorenone, anthraquinodimethane, diphenoquinone, thiopyran dioxide, azole, oxadiazole, triazole, imidazole, perylene tetracarboxylic acid, fluorenylene methane, anthrone or derivatives thereof, metal complex compounds, or nitrogen-containing 5-membered ring derivatives.

In some embodiments, the hole blocking layer is used to block holes from reaching the negative electrode, and generally has same formation conditions as the hole injection layer 104. The hole blocking layer includes a hole blocking material, and the hole blocking material includes but is not limited to at least one of oxadiazole derivatives, triazole derivatives, phenanthroline derivatives, bromocresol purple (BCP), or aluminum complexs.

Preferably, the light-emitting layer 107 includes the host material and the guest material, and the guest material is one or more of the above-mentioned organic compounds.

Preferably, the mass ratio of the host material to the guest material ranges from 99:1 to 70:30, for example, 90:10, 85:15, 80:20, 75:25, etc. The guest material is dispersed in the host material, and the mass ratio of the host material to the guest material ranging from 99:1 to 70:30 is beneficial to inhibit crystallization of the light-emitting layer 107 and inhibit concentration quenching of the guest material caused by high concentration, thereby improving the luminous efficiency of the light-emitting component. Preferably, the host material may be anthracene-based, boroxy ring-based, or exciplex-based host materials.

A light-emitting wavelength of the light-emitting component may range from 300 nm to 1000 nm, preferably from 350 nm to 900 nm, and more preferably, from 400 nm to 800 nm. The light emitted by the light-emitting component may be red light, green light, or blue light, and preferably, blue light.

In some embodiments, the light-emitting component also includes a substrate, and the first electrode 101, the hole injection layer 104, the hole transport layer 105, the electron blocking layer 106, the light-emitting layer 107, the electron transport layer 108, the electron injection layer 109, and the second electrode 102 are sequentially stacked on the substrate. The substrate may be a transparent substrate or an opaque substrate, and when the substrate is a transparent substrate, a transparent light-emitting component may be made. The substrate may be a rigid substrate or a flexible substrate, and a material of the substrate may include, but is not limited to, plastic, polymer, metal, semiconductor wafer, glass, etc. Preferably, the substrate includes at least one smooth surface on which the anode is formed. More preferably, the surface is free of surface defects. Preferably, the material of the substrate is a polymer film or plastic, which includes, but is not limited to, polyethylene terephthalate (PET) or polyethylene glycol(2,6-naphthalene) (PEN). A glass transition temperature of the substrate is greater than or equal to 150° C., preferably, greater than or equal to 200° C., more preferably, greater than or equal to 250° C., and most preferably, greater than or equal to 300° C.

In some embodiments, the mixture layer or the light-emitting layer may be formed by printing or coating a composition. Suitable printing or coating processes include, but are not limited to, inkjet printing, nozzle printing, typography, screen printing, dip coating, spin coating, knife coating, roll printing, twist roll printing, planographic printing, flexographic printing, rotary printing, spraying coating, brushing, pad printing, slot extrusion coating, etc. Preferred are gravure printing, nozzle printing, and inkjet printing.

The composition may be a solution or a suspension, and the composition may include a dispersoid and a dispersant. Wherein, the dispersoid is one or more of the organic compounds described above, and the dispersant is used to disperse the dispersoid.

In the composition, a mass fraction of the organic compound may range from 0.01% to 10%, preferably 0.1% to 15%, more preferably 0.2% to 5%, and most preferably 0.25% to 3%.

Preferably, a Hansen solubility parameter of the dispersant has following ranges: Od (dispersion force) in a range of 17.0 MPa^{1/2} to 23.2 MPa^{1/2}, preferably 18.5 MPa^{1/2} to 21.0 MPa^{1/2} , δp (polar force) in a range of 0.2 MPa^{1/2} to 12.5 MPa^{1/2} , preferably 2.0 MPa^{1/2} to 6.0 MPa^{1/2}, and δh (hydrogen bonding force) in a range of 0.9 MPa^{1/2} to 14.2 MPa^{1/2}, preferably 2.0 MPa^{1/2} to 6.0 MPa^{1/2}.

Preferably, a boiling point of the dispersant is greater than or equal to 150° C., preferably greater than or equal to 180° C., more preferably greater than or equal to 200° C., even more preferably greater than or equal to 250° C., further preferably greater than or equal to 275° C., and most preferably greater than or equal to 300° C. The boiling point of the dispersant being at least greater than or equal to 150° C. is beneficial to preventing nozzle clogging in inkjet printingheads during inkjet printing, and a higher boiling point is beneficial for preventing clogging.

The dispersant may include at least one organic solvent that can be evaporated from the solvent system, thereby forming a thin film containing functional materials. The organic solvent may include at least one first organic solvent, and the first organic solvent may be selected from aromatic or heteroaromatic based solvents. Specifically, the first organic solvent may be selected from p-diisopropylbenzene, pentylbenzene, tetrahydronaphthalene, cyclohexylbenzene, chloronaphthalene, 1,4-dimethylnaphthalene, 3-isopropylbiphenyl, p-methylcumene, dipentylbenzene, tripentylbenzene, amyltoluene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, cyclohexylbenzene, benzylbutylbenzene, dimethylnaphthalene, 3-isopropyl biphenyl, p-methylcumene, 1-methylnaphthalene, 1,2,4-trichlorobenzene, 4,4-difluorodiphenylmethane, 1,2-dimethoxy-4-(1-propenyl)benzene, diphenylmethane, 2-phenyl pyridine, 3-phenyl pyridine, N-methyl diphenylamine, 4-isopropyl biphenyl, α, α-dichlorodiphenylmethane, 4-(3-phenylpropyl)pyridine, benzyl benzoate, 1,1-bis(3,4-dimethylphenyl)ethane, 2-isopropylnaphthalene, quinoline, isoquinoline, methyl 2-furoate, and ethyl 2-furancarboxylate.

The first organic solvent may be selected from aromatic ketone solvents. Specifically, the first organic solvent may be selected from 1-tetralone, 2-tetralone, 2-(phenylepoxy)tetralone, 6-(methoxy)tetralone, acetophenone, propiophenone, benzophenone , and their derivatives, such as 4-methylacetophenone, 3-methylacetophenone, 2-methylacetophenone, 4-methylpropiophenone, 3-methylpropiophenone, and 2-methylpropiophenone.

The first organic solvent may be selected from aromatic ether solvents. Specifically, the first organic solvent may be selected from 3-phenoxytoluene, butoxybenzene, p-anisaldehyde dimethylacetal, tetrahydro-2-phenoxy-2H-pyran, 1,2-dimethoxy-4-(1-propenyl) benzene, 1,4-benzodioxane, 1,3-dipropylbenzene, 2,5-dimethoxytoluene, 4-ethyl phenethyl ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenyl anisole, 1,2-dimethoxybenzene, 1-methoxynaphthalene, diphenyl ether, 2-phenoxymethyl ether, 2-phenoxytetrahydrofuran, and ethyl-2-naphthyl ether.

The first organic solvent may be selected from aliphatic ketones. Specifically, the first organic solvent may be selected from aliphatic ketones, for example, 2-nonanone, 3-nonanone, 5-nonanone, 2-decanone, 2,5-hexanedione, 2,6,8-trimethyl-4-nonanone, fenone, phorone, isophorone, and di-n-amyl ketone, or aliphatic ethers, for example, amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, and tetraethylene glycol dimethyl ether.

The first organic solvent may be selected from organic ester solvents. Specifically, the first organic solvent may be selected from alkyl octanoate, alkyl sebacate, alkyl stearate, alkyl benzoate, alkyl phenylacetate, alkyl cinnamate, alkyl oxalate, alkyl maleate, alkyl lactone, and alkyl oleate. Preferably, the first organic solvent may be octyl octanoate, diethyl sebacate, diallyl phthalate, or isononyl isononanoate.

The organic solvent may also include a second organic solvent, and the second organic solvent may be selected from one or more of methanol, ethanol, 2-methoxyethanol, dichloromethane, chloroform, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2 dichloroethane, 3-phenoxytoluene, 1,1,1-trichloroethane, 1,1,2,2-tetrachloroethane, ethyl acetate, butyl acetate, dimethylformamide, dimethylacetamide, dimethylsulfoxide, tetrahydronaphthalene, decalin, or indene.

In addition to the dispersoid and the dispersant, the composition may also include one or more components such as surfactants, lubricants, wetting agents, dispersing agents, hydrophobic agents, binders, etc., to adjust viscosity, film-forming properties, improve adhesion, and the like.

Exemplary manufacturing methods of the organic compound provided in the present disclosure are shown in following examples 1 to 15.

### Example 1

Synthesis of organic compound M1

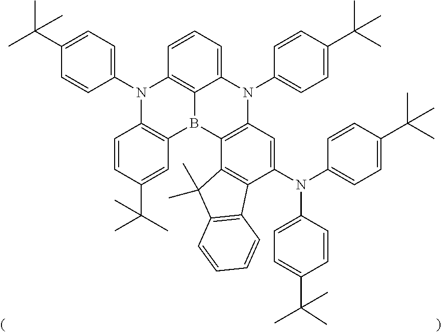 [SMILES: CC(C)(C)c1ccc(N(c2ccc(C(C)(C)C)cc2)c2cc3c(c4c2-c2ccccc2C4(C)C)B2c4cc(C(C)(C)C)ccc4N(c4ccc(C(C)(C)C)cc4)c4cccc(c42)N3c2ccc(C(C)(C)C)cc2)cc1]

A synthetic route of the organic compound M1 is as follows.

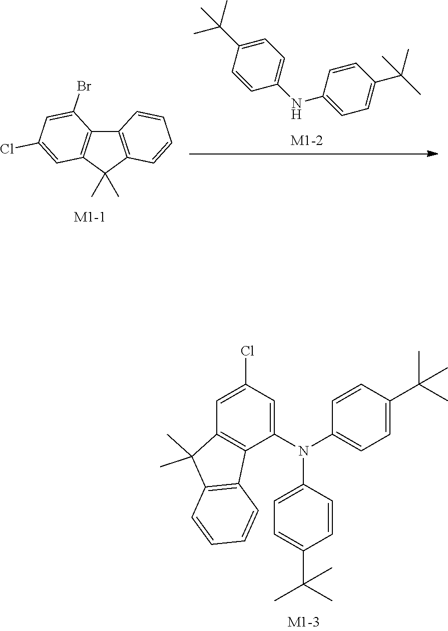 [SMILES: CC1(C)c2ccccc2-c2c(Br)cc(Cl)cc21 ; CC(C)(C)c1ccc(Nc2ccc(C(C)(C)C)cc2)cc1 ; CC(C)(C)c1ccc(N(c2ccc(C(C)(C)C)cc2)c2cc(Cl)cc3c2-c2ccccc2C3(C)C)cc1]

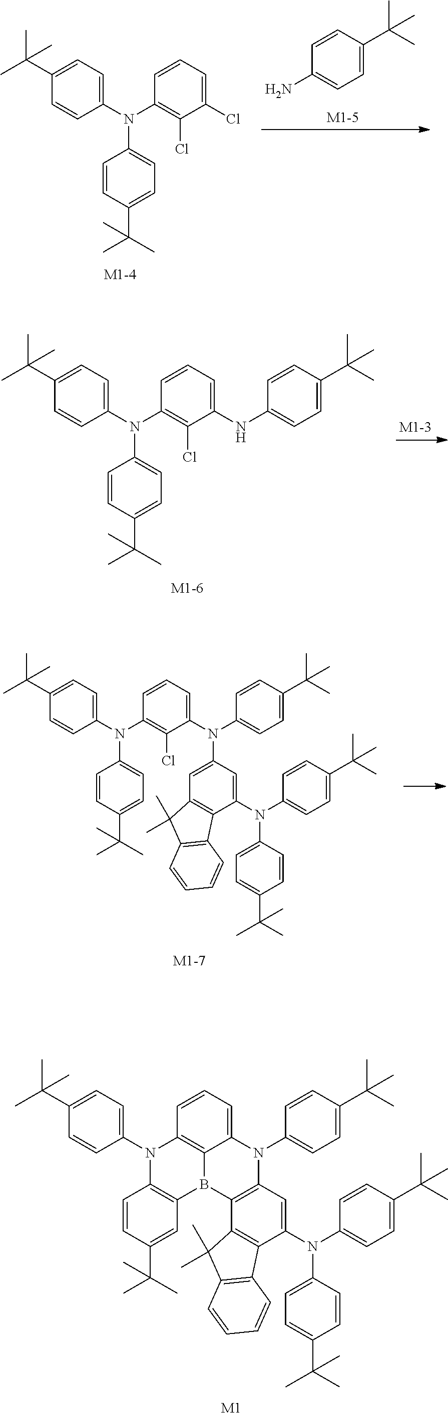

Specific synthesis steps of the organic compound M1 are as follows.

Synthesis of intermediate M1-3: under a nitrogen atmosphere, (30.8 g, 100 mmol) of intermediate M1-1, (28.1 g, 100 mmol) of compound M1-2, (2.76 g, 3 mmol) of compound Pd2(dba)3, (1.2 g, 6 mmol) of compound tri-tert-butyl phosphine, (18.2 g, 200 mmol) of compound sodium tert-butoxide, and 250 mL of anhydrous toluene solvent were mixed, heated to 60° C., and stirred for 6 hours for reaction. Then, the reaction solution was cooled to room temperature, quenched by adding double distilled water, rotary evaporated to remove most of solvents, and dissolved in dichloromethane and washed with water for three times. Organic phase was collected and mixed with silica gel for purification by column chromatography. The yield is 75%.

Synthesis of intermediate M1-6: under the nitrogen atmosphere, (25.6g, 60 mmol) of intermediate M1-4, (8.9 g, 60 mmol) of compound M1-5, (1.66 g, 1.8 mmol) of compound Pd2(dba)3, (0.72 g, 3.6 mmol) of compound tri-tert-butyl phosphine, (11 g, 120 mmol) of compound sodium tert-butoxide, and 150 mL of anhydrous toluene solvent were mixed, heated to 90° C., and stirred for 6 hours for reaction. Then, the reaction solution was cooled to room temperature, quenched by adding double distilled water, rotary evaporated to remove most of solvents, and dissolved in dichloromethane and washed with water for three times. Organic phase was collected and mixed with silica gel for purification by column chromatography. The yield is 68%.

Synthesis of intermediate M1-7: according to the synthesis steps of the intermediate M1-6, the compounds M1-4 and M1-5 were replaced by compounds M1-3 and M1-6, respectively. The yield is 72%.

Synthesis of the organic compound M1: under the nitrogen atmosphere, (20.2 g, 20 mmol) of compound M1-7 and 100 mL of anhydrous tetrahydrofuran were mixed and cooled to −30° C., and 25 mmol of tert-butyl lithium solution was slowly added dropwise. After that, the reaction solution was heated to 60° C. and stirred for 2 hours, and then cooled to −30° C. for adding 30 mmol of boron tribromide at one time. Then the reaction solution naturally rose to room temperature for reaction for 1 hour, then 40 mmol of N,N-diisopropylethylamine was added, and the reaction solution was heated to 100° C. slowly and reacted for 3 hours. After reaction, the reaction solution was cooled to room temperature, and the reaction was quenched by addition of aqueous sodium acetate. The reaction solution was rotary evaporated to remove most of solvents, and dissolved in dichloromethane and washed with water for three times. Organic phase was collected and rotary evaporated for purification by column chromatography. The yield is 27%. A result of atmospheric solids analysis probe mass spectrometry (ASAP-MS) of the organic compound M1: the mass-to-charge ratio is 984[M⁺].

### Example 2

Synthesis of organic compound M2

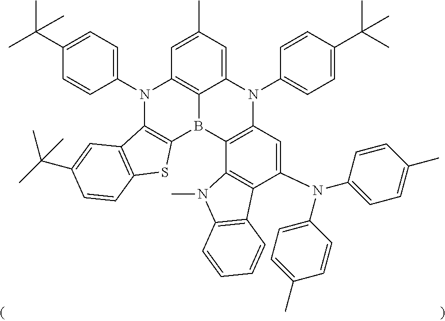 [SMILES: Cc1ccc(N(c2ccc(C)cc2)c2cc3c(c4c2c2ccccc2n4C)B2c4sc5ccc(C(C)(C)C)cc5c4N(c4ccc(C(C)(C)C)cc4)c4cc(C)cc(c42)N3c2ccc(C(C)(C)C)cc2)cc1]

A synthetic route of the organic compound M2 is as follows.

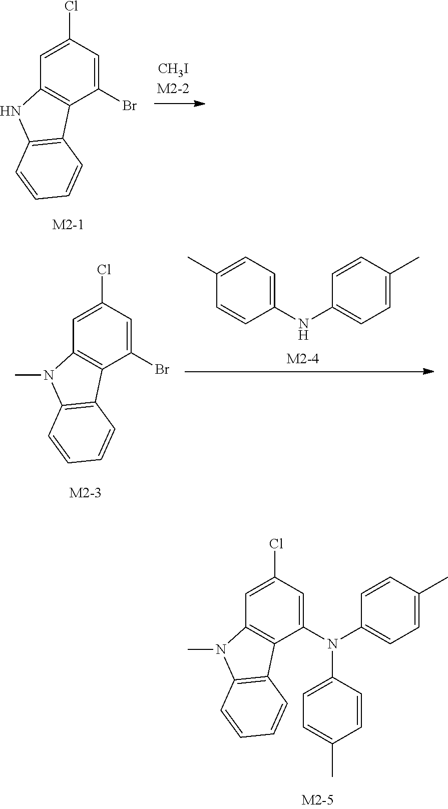

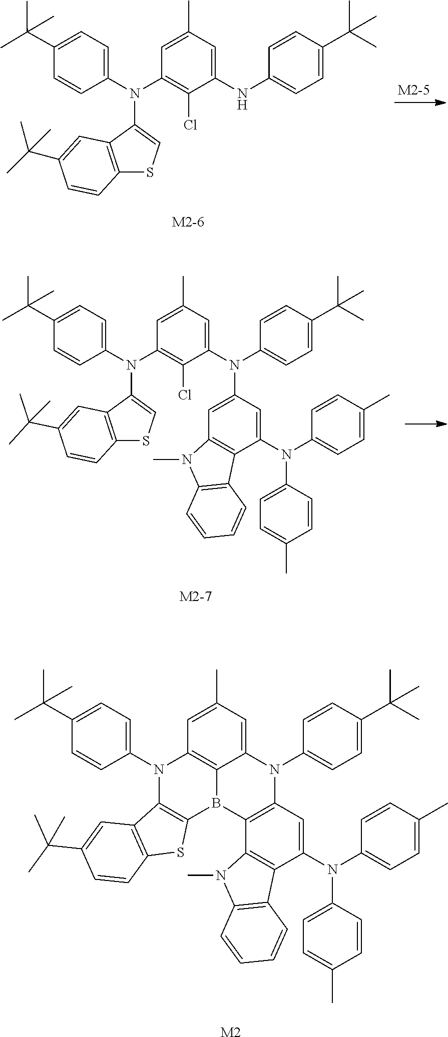

Specific synthesis steps of the organic compound M2 are as follows.

Synthesis of intermediate M2-3: under the nitrogen environment, (28 g, 100 mmol) of compound M2-1, (6 g, 150 mmol) of NaOH, and 100 mL of dimethylformamide were added to a 250 mL two-necked flask and stirred for 1 hour for reaction, and (14.2 g, 100 mmol) of compound M2-2 was added at one time and stirred for 4 hours for reaction. After reaction, the reaction solution was poured into 400 mL of pure water, and after stirring, a solid was obtained by suction filtration and then purified by recrystallization with a mixing solution of ethanol and dichloromethane. The yield is 84%.

Synthesis of intermediate M2-5: according to the synthesis steps of the intermediate M1-3, the compounds M1-1 and M1-2 were replaced by compounds M2-3 and M2-4, respectively. The yield is 70%.

Synthesis of intermediate M2-7: according to the synthesis steps of the intermediate M1-6, the compounds M1-4 and M1-5 were replaced by compounds M2-5 and M2-6, respectively. The yield is 74%.

Synthesis of organic compound M2: according to the synthesis steps of the compound M1, the compound M1-7 is replaced by compound M2-7. The yield is 26%. A result of atmospheric solids analysis probe mass spectrometry (ASAP-MS) of the organic compound M2: the mass-to-charge ratio is 957[M⁺].

### Example 3

Synthesis of organic compound M3

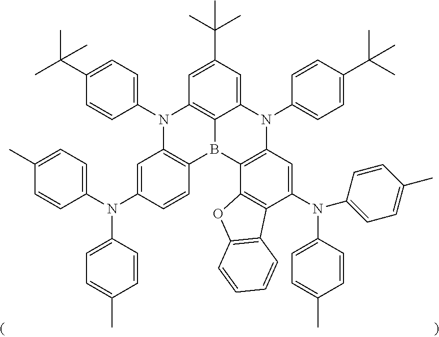

A synthetic route of the organic compound M3 is as follows.

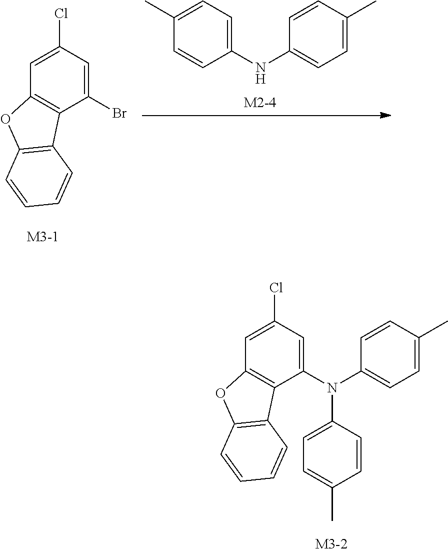

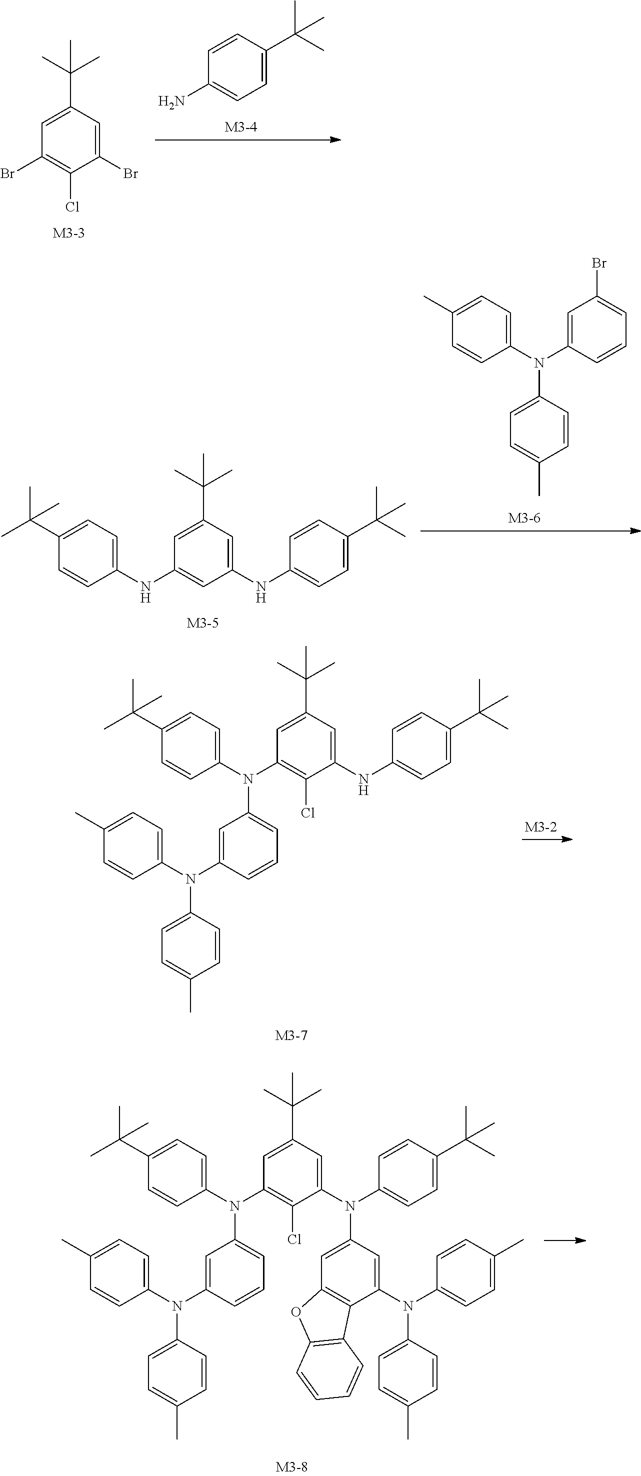

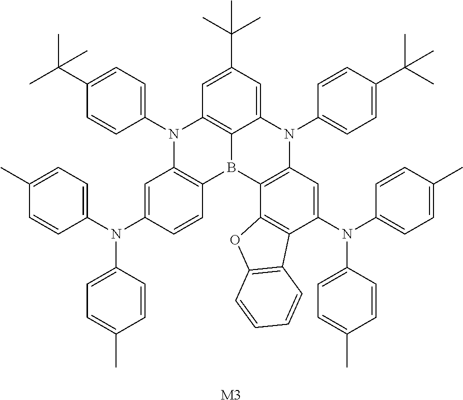

Specific synthesis steps of the organic compound M3 are as follows.

Synthesis of intermediate M3-2: according to the synthesis steps of the intermediate M1-3, the compounds M1-1 and M1-2 were replaced by compounds M3-1 and M2-4, respectively. The yield is 71%.

Synthesis of intermediate M3-5: according to the synthesis steps of the intermediate M1-6, the compounds M1-4 and M1-5 were replaced by compound M3-3 and twice the molar amount of compound M3-4, respectively. The yield is 72%.

Synthesis of intermediate M3-7: according to the synthesis steps of the intermediate M1-7, the compounds M1-6 and M1-3 were replaced by compounds M3-5 and M3-6, respectively. The yield is 62%.

Synthesis of intermediate M3-8: according to the synthesis steps of the intermediate M1-7, the compounds M1-6 and M1-3 were replaced by compounds M3-7 and M3-2, respectively. The yield is 68%.

Synthesis of organic compound M3: according to the synthesis steps of the compound M1, the compound M1-7 is replaced by compound M3-8. The yield is 28%. A result of atmospheric solids analysis probe mass spectrometry (ASAP-MS) of the organic compound M3: the mass-to-charge ratio is 943[M⁺].

### Example 4

Synthesis of organic compound M4

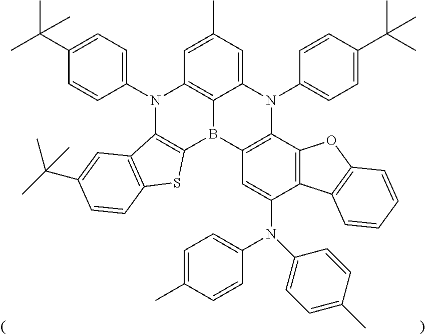 [SMILES: Cc1ccc(N(c2ccc(C)cc2)c2cc3c(c4oc5ccccc5c24)N(c2ccc(C(C)(C)C)cc2)c2cc(C)cc4c2B3c2sc3ccc(C(C)(C)C)cc3c2N4c2ccc(C(C)(C)C)cc2)cc1]

A synthetic route of the organic compound M4 is as follows.

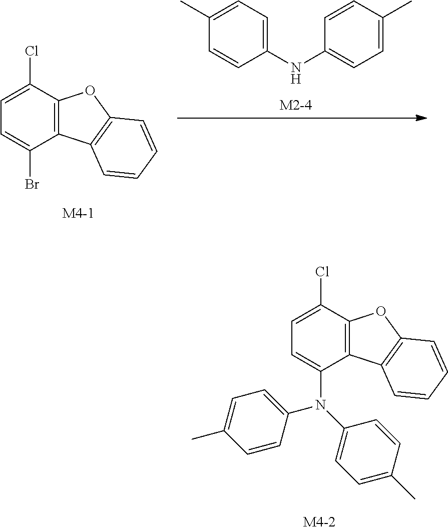

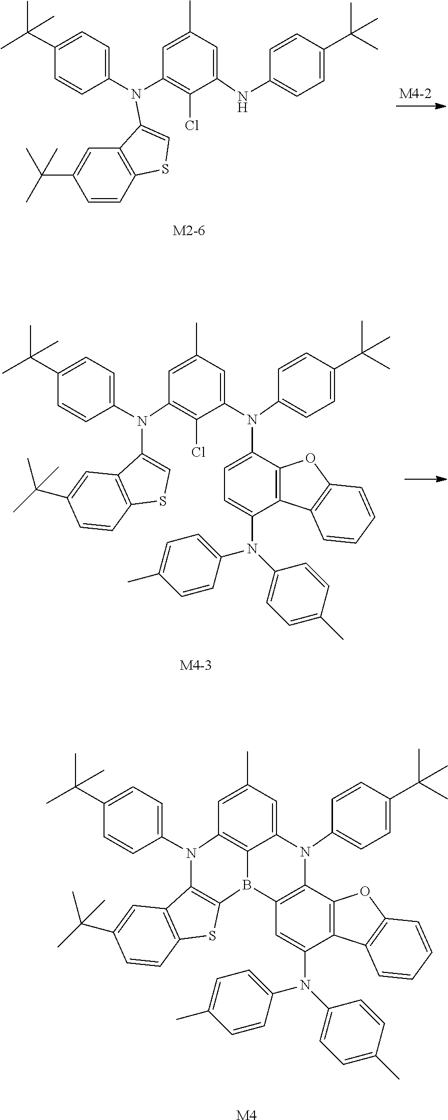

Specific synthesis steps of the organic compound M4 are as follows.

Synthesis of intermediate M4-2: according to the synthesis steps of the intermediate M1-3, the compounds M1-1 and M1-2 were replaced by compounds M4-1 and M2-4, respectively. The yield is 75%.

Synthesis of intermediate M4-3: according to the synthesis steps of the intermediate M1-6, the compounds M1-4 and M1-5 were replaced by compounds M4-2 and M2-6, respectively. The yield is 73%.

Synthesis of organic compound M4: according to the synthesis steps of the compound M1, the compound M1-7 is replaced by compound M4-3. The yield is 24%. A result of atmospheric solids analysis probe mass spectrometry (ASAP-MS) of the organic compound M4: the mass-to-charge ratio is 944[M⁺].

### Example 5

Synthesis of organic compound M5

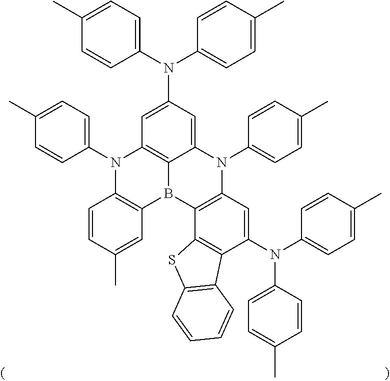

A synthetic route of the organic compound M5 is as follows.

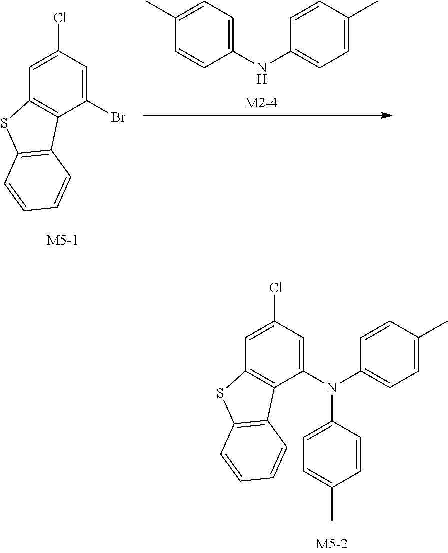

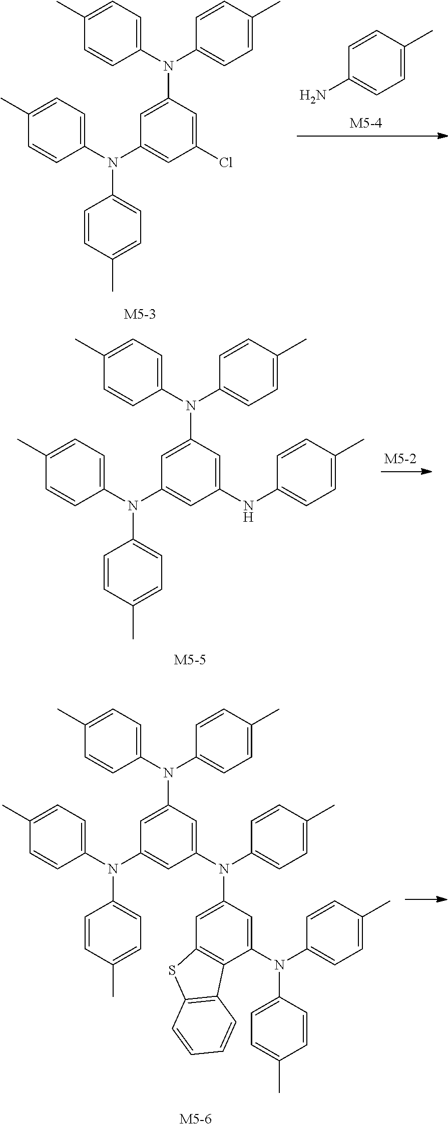

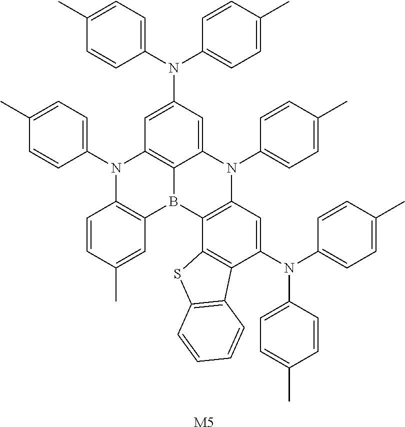

Specific synthesis steps of the organic compound M5 are as follows.

Synthesis of intermediate M5-2: according to the synthesis steps of the intermediate M1-3, the compounds M1-1 and M1-2 were replaced by compounds M5-1 and M2-4, respectively. The yield is 73%.

Synthesis of intermediate M5-5: according to the synthesis steps of the intermediate M1-6, the compounds M1-4 and M1-5 were replaced by compounds M5-3 and M5-4, respectively. The yield is 75%.

Synthesis of intermediate M5-6: according to the synthesis steps of the intermediate M1-6, the compounds M1-4 and M1-5 were replaced by compounds M5-2 and M5-5, respectively. The yield is 71%.

Synthesis of organic compound M5: under the nitrogen atmosphere, (28.5 g, 30 mmol) of compound M5-6 and 50 mL of o-dichlorobenzene were mixed, 35 mmol of boron tribromide was slowly added during stirring, and the reaction solution was heated to 180° C. for 12 hours for reaction. After cooled to room temperature, 60 mmol of diisopropylethylamine was added and reacted for 1 hour at room temperature. The reaction was quenched by adding double distilled water, then extracted with dichloromethane, and washed three times with water. Organic phase was collected and mixed with silica gel for purification by column chromatography. The yield is 26%. A result of atmospheric solids analysis probe mass spectrometry (ASAP-MS) of the organic compound M5: the mass-to-charge ratio is 959[M⁺].

### Example 6

Synthesis of organic compound M6

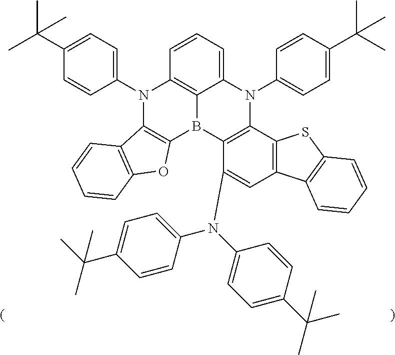 [SMILES: CC(C)(C)c1ccc(N(c2ccc(C(C)(C)C)cc2)c2cc3c(sc4ccccc43)c3c2B2c4oc5ccccc5c4N(c4ccc(C(C)(C)C)cc4)c4cccc(c42)N3c2ccc(C(C)(C)C)cc2)cc1]

A synthetic route of the organic compound M6 is as follows.

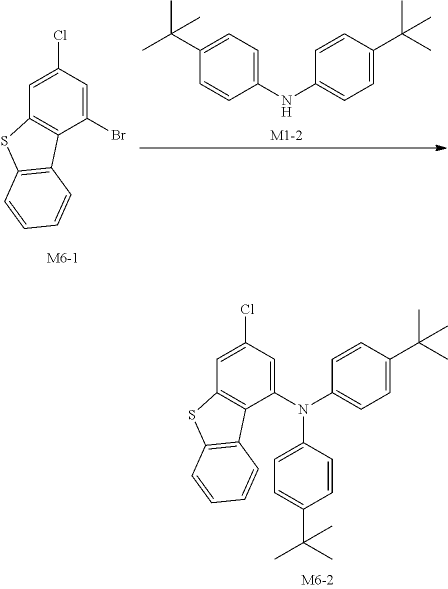 [SMILES: Clc1cc(Br)c2c(c1)sc1ccccc12 ; CC(C)(C)c1ccc(Nc2ccc(C(C)(C)C)cc2)cc1 ; CC(C)(C)c1ccc(N(c2ccc(C(C)(C)C)cc2)c2cc(Cl)cc3sc4ccccc4c23)cc1]

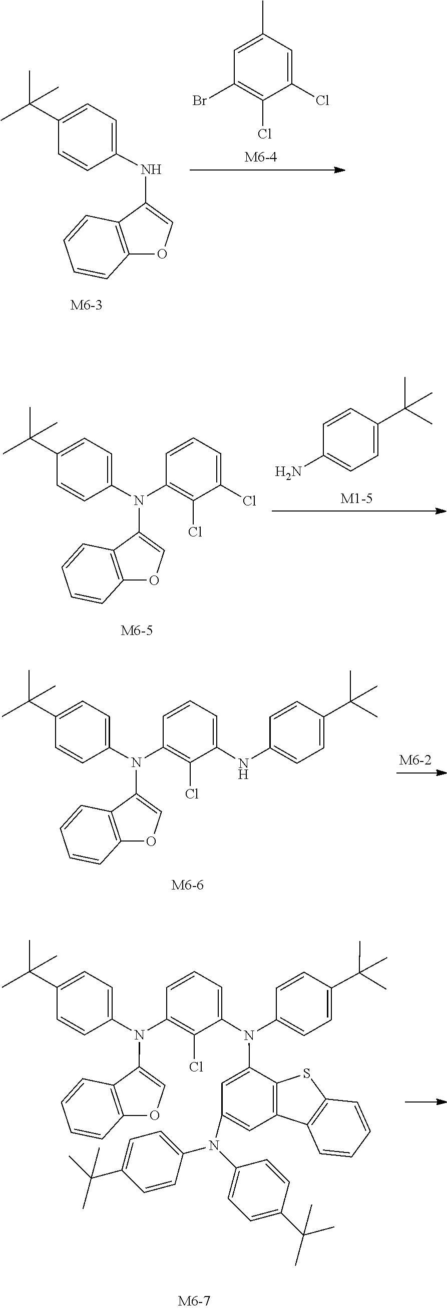

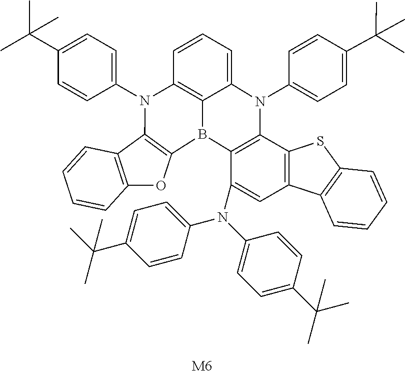 [SMILES: CC(C)(C)c1ccc(N(c2ccc(C(C)(C)C)cc2)c2cc3c(sc4ccccc43)c3c2B2c4oc5ccccc5c4N(c4ccc(C(C)(C)C)cc4)c4cccc(c42)N3c2ccc(C(C)(C)C)cc2)cc1 ; "M6"]

Specific synthesis steps of the organic compound M6 are as follows.

Synthesis of intermediate M6-2: according to the synthesis steps of the intermediate M1-3, the compound M1-1 is replaced by compound M6-1. The yield is 76%.

Synthesis of intermediate M6-5: according to the synthesis steps of the intermediate M1-3, the compounds M1-1 and M1-2 were replaced by compounds M6-4 and M6-3, respectively. The yield is 72%.

Synthesis of intermediate M6-6: according to the synthesis steps of the intermediate M1-6, the compound M1-4 is replaced by compound M6-5. The yield is 70%.

Synthesis of intermediate M6-7: according to the synthesis steps of the intermediate M1-6, the compounds M1-4 and M1-5 were replaced by compounds M6-2 and M6-6, respectively. The yield is 73%.

Synthesis of organic compound M6: according to the synthesis steps of the compound M1, the compound M1-7 is replaced by compound M6-7. The yield is 24%. A result of atmospheric solids analysis probe mass spectrometry (ASAP-MS) of the organic compound M6: the mass-to-charge ratio is 958[M⁺].

### Example 7

Synthesis of organic compound M7

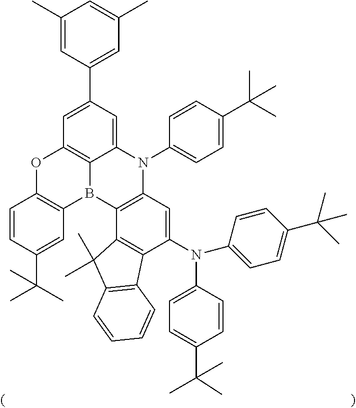 [SMILES: Cc1cc(C)cc(-c2cc3c4c(c2)N(c2ccc(C(C)(C)C)cc2)c2cc(N(c5ccc(C(C)(C)C)cc5)c5ccc(C(C)(C)C)cc5)c5c(c2B4c2cc(C(C)(C)C)ccc2O3)C(C)(C)c2ccccc2-5)c1]

A synthetic route of the organic compound M7 is as follows.

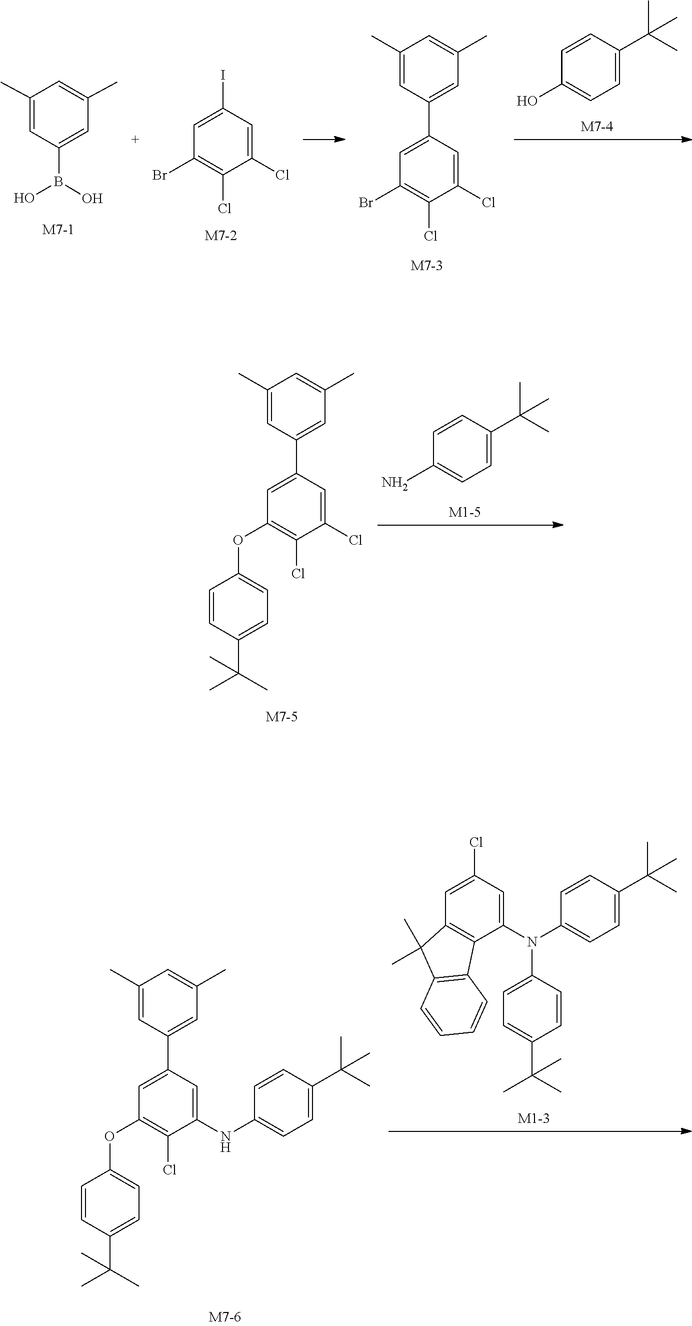

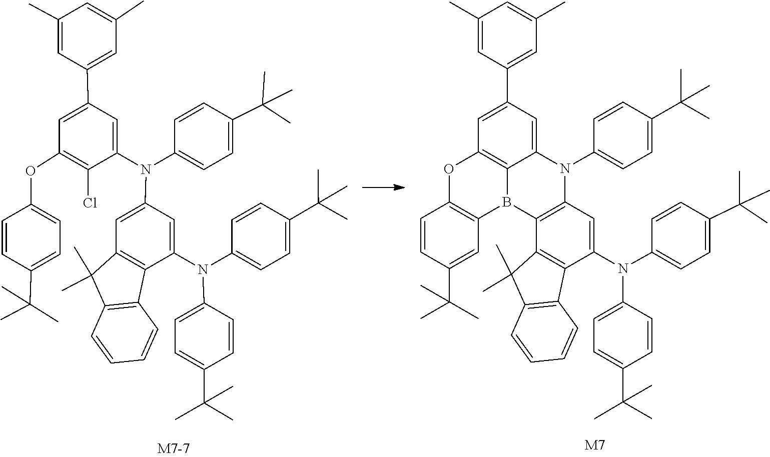

Specific synthesis steps of the organic compound M7 are as follows.

Synthesis of intermediate M7-3: under the nitrogen atmosphere, (15 g, 100 mmol) of compound M7-1, (35.2 g, 100 mmol) of compound M7-2, (3.3 g, 3 mmol) of tetrakis (triphenylphosphine) palladium, (20.6 g, 150 mmol, 40 mL) of potassium carbonate aqueous solution, and 200 mL of toluene were mixed, heated to 110° C., and stirred for 12 hours for reaction. After reaction, the reaction solution was cooled to room temperature, and the filtrate is collected by suction filtration, then rotary evaporated to remove most of solvents, and dissolved in dichloromethane and washed with water for three times. Organic phase was collected and mixed with silica gel for purification by column chromatography. The yield is 72%.

Synthesis of intermediate M7-5: under the nitrogen atmosphere, (19.8 g, 60 mmol) of compound M7-3, (9 g, 60 mmol) of compound M7-4, (0.57 g, 3 mmol) of Cul, (13.8 g, 100 mmol) of potassium carbonate, and 150 mL of dimethylformamide were mixed, heated to 110° C., and stirred for 12 hours for reaction. The reaction solution was cooled to room temperature, then rotary evaporated to remove most of solvents, and dissolved in dichloromethane and washed with water for three times. Organic phase was collected and mixed with silica gel for purification by column chromatography. The yield is 61%.

Synthesis of intermediate M7-6: according to the synthesis steps of the intermediate M1-6, the compound M1-4 is replaced by compound M7-5. The yield is 72%.

Synthesis of intermediate M7-7: according to the synthesis steps of the intermediate M1-6, the compounds M1-4 and M1-5 were replaced by compounds M1-3 and M7-6, respectively. The yield is 70%.

Synthesis of organic compound M7: according to the synthesis steps of the compound M1, the compound M1-7 is replaced by compound M7-7. The yield is 29%. A result of atmospheric solids analysis probe mass spectrometry (ASAP-MS) of the organic compound M7: the mass-to-charge ratio is 957[M⁺].

### Example 8

Synthesis of organic compound M8

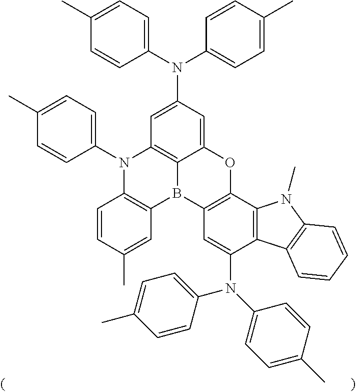 [SMILES: Cc1ccc(N(c2ccc(C)cc2)c2cc3c4c(c2)N(c2ccc(C)cc2)c2ccc(C)cc2B4c2cc(N(c4ccc(C)cc4)c4ccc(C)cc4)c4c5ccccc5n(C)c4c2O3)cc1]

A synthetic route of the organic compound M8 is as follows.

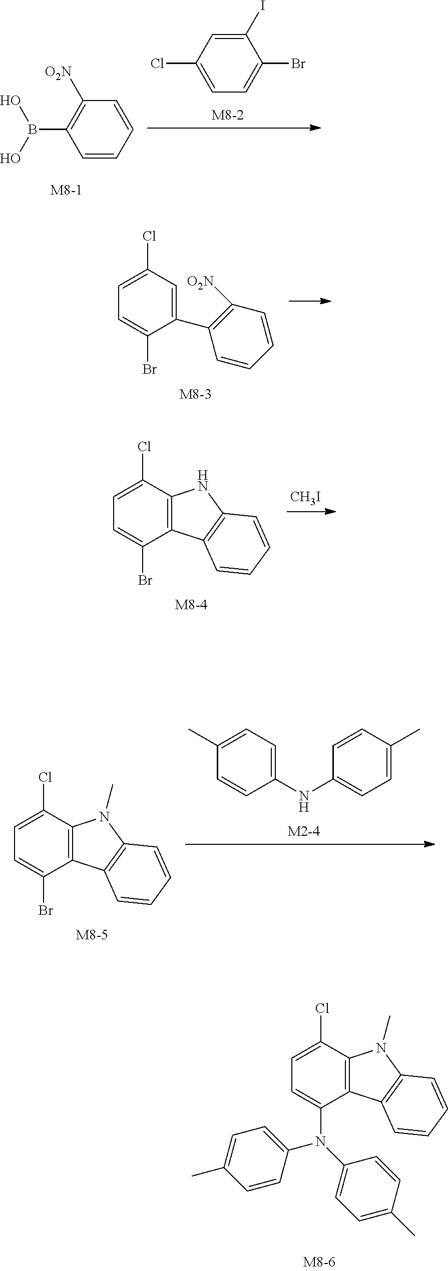

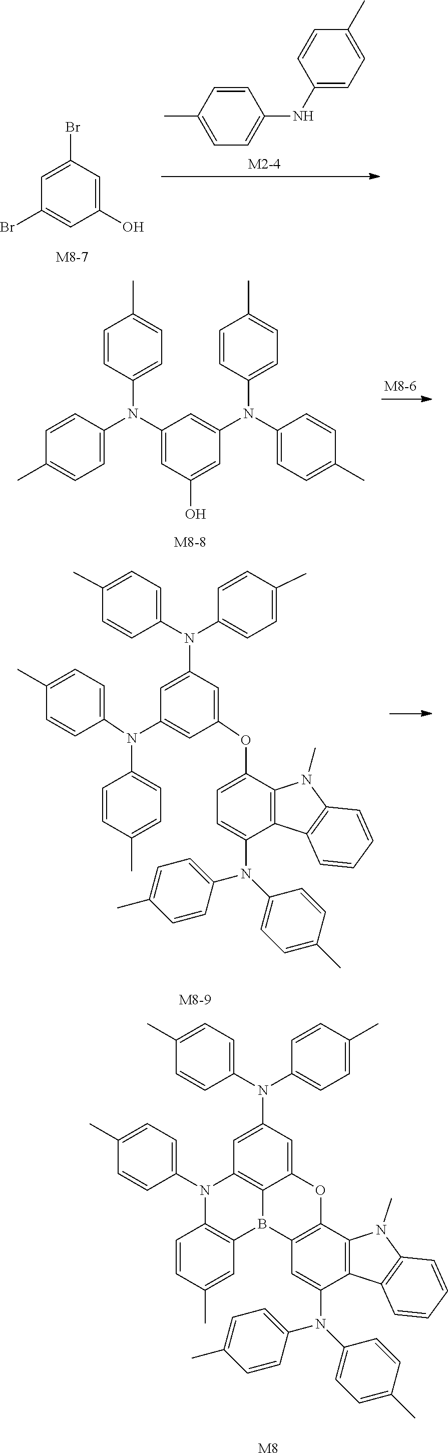

Specific synthesis steps of the organic compound M8 are as follows.

Synthesis of intermediate M8-3: according to the synthesis steps of the intermediate M7-3, the compounds M7-1 and M7-2 were replaced by compounds M8-1 and M8-2, respectively. The yield is 58%.

Synthesis of intermediate M8-4: under the nitrogen atmosphere, (18.8 g, 60 mmol) of compound M8-3 and (60.6 g, 150 mmol) of triethylphosphorus were mixed, heated to 190° C., and stirred for 12 hours for reaction. After the reaction, the reaction solution was distilled under reduced pressure to remove most of the solvents, and dissolved in dichloromethane and washed with water for three times. Organic phase was collected and mixed with silica gel for purification by column chromatography. The yield is 76%.

Synthesis of intermediate M8-5: under the nitrogen environment, (11.2 g, 40 mmol) of compound M8-4, (3.2 g, 80 mmol) of NaOH, and 80 mL of dimethylformamide were added to a 250 mL two-necked flask and stirred for 1 hour for reaction, and (5.7 g, 40 mmol) of iodomethane was added at one time and stirred for 4 hours for reaction. After reaction, the reaction solution was poured into 300 mL of pure water, and after stirring, a solid was obtained by suction filtration and then purified by recrystallization with a mixing solution of ethanol and dichloromethane. The yield is 80%.

Synthesis of intermediate M8-6: according to the synthesis steps of the intermediate M1-3, the compounds M1-1 and M1-2 were replaced by compounds M8-5 and M2-4, respectively. The yield is 73%.

Synthesis of intermediate M8-8: according to the synthesis steps of the intermediate M1-3, the compounds M1-1 and M1-2 were replaced by compound M8-7 and twice the molar amount of compound M2-4, respectively. The yield is 65%.

Synthesis of intermediate M8-9: according to the synthesis steps of the intermediate M7-5, the compounds M7-3 and M7-4 were replaced by compounds M8-6 and M8-8, respectively. The yield is 62%.

Synthesis of organic compound M8: according to the synthesis steps of the compound M5, the compound M5-6 is replaced by compound M8-9. The yield is 28%. A result of atmospheric solids analysis probe mass spectrometry (ASAP-MS) of the organic compound M8: the mass-to-charge ratio is 867[M⁺].

### Example 9

Synthesis of organic compound M9

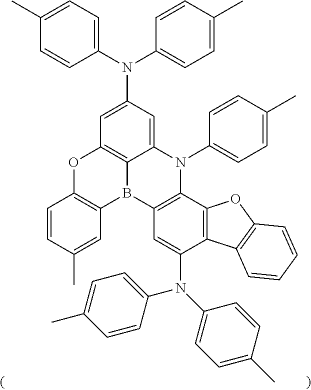 [SMILES: Cc1ccc(N(c2ccc(C)cc2)c2cc3c4c(c2)N(c2ccc(C)cc2)c2c(cc(N(c5ccc(C)cc5)c5ccc(C)cc5)c5c2oc2ccccc25)B4c2cc(C)ccc2O3)cc1]

A synthetic route of the organic compound M9 is as follows.

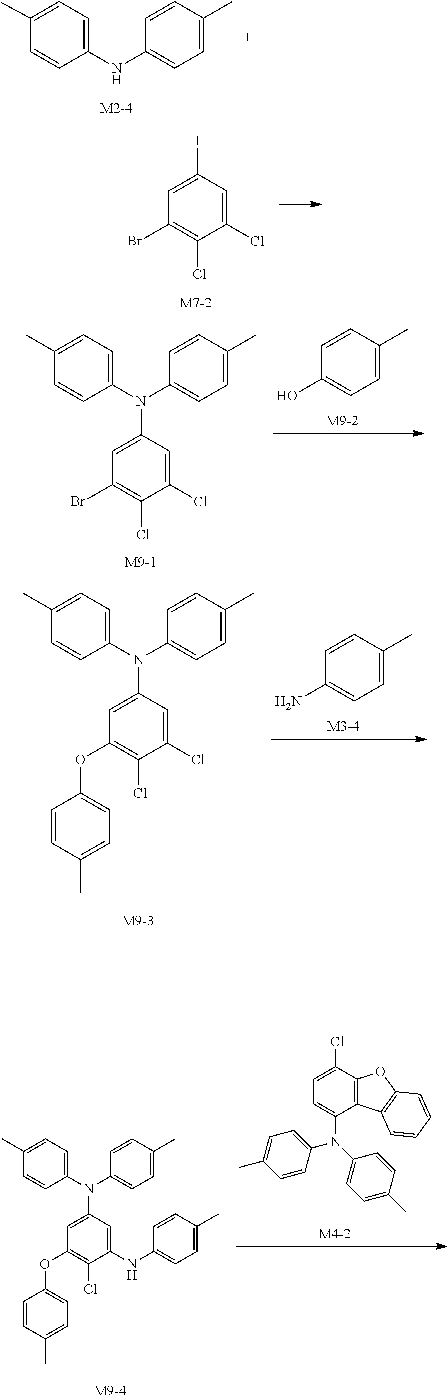

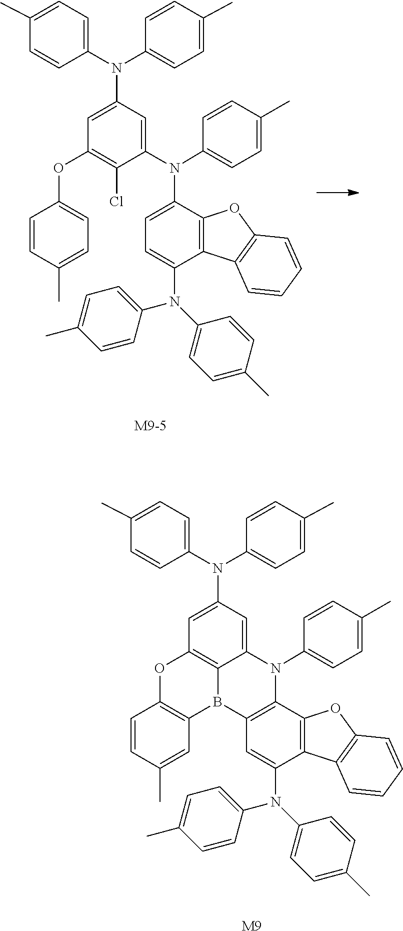 [SMILES: Cc1ccc(Oc2cc(N(c3ccc(C)cc3)c3ccc(C)cc3)cc(N(c3ccc(C)cc3)c3ccc(N(c4ccc(C)cc4)c4ccc(C)cc4)c4c3oc3ccccc34)c2Cl)cc1 ; Cc1ccc(N(c2ccc(C)cc2)c2cc3c4c(c2)N(c2ccc(C)cc2)c2c(cc(N(c5ccc(C)cc5)c5ccc(C)cc5)c5c2oc2ccccc25)B4c2cc(C)ccc2O3)cc1 ; "M9"]

Specific synthesis steps of the organic compound M9 are as follows.

Synthesis of intermediate M9-1: according to the synthesis steps of the intermediate M1-3, the compounds M1-1 and M1-2 were replaced by compounds M7-2 and M2-4, respectively. The yield is 68%.

Synthesis of intermediate M9-3: according to the synthesis steps of the intermediate M7-5, the compounds M7-3 and M7-4 were replaced by compounds M9-1 and M9-2, respectively. The yield is 65%.

Synthesis of intermediate M9-4: according to the synthesis steps of the intermediate M1-6, the compounds M1-4 and M1-5 were replaced by compounds M9-3 and M5-4, respectively. The yield is 71%.

Synthesis of intermediate M9-5: according to the synthesis steps of the intermediate M1-6, the compounds M1-4 and M1-5 were replaced by compounds M4-2 and M9-4, respectively. The yield is 66%.

Synthesis of organic compound M9: according to the synthesis steps of the compound M1, the compound M1-7 is replaced by compound M9-5. The yield is 26%. A result of atmospheric solids analysis probe mass spectrometry (ASAP-MS) of the organic compound M9: the mass-to-charge ratio is 854[M⁺].

### Example 10

Synthesis of organic compound M10

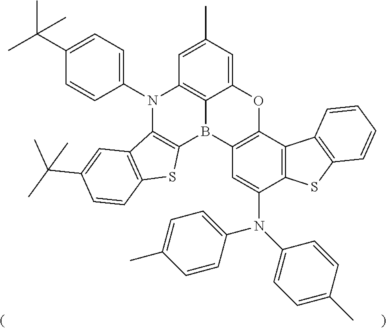 [SMILES: Cc1ccc(N(c2ccc(C)cc2)c2cc3c(c4c2sc2ccccc24)Oc2cc(C)cc4c2B3c2sc3ccc(C(C)(C)C)cc3c2N4c2ccc(C(C)(C)C)cc2)cc1]

A synthetic route of the organic compound M10 is as follows.

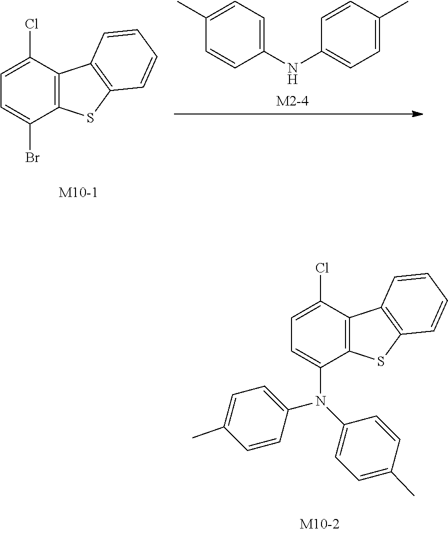

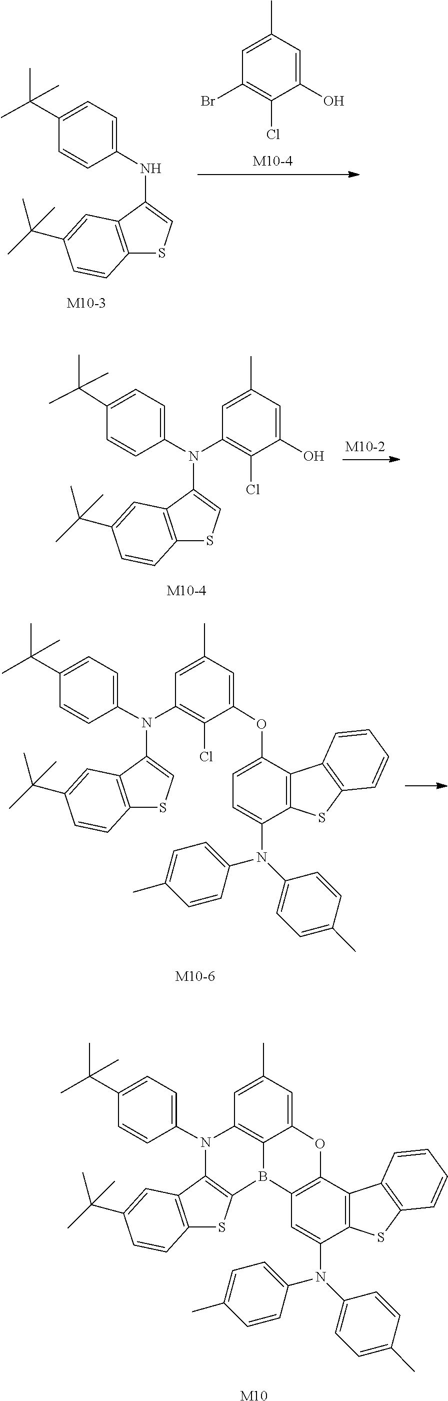

Specific synthesis steps of the organic compound M10 are as follows.

Synthesis of intermediate M10-2: according to the synthesis steps of the intermediate M1-3, the compounds M1-1 and M1-2 were replaced by compounds M10-1 and M2-4, respectively. The yield is 72%.

Synthesis of intermediate M10-5: according to the synthesis steps of the intermediate M1-3, the compounds M1-1 and M1-2 were replaced by compounds M10-4 and M10-3, respectively. The yield is 65%.

Synthesis of intermediate M10-6: according to the synthesis steps of the intermediate M7-5, the compounds M7-3 and M7-4 were replaced by compounds M10-2 and M10-5, respectively. The yield is 70%.

Synthesis of organic compound M10: according to the synthesis steps of the compound M1, the compound M1-7 is replaced by compound M10-6. The yield is 26%. A result of atmospheric solids analysis probe mass spectrometry (ASAP-MS) of the organic compound M10: the mass-to-charge ratio is 829[M⁺].

### Example 11

Synthesis of organic compound M11

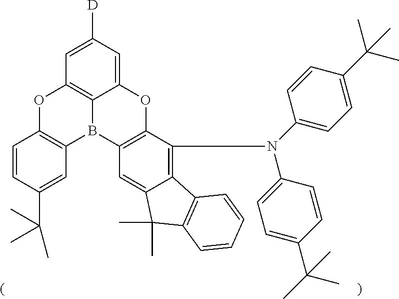 [SMILES: [2H]c1cc2c3c(c1)Oc1c(cc4c(c1N(c1ccc(C(C)(C)C)cc1)c1ccc(C(C)(C)C)cc1)-c1ccccc1C4(C)C)B3c1cc(C(C)(C)C)ccc1O2]

A synthetic route of the organic compound M11 is as follows.

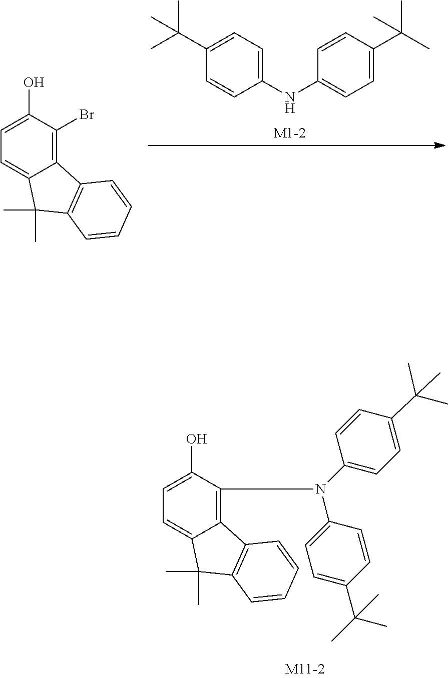 [SMILES: CC1(C)c2ccccc2-c2c1ccc(O)c2Br ; CC(C)(C)c1ccc(Nc2ccc(C(C)(C)C)cc2)cc1 ; CC(C)(C)c1ccc(N(c2ccc(C(C)(C)C)cc2)c2c(O)ccc3c2-c2ccccc2C3(C)C)cc1]

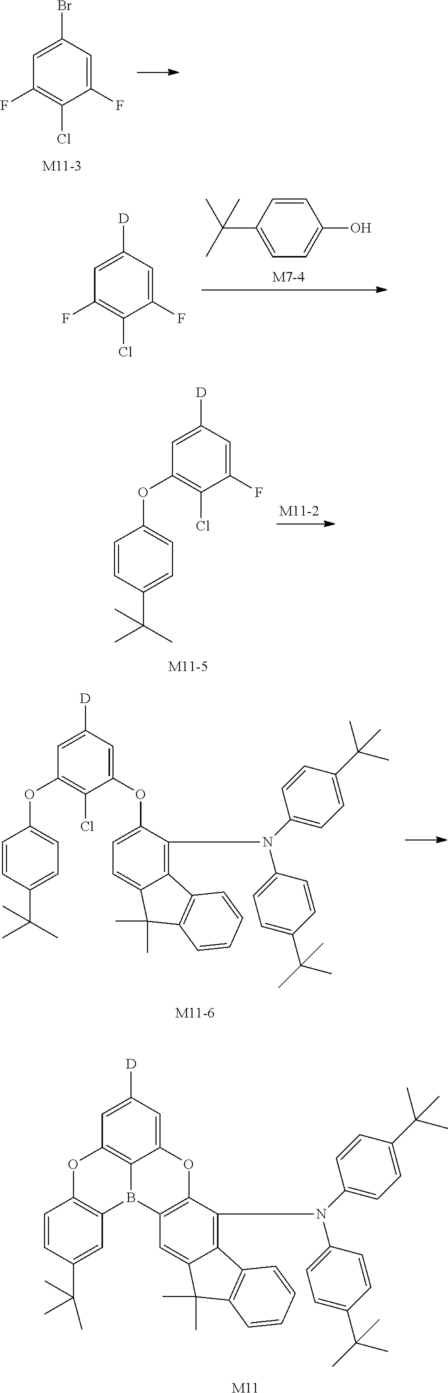

Specific synthesis steps of the organic compound M11 are as follows.

Synthesis of intermediate M11-2: according to the synthesis steps of the intermediate M1-3, the compound M1-1 is replaced by compound M11-1. The yield is 62%.

Synthesis of intermediate M11-4: under the nitrogen atmosphere, (22.7 g, 100 mmol) of compound M11-3 and 100 mL of anhydrous tetrahydrofuran were mixed, stirred for dissolving, and cooled to −78° C. 100 mmol of n-butyl lithium was added dropwise and then reacting for 2 hours. Then 150 mmol of deuterated water was added at one time, and when the reaction solution slowly rose to room temperature, the reaction solution was stirred for 4 hours for reaction. After the reaction, the reaction solution was rotary evaporated to remove most of solvents, dissolved in dichloromethane, and washed with water for three times. Organic phase was collected and mixed with silica gel for purification by column chromatography. The yield is 72%.

Synthesis of intermediate M11-5: under the nitrogen atmosphere, (9 g, 60 mmol) of compound M11-3, (9 g, 60 mmol) of compound M7-4, (39 g, 120 mmol) of cesium carbonate, and 150 mL of dimethylformamide were mixed and reacted for 12 hours under reflux. After reaction, the reaction solution was cooled to room temperature, then rotary evaporated to remove most of solvents, and extracted with dichloromethane and washed with water for three times. Organic phase was collected and mixed with silica gel for purification by column chromatography. The yield is 62%.

Synthesis of intermediate M11-6: according to the synthesis steps of the intermediate M11-5, the compounds M11-4 and M7-4 were replaced by compounds M11-5 and M11-2, respectively. The yield is 73%.

Synthesis of organic compound M11: according to the synthesis steps of the compound Ml, the compound M1-7 is replaced by compound M11-6. The yield is 35%. A result of atmospheric solids analysis probe mass spectrometry (ASAP-MS) of the organic compound M11: the mass-to-charge ratio is 723[M⁺].

### Example 12

Synthesis of organic compound M12

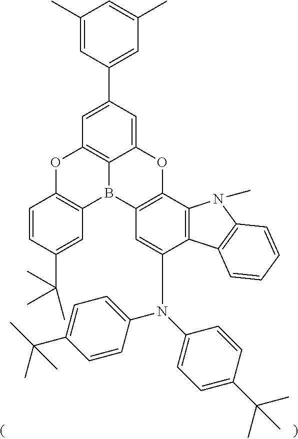 [SMILES: Cc1cc(C)cc(-c2cc3c4c(c2)Oc2c(cc(N(c5ccc(C(C)(C)C)cc5)c5ccc(C(C)(C)C)cc5)c5c6ccccc6n(C)c25)B4c2cc(C(C)(C)C)ccc2O3)c1]

A synthetic route of the organic compound M12 is as follows.

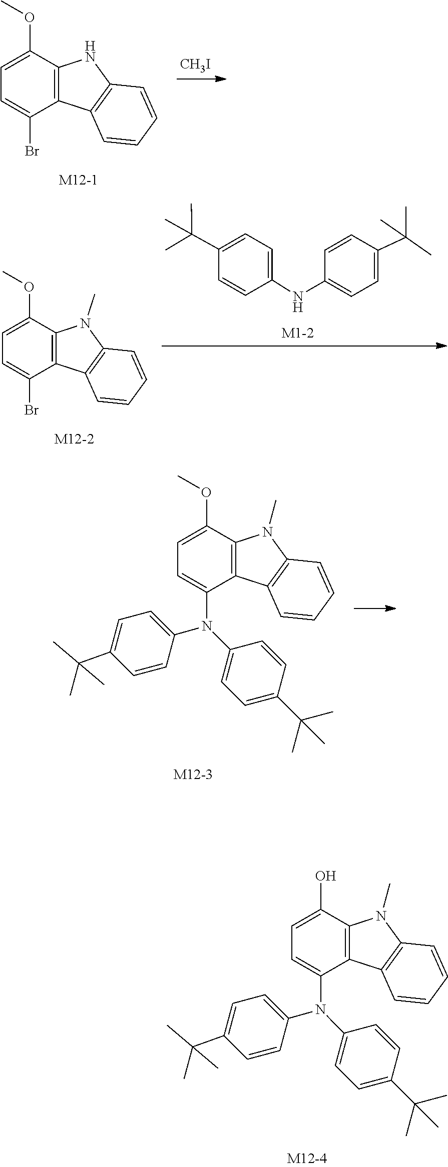

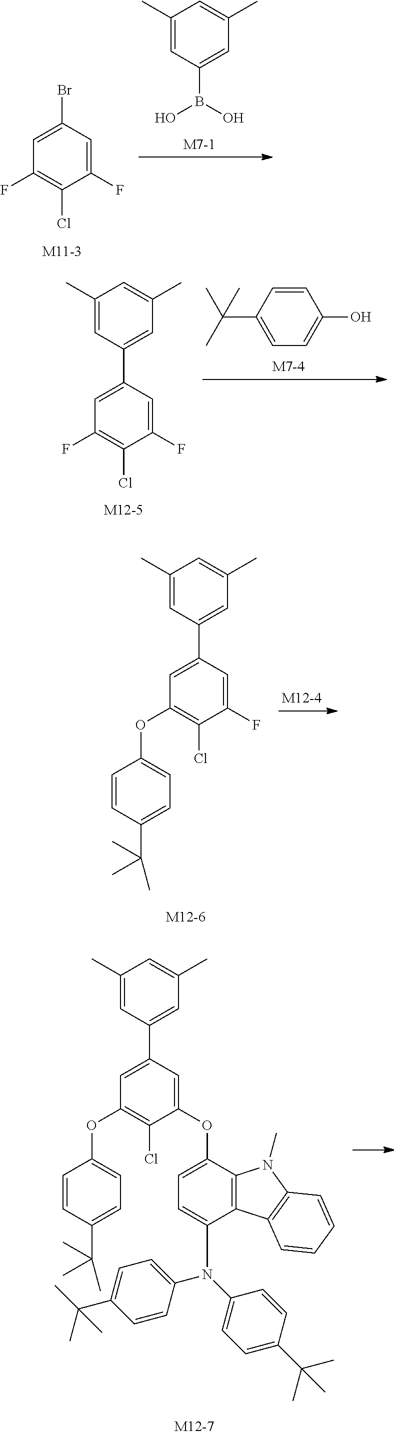

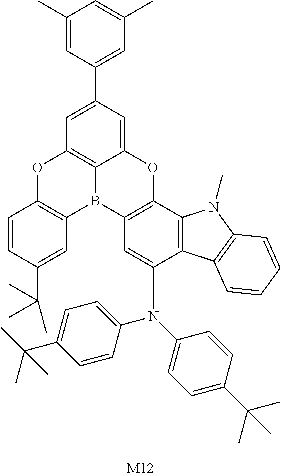 [SMILES: Cc1cc(C)cc(-c2cc3c4c(c2)Oc2c(cc(N(c5ccc(C(C)(C)C)cc5)c5ccc(C(C)(C)C)cc5)c5c6ccccc6n(C)c25)B4c2cc(C(C)(C)C)ccc2O3)c1 ; "M12"]

Specific synthesis steps of the organic compound M12 are as follows.

Synthesis of intermediate M12-2: according to the synthesis steps of the intermediate M8-5, the compound M8-4 is replaced by compound M12-1. The yield is 78%.

Synthesis of intermediate M12-3: according to the synthesis steps of the intermediate M1-3, the compound M1-1 is replaced by compound M12-2. The yield is 76%.

Synthesis of intermediate M12-4: under the nitrogen atmosphere, (19.6 g, 40 mmol) of compound M12-2 and 100 mL of dichloromethane were added to a 350 mL three-necked flask. 60 mmol of boron tribromide in a dichloromethane solution was slowly added under ice bath, and after the temperature slowly rose to room temperature, the reaction solution was stirred for 24 hours for reaction at the room temperature. The reaction was quenched by adding water, and the reaction solution was extracted with dichloromethane and washed with water for three times. Organic phase was collected and mixed with silica gel for purification by column chromatography. The yield is 72%.

Synthesis of intermediate M12-5: according to the synthesis steps of the intermediate M7-3, the compound M7-2 is replaced by compound M11-3. The yield is 78%.

Synthesis of intermediate M12-6: according to the synthesis steps of the intermediate M11-5, the compound M11-4 is replaced by compound M12-5. The yield is 64%.

Synthesis of intermediate M12-7: according to the synthesis steps of the intermediate M11-5, the compounds M11-4 and M7-4 were replaced by compounds M12-6 and M12-4, respectively. The yield is 70%.

Synthesis of organic compound M12: according to the synthesis steps of the compound M1, the compound M1-7 is replaced by compound M12-7. The yield is 33%. A result of atmospheric solids analysis probe mass spectrometry (ASAP-MS) of the organic compound M12: the mass-to-charge ratio is 813[M⁺].

### Example 13

Synthesis of organic compound M13

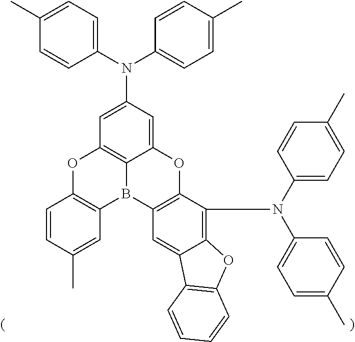

A synthetic route of the organic compound M13 is as follows.

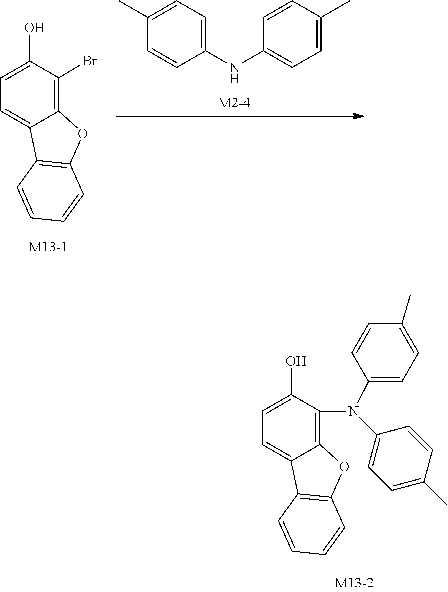

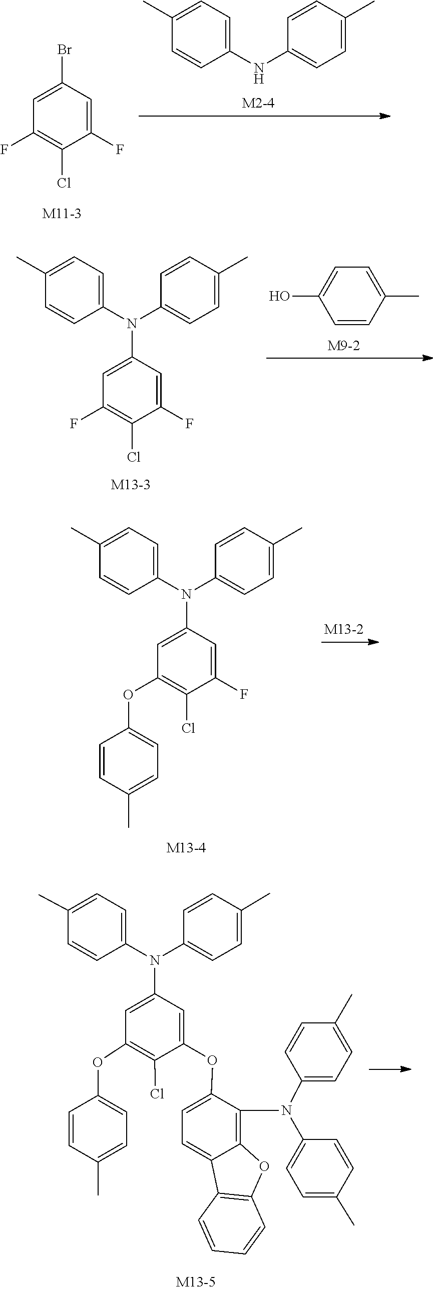

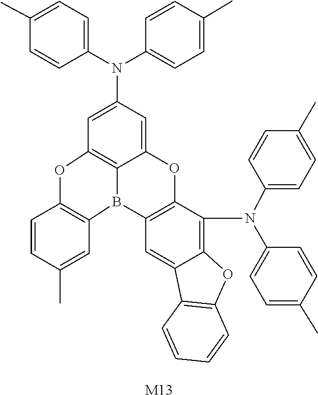

Specific synthesis steps of the organic compound M13 are as follows.

Synthesis of intermediate M13-2: according to the synthesis steps of the intermediate M1-3, the compounds M1-1 and M1-2 were replaced by compounds M13-1 and M2-4, respectively. The yield is 67%.

Synthesis of intermediate M13-3: according to the synthesis steps of the intermediate M1-3, the compounds M1-1 and M1-2 were replaced by compounds M11-3 and M2-4, respectively. The yield is 65%.

Synthesis of intermediate M13-4: according to the synthesis steps of the intermediate M11-5, the compounds M11-4 and M7-4 were replaced by compounds M13-3 and M9-2, respectively. The yield is 62%.

Synthesis of intermediate M13-5: according to the synthesis steps of the intermediate M11-5, the compounds M11-4 and M7-4 were replaced by compounds M13-4 and M13-2, respectively. The yield is 60%.

Synthesis of organic compound M13: according to the synthesis steps of the compound M1, the compound M1-7 is replaced by compound M13-5. The yield is 33%. A result of atmospheric solids analysis probe mass spectrometry (ASAP-MS) of the organic compound M13: the mass-to-charge ratio is 765[M⁺].

### Example 14

Synthesis of organic compound M14

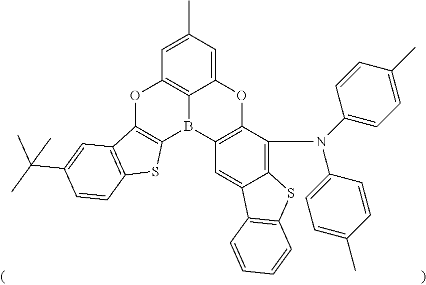 [SMILES: Cc1ccc(N(c2ccc(C)cc2)c2c3c(cc4c2sc2ccccc24)B2c4sc5ccc(C(C)(C)C)cc5c4Oc4cc(C)cc(c42)O3)cc1]

A synthetic route of the organic compound M14 is as follows.

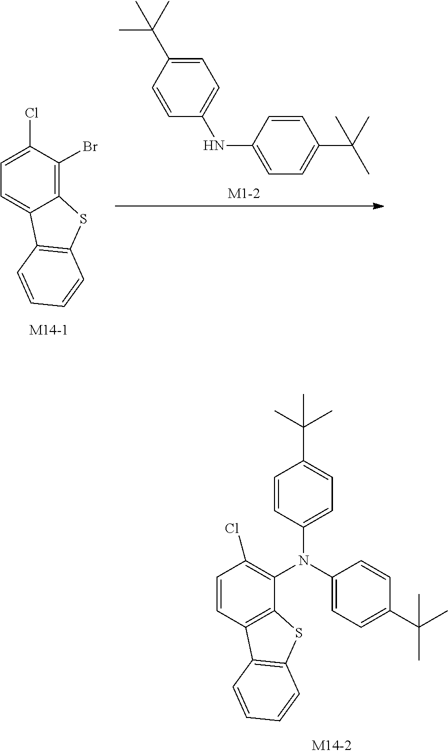 [SMILES: Clc1ccc2c(sc3ccccc32)c1Br ; CC(C)(C)c1ccc(Nc2ccc(C(C)(C)C)cc2)cc1 ; CC(C)(C)c1ccc(N(c2ccc(C(C)(C)C)cc2)c2c(Cl)ccc3c2sc2ccccc23)cc1]

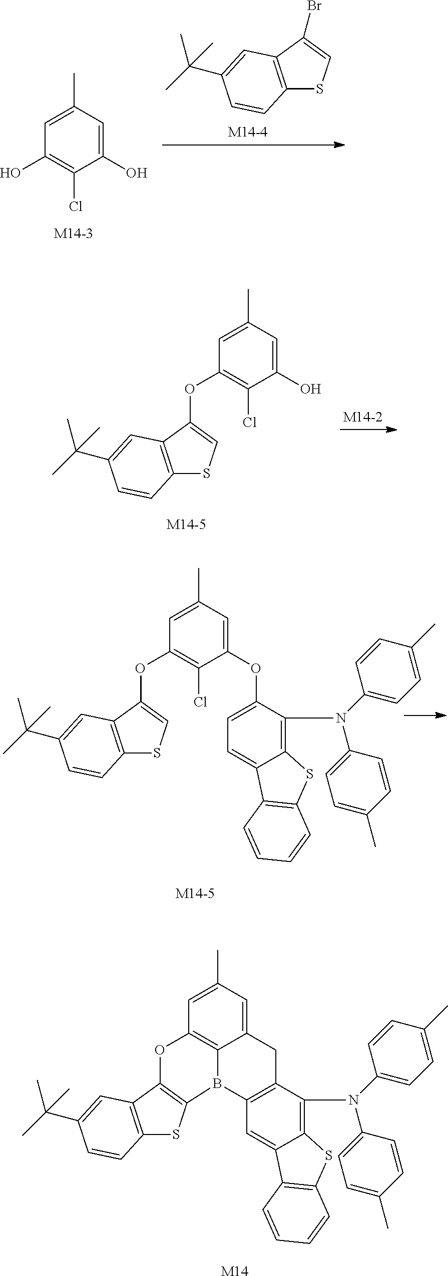

Specific synthesis steps of the organic compound M14 are as follows.

Synthesis of intermediate M14-2: according to the synthesis steps of the intermediate M1-3, the compound M1-1 is replaced by compound M14-1. The yield is 69%.

Synthesis of intermediate M14-5: according to the synthesis steps of the intermediate M7-5, the compounds M7-3 and M7-4 were replaced by compounds M14-4 and M14-3, respectively. The yield is 68%.

Synthesis of intermediate M14-6: according to the synthesis steps of the intermediate M7-5, the compounds M7-3 and M7-4 were replaced by compounds M14-2 and M14-5, respectively. The yield is 62%.

Synthesis of organic compound M14: according to the synthesis steps of the compound M1, the compound M1-7 is replaced by compound M14-6. The yield is 34%. A result of atmospheric solids analysis probe mass spectrometry (ASAP-MS) of the organic compound M14: the mass-to-charge ratio is 698[M⁺].

### Example 15

Synthesis of organic compound M15

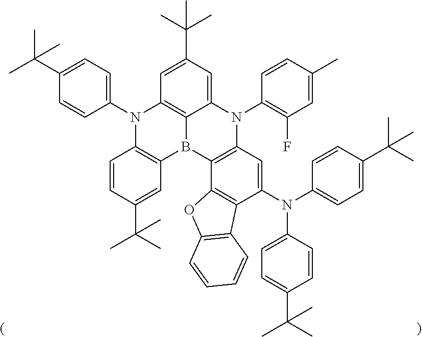 [SMILES: Cc1ccc(N2c3cc(C(C)(C)C)cc4c3B(c3cc(C(C)(C)C)ccc3N4c3ccc(C(C)(C)C)cc3)c3c2cc(N(c2ccc(C(C)(C)C)cc2)c2ccc(C(C)(C)C)cc2)c2c3oc3ccccc32)c(F)c1]

A synthetic route of the organic compound M15 is as follows.

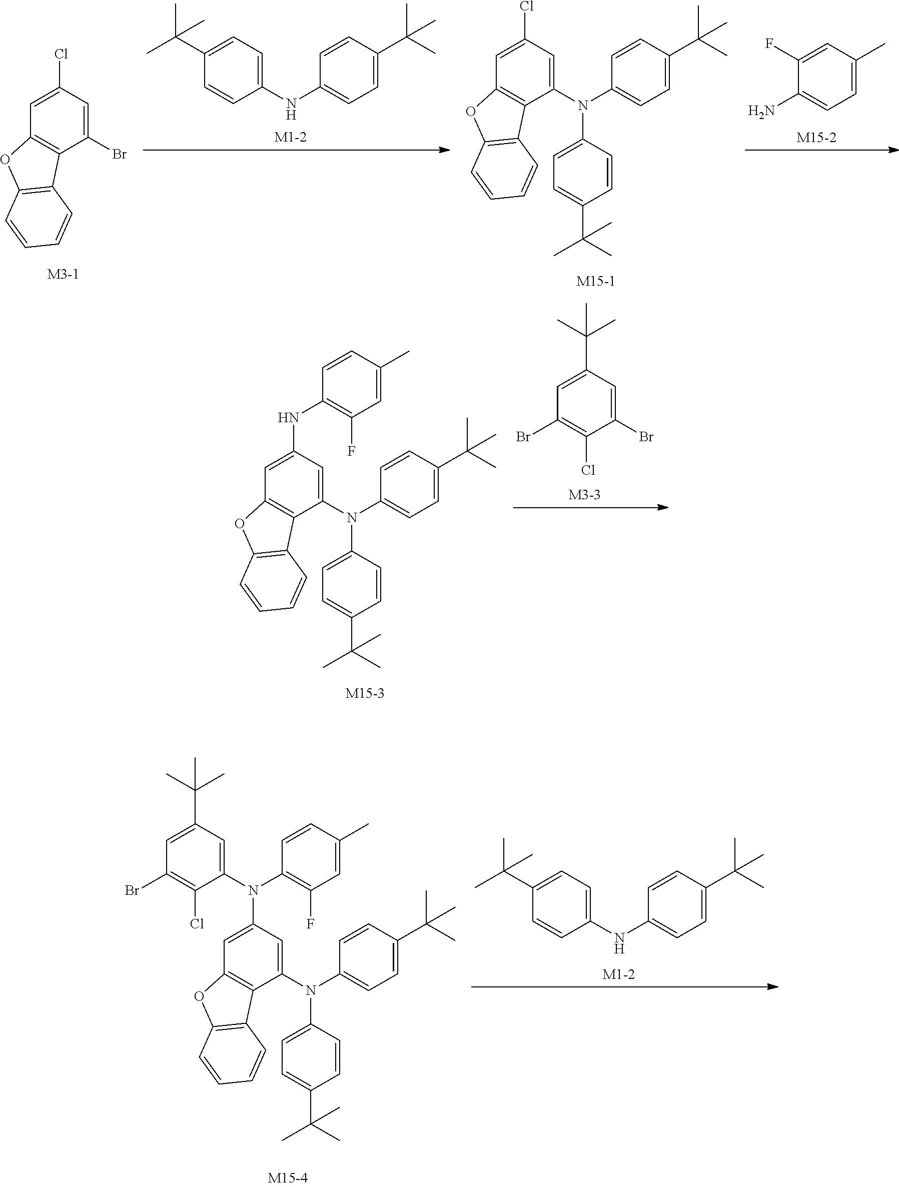

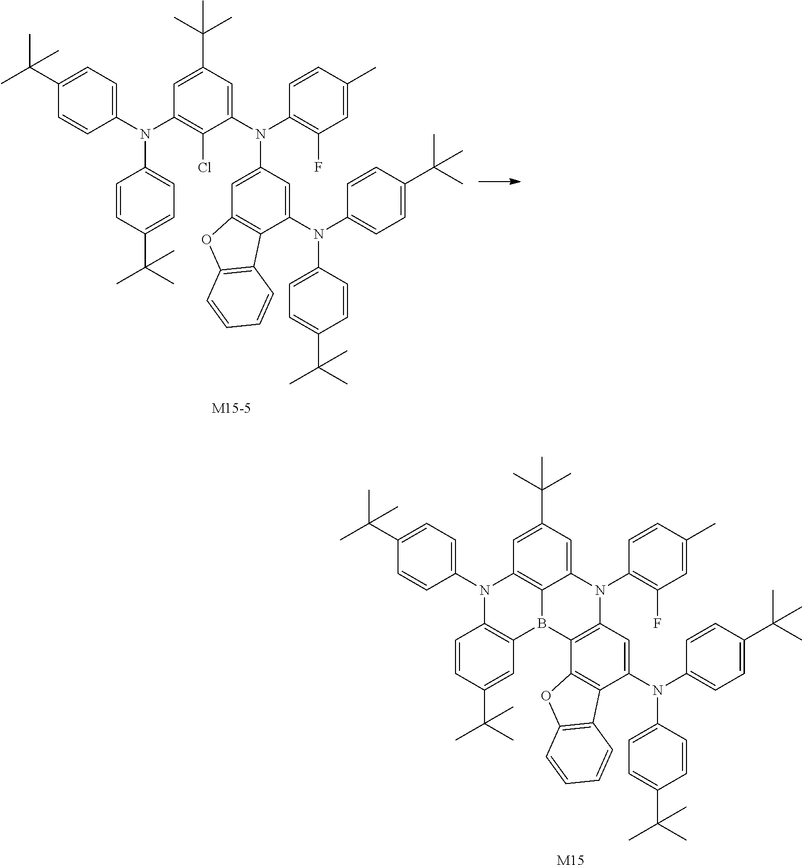 [SMILES: Cc1ccc(N(c2cc(N(c3ccc(C(C)(C)C)cc3)c3ccc(C(C)(C)C)cc3)c3c(c2)oc2ccccc23)c2cc(C(C)(C)C)cc(N(c3ccc(C(C)(C)C)cc3)c3ccc(C(C)(C)C)cc3)c2Cl)c(F)c1 ; Cc1ccc(N2c3cc(C(C)(C)C)cc4c3B(c3cc(C(C)(C)C)ccc3N4c3ccc(C(C)(C)C)cc3)c3c2cc(N(c2ccc(C(C)(C)C)cc2)c2ccc(C(C)(C)C)cc2)c2c3oc3ccccc32)c(F)c1 ; "M15"]

Specific synthesis steps of the organic compound M15 are as follows.

Synthesis of intermediate M15-1: according to the synthesis steps of the intermediate M1-3, the compound M1-1 is replaced by compound M3-1. The yield is 70%.

Synthesis of intermediate M15-3: according to the synthesis steps of the intermediate M1-6, the compounds M1-4 and M1-5 were replaced by compounds M15-1 and M15-2, respectively. The yield is 73%.

Synthesis of intermediate M15-4: according to the synthesis steps of the intermediate M1-7, the compounds M1-3 and M1-6 were replaced by compounds M15-1 and M15-2, respectively. The yield is 64%.

Synthesis of intermediate M15-5: according to the synthesis steps of the intermediate M1-7, the compounds M1-3 and M1-6 were replaced by compounds M15-4 and M1-2, respectively. The yield is 69%.

Synthesis of organic compound M15: according to the synthesis steps of the compound Ml, the compound M1-7 is replaced by compound M15-5. The yield is 30%. A result of atmospheric solids analysis probe mass spectrometry (ASAP-MS) of the organic compound M15: the mass-to-charge ratio is 990[M⁺].

### Example 16

Synthesis of organic compound M16

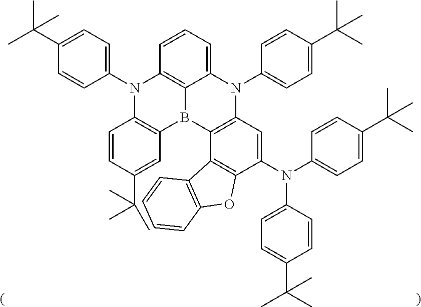 [SMILES: CC(C)(C)c1ccc(N2c3ccc(C(C)(C)C)cc3B3c4c2cccc4N(c2ccc(C(C)(C)C)cc2)c2cc(N(c4ccc(C(C)(C)C)cc4)c4ccc(C(C)(C)C)cc4)c4oc5ccccc5c4c23)cc1]

A synthetic route of the organic compound M16 is as follows.

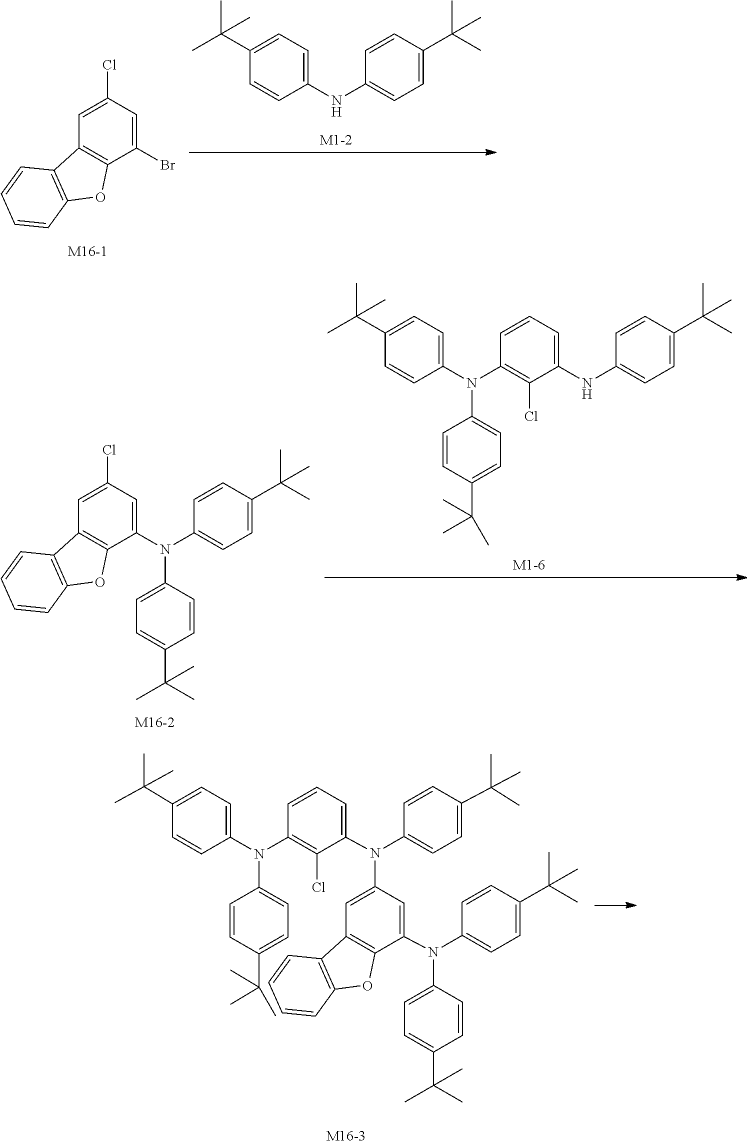 [SMILES: Clc1cc(Br)c2oc3ccccc3c2c1 ; CC(C)(C)c1ccc(Nc2ccc(C(C)(C)C)cc2)cc1 ; CC(C)(C)c1ccc(N(c2ccc(C(C)(C)C)cc2)c2cc(Cl)cc3c2oc2ccccc23)cc1 ; CC(C)(C)c1ccc(Nc2cccc(N(c3ccc(C(C)(C)C)cc3)c3ccc(C(C)(C)C)cc3)c2Cl)cc1 ; CC(C)(C)c1ccc(N(c2ccc(C(C)(C)C)cc2)c2cccc(N(c3ccc(C(C)(C)C)cc3)c3cc(N(c4ccc(C(C)(C)C)cc4)c4ccc(C(C)(C)C)cc4)c4oc5ccccc5c4c3)c2Cl)cc1]

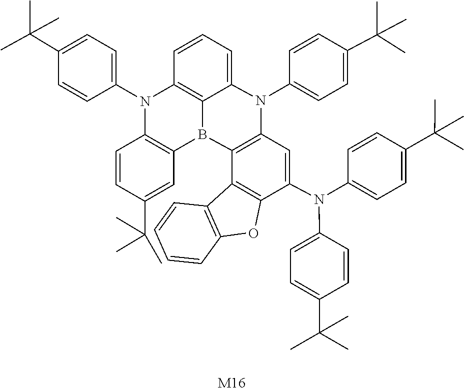 [SMILES: CC(C)(C)c1ccc(N2c3ccc(C(C)(C)C)cc3B3c4c2cccc4N(c2ccc(C(C)(C)C)cc2)c2cc(N(c4ccc(C(C)(C)C)cc4)c4ccc(C(C)(C)C)cc4)c4oc5ccccc5c4c23)cc1 ; "M16"]

Specific synthesis steps of the organic compound M16 are as follows.

Synthesis of intermediate M16-2: according to the synthesis steps of the intermediate M1-3, the compound M1-1 is replaced by compound M16-1. The yield is 72%.

Synthesis of intermediate M16-3: according to the synthesis steps of the intermediate M1-6, the compounds M1-4 and M1-5 were replaced by compounds M16-2 and M1-6, respectively. The yield is 74%.

Synthesis of organic compound M16: according to the synthesis steps of the compound M1, the compound M1-7 is replaced by compound M16-3. The yield is 28%. A result of atmospheric solids analysis probe mass spectrometry (ASAP-MS) of the organic compound M16: the mass-to-charge ratio is 958[M⁺].

Exemplary manufacturing steps of the light-emitting component provided in the present disclosure are shown in example 17.

### Example 17

In this embodiment, the manufacturing steps of the light-emitting component having anode (ITO)/hole injection layer (40 nm)/hole transport layer (100 nm)/light-emitting layer (the mass ratio of host material to guest material=3%) (50 nm)/electron transport layer (25 nm)/ cathode (Liq) (1 nm)/Al (150 nm) are as follows.

a. Cleaning of conductive glass substrates: when used for the first time, they may be cleaned with various solvents, such as chloroform, ketone, and isopropanol, and then subjected to ultraviolet ozone plasma treatment.

b. Film forming by thermal evaporation in high vacuum (1×10⁻⁶ mbar) in sequence according to an order of hole injection layer (40 nm), hole transport layer (100 nm), light-emitting layer (50 nm), and electron transport layer (25 nm).

c. Cathode: Liq/Al (1 nm/100 nm) may be formed by thermal evaporation in high vacuum (1×10⁻⁶ mbar).

d. Encapsulation: devices are encapsulated with UV-curable resins in the glove box under the nitrogen atmosphere.

In the embodiments, the guest material is the organic compounds M1 to M16, respectively, to form light-emitting components 1 to 16, and the guest material is Ref-1 to form a comparative component 1.

A structural formula of Ref-1 is

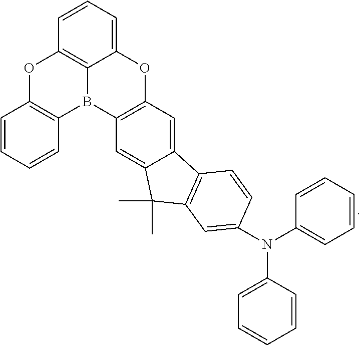 [SMILES: CC1(C)c2cc(N(c3ccccc3)c3ccccc3)ccc2-c2cc3c(cc21)B1c2ccccc2Oc2cccc(c21)O3]

In the light-emitting components 1 to 16 and the comparative component 1, the structural formula of the material of the hole injection layer is:

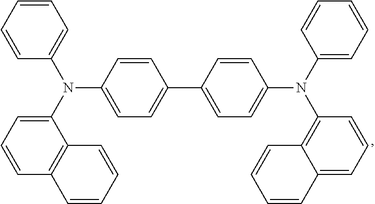 [SMILES: c1ccc(N(c2ccc(-c3ccc(N(c4ccccc4)c4cccc5ccccc45)cc3)cc2)c2cccc3ccccc23)cc1]

the structural formula of the material of the hole transport layer is:

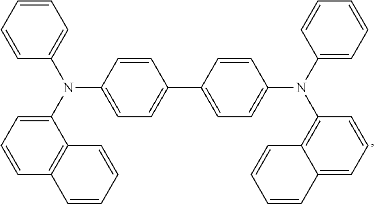 [SMILES: c1ccc(N(c2ccc(-c3ccc(N(c4ccccc4)c4cccc5ccccc45)cc3)cc2)c2cccc3ccccc23)cc1]

the structural formula of the host material in the light-emitting layer is:

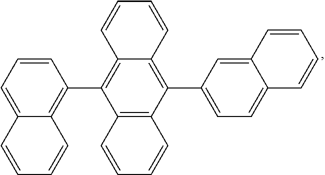 [SMILES: c1ccc2cc(-c3c4ccccc4c(-c4cccc5ccccc45)c4ccccc34)ccc2c1]

the structural formula of the material of the electron transport layer is:

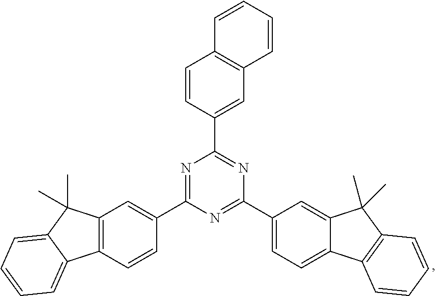 [SMILES: CC1(C)c2ccccc2-c2ccc(-c3nc(-c4ccc5c(c4)C(C)(C)c4ccccc4-5)nc(-c4ccc5ccccc5c4)n3)cc21]

and the structural formula of Liq is:

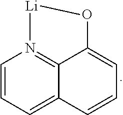

In the embodiments, an external quantum efficiency (EQE) test and a light-emitting service life test (T90©1000 nits, refers to the time for the device under test to decay from 1000 nits to 900 nits) were carried out on the light-emitting components 1 to 16 and the comparative component 1. The results obtained are shown in Table 1.

TABLE 1
performance data of the light-emitting components
1 to 16 and the comparative component 1.

| OLEDdevice | guest material | EQE | T90@1000 nits |
|---|---|---|---|
| light-emitting | M1 | 1.72 | 1.78 |
| component 1 | | | |
| light-emitting | M2 | 1.70 | 1.77 |
| component 2 | | | |
| light-emitting | M3 | 1.78 | 1.85 |
| component 3 | | | |
| light-emitting | M4 | 1.76 | 1.83 |
| component 4 | | | |
| light-emitting | M5 | 1.75 | 1.81 |
| component 5 | | | |
| light-emitting | M6 | 1.73 | 1.80 |
| component 6 | | | |
| light-emitting | M7 | 1.66 | 1.72 |
| component 7 | | | |
| light-emitting | M8 | 1.64 | 1.70 |
| component 8 | | | |
| light-emitting | M9 | 1.69 | 1.75 |
| component 9 | | | |
| light-emitting | M10 | 1.67 | 1.74 |
| component 10 | | | |
| light-emitting | M11 | 1.63 | 1.68 |
| component 11 | | | |
| light-emitting | M12 | 1.60 | 1.65 |
| component 12 | | | |
| light-emitting | M13 | 1.58 | 1.64 |
| component 13 | | | |
| light-emitting | M14 | 1.61 | 1.67 |
| component 14 | | | |
| light-emitting | M15 | 1.77 | 1.84 |
| component 15 | | | |
| light-emitting | M16 | 1.75 | 1.82 |
| component 16 | | | |
| comparative | Ref-1 | 1 | 1 |
| component 1 | | | |

From the data in Table 1, it can be known that when the external quantum efficiency and light-emitting service life of the comparative component 1 are used as a reference value 1, the external quantum efficiency of light-emitting components 1 to 16 is significantly improved, and the light-emitting service life thereof is also effectively prolonged. It indicates that the introduction of the amino group enhances the resonance and space effects of the organic compound and improves the performance of the guest material. Therefore, the luminous efficiency and the light-emitting service life of the light-emitting component are effectively improved.

The light-emitting component of the present disclosure can enhance conjugated effect and resonance effect of materials applied into the light-emitting component by using the organic compound having the heterocyclic group and the amino group at a same time. Therefore, material performances can be improved, the luminous efficiency of the light-emitting component can be improved, and the light-emitting service life of the light-emitting component can be extended.

The present disclosure further provides a display panel, which includes the light-emitting component mentioned above.

The display panel also includes an array substrate disposed on one side of the light-emitting component and an encapsulation layer disposed on one side of the light-emitting component away from the array substrate and covering the light-emitting component.

The display panel further includes a polarizer layer on one side of the encapsulation layer away from the light-emitting component and a cover layer on one side of the polarizer layer away from the light-emitting component. Wherein, the polarizer layer may be replaced by a color filter layer, and the color filter layer may include a plurality of color resists and a black matrix located on both sides of the color resists.

The display panel of the present disclosure uses the light-emitting component having the organic compound containing the amino group. By using the organic compound having the heterocyclic group and the amino group at a same time, the conjugated effect and resonance effect of materials applied into the light-emitting component can be enhanced. Therefore, material performances can be improved, the luminous efficiency of the light-emitting component can be improved, and the light-emitting service life of the light-emitting component can be extended. Therefore, the luminous efficiency of the display panel is improved, and the service life of the display panel is extended.

The organic compound, the light-emitting component, and the display panel are disclosed. The organic compound has the structure shown as general formula (1):

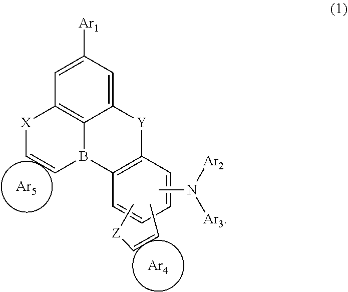

This organic compound can enhance conjugated effect and resonance effect of materials applied into the light-emitting component by having the heterocyclic group and the amino group at the same time. Therefore, material performances can be improved, the luminous efficiency of the light-emitting component can be improved, and the light-emitting service life of the light-emitting component can be extended.

The organic compound, the light-emitting component, and the display panel provided in the embodiments of the present disclosure are described in detail above. Specific examples are used herein to explain the principles and implementation of the present disclosure. The descriptions of the above embodiments are only used to help understand the method of the present disclosure and its core ideas; meanwhile, for those skilled in the art, the range of specific implementation and application may be changed according to the ideas of the present disclosure. In summary, the content of the specification should not be construed as causing limitations to the present disclosure.

What is claimed is:

1. An organic compound, comprising a structure shown as general formula 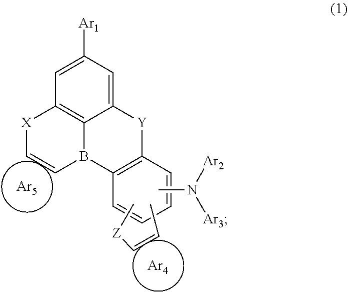
wherein Z is selected from CR₁R₂, NR₃, O, or S;
X and Y are each independently selected from O or NR₄,
R₁ to R₄ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms;
R₁ and R₂ are connected in a ring or independent of each other;
Ar₁ is selected from H, D, a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms;
Ar₂ and Ar₃ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms; and
Ar₄ and Ar₅ are each independently selected from a substituted or unsubstituted aromatic group with 6 to 30 carbon atoms or a substituted or unsubstituted heteroaromatic group with 5 to 30 carbon atoms.

2. The organic compound according to claim 1, comprising a structure shown as general formula (2), general formula (3), general formula (4), general formula (5), general formula (6), or general formula (7):

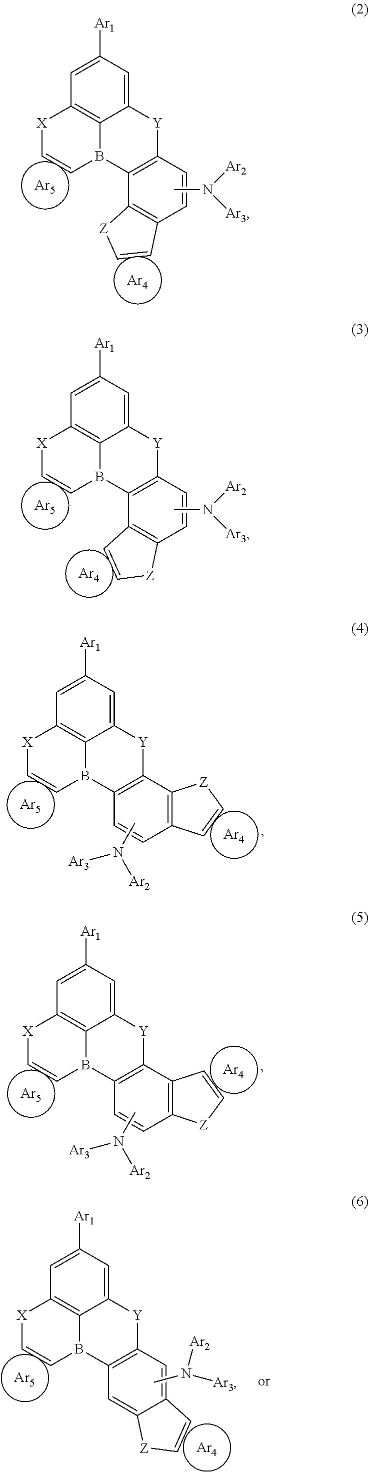

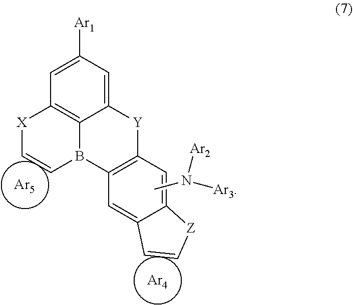

3. The organic compound according to claim 2, comprising a structure shown as general formula (8), general formula (9), general formula (10), general formula (11), general formula (12), or general formula (13):

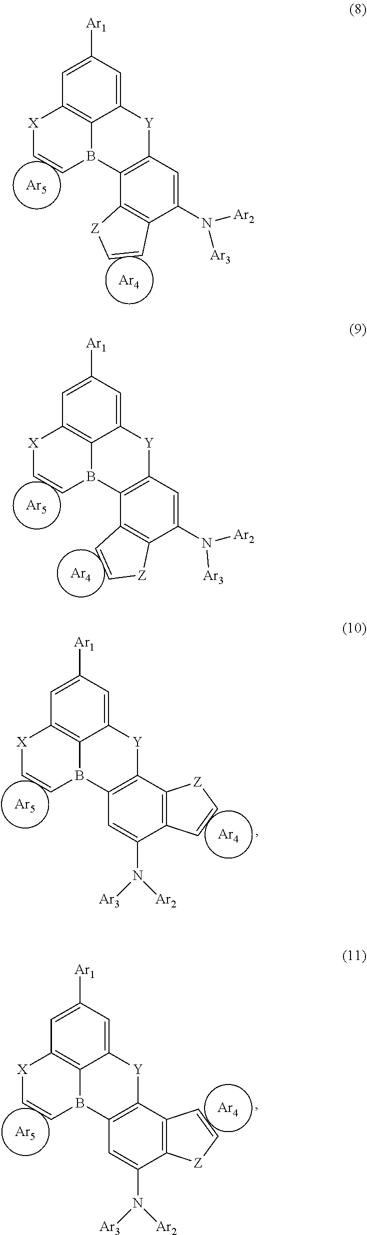

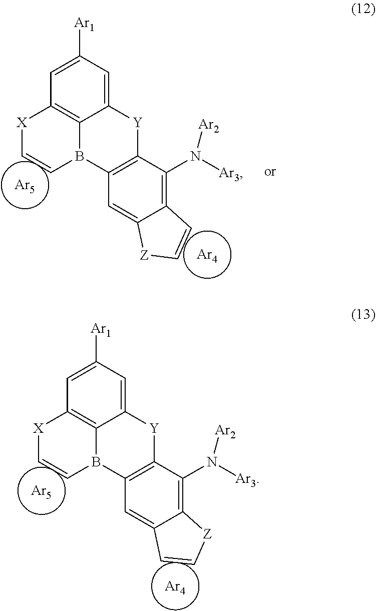

4. The organic compound according to claim 1, comprising a structure shown as general formula (14): 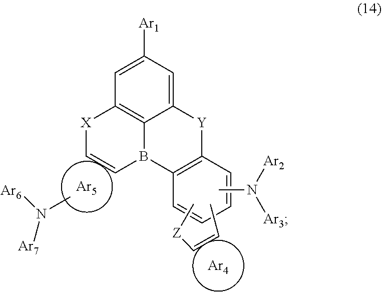
wherein Ar₆ and Ar₇ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms.

5. The organic compound according to claim 1, comprising a structure shown as general formula (15): 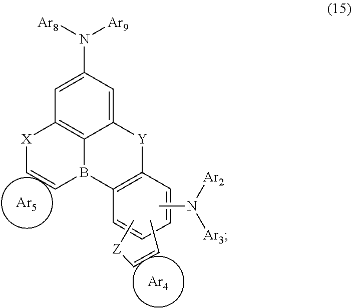
wherein Ar₈ and Ar₉ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms.

6. The organic compound according to claim 1, wherein Z is selected from CR₁ R₂, O, or S,
X and Y are each independently selected from O or NR₄, and X and Y are not O at a same time; and
R₁ to R₄ are each independently selected from a substituted or unsubstituted alkyl group with 1 to 12 carbon atoms, a substituted or unsubstituted aromatic group with 6 to 20 carbon atoms, or a substituted or unsubstituted heteroaromatic group with 5 to 20 carbon atoms.

7. The organic compound according to claim 6, wherein R₄ is selected from a methyl group, a substituted or unsubstituted phenyl group, a substituted or unsubstituted naphthyl group, a substituted or unsubstituted dibenzofuryl group, a substituted or unsubstituted dibenzothienyl group, a substituted or unsubstituted fluorenyl group, or a substituted or unsubstituted carbazolyl group.

8. The organic compound according to claim 1, wherein Ar₁ is selected from H, D, a methyl group, an isopropyl group, a tert-butyl group, a tert-amyl group, a substituted or unsubstituted phenyl group, a substituted or unsubstituted naphthyl group, a substituted or unsubstituted dibenzofuryl group, a substituted or unsubstituted dibenzothienyl group, a substituted or unsubstituted fluorenyl group, a substituted or unsubstituted carbazolyl group, or an amino group.

9. The organic compound according to claim 1, wherein Ar₂ and Ar₃ are independently selected from a substituted or unsubstituted phenyl group, a substituted or unsubstituted naphthyl group, a substituted or unsubstituted triphenyl group, a substituted or unsubstituted dibenzofuryl group, a substituted or unsubstituted dibenzothienyl group, a substituted or unsubstituted fluorenyl group, a substituted or unsubstituted carbazolyl group, or a methyl group; and
Ar₄ and Ar₅ are independently selected from a substituted or unsubstituted phenyl group, a substituted or unsubstituted naphthyl group, a substituted or unsubstituted triphenyl group, a substituted or unsubstituted dibenzofuryl group, a substituted or unsubstituted dibenzothienyl group, a substituted or unsubstituted fluorenyl group, or a substituted or unsubstituted carbazolyl group.

10. The organic compound according to claim 1, being one selected from following compounds:

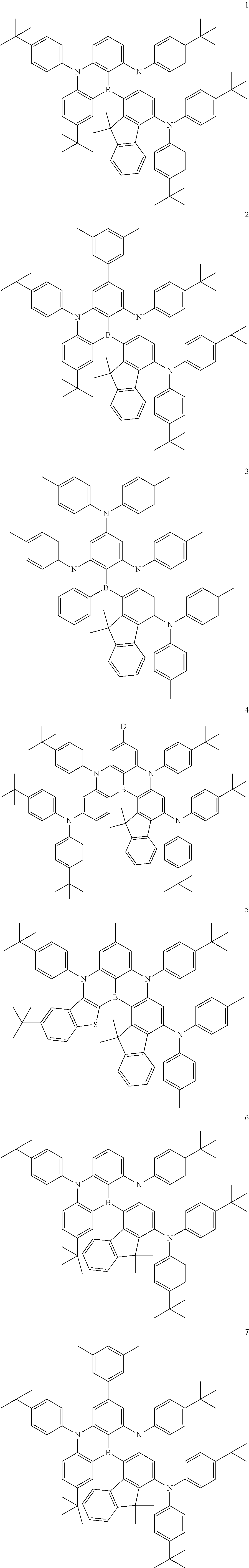

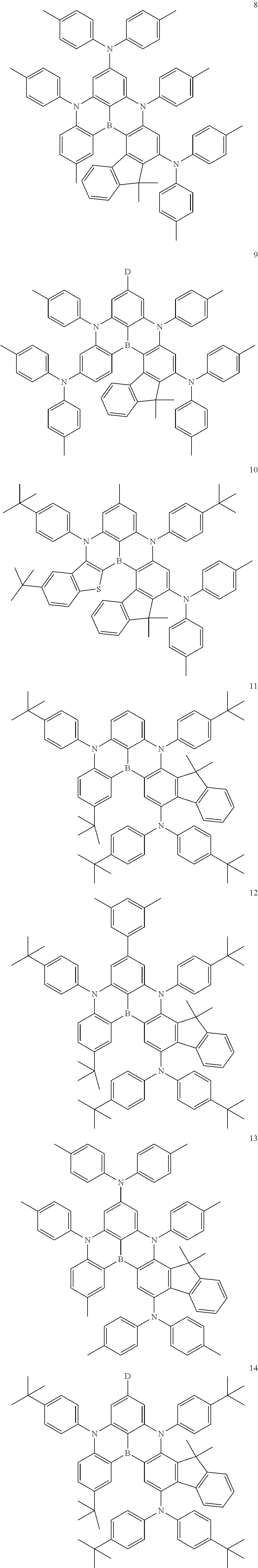

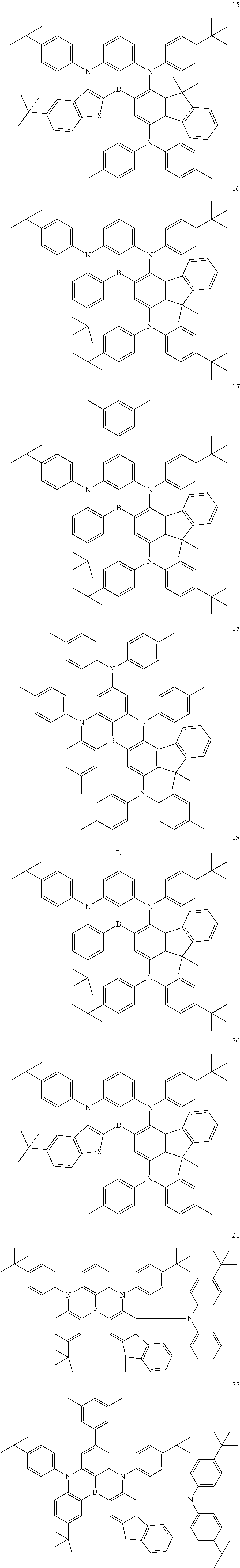

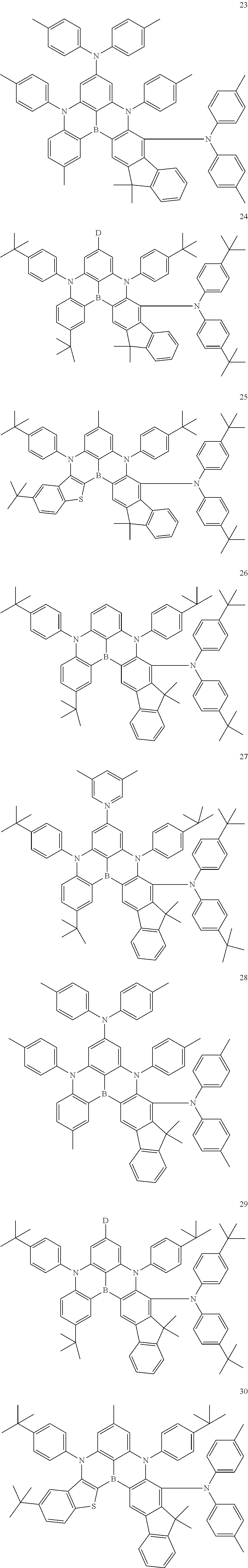

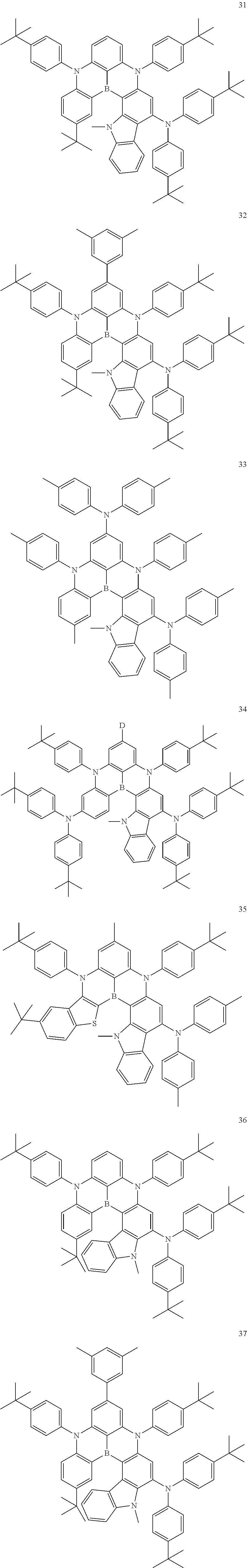

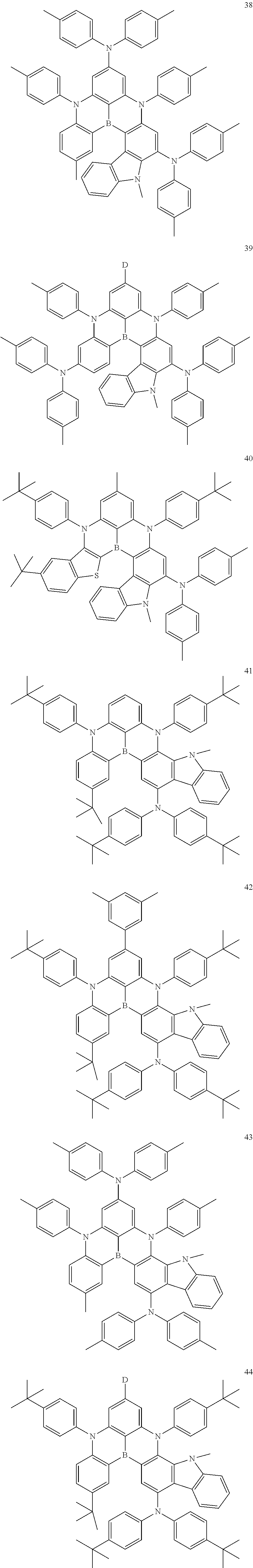

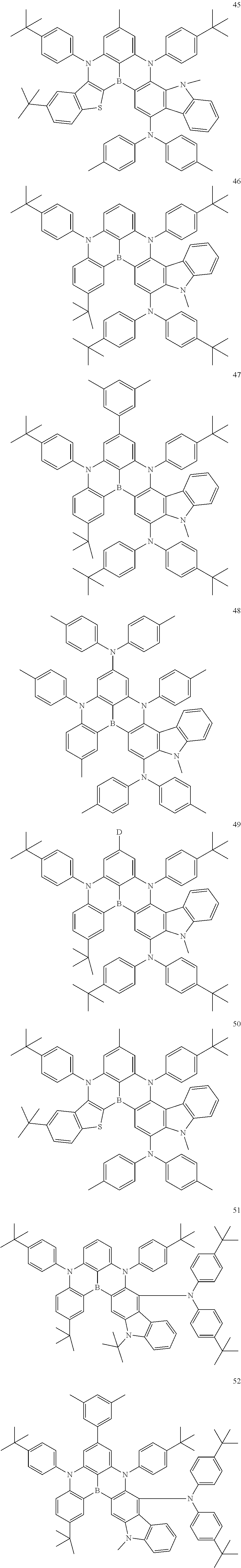

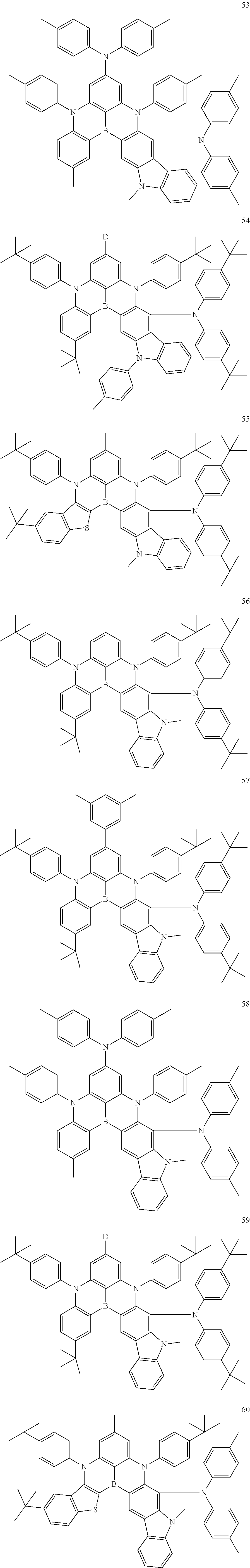

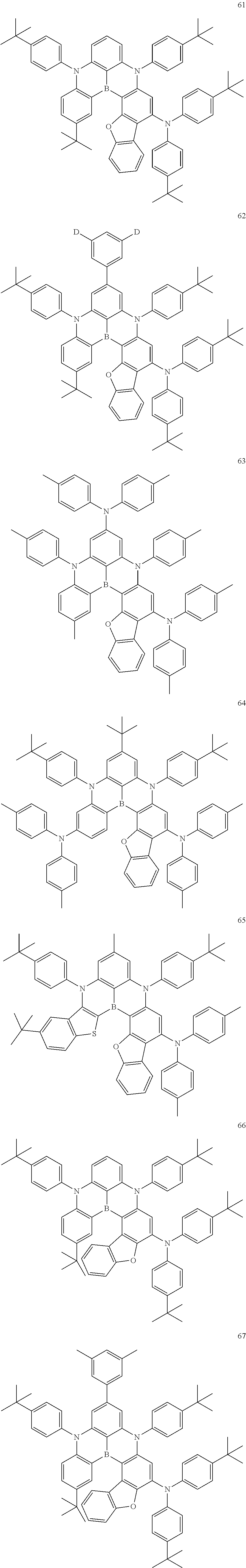

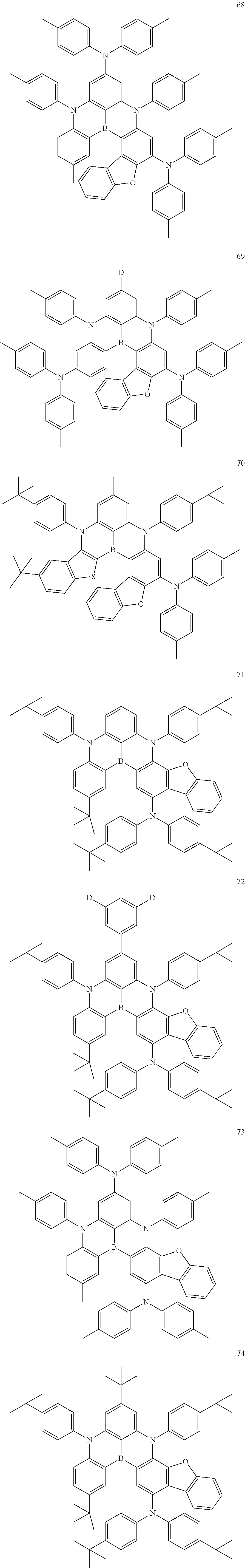

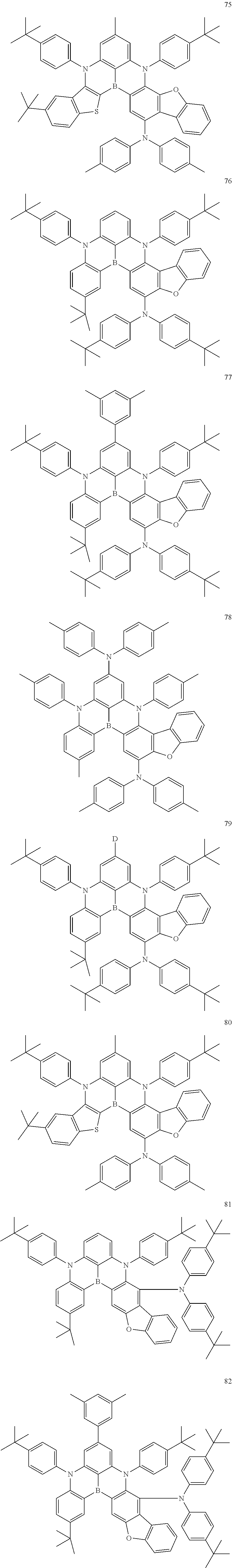

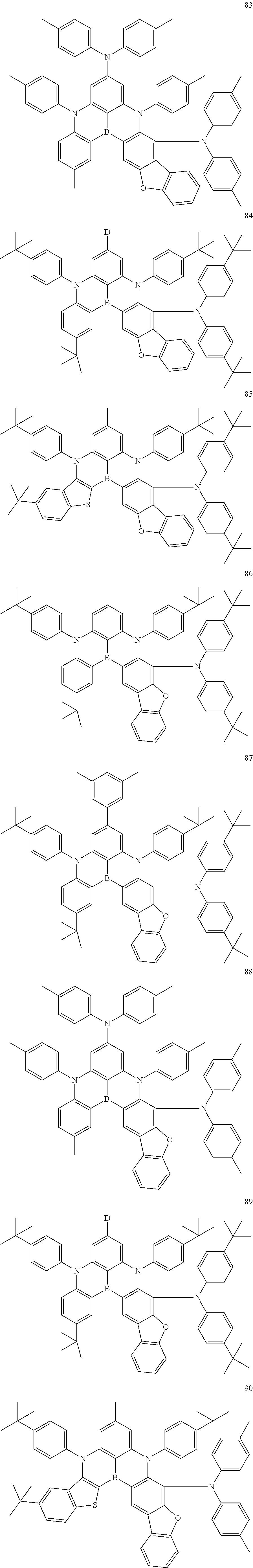

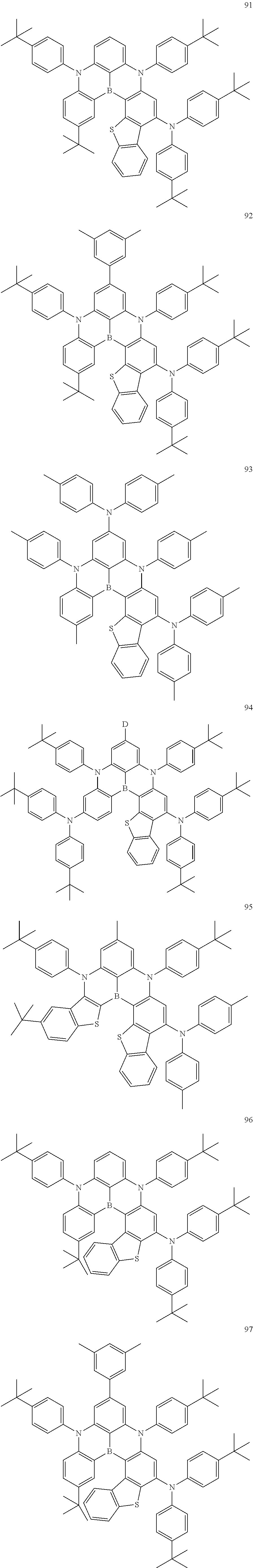

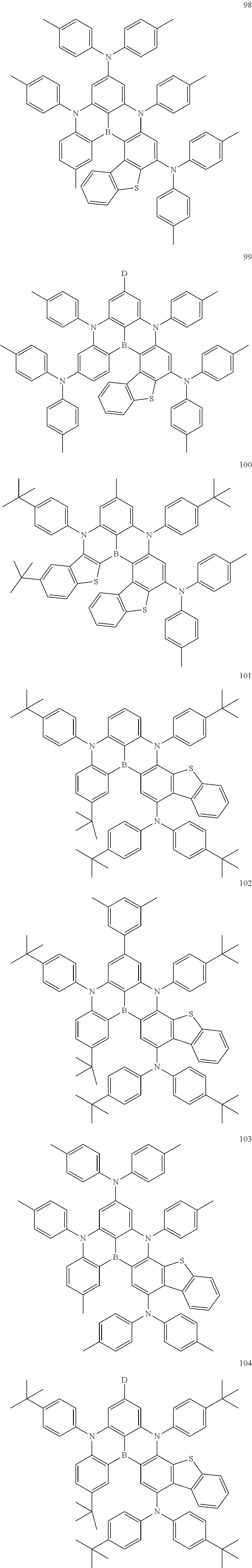

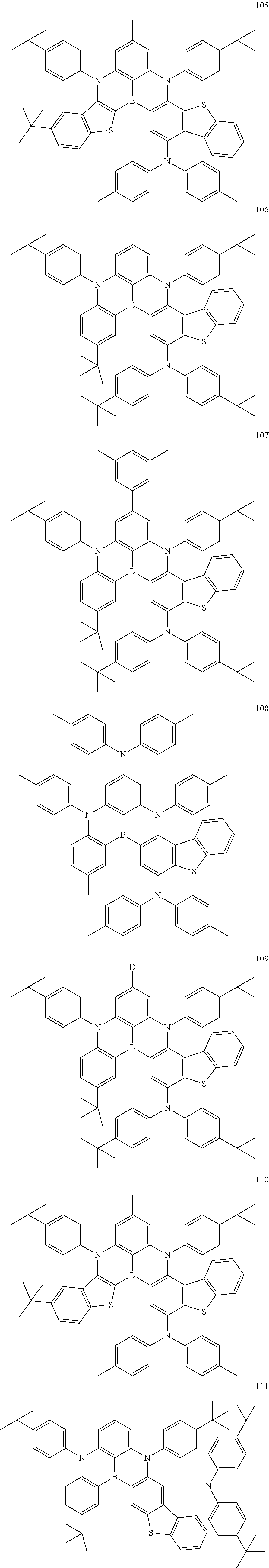

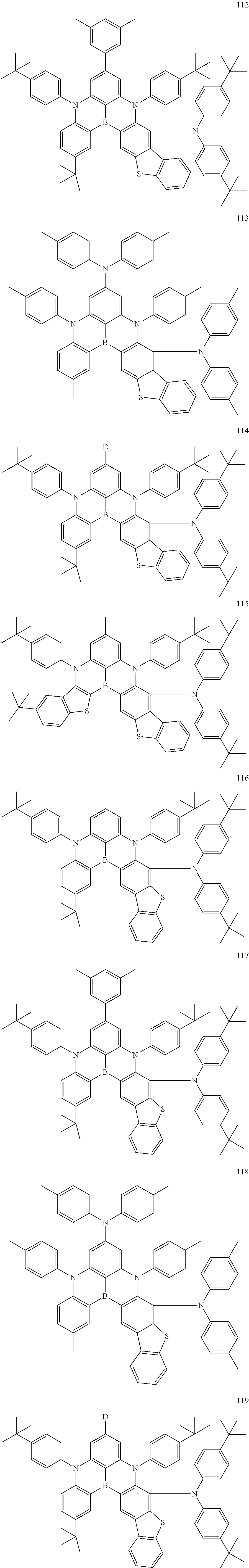

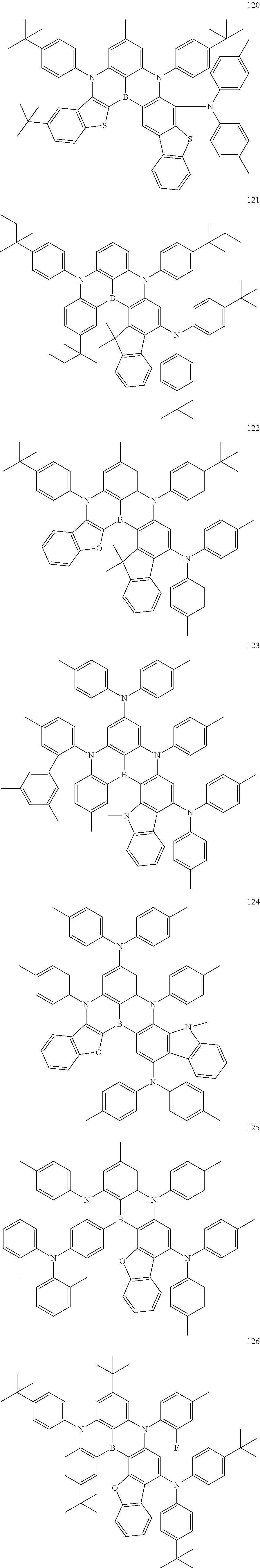

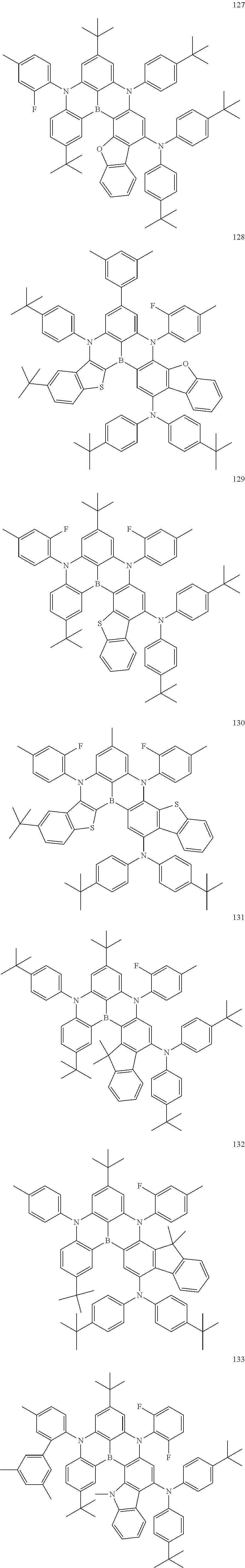

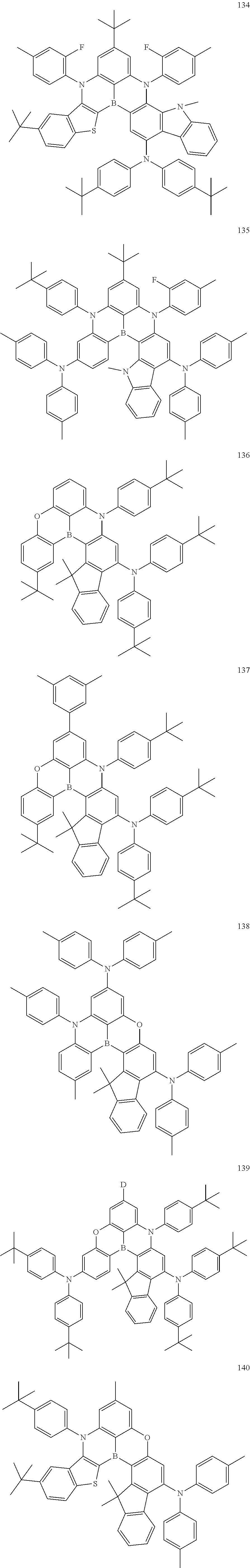

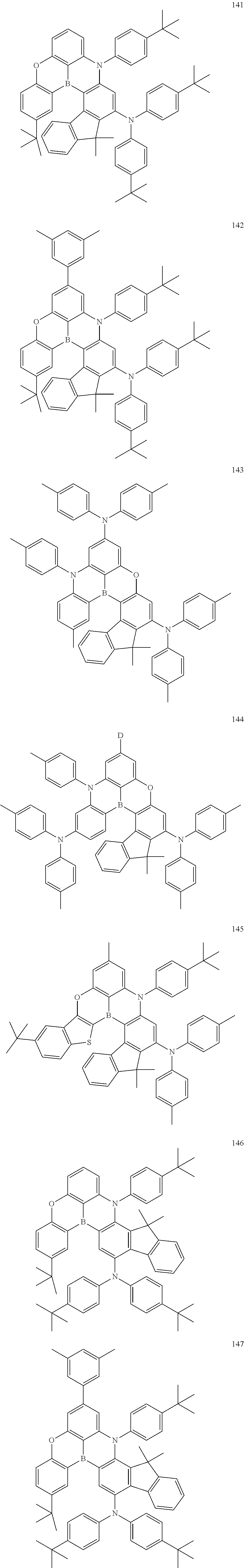

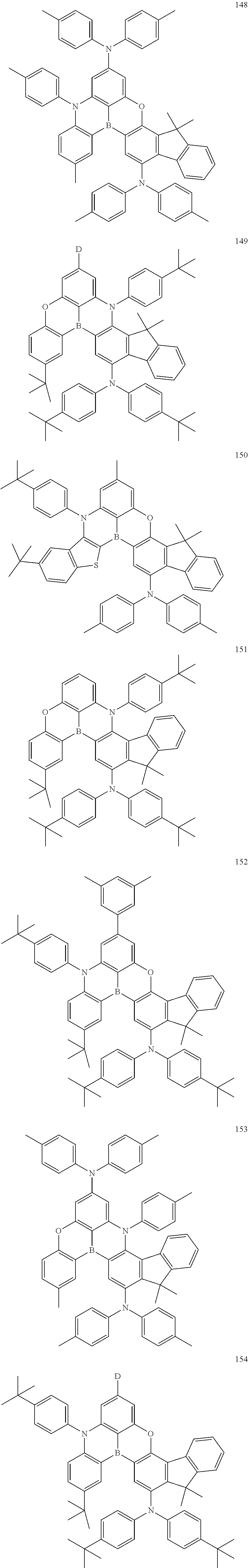

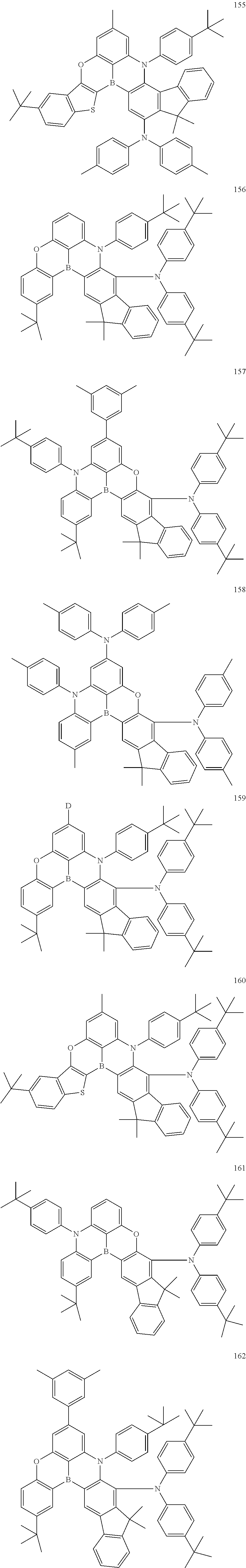

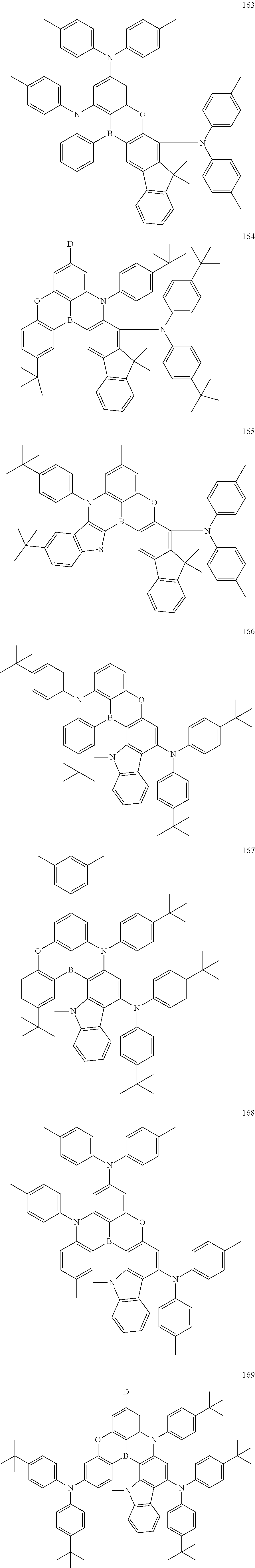

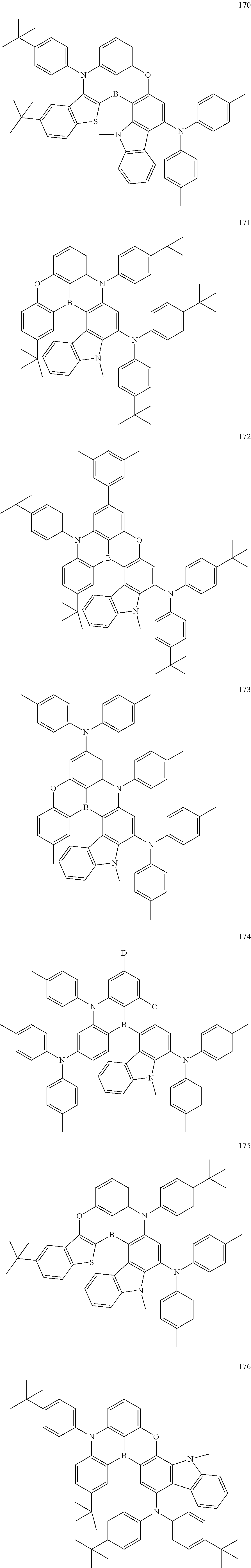

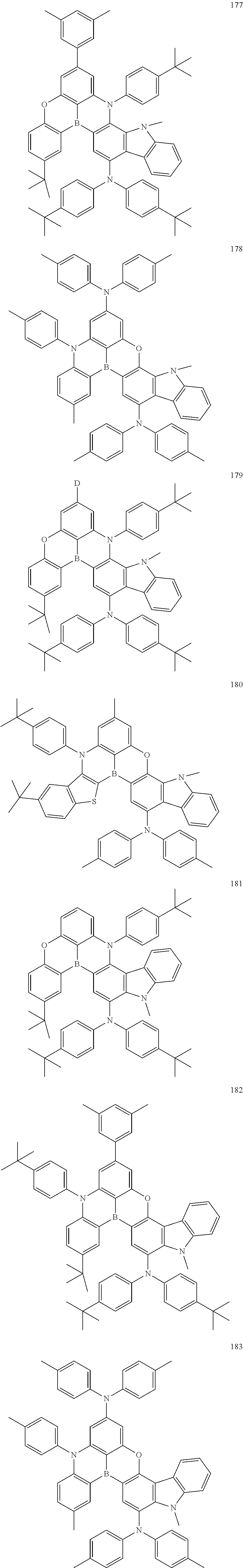

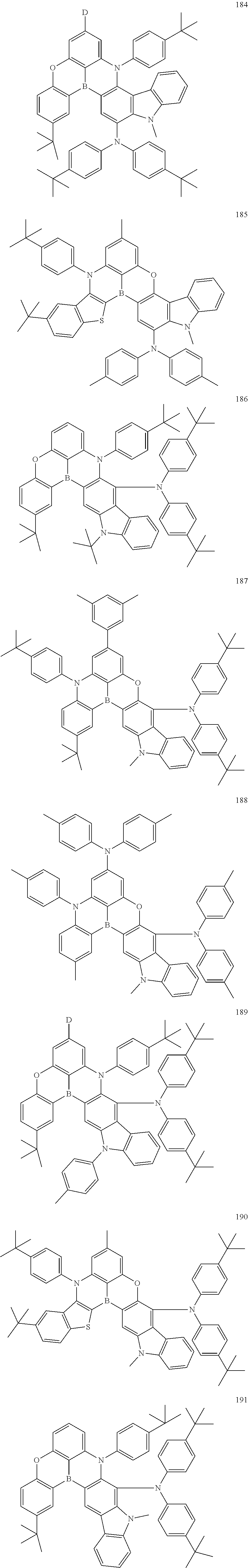

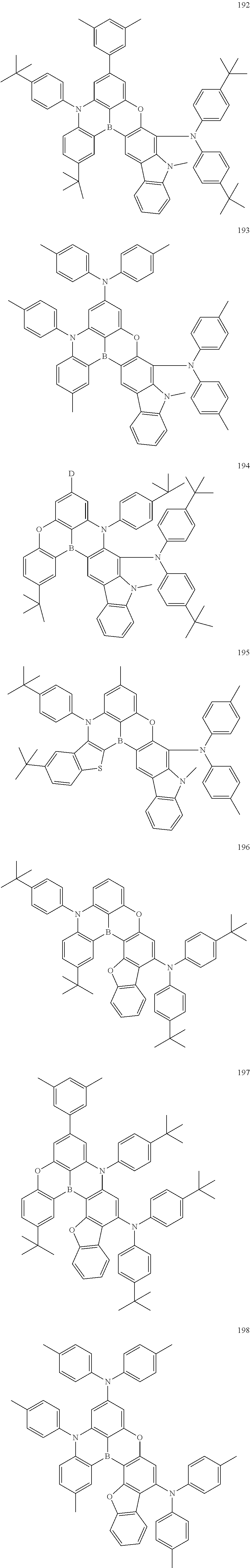

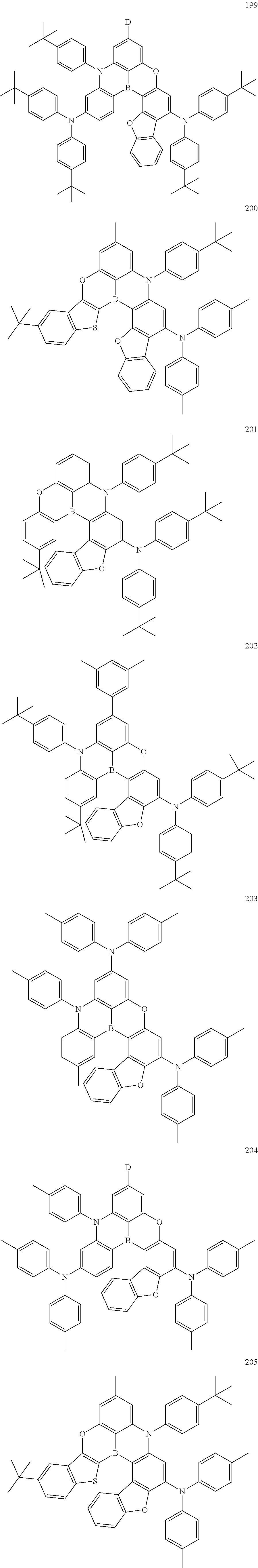

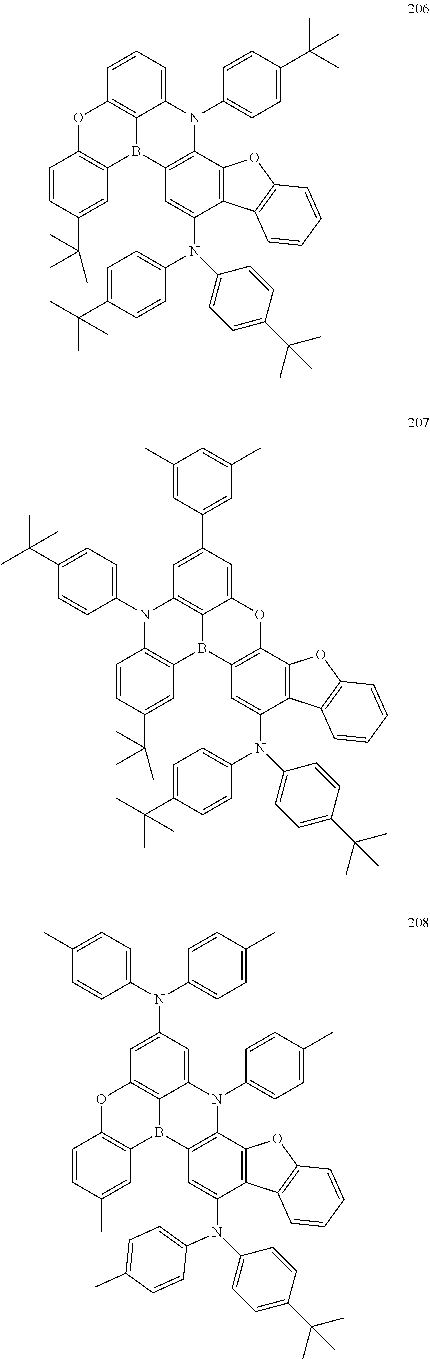

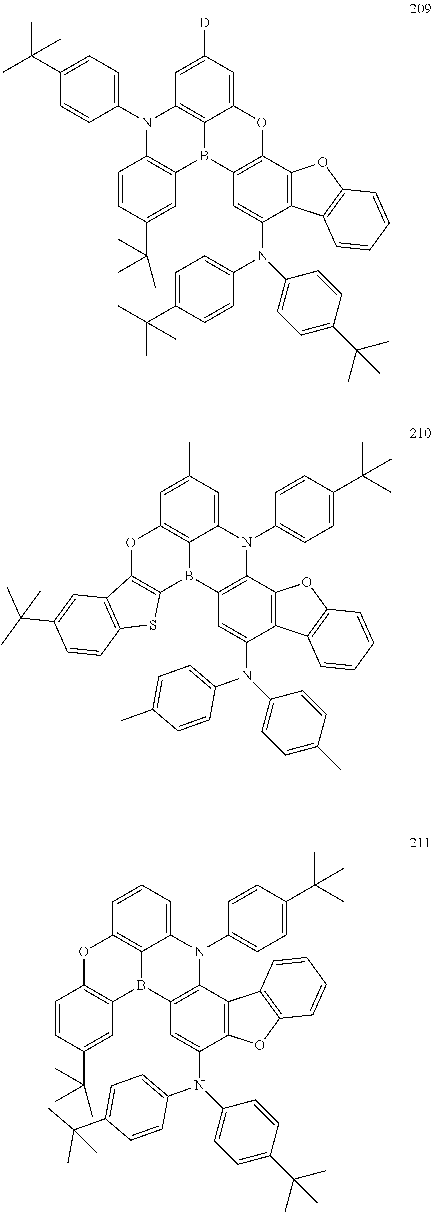

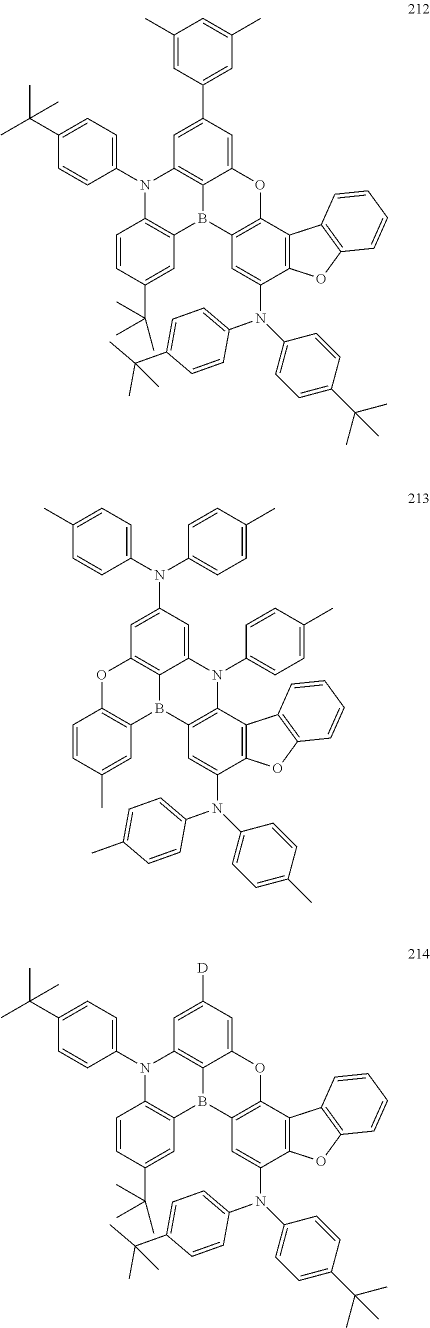 [SMILES: Cc1cc(C)cc(-c2cc3c4c(c2)N(c2ccc(C(C)(C)C)cc2)c2ccc(C(C)(C)C)cc2B4c2cc(N(c4ccc(C(C)(C)C)cc4)c4ccc(C(C)(C)C)cc4)c4oc5ccccc5c4c2O3)c1 ; Cc1ccc(N(c2ccc(C)cc2)c2cc3c4c(c2)N(c2ccc(C)cc2)c2c(cc(N(c5ccc(C)cc5)c5ccc(C)cc5)c5oc6ccccc6c25)B4c2cc(C)ccc2O3)cc1 ; [2H]c1cc2c3c(c1)N(c1ccc(C(C)(C)C)cc1)c1ccc(C(C)(C)C)cc1B3c1cc(N(c3ccc(C(C)(C)C)cc3)c3ccc(C(C)(C)C)cc3)c3oc4ccccc4c3c1O2]

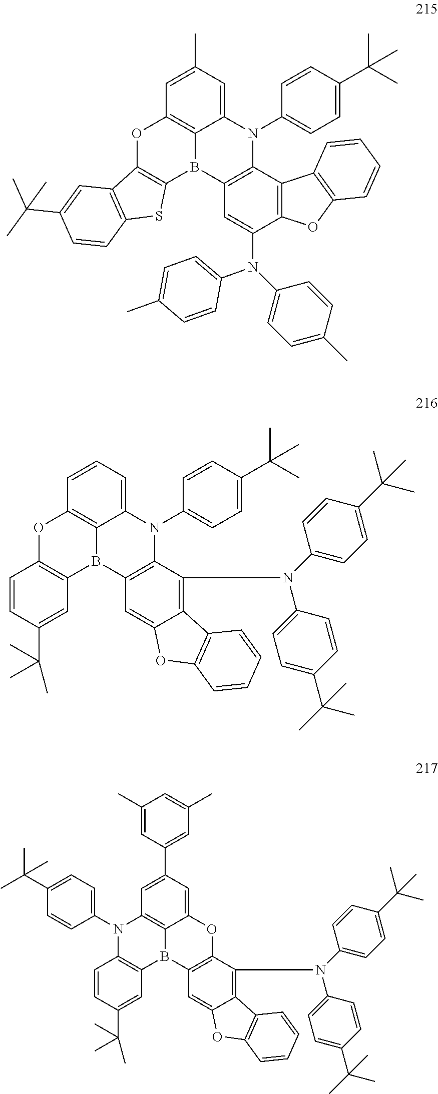

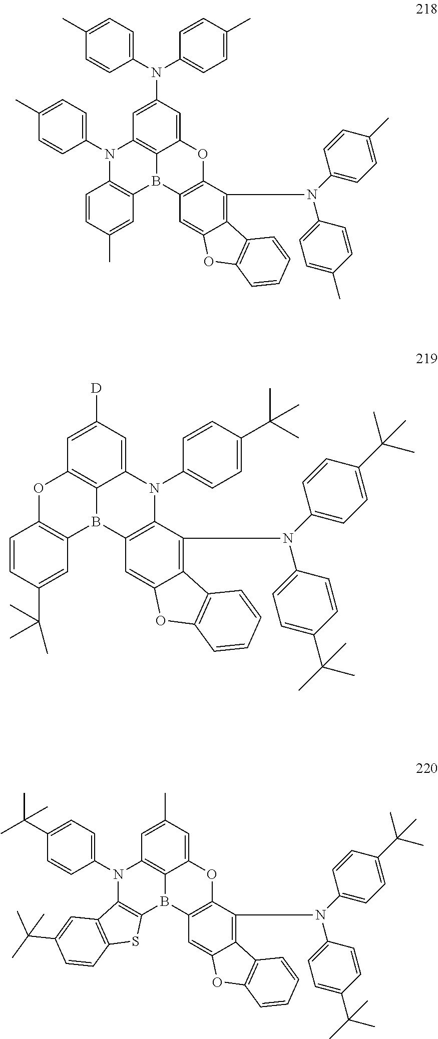

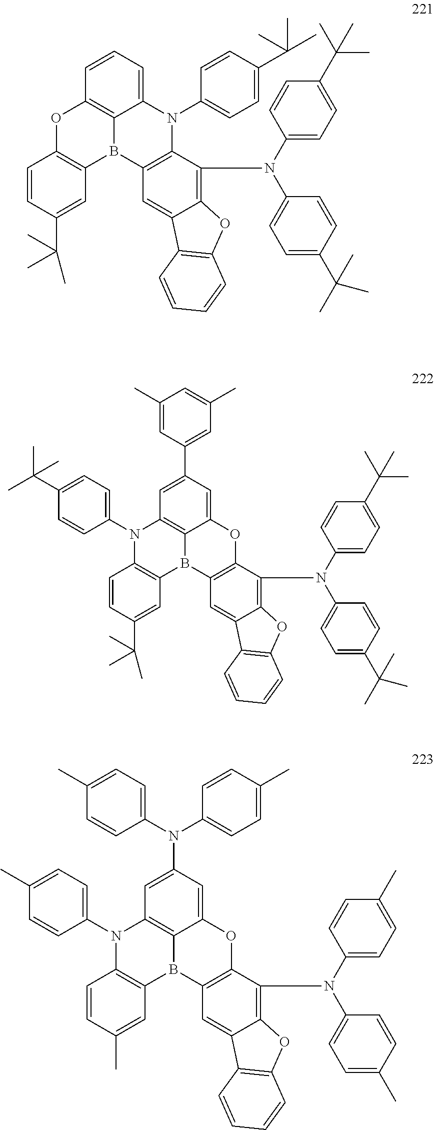

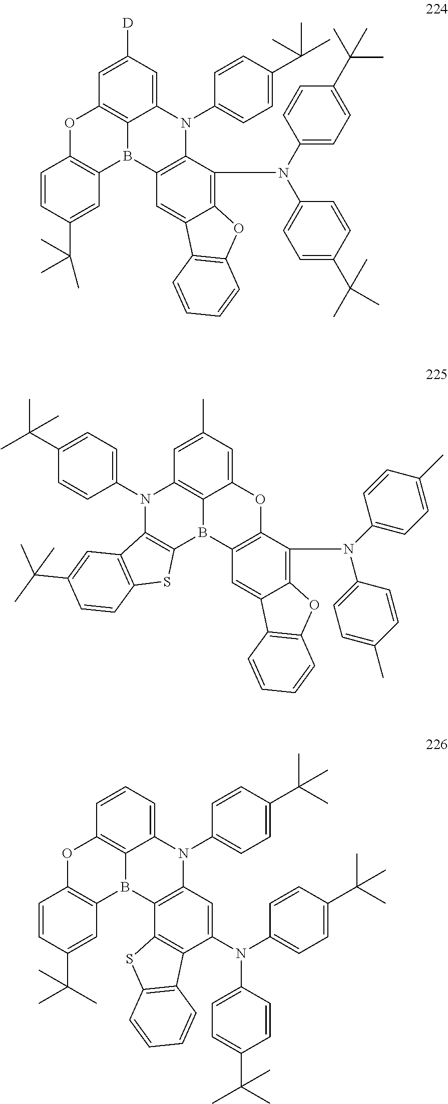

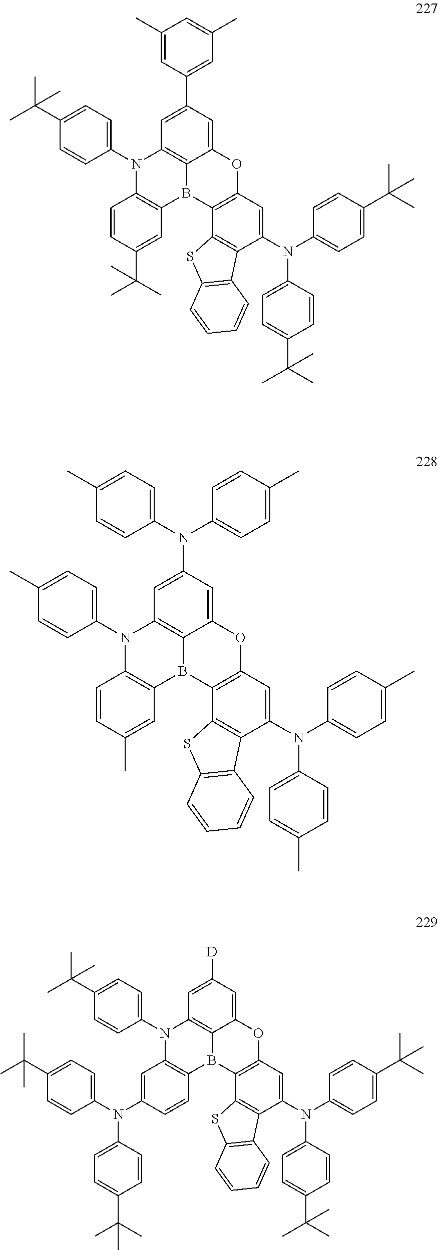

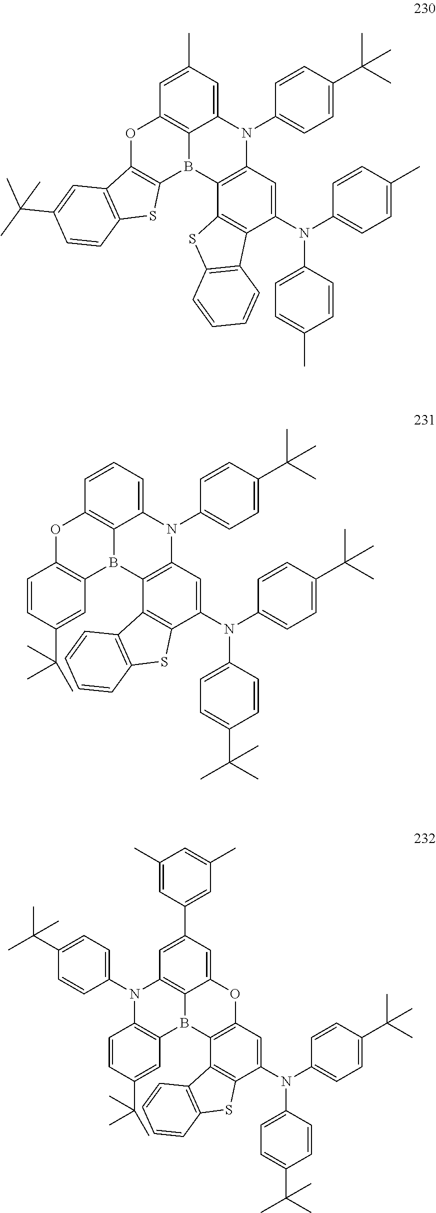

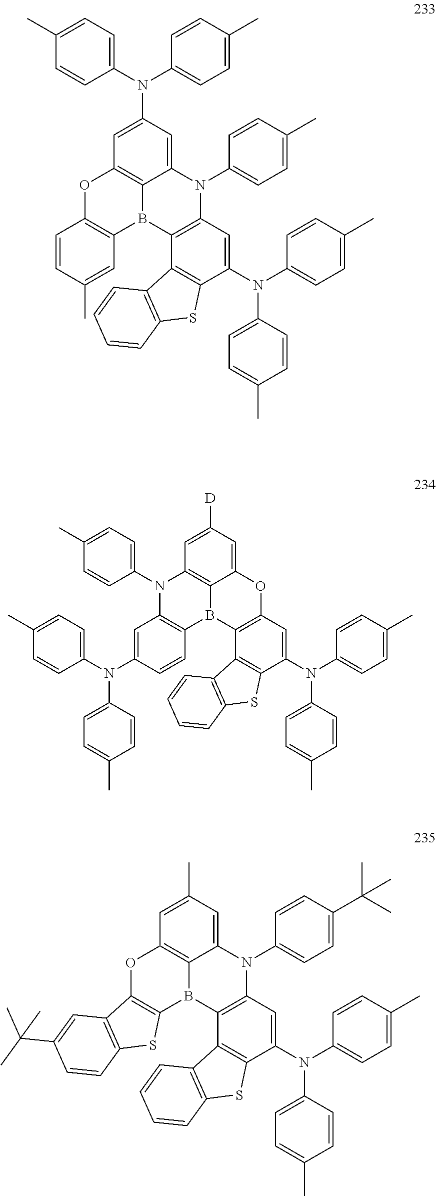

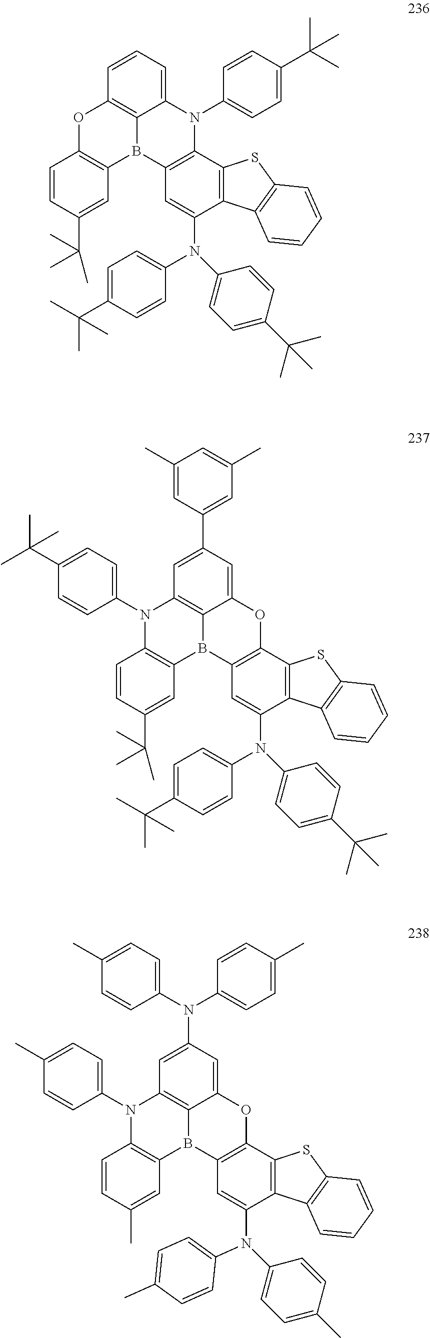

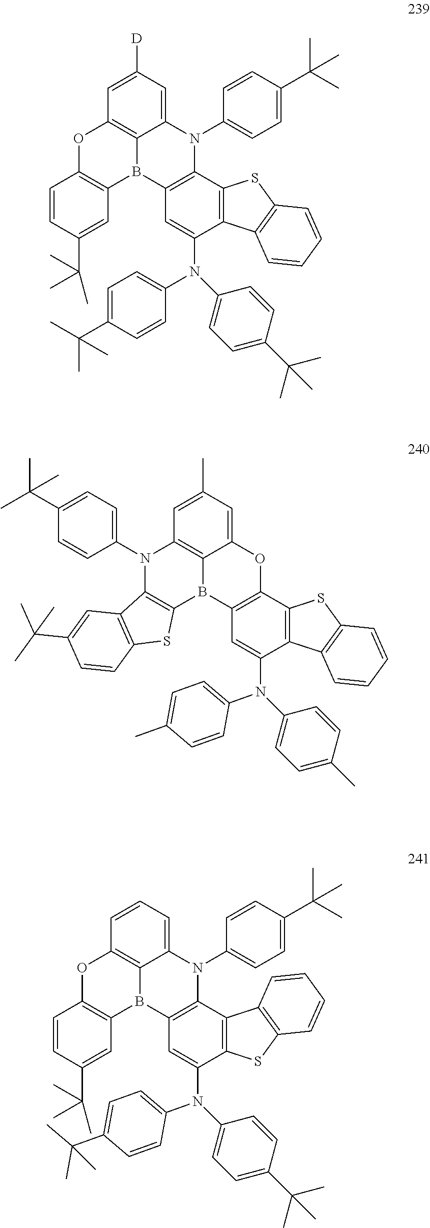

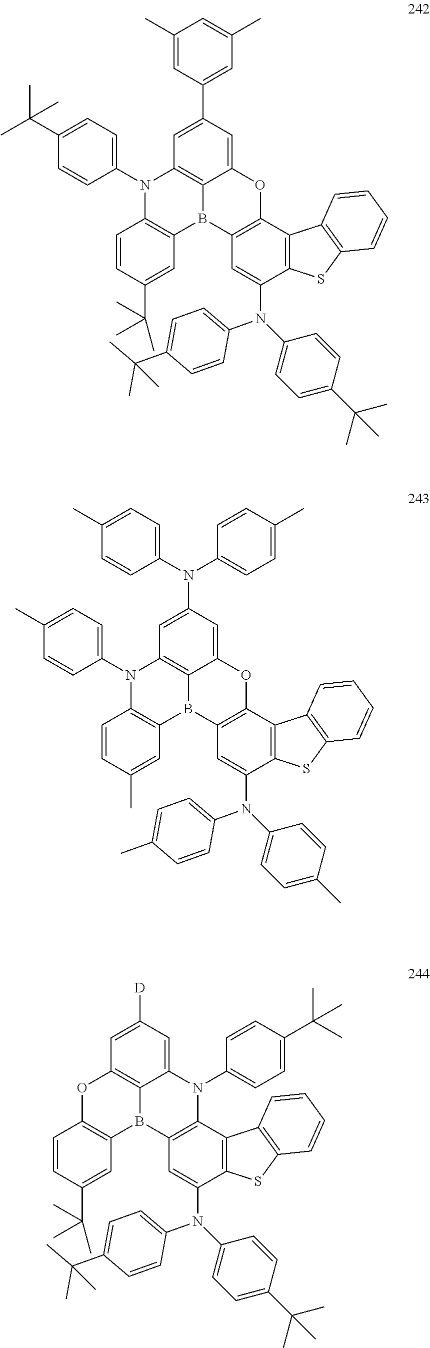 [SMILES: Cc1cc(C)cc(-c2cc3c4c(c2)N(c2ccc(C(C)(C)C)cc2)c2ccc(C(C)(C)C)cc2B4c2cc(N(c4ccc(C(C)(C)C)cc4)c4ccc(C(C)(C)C)cc4)c4sc5ccccc5c4c2O3)c1 ; Cc1ccc(N(c2ccc(C)cc2)c2cc3c4c(c2)N(c2ccc(C)cc2)c2ccc(C)cc2B4c2cc(N(c4ccc(C)cc4)c4ccc(C)cc4)c4sc5ccccc5c4c2O3)cc1 ; [2H]c1cc2c3c(c1)N(c1ccc(C(C)(C)C)cc1)c1c(cc(N(c4ccc(C(C)(C)C)cc4)c4ccc(C(C)(C)C)cc4)c4sc5ccccc5c14)B3c1cc(C(C)(C)C)ccc1O2]

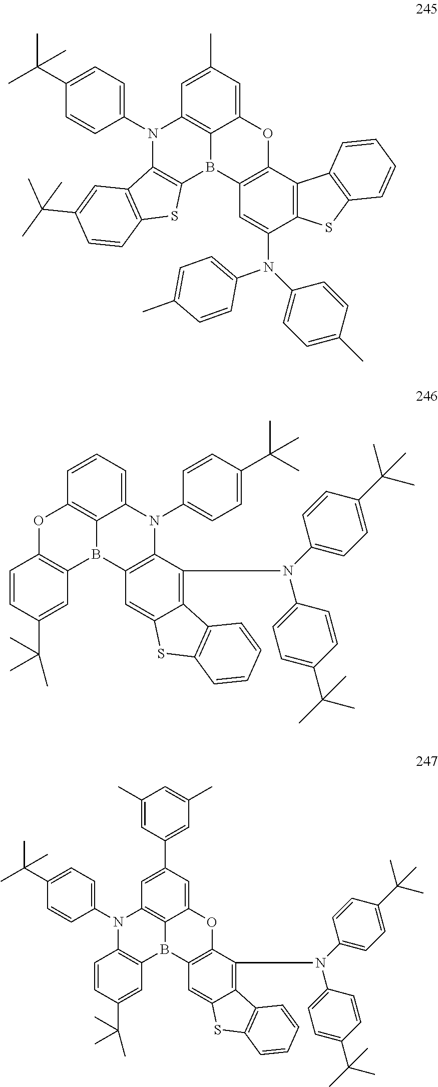

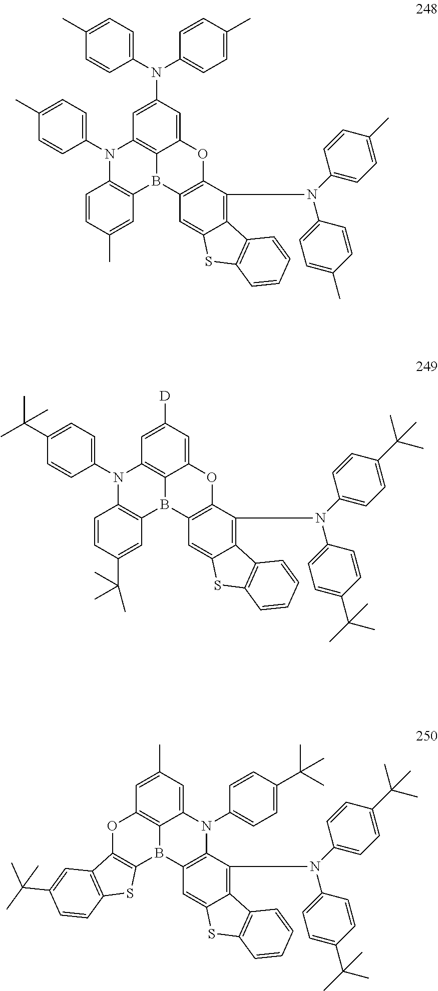

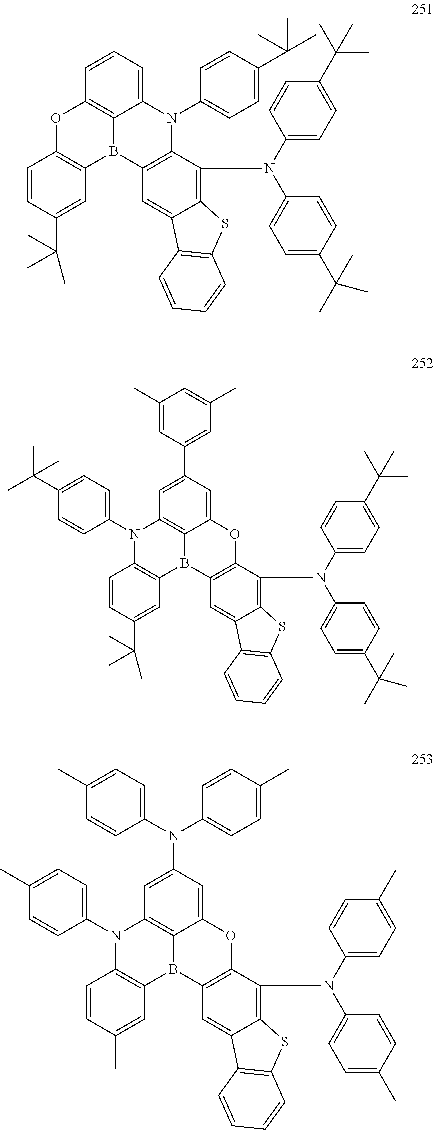

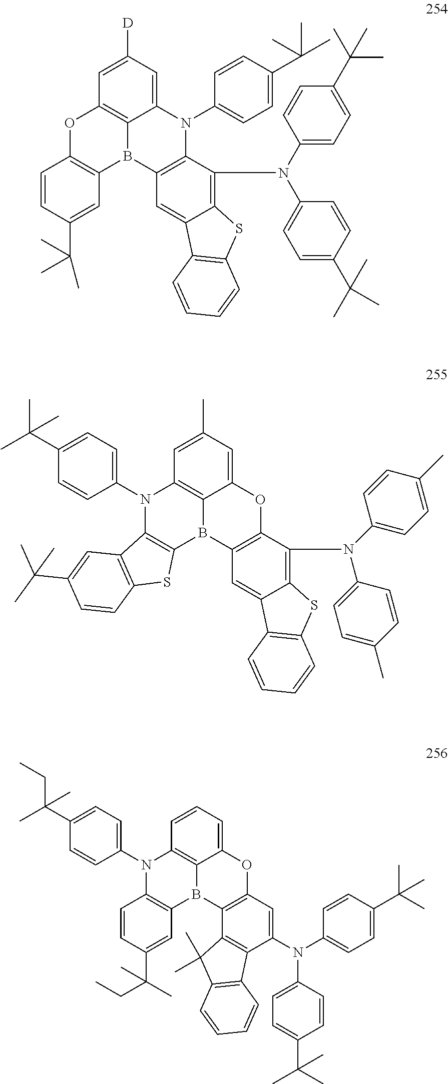

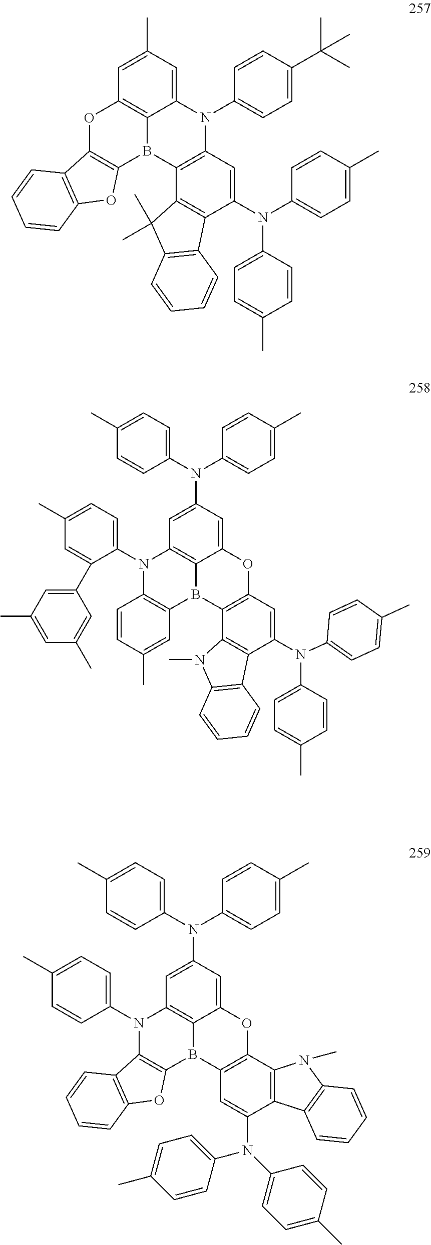

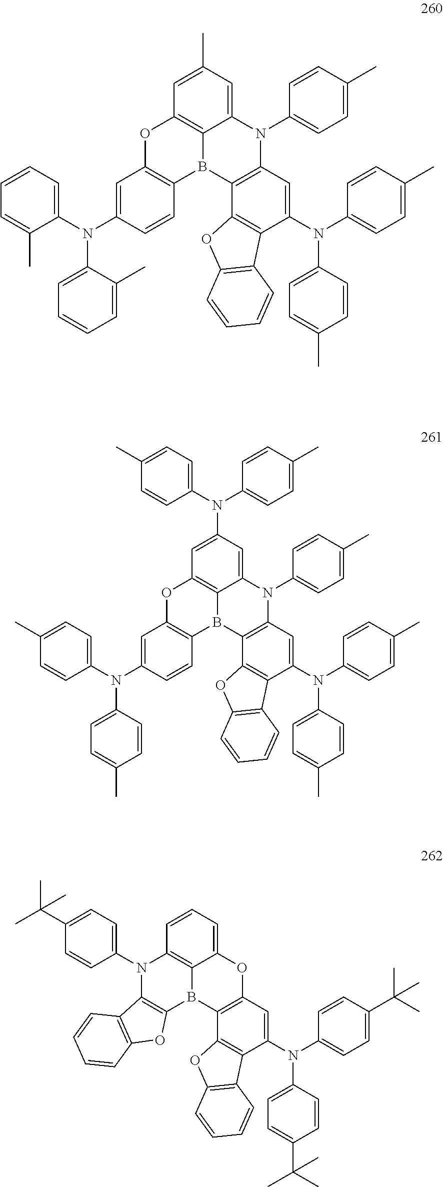

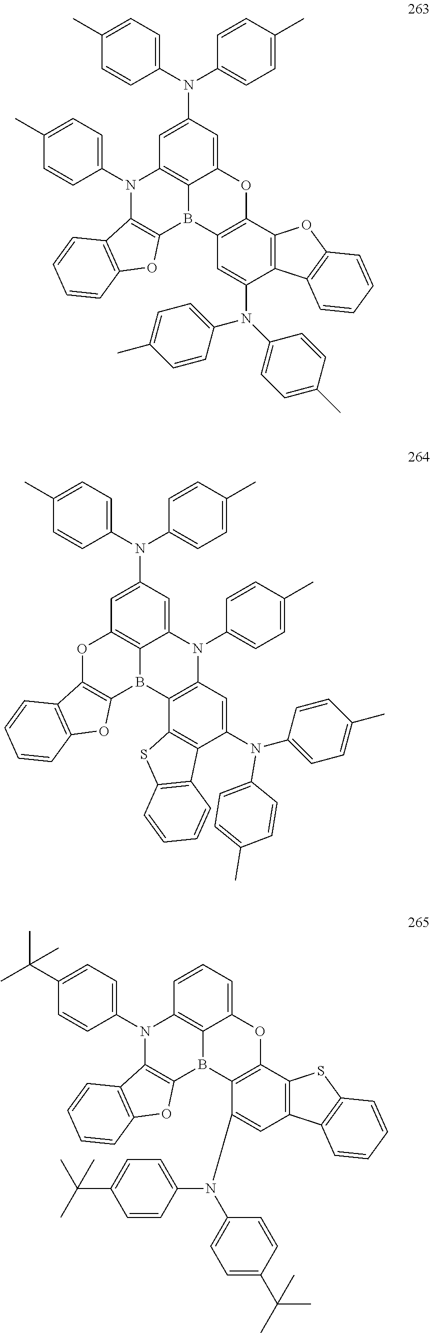

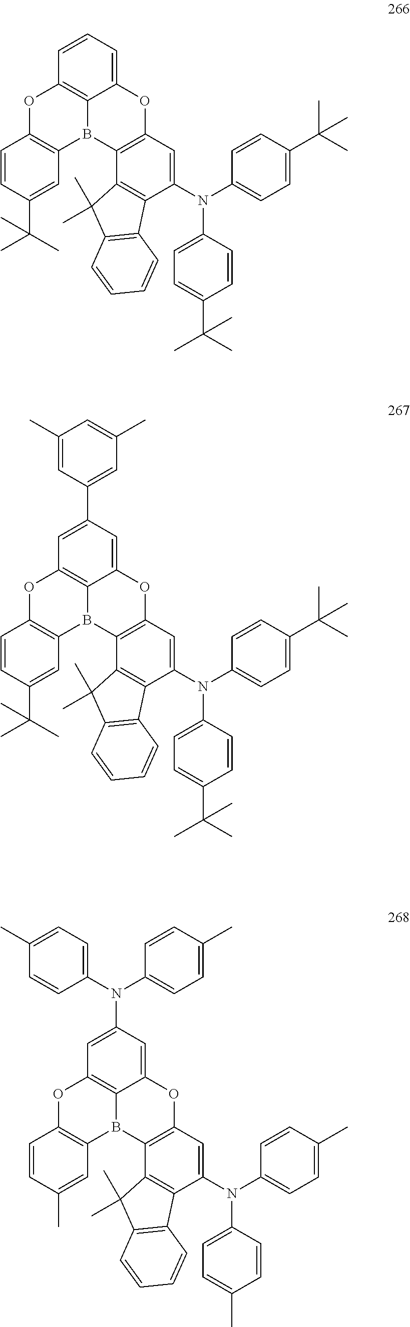

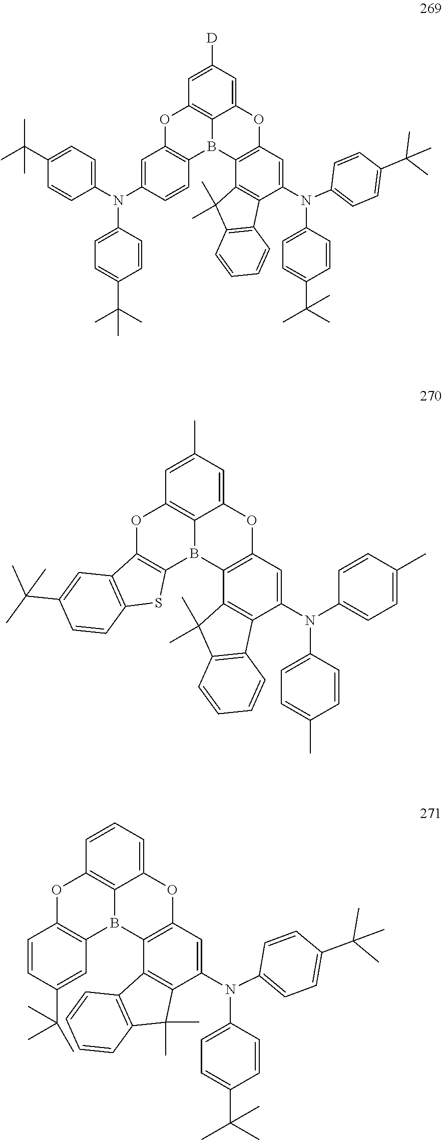

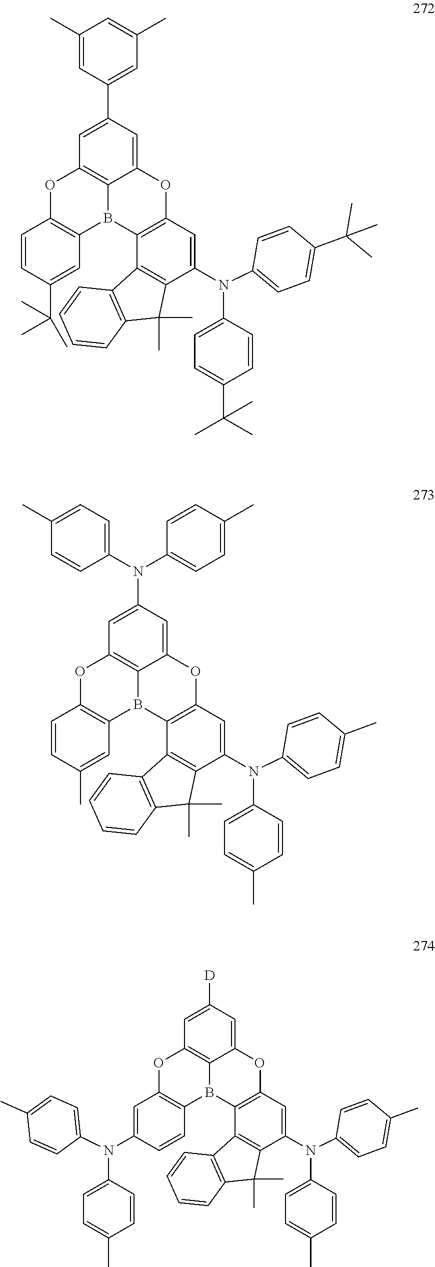

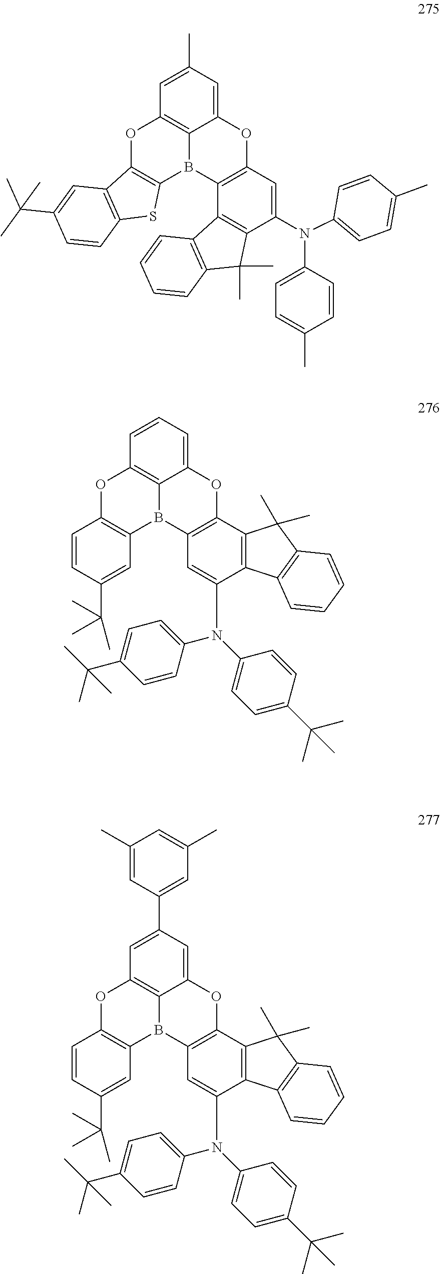

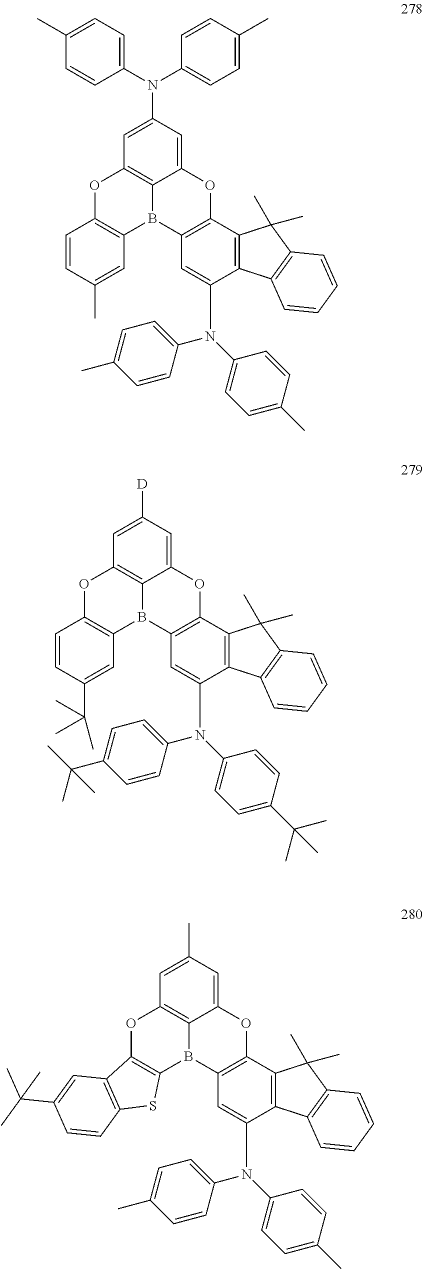 [SMILES: Cc1ccc(N(c2ccc(C)cc2)c2cc3c4c(c2)Oc2c(cc(N(c5ccc(C)cc5)c5ccc(C)cc5)c5c2C(C)(C)c2ccccc2-5)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4c1C(C)(C)c1ccccc1-4)B3c1cc(C(C)(C)C)ccc1O2 ; Cc1ccc(N(c2ccc(C)cc2)c2cc3c(c4c2-c2ccccc2C4(C)C)Oc2cc(C)cc4c2B3c2sc3ccc(C(C)(C)C)cc3c2O4)cc1]

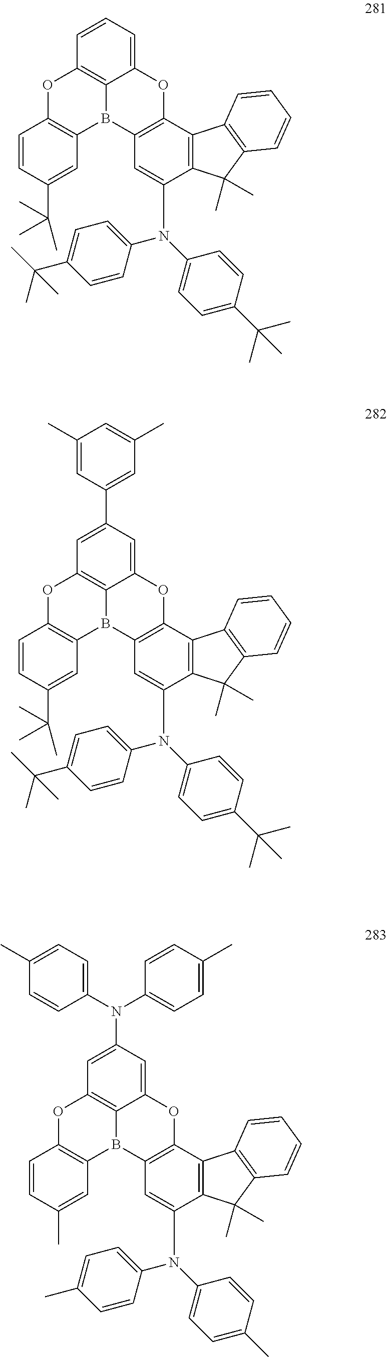 [SMILES: CC(C)(C)c1ccc(N(c2ccc(C(C)(C)C)cc2)c2cc3c(c4c2C(C)(C)c2ccccc2-4)Oc2cccc4c2B3c2cc(C(C)(C)C)ccc2O4)cc1 ; Cc1cc(C)cc(-c2cc3c4c(c2)Oc2c(cc(N(c5ccc(C(C)(C)C)cc5)c5ccc(C(C)(C)C)cc5)c5c2-c2ccccc2C5(C)C)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5c2-c2ccccc2C5(C)C)B4c2cc(C)ccc2O3)cc1]

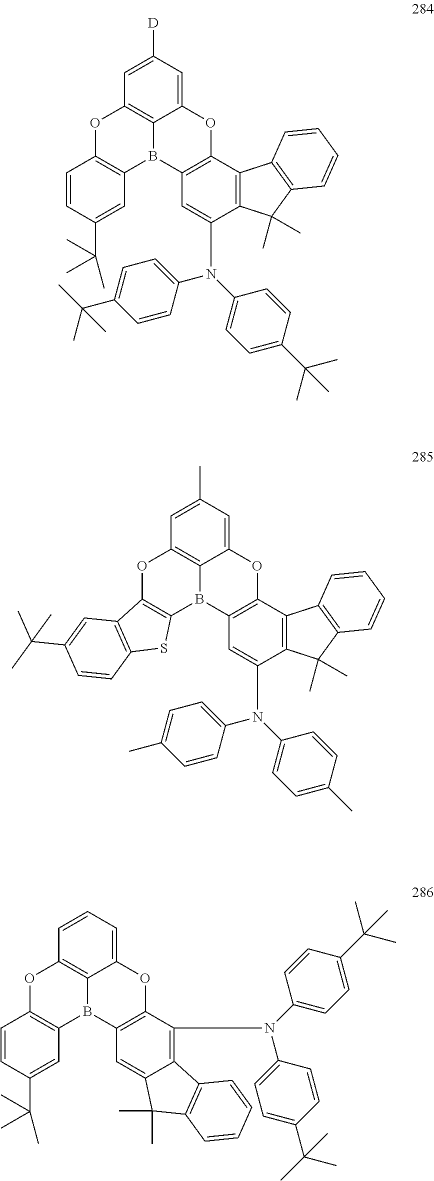 [SMILES: [2H]c1cc2c3c(c1)Oc1c(cc(N(c4ccc(C(C)(C)C)cc4)c4ccc(C(C)(C)C)cc4)c4c1-c1ccccc1C4(C)C)B3c1cc(C(C)(C)C)ccc1O2 ; Cc1ccc(N(c2ccc(C)cc2)c2cc3c(c4c2C(C)(C)c2ccccc2-4)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4c2-c2ccccc2C4(C)C)B2c4cc(C(C)(C)C)ccc4Oc4cccc(c42)O3)cc1]

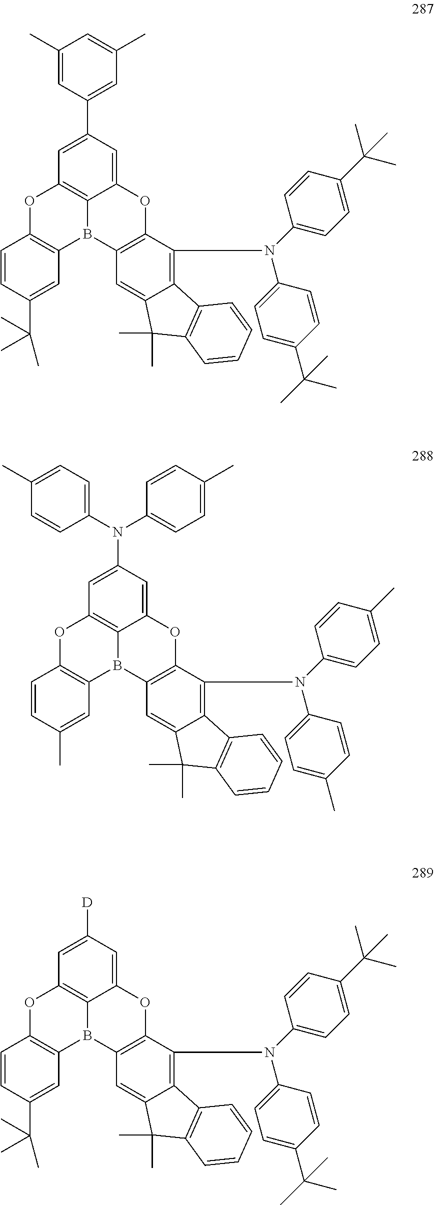

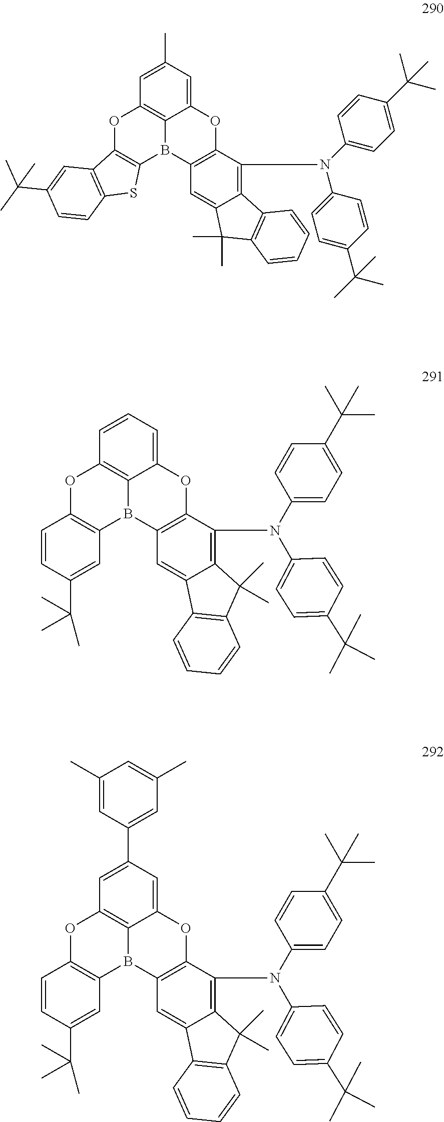 [SMILES: Cc1cc2c3c(c1)Oc1c(sc4ccc(C(C)(C)C)cc14)B3c1cc3c(c(N(c4ccc(C(C)(C)C)cc4)c4ccc(C(C)(C)C)cc4)c1O2)-c1ccccc1C3(C)C ; CC(C)(C)c1ccc(N(c2ccc(C(C)(C)C)cc2)c2c3c(cc4c2C(C)(C)c2ccccc2-4)B2c4cc(C(C)(C)C)ccc4Oc4cccc(c42)O3)cc1 ; Cc1cc(C)cc(-c2cc3c4c(c2)Oc2c(cc5c(c2N(c2ccc(C(C)(C)C)cc2)c2ccc(C(C)(C)C)cc2)C(C)(C)c2ccccc2-5)B4c2cc(C(C)(C)C)ccc2O3)c1]

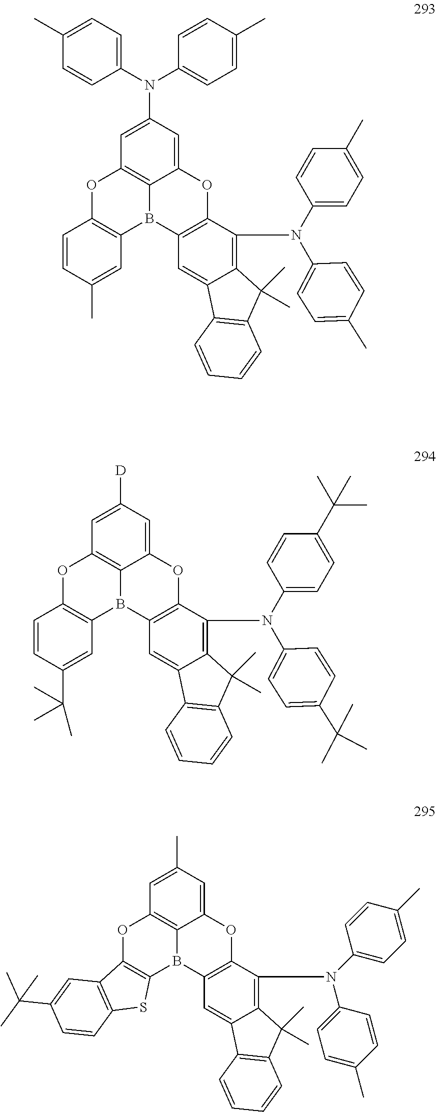

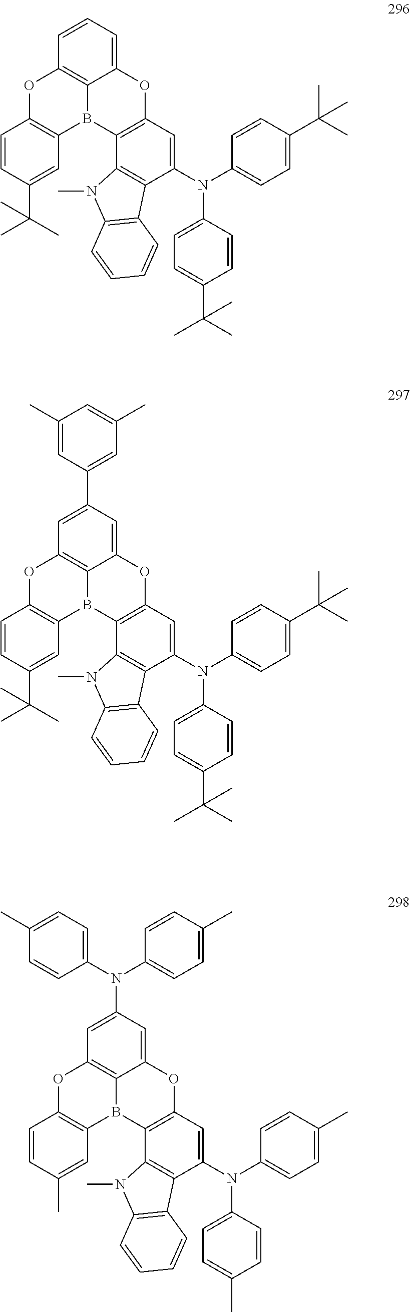

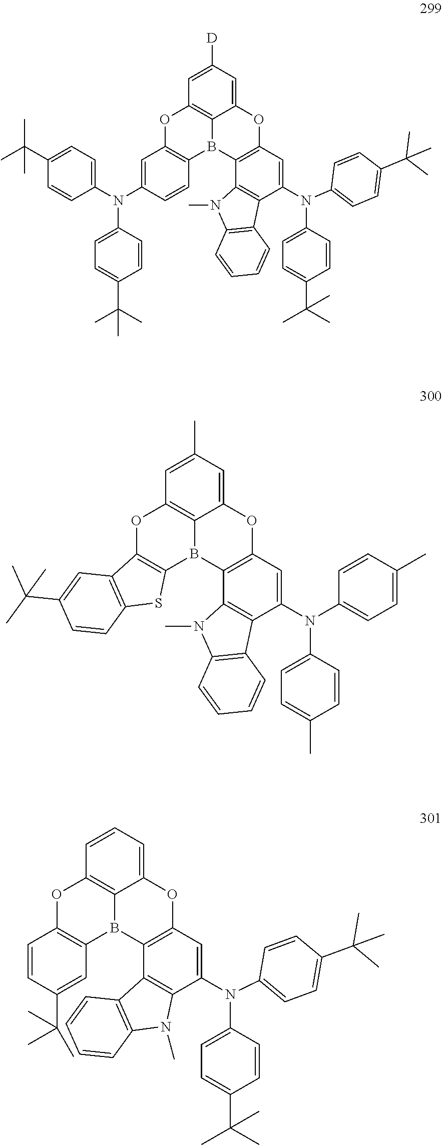

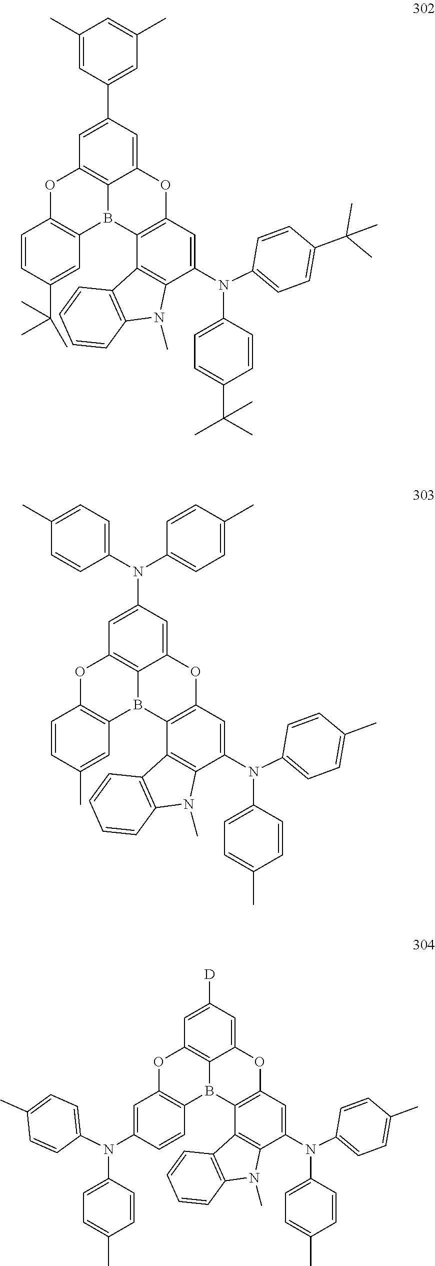

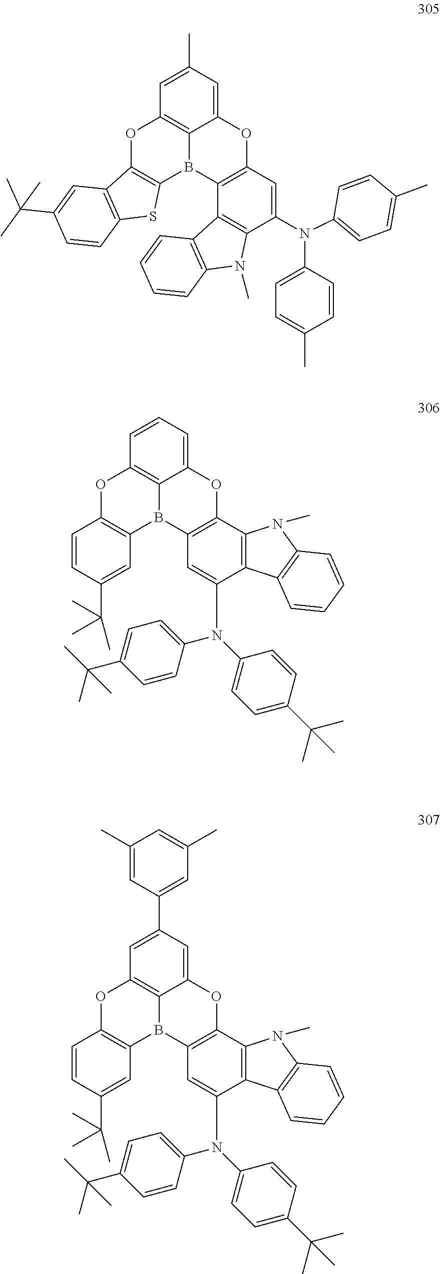

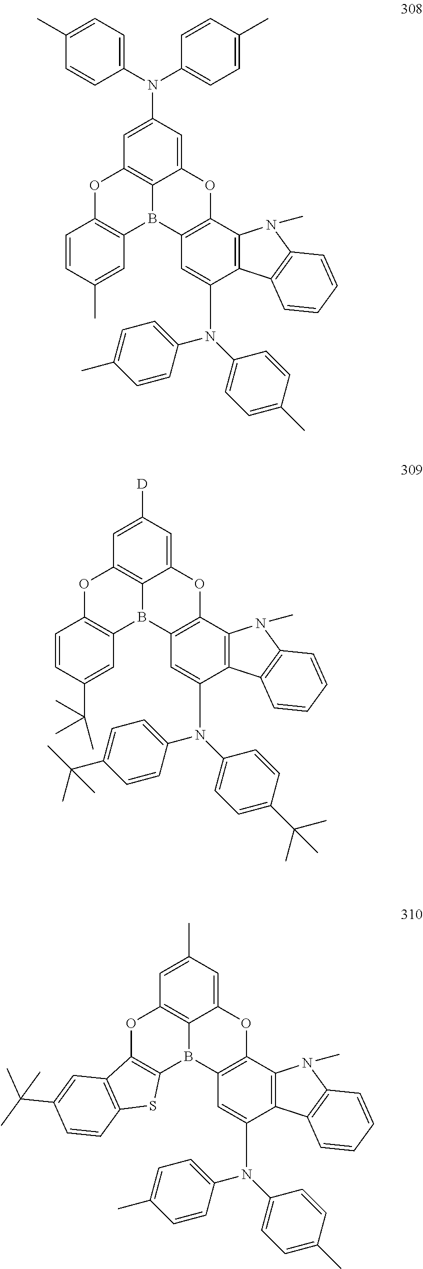 [SMILES: Cc1ccc(N(c2ccc(C)cc2)c2cc3c4c(c2)Oc2c(cc(N(c5ccc(C)cc5)c5ccc(C)cc5)c5c6ccccc6n(C)c25)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4c5ccccc5n(C)c14)B3c1cc(C(C)(C)C)ccc1O2 ; Cc1ccc(N(c2ccc(C)cc2)c2cc3c(c4c2c2ccccc2n4C)Oc2cc(C)cc4c2B3c2sc3ccc(C(C)(C)C)cc3c2O4)cc1]

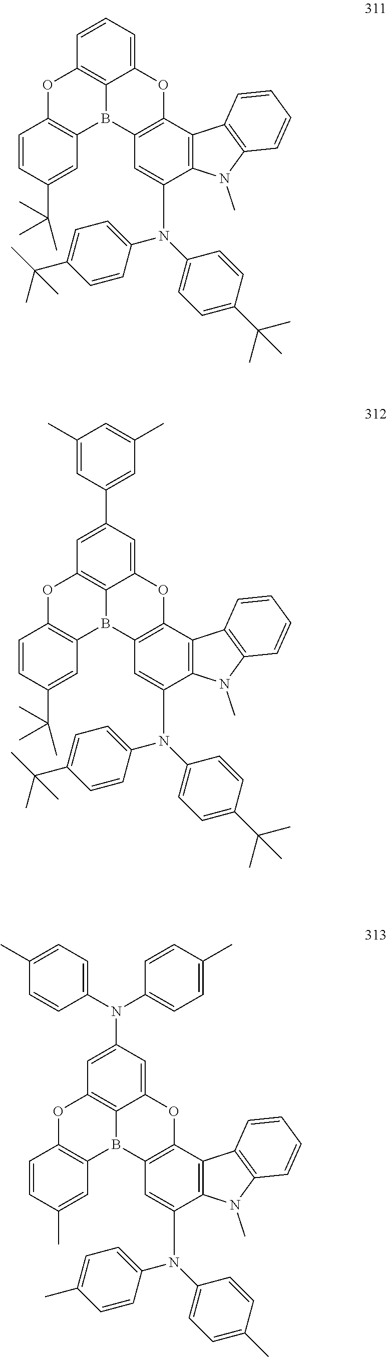 [SMILES: Cn1c2ccccc2c2c3c(cc(N(c4ccc(C(C)(C)C)cc4)c4ccc(C(C)(C)C)cc4)c21)B1c2cc(C(C)(C)C)ccc2Oc2cccc(c21)O3 ; Cc1cc(C)cc(-c2cc3c4c(c2)Oc2c(cc(N(c5ccc(C(C)(C)C)cc5)c5ccc(C(C)(C)C)cc5)c5c2c2ccccc2n5C)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5c2c2ccccc2n5C)B4c2cc(C)ccc2O3)cc1]

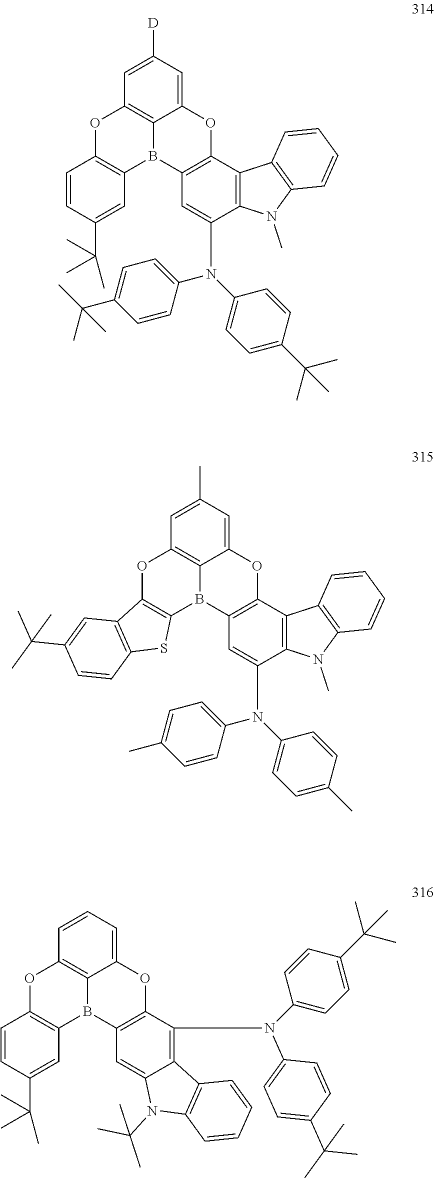 [SMILES: [2H]c1cc2c3c(c1)Oc1c(cc(N(c4ccc(C(C)(C)C)cc4)c4ccc(C(C)(C)C)cc4)c4c1c1ccccc1n4C)B3c1cc(C(C)(C)C)ccc1O2 ; Cc1ccc(N(c2ccc(C)cc2)c2cc3c(c4c5ccccc5n(C)c24)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4c2c2ccccc2n4C(C)(C)C)B2c4cc(C(C)(C)C)ccc4Oc4cccc(c42)O3)cc1]

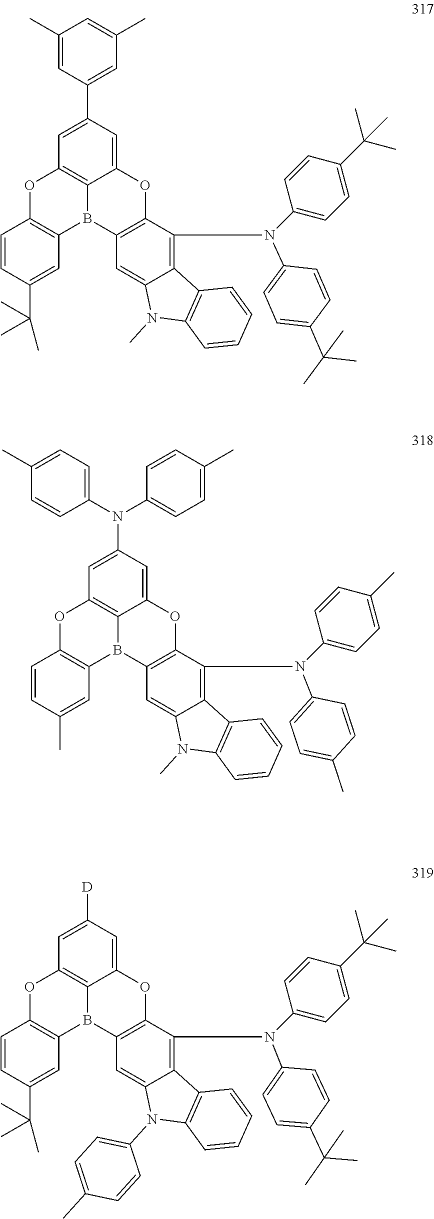

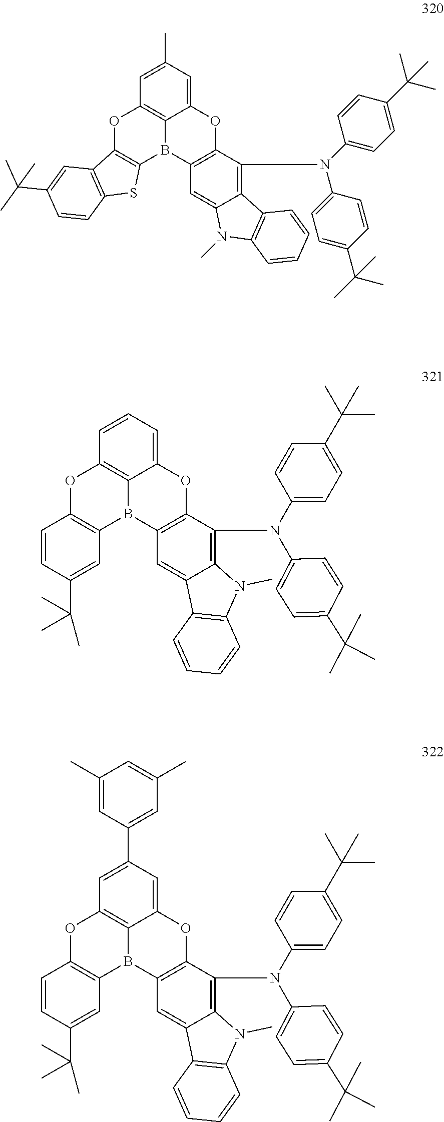 [SMILES: Cc1cc2c3c(c1)Oc1c(sc4ccc(C(C)(C)C)cc14)B3c1cc3c(c(N(c4ccc(C(C)(C)C)cc4)c4ccc(C(C)(C)C)cc4)c1O2)c1ccccc1n3C ; Cn1c2ccccc2c2cc3c(c(N(c4ccc(C(C)(C)C)cc4)c4ccc(C(C)(C)C)cc4)c21)Oc1cccc2c1B3c1cc(C(C)(C)C)ccc1O2 ; Cc1cc(C)cc(-c2cc3c4c(c2)Oc2c(cc5c6ccccc6n(C)c5c2N(c2ccc(C(C)(C)C)cc2)c2ccc(C(C)(C)C)cc2)B4c2cc(C(C)(C)C)ccc2O3)c1]

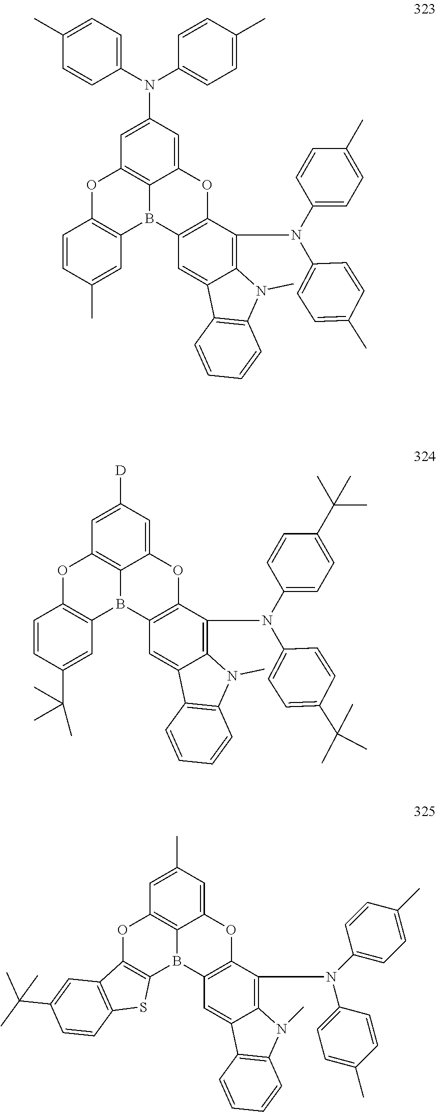

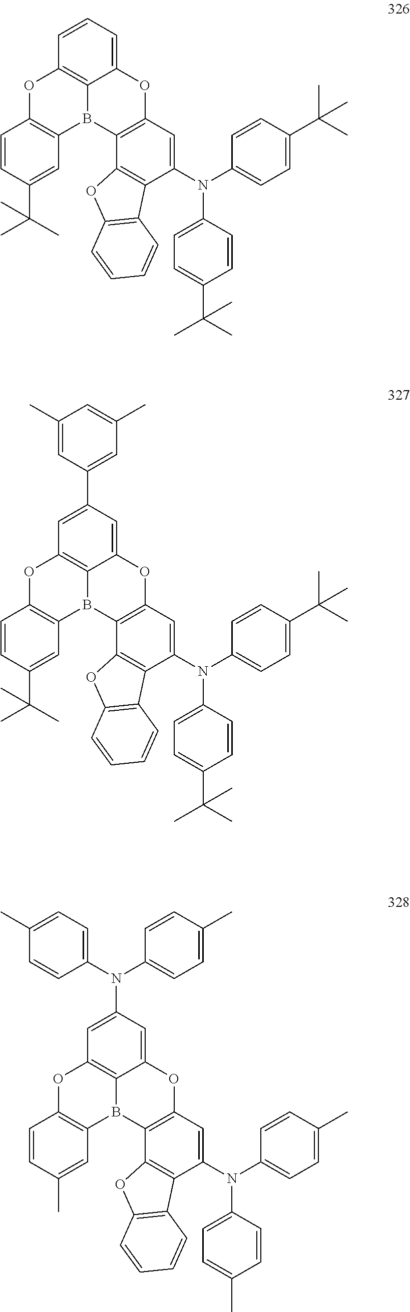

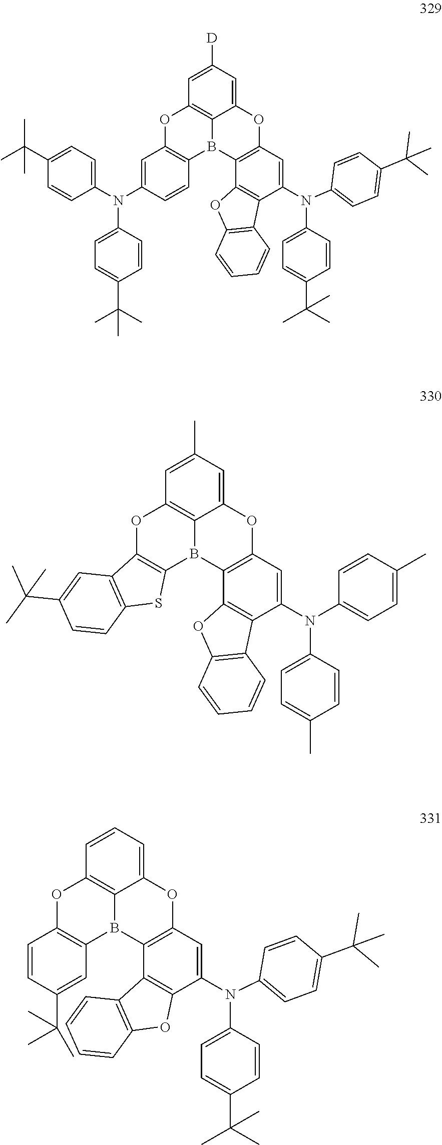

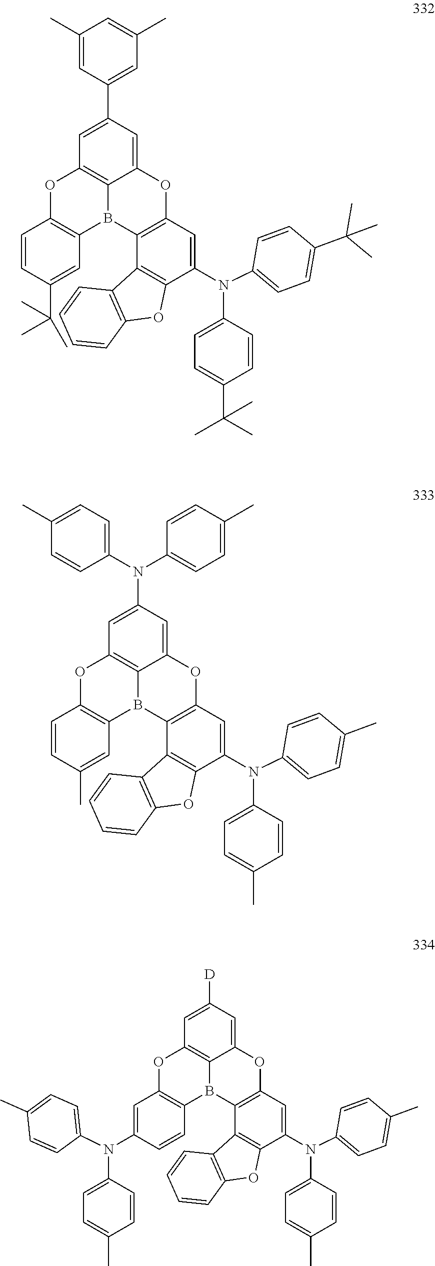

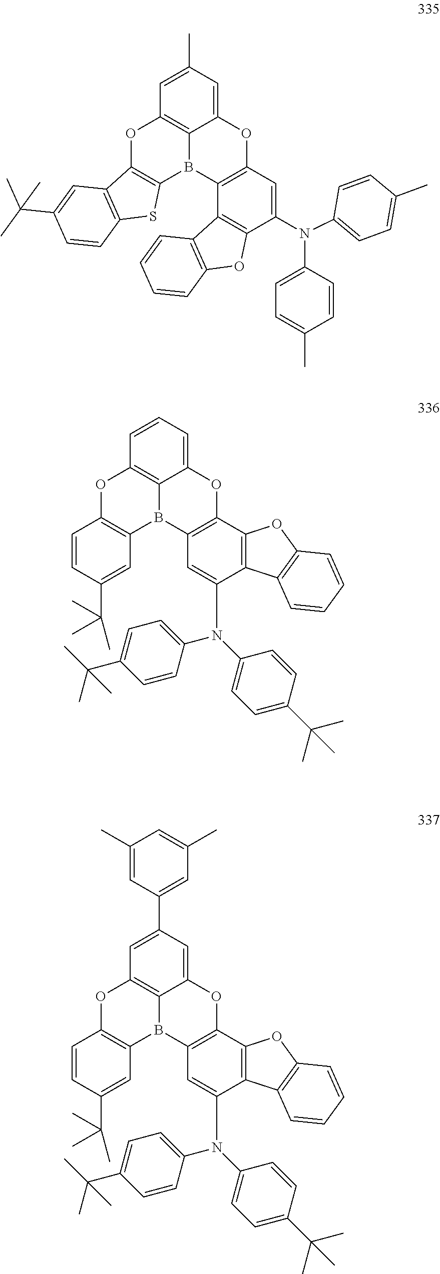

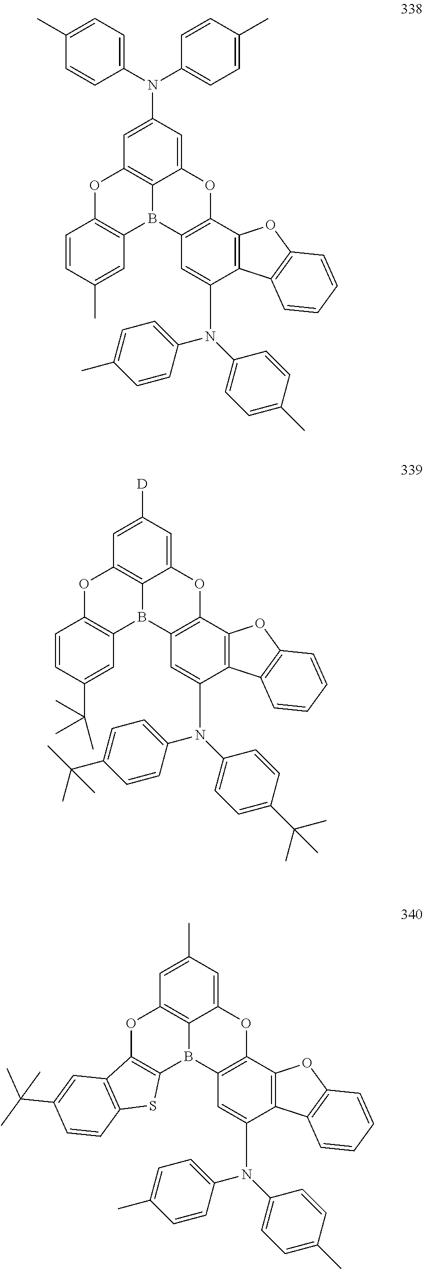 [SMILES: Cc1ccc(N(c2ccc(C)cc2)c2cc3c4c(c2)Oc2c(cc(N(c5ccc(C)cc5)c5ccc(C)cc5)c5c2oc2ccccc25)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4c1oc1ccccc14)B3c1cc(C(C)(C)C)ccc1O2 ; Cc1ccc(N(c2ccc(C)cc2)c2cc3c(c4oc5ccccc5c24)Oc2cc(C)cc4c2B3c2sc3ccc(C(C)(C)C)cc3c2O4)cc1]

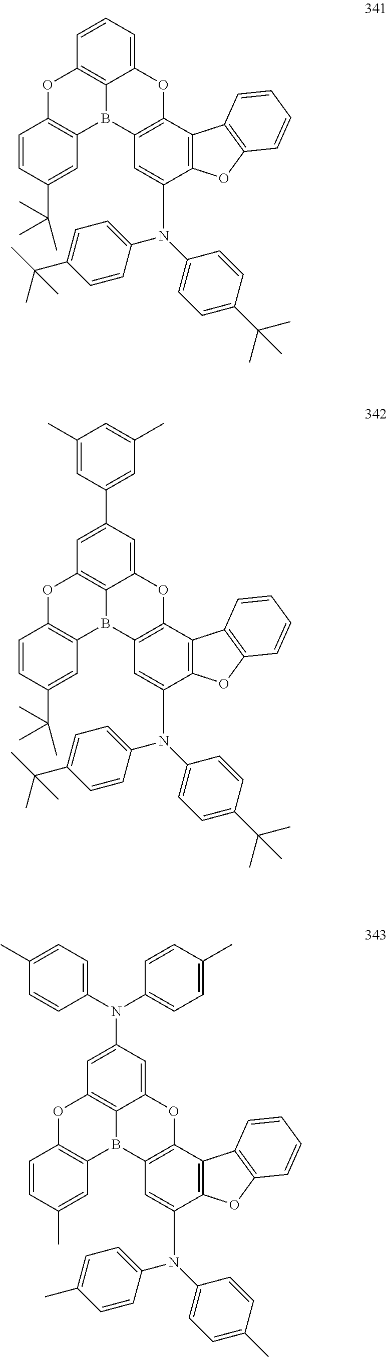 [SMILES: CC(C)(C)c1ccc(N(c2ccc(C(C)(C)C)cc2)c2cc3c(c4c2oc2ccccc24)Oc2cccc4c2B3c2cc(C(C)(C)C)ccc2O4)cc1 ; Cc1cc(C)cc(-c2cc3c4c(c2)Oc2c(cc(N(c5ccc(C(C)(C)C)cc5)c5ccc(C(C)(C)C)cc5)c5oc6ccccc6c25)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5oc6ccccc6c25)B4c2cc(C)ccc2O3)cc1]

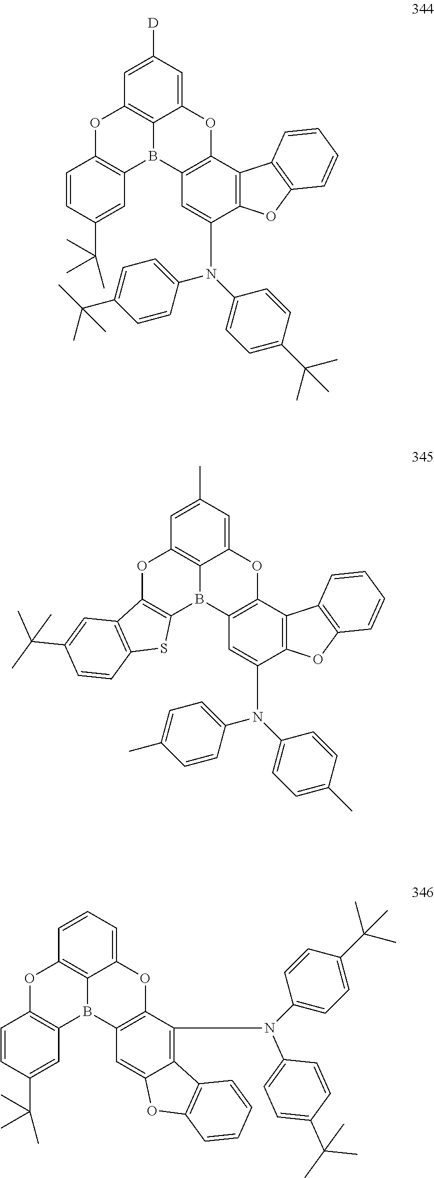 [SMILES: [2H]c1cc2c3c(c1)Oc1c(cc(N(c4ccc(C(C)(C)C)cc4)c4ccc(C(C)(C)C)cc4)c4oc5ccccc5c14)B3c1cc(C(C)(C)C)ccc1O2 ; Cc1ccc(N(c2ccc(C)cc2)c2cc3c(c4c2oc2ccccc24)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4oc5ccccc5c24)B2c4cc(C(C)(C)C)ccc4Oc4cccc(c42)O3)cc1]

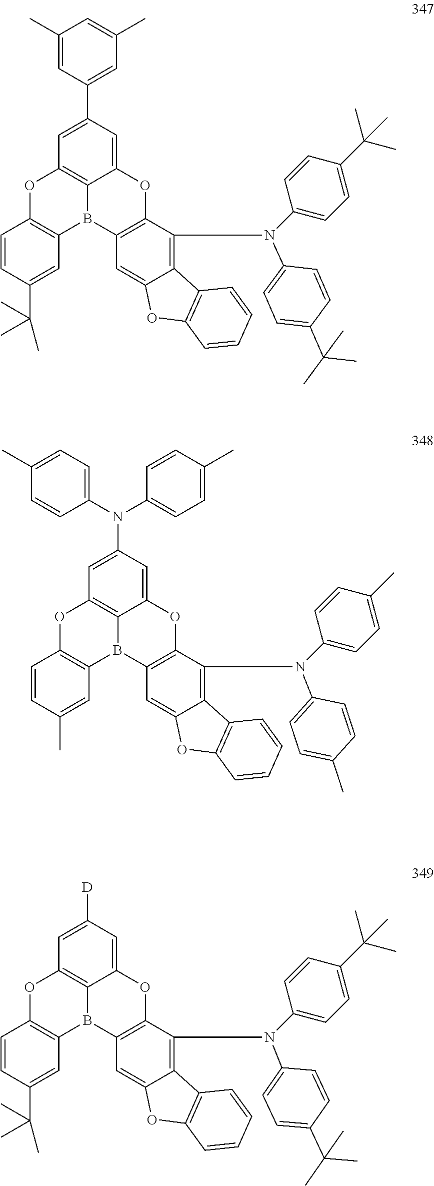

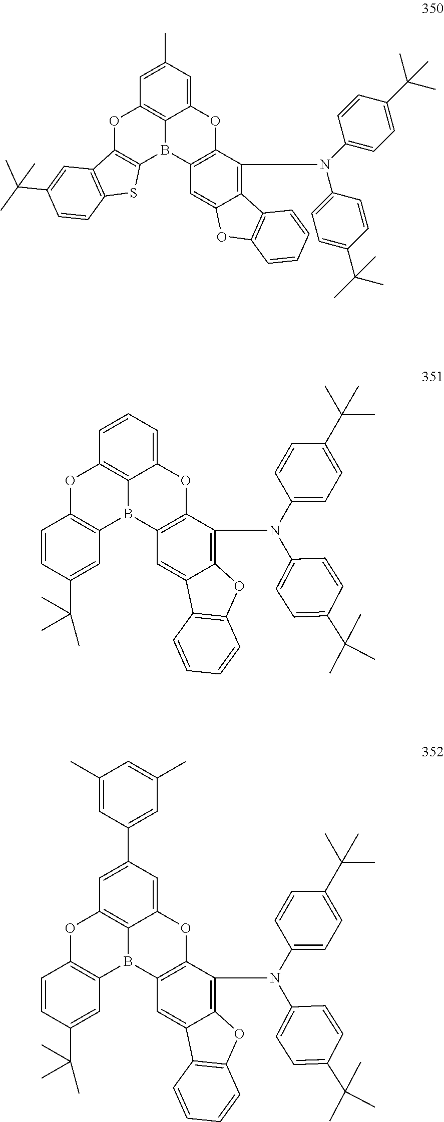 [SMILES: Cc1cc2c3c(c1)Oc1c(sc4ccc(C(C)(C)C)cc14)B3c1cc3oc4ccccc4c3c(N(c3ccc(C(C)(C)C)cc3)c3ccc(C(C)(C)C)cc3)c1O2 ; CC(C)(C)c1ccc(N(c2ccc(C(C)(C)C)cc2)c2c3c(cc4c2oc2ccccc24)B2c4cc(C(C)(C)C)ccc4Oc4cccc(c42)O3)cc1 ; Cc1cc(C)cc(-c2cc3c4c(c2)Oc2c(cc5c(oc6ccccc65)c2N(c2ccc(C(C)(C)C)cc2)c2ccc(C(C)(C)C)cc2)B4c2cc(C(C)(C)C)ccc2O3)c1]

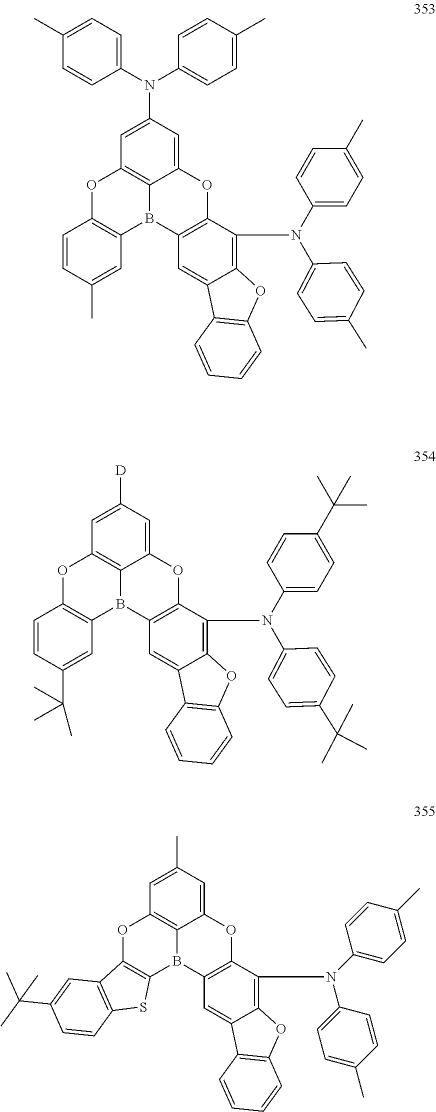

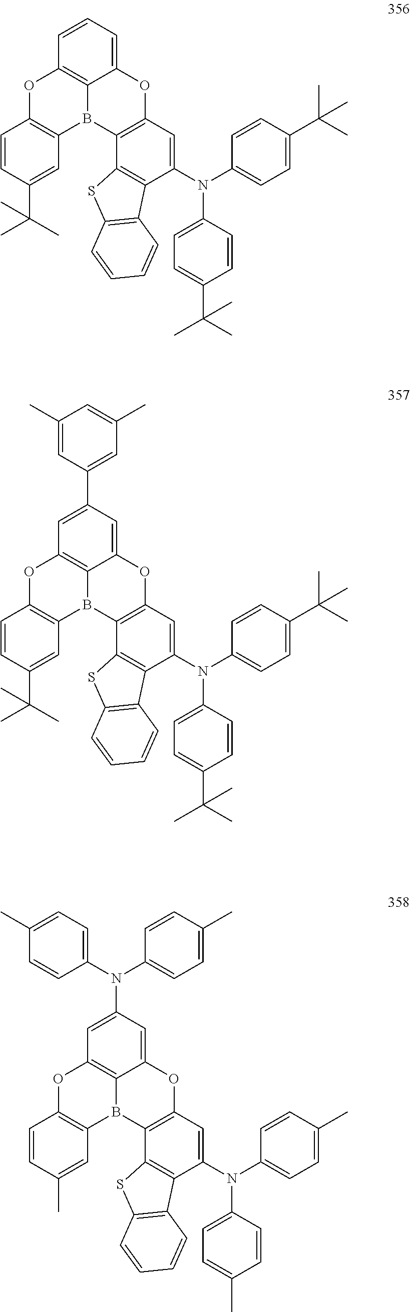

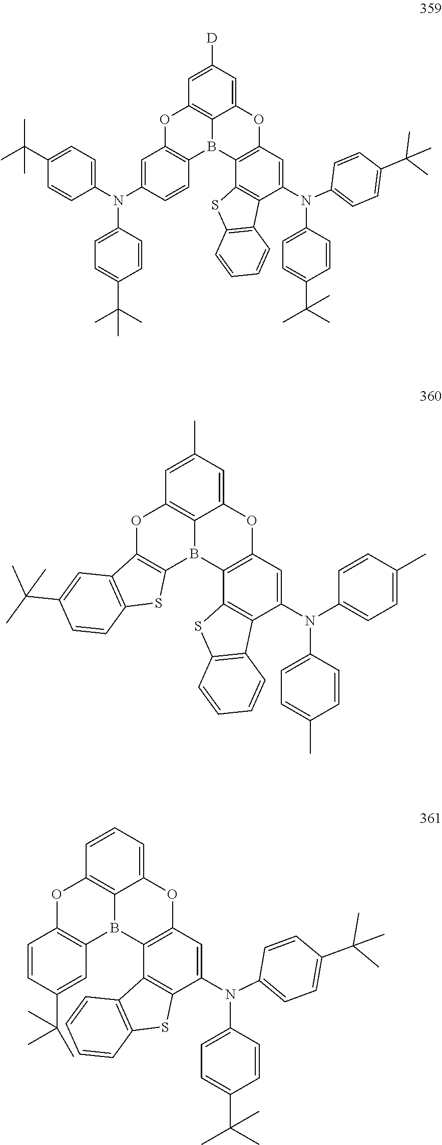

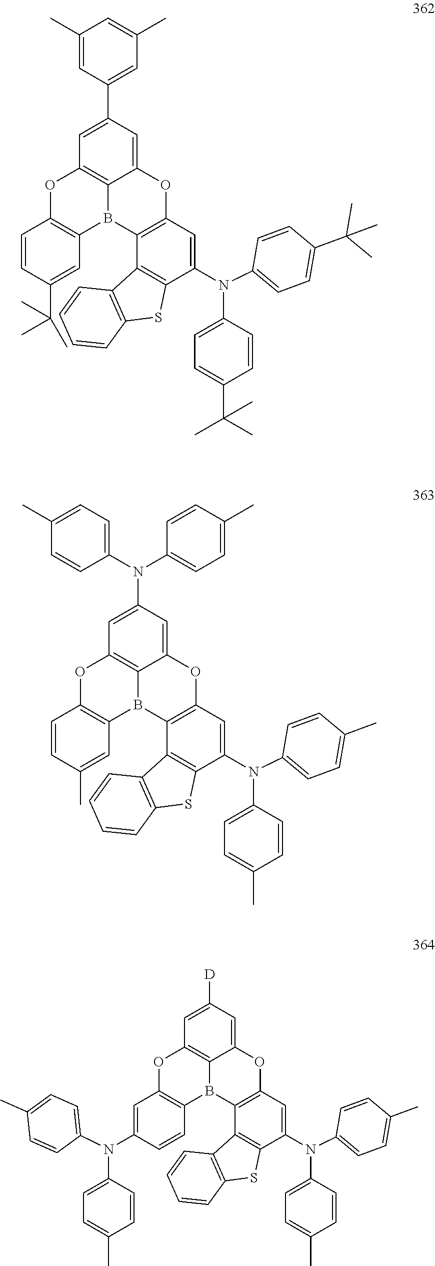

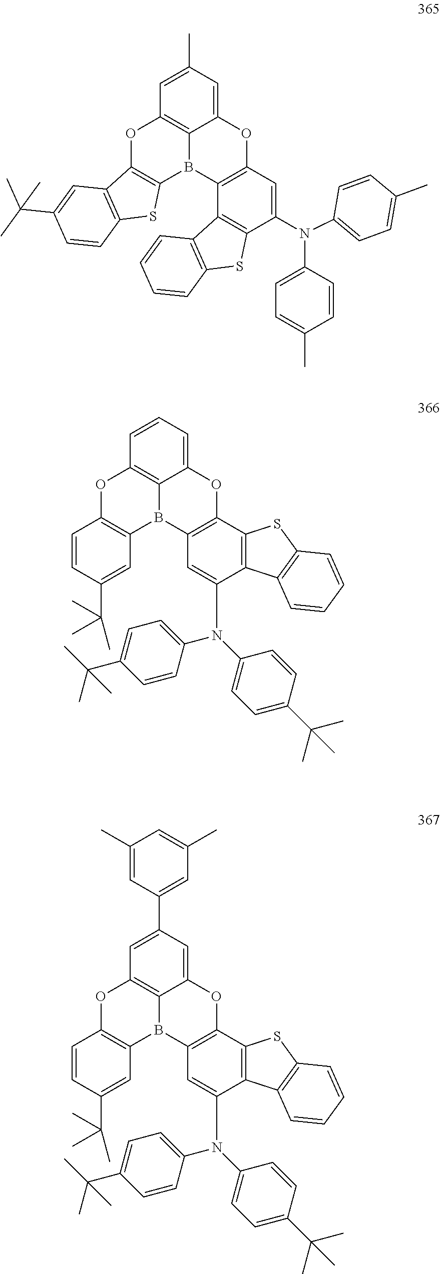

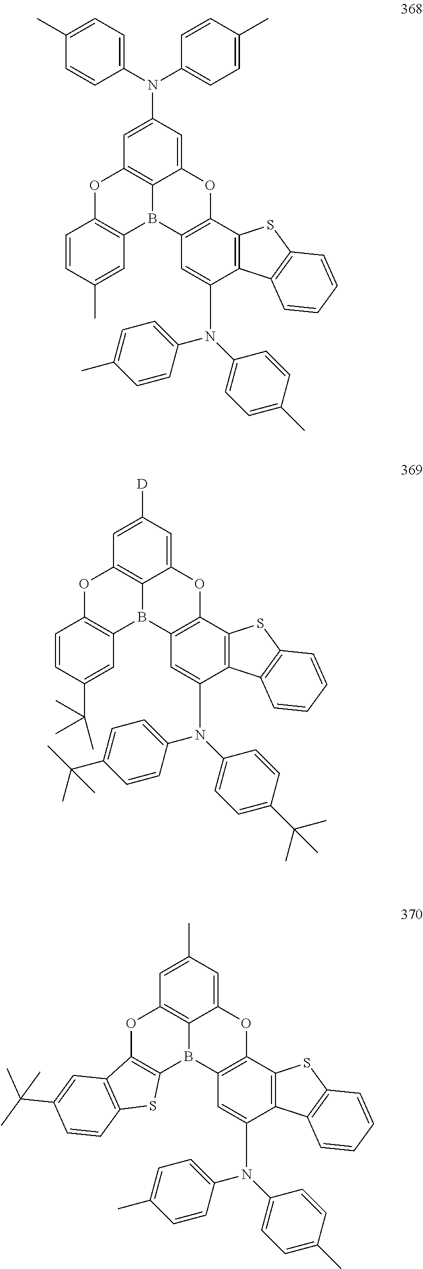 [SMILES: Cc1ccc(N(c2ccc(C)cc2)c2cc3c4c(c2)Oc2c(cc(N(c5ccc(C)cc5)c5ccc(C)cc5)c5c2sc2ccccc25)B4c2cc(C)ccc2O3)cc1 ; [2H]c1cc2c3c(c1)Oc1c(cc(N(c4ccc(C(C)(C)C)cc4)c4ccc(C(C)(C)C)cc4)c4c1sc1ccccc14)B3c1cc(C(C)(C)C)ccc1O2 ; Cc1ccc(N(c2ccc(C)cc2)c2cc3c(c4sc5ccccc5c24)Oc2cc(C)cc4c2B3c2sc3ccc(C(C)(C)C)cc3c2O4)cc1]

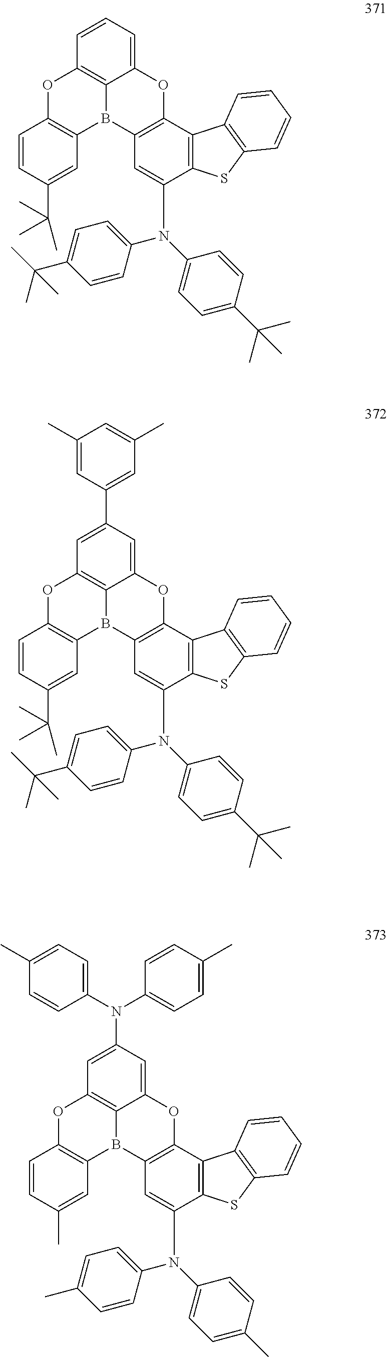 [SMILES: CC(C)(C)c1ccc(N(c2ccc(C(C)(C)C)cc2)c2cc3c(c4c2sc2ccccc24)Oc2cccc4c2B3c2cc(C(C)(C)C)ccc2O4)cc1 ; Cc1cc(C)cc(-c2cc3c4c(c2)Oc2c(cc(N(c5ccc(C(C)(C)C)cc5)c5ccc(C(C)(C)C)cc5)c5sc6ccccc6c25)B4c2cc(C(C)(C)C)ccc2O3)c1 ; Cc1ccc(N(c2ccc(C)cc2)c2cc3c4c(c2)Oc2c(cc(N(c5ccc(C)cc5)c5ccc(C)cc5)c5sc6ccccc6c25)B4c2cc(C)ccc2O3)cc1]

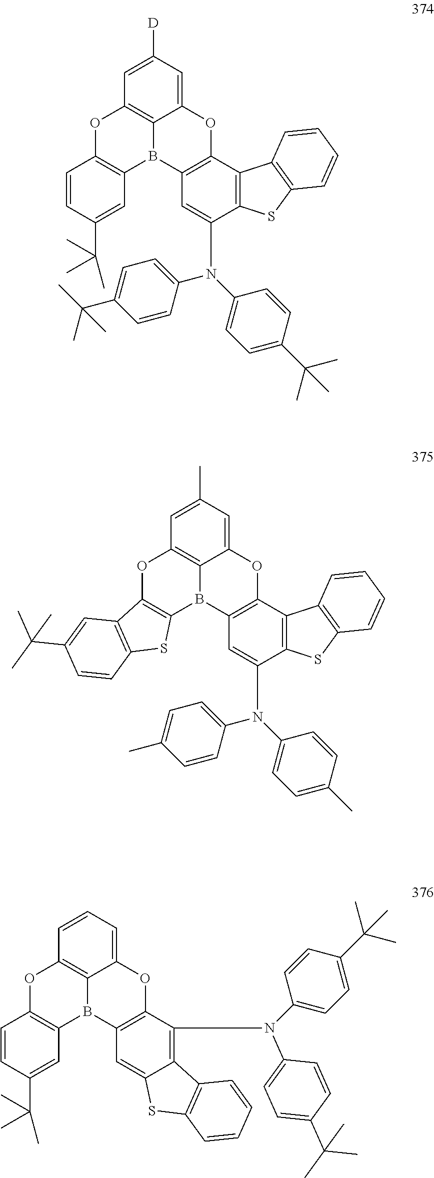 [SMILES: [2H]c1cc2c3c(c1)Oc1c(cc(N(c4ccc(C(C)(C)C)cc4)c4ccc(C(C)(C)C)cc4)c4sc5ccccc5c14)B3c1cc(C(C)(C)C)ccc1O2 ; Cc1ccc(N(c2ccc(C)cc2)c2cc3c(c4c2sc2ccccc24)Oc2cc(C)cc4c2B3c2sc3ccc(C(C)(C)C)cc3c2O4)cc1 ; CC(C)(C)c1ccc(N(c2ccc(C(C)(C)C)cc2)c2c3c(cc4sc5ccccc5c24)B2c4cc(C(C)(C)C)ccc4Oc4cccc(c42)O3)cc1]

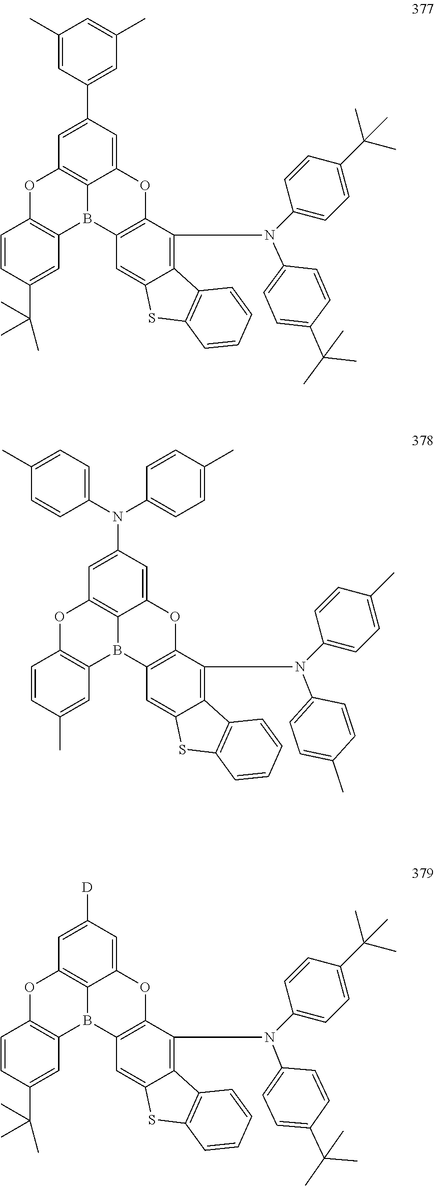

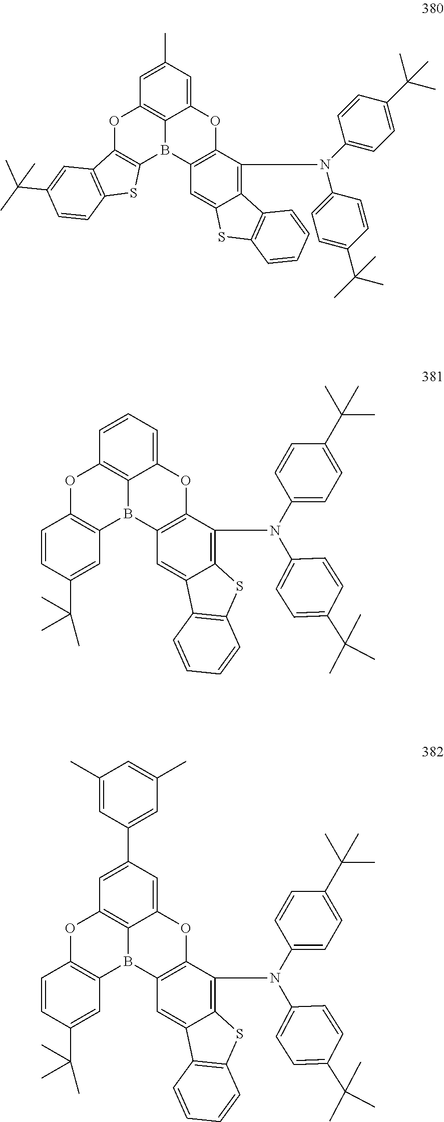 [SMILES: Cc1cc2c3c(c1)Oc1c(sc4ccc(C(C)(C)C)cc14)B3c1cc3sc4ccccc4c3c(N(c3ccc(C(C)(C)C)cc3)c3ccc(C(C)(C)C)cc3)c1O2 ; CC(C)(C)c1ccc(N(c2ccc(C(C)(C)C)cc2)c2c3c(cc4c2sc2ccccc24)B2c4cc(C(C)(C)C)ccc4Oc4cccc(c42)O3)cc1 ; Cc1cc(C)cc(-c2cc3c4c(c2)Oc2c(cc5c(sc6ccccc65)c2N(c2ccc(C(C)(C)C)cc2)c2ccc(C(C)(C)C)cc2)B4c2cc(C(C)(C)C)ccc2O3)c1]

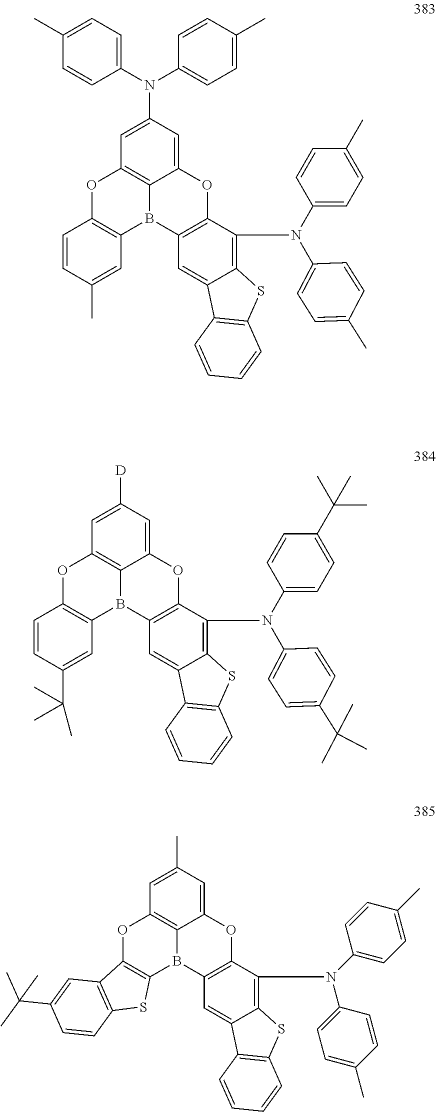

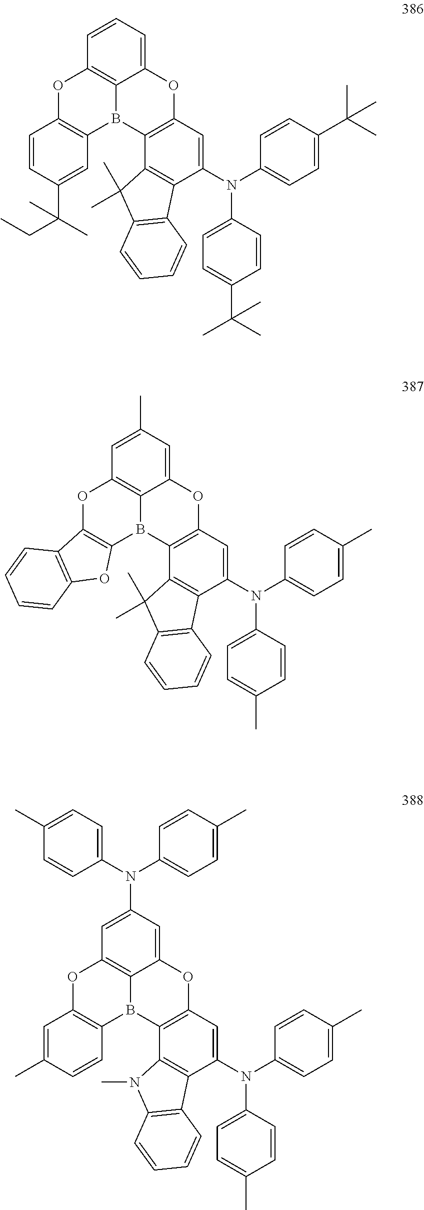

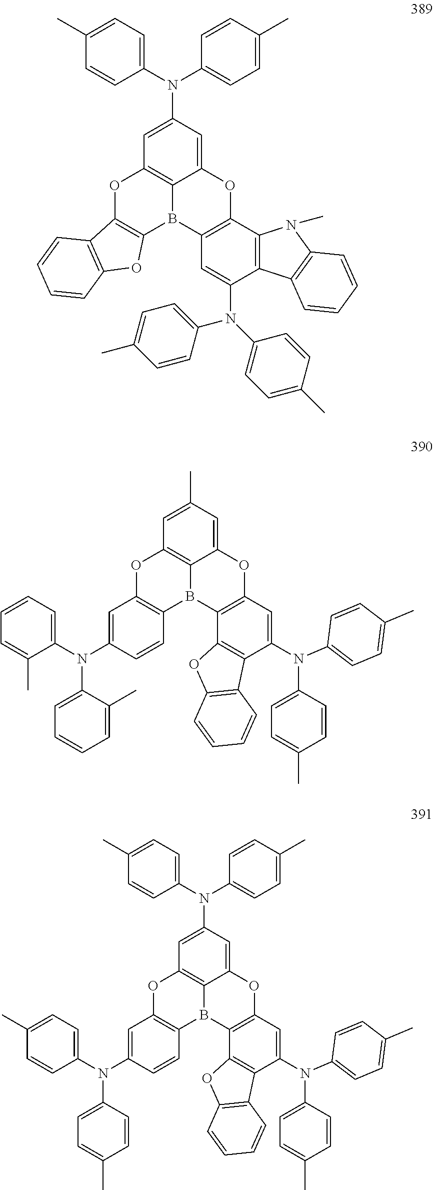

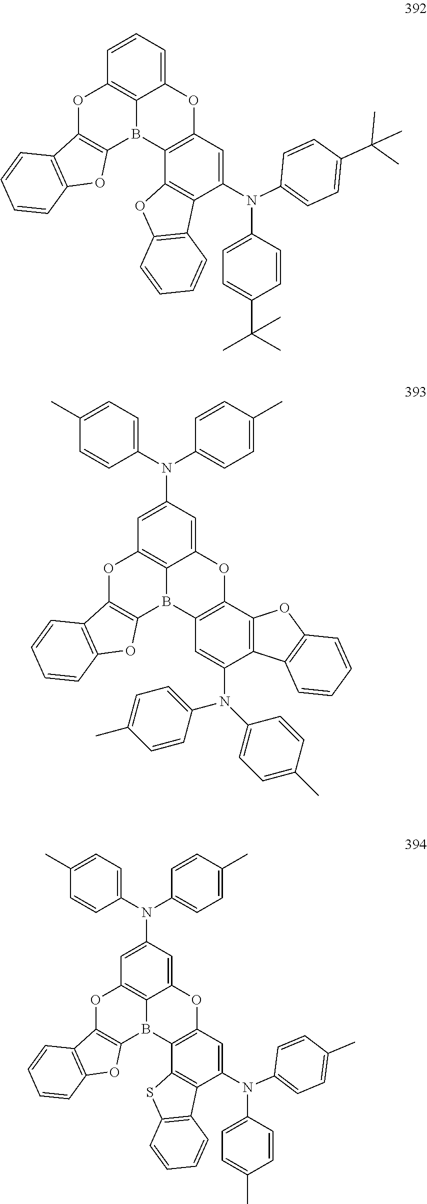 [SMILES: CC(C)(C)c1ccc(N(c2ccc(C(C)(C)C)cc2)c2cc3c(c4oc5ccccc5c24)B2c4oc5ccccc5c4Oc4cccc(c42)O3)cc1 ; Cc1ccc(N(c2ccc(C)cc2)c2cc3c4c(c2)Oc2c(cc(N(c5ccc(C)cc5)c5ccc(C)cc5)c5c2oc2ccccc25)B4c2oc4ccccc4c2O3)cc1 ; Cc1ccc(N(c2ccc(C)cc2)c2cc3c4c(c2)Oc2c(oc5ccccc25)B4c2c(cc(N(c4ccc(C)cc4)c4ccc(C)cc4)c4c2sc2ccccc24)O3)cc1]

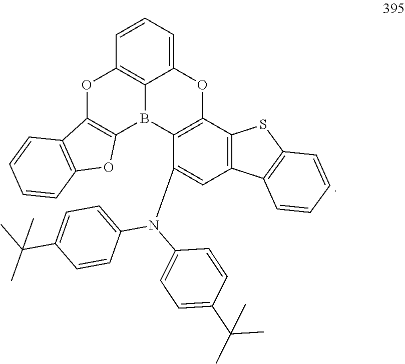 [SMILES: CC(C)(C)c1ccc(N(c2ccc(C(C)(C)C)cc2)c2cc3c(sc4ccccc43)c3c2B2c4oc5ccccc5c4Oc4cccc(c42)O3)cc1]

11. A light-emitting component, comprising:
a pair of electrodes comprising a first electrode and a second electrode; and
an organic functional layer disposed between the first electrode and the second electrode;
wherein a material of the organic functional layer comprises one or more of organic compounds comprising a structure shown as general formula (1): 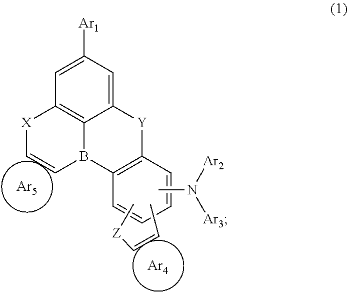
wherein Z is selected from CR₁ R₂, NR₃, O, or S,
X and Y are each independently selected from O or NR₄,
R₁ to R₄ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms;
R₁ and R₂ are connected in a ring or independent of each other;
Ar₁ is selected from H, D, a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms;
Ar₂ and Ar₃ are each independently selected from a substituted or unsubstituted alkyl group with 1 to 20 carbon atoms, a substituted or unsubstituted aromatic group with 6 to 30 carbon atoms, or a substituted or unsubstituted heteroaromatic group with 5 to 30 carbon atoms; and
Ar₄ and Ar5 are each independently selected from a substituted or unsubstituted aromatic group with 6 to 30 carbon atoms or a substituted or unsubstituted heteroaromatic group with 5 to 30 carbon atoms.

12. The light-emitting component according to claim 11, wherein the organic functional layer at least comprises a light-emitting layer, the light-emitting layer comprises a host material and a guest material, and the guest material comprises one or more of the organic compounds.

13. The light-emitting component according to claim 12, wherein in the light-emitting layer, a mass ratio of the host material to the guest material ranges from 99:1 to 70:30.

14. A display panel, comprising the light-emitting component according to claim 11.
